(19) United States
(12) Patent Application Publication
(10) Pub. No.: US 2019/0181353 A1
(43) Pub. Date: Jun. 13, 2019

(54) ORGANIC LIGHT-EMITTING DEVICE

(71) Applicants: Samsung Electronics Co., Ltd., Suwon-si (KR); Samsung SDI Co., Ltd., Yongin-si (KR)

(72) Inventors: Sooghang IHN, Hwaseong-si (KR); Myungsun SIM, Suwon-si (KR); Hasup LEE, Seoul (KR); Wook KIM, Suwon-si (KR); Jongsoo KIM, Seoul (KR); Joonghyuk KIM, Seoul (KR); Hiroshi MIYAZAKI, Hwaseong-si (KR); Soonok JEON, Suwon-si (KR); Yeonsook CHUNG, Seoul (KR)

(21) Appl. No.: 16/213,296

(22) Filed: Dec. 7, 2018

(30) Foreign Application Priority Data
Dec. 7, 2017 (KR) 10-2017-0167521
Nov. 30, 2018 (KR) 10-2018-0153031

(51) Int. Cl. H01L 51/00; C09K 11/06

(52) U.S. Cl. CPC H01L 51/0072; H01L 51/5028; H01L 51/0055; C09K 11/06

(57) ABSTRACT

An organic light-emitting device including a first electrode, a second electrode facing the first electrode, and an organic layer disposed between the first electrode and the second electrode, wherein the organic layer includes an emission layer, wherein the an emission layer including an auxiliary dopant, a fluorescent dopant, and a host, wherein the auxiliary dopant includes a compound represented by Formula 1, and wherein the fluorescent dopant emits prompt fluorescence:

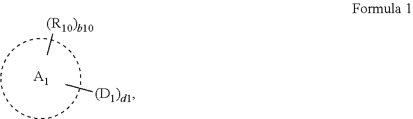

wherein in Formula 1, groups and variables are the same as described in the specification.

### CROSS-REFERENCE TO RELATED APPLICATION

This application claims priority to Korean Patent Application No. 10-2017-0167521, filed on Dec. 7, 2017, and Korean Patent Application No. 10-2018-0153031, filed on Nov. 30, 2018, in the Korean Intellectual Property Office, and all the benefits accruing therefrom under 35 U.S.C. § 119, the contents of which are incorporated herein in their entireties by reference.

### BACKGROUND

### 1. Field

The present disclosure relates to an organic light-emitting device.

### 2. Description of the Related Art

Organic light-emitting devices (OLEDs) are self-emission devices that produce full-color images, and that also have wide viewing angles, high contrast ratios, short response times, and excellent characteristics in terms of brightness, driving voltage, and response speed, compared to devices in the art.

In an example, an organic light-emitting device includes an anode, a cathode, and an organic layer that is disposed between the anode and the cathode and includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. Carriers, such as holes and electrons, recombine in an emission layer region to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

Aspects of the present invention provide an organic light-emitting device that emits fluorescence having a relatively small full width at half maximum and has high efficiency and a long lifespan.

Additional aspects will be set forth in part in the description which follows and, in part, will be apparent from the description, or may be learned by practice of the presented embodiments.

An aspect provides an organic light-emitting device including:

a first electrode;

a second electrode facing the first electrode; and

an organic layer disposed between the first electrode and the second electrode,

wherein the organic layer includes an emission layer,

the emission layer includes an auxiliary dopant, a fluorescent dopant, and a host,

the auxiliary dopant includes a compound represented by Formula 1, and

the fluorescent dopant emits prompt fluorescence:

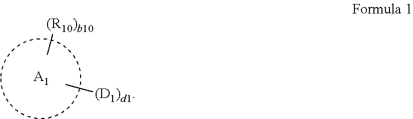

In Formula 1, A₁ may be i) a C₅-C₆₀ carbocyclic group including at least one of a cyano group (—CN) and a fluoro group (—F), ii) a C₅-C₆₀ heterocyclic group including a least one of a cyano group and a fluoro group, or iii) a π electron-depleted nitrogen-containing cyclic group, and

in Formula 1, D₁ may be a group represented by Formula 2-1 or 2-2:

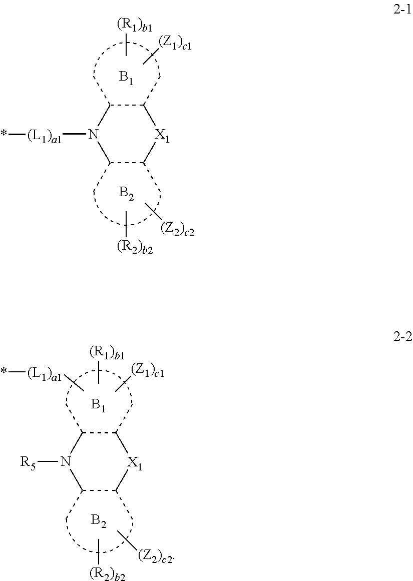

In Formula 1, d1 may be an integer from 3 to 10, and groups D1 in the number of d1 may be identical to or different from each other,

B₁ and B₂ in Formulae 2-1 and 2-2 may each independently be a benzene group, a naphthalene group, an anthracene group, a phenanthrene group, a triphenylene group, a fluorene group, a dibenzosilole group, a carbazole group, a dibenzofuran group, or a dibenzothiophene group,

X₁ in Formulae 2-1 and 2-2 may be a single bond, C(R₃)(R₄), Si(R₃)(R₄), N(R₃), O, or S,

L₁ in Formulae 2-1 and 2-2 may be selected from:

a single bond; and

a π electron-depleted nitrogen-free cyclic group, which is unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃),

a1 in Formulae 2-1 and 2-2 may be an integer from 1 to 5,

R₁ to R₅ and R₁₀ in Formulae 1, 2-1, and 2-2 may each independently be selected from:

hydrogen and deuterium;

a C₁-C₂₀ alkyl group and a C₁-C₂₀ alkoxy group, each unsubstituted or substituted with at least one selected from deuterium, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃);

a π electron-depleted nitrogen-free cyclic group, which is unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃); and

—Si(Q₄₀₄)(Q₄₀₅)(Q₄₀₆),

b1, b2, and b10 in Formulae 1, 2-1, and 2-2 may each independently be an integer from 0 to 10,

Z₁ and Z₂ in Formulae 2-1 and 2-2 may each independently be selected from:

—C(Q₄₀₇)(Q₄₀₈)(Q₄₀₉) and —Si(Q₄₀₇)(Q₄₀₈)(Q₄₀₉); and

a π electron-depleted nitrogen-free cyclic group, which is unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃),

c1 and c2 in Formulae 2-1 and 2-2 may each independently be an integer from 0 to 5,

Q₄₀₁ to Q₄₀₉ may each independently be selected from hydrogen, deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, and a tetraphenyl group,

i) at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 may be equal to or greater than one, and

* indicates a binding site to a neighboring atom.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view of an organic light-emitting device (OLED) according to an embodiment;

FIG. 2 is a graph of intensity (arbitrary units, arb. unit) versus wavelength (nanometers, nm), illustrating electroluminescence (EL) spectra of OLEDs 1-1 to 1-3;

FIG. 3 is a graph of intensity (arbitrary units, arb. unit) versus wavelength (nanometers, nm), illustrating EL spectra of OLEDs 2-1 to 2-3;

FIG. 4 is a graph of intensity (arbitrary units, arb. unit) versus wavelength (nanometers, nm), illustrating EL spectra of OLEDs 3-1 and 3-2;

FIG. 5 is a graph of intensity (arbitrary units, arb. unit) versus wavelength (nanometers, nm), illustrating EL spectra of OLEDs 4-1 and 4-2;

FIGS. 6 to 9 are graphs of intensity (arbitrary units, a. u.) versus time (nanoseconds, ns), illustrating time-resolved photoluminescence (TRPL) spectra of Films 1 to 4, respectively;

FIG. 10 is a graph of external quantum efficiency (percent, %) versus luminance (candelas per square meter, cd/m²), showing luminance versus external quantum efficiency (EQE) for OLEDs 1-2 and 1-3;

FIG. 11 is a graph of luminance (percent, %) versus time (hours, hrs), showing time versus luminance for OLEDs 1-1, 1-2, and 1-3;

FIG. 12 is a graph of external quantum efficiency (percent, %) versus luminance (candelas per square meter, cd/m²), showing luminance versus EQE for OLEDs 2-2 and 2-3;

FIG. 13 is a graph of luminance (percent, %) versus time (hours, hrs), showing time versus luminance for OLEDs 2-1, 2-2, and 2-3;

FIG. 14 a graph of external quantum efficiency (percent, %) versus luminance (candelas per square meter, cd/m²), showing luminance versus EQE for OLEDs 3-1 and 3-2;

FIG. 15 is a graph of external quantum efficiency (percent, %) versus luminance (candelas per square meter, cd/m²), showing luminance versus EQE for OLEDs 4-1 and 4-2; and

FIG. 16 is a graph of luminance (percent, %) versus time (hours, hrs), showing time versus luminance for OLEDs 4-1 and 4-2.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

In an embodiment, an organic light-emitting device is provided. The organic light-emitting device according to an embodiment may include:

a first electrode;

a second electrode facing the first electrode; and

an organic layer disposed between the first electrode and the second electrode,

wherein the organic layer may include an emission layer.

The emission layer may include an auxiliary dopant, a fluorescent dopant, and a host.

The auxiliary dopant may include a compound represented by Formula 1:

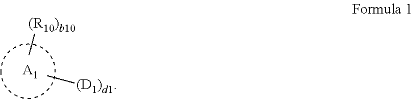

A₁ in Formula 1 may be i) a C₅-C₆₀ carbocyclic group including at least one of a cyano group (—CN) and a fluoro group (—F), ii) a C₅-C₆₀ heterocyclic group including at least one of a cyano group and a fluoro group, or iii) a π electron-depleted nitrogen-containing cyclic group.

For example, A₁ may be:

i) a benzene group, a naphthalene group, an anthracene group, a phenanthrene group, a triphenylene group, a chrysene group, a fluorene group, a benzofluorene group or a dibenzofluorene group, including at least one selected from a cyano group and a fluoro group;

ii) a dibenzosilole group, a carbazole group, a dibenzofuran group, a dibenzothiophene group, an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinolic group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, or an azacarbazole group, each including at least one selected from a cyano group and a fluoro group; or

iii) an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinolic, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group or azacarbazole group,

but embodiments of the present disclosure are not limited thereto.

The “C₅-C₆₀ carbocyclic group including at least one of a cyano group and a fluoro group” means a C₅-C₆₀ carbocyclic group substituted with at least one of a cyano group and a fluoro group (for example, a phenyl group substituted with a cyano group) and a C₅-C₆₀ carbocyclic group substituted with at least one group that is substituted with at least one of a cyano group and a fluoro group (for example, a phenyl group substituted with —CF₃).

D₁ in Formula 1 may be a group represented by Formula 2-1 or 2-2:

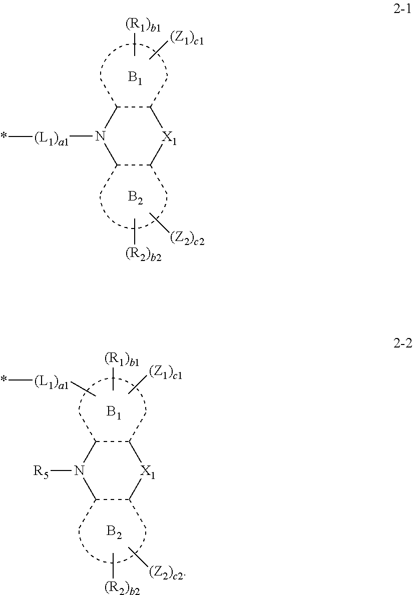

Formulae 2-1 and 2-2 are the same as described below.

In Formula 1, d1 indicates the number of groups D₁ and may be an integer from 3 to 10, and groups D₁ in the number of d1 may be identical to or different from each other.

For example, d1 may be 3, 4, or 5, but embodiments of the present disclosure are not limited thereto.

In Formulae 2-1 and 2-2, B₁ and B₂ may each independently be a benzene group, a naphthalene group, an anthracene group, a phenanthrene group, a triphenylene group, a fluorene group, a dibenzosilole group, a carbazole group, a dibenzofuran group, or a dibenzothiophene group.

In Formulae 2-1 and 2-2, X₁ may be a single bond, C(R₃)(R₄), Si(R₃)(R₄), N(R₃), O, or S.

For example, X₁ may be a single bond, but embodiments of the present disclosure are not limited thereto.

In Formulae 2-1 and 2-2, L₁ may be selected from:

a single bond; and

a π electron-depleted nitrogen-free cyclic group unsubstituted or substituted with at least one selected from deuterium a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃) (for example, a phenylene group, a heptalenylene group, an indenylene group, a naphthylene group, an azulenylene group, an indacenylene group, an acenaphthylenylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentacenylene group, a hexacenylene group, a rubicenylene group, a coronenylene group, an ovalenylene group, a pyrrolylene group, an isoindolylene group, an indolylene group, a furanylene group, a thiophenylene group, a benzofuranylene group, a benzothiophenylene group, a benzocarbazolylene group, a dibenzocarbazolylene group, a dibenzofuranylene group, a dibenzothiophenylene group, a carbazolylene group, a dibenzosilolylene group, an indenocarbazolylene group, an indolocarbazolylene group, a benzofurocarbazolylene group, a benzothienocarbazolylene group, a benzosilolocarbazolylene group, and a triindolophenylene group, each unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃)).

In Formulae 2-1 and 2-2, a1 indicates the number of L₁, and may be selected from an integer of 1 to 5. When a1 is two or more, two or more groups L₁ may be identical to or different from each other.

For example, a1 may be 1 or 2, but embodiments of the present disclosure are not limited thereto.

In Formulae 1, 2-1, and 2-2, R₁ to R₅ and R₁₀ may each independently be selected from:

hydrogen and deuterium;

a C₁-C₂₀ alkyl group and a C₁-C₂₀ alkoxy group, each unsubstituted or substituted with at least one selected from deuterium, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃);

a π electron-depleted nitrogen-free cyclic group unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃) (for example, a phenyl group, a heptalenyl group, an indenyl group, a naphthyl group, an azulenyl group, an indacenyl group, an acenaphthylenyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentacenyl group, a hexacenyl group, a rubicenyl group, a coronenyl group, an ovalenyl group, a pyrrolyl group, an isoindolyl group, an indolyl group, a furanyl group, a thiophenyl group, a benzofuranyl group, a benzothiophenyl group, a benzocarbazolyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, and a triindolophenyl group, each unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃)); and

—Si(Q₄₀₄)(Q₄₀₅)(Q₄₀₆).

In an embodiment, R₁ to R₅ and R₁₀ may each independently be selected from: hydrogen and deuterium;

a C₁-C₂₀ alkyl group unsubstituted or substituted with at least one selected from deuterium and a phenyl group;

a phenyl group unsubstituted or substituted with at least one selected from deuterium, a C₁-C₂₀ alkyl group, a C₁-C₂₀ alkoxy group, a phenyl group, and —Si(Q₄₀₁)(Q₄₀₂)(Q₄₀₃); and

—Si(Q₄₀₄)(Q₄₀₅)(Q₄₀₆),

but embodiments of the present disclosure are not limited thereto.

In Formulae 1, 2-1, and 2-2, b1, b2, and b10 each independently indicate the number of R₁, R₂, and R₁₀, respectively, and may each independently be selected from an integer of 0 to 10. When b1 is two or more, two or more groups R₁ may be identical to or different from each other, when b2 is two or more, two or more groups R₂ may be identical to or different from each other, and when b10 is two or more, two or more groups R₁₀ may be identical to or different from each other.

In Formulae 2-1 and 2-2, Z₁ and Z₂ may each independently be selected from:

—C(Q₄₀₇)(Q₄₀₈)(Q₄₀₉) and —Si(Q₄₀₇)(Q₄₀₈)(Q₄₀₉); and

a π electron-depleted nitrogen-free cyclic group unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃) (for example, a phenyl group, a heptalenyl group, an indenyl group, a naphthyl group, an azulenyl group, an indacenyl group, an acenaphthylrenyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentacenyl group, a hexacenyl group, a rubicenyl group, a coronenyl group, an ovalenyl group, a pyrrolyl group, an isoindolyl group, an indolyl group, a furanyl group, a thiophenyl group, a benzofuranyl group, a benzothiophenyl group, a benzocarbazolyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, and a triindolophenyl group, each unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃)).

In an embodiment, Z₁ and Z₂ may each independently be selected from:

—C(Q₄₀₇)(Q₄₀₈)(Q₄₀₉) and —Si(Q₄₀₇)(Q₄₀₈)(Q₄₀₉); and

a phenyl group, a naphthyl group, a fluorenyl group, a dibenzosilolyl group, a carbazolyl group, a dibenzofuranyl group, a dibenzothiophenyl group, a biphenyl group, a terphenyl group, and a tetraphenyl group, each unsubstituted or substituted with at least one selected from deuterium, a C₁-C₂₀ alkyl group, a C₁-C₂₀ alkoxy group, a phenyl group, and —Si(Q₄₀₁)(Q₄₀₂)(Q₄₀₃).

In one or more embodiments, Z₁ and Z₂ may each independently be selected from —CH₃, —CD₃, —CD₂H, —CDH₂, groups represented by Formulae 9-1 to 9-19, groups represented by Formulae 10-1 to 10-60, and —Si(Q₄₀₇)(Q₄₀₈)(Q₄₀₉), and

Q₄₀₇ to Q₄₀₉ may each independently be selected from hydrogen, —CH₃, —CD₃, —CD₂H, —CDH₂, and groups represented by Formulae 9-1 to 9-19, but embodiments of the present disclosure are not limited thereto:

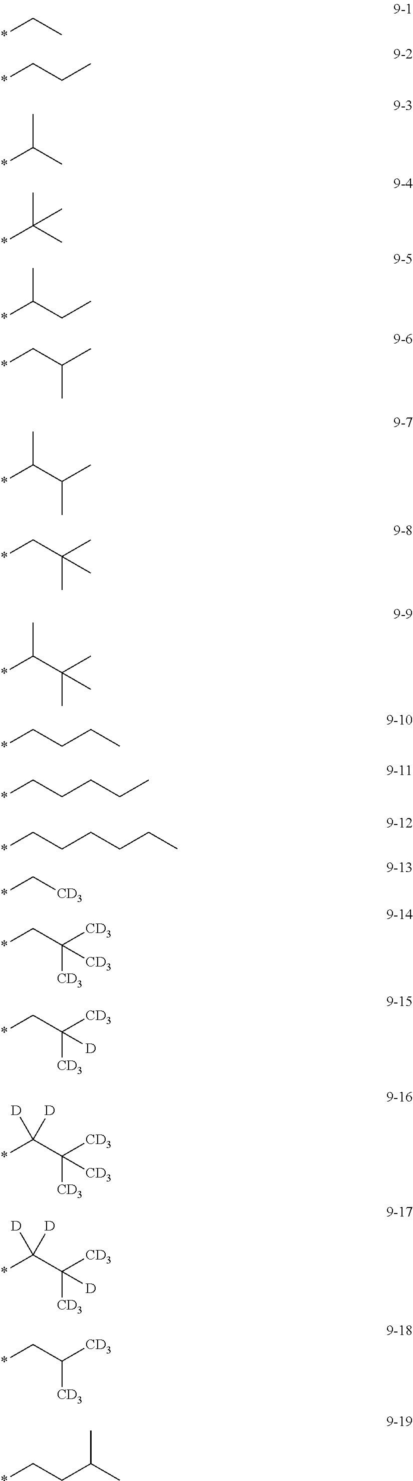

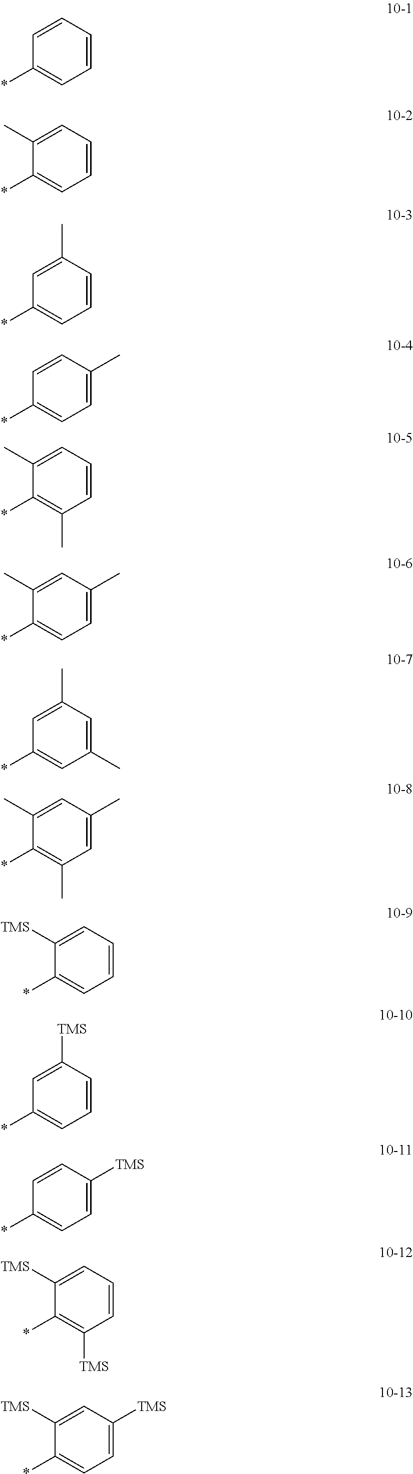

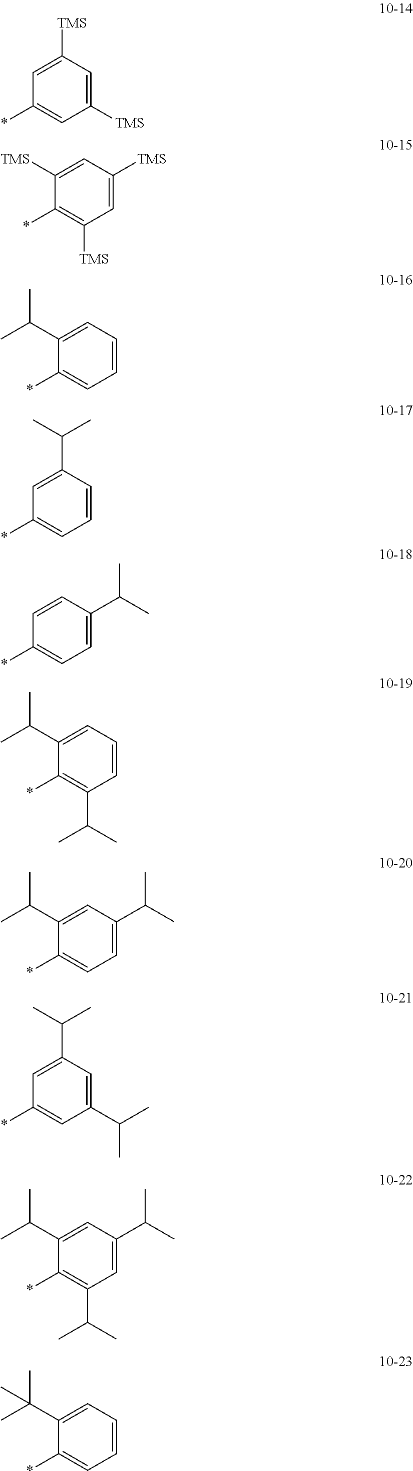

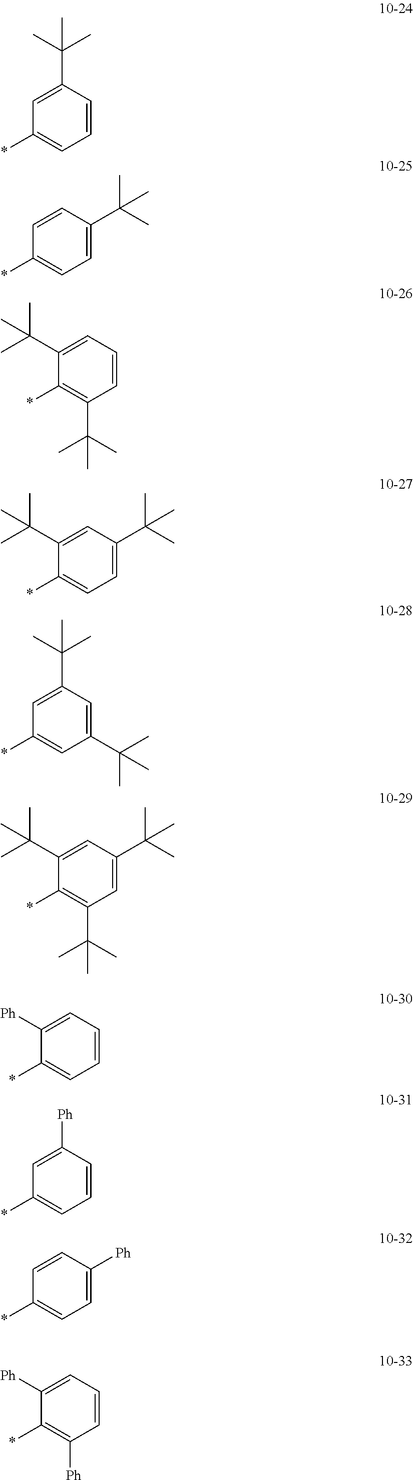

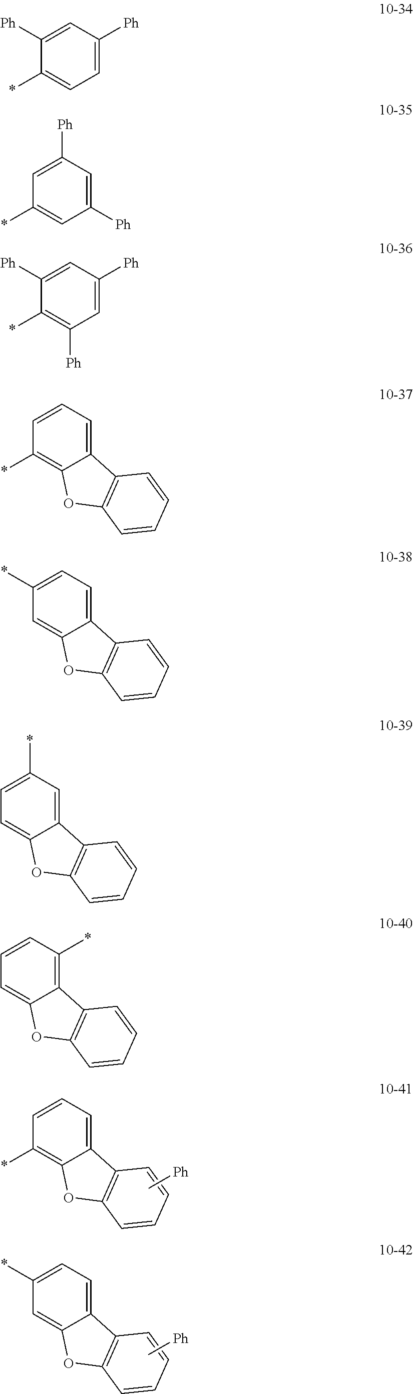

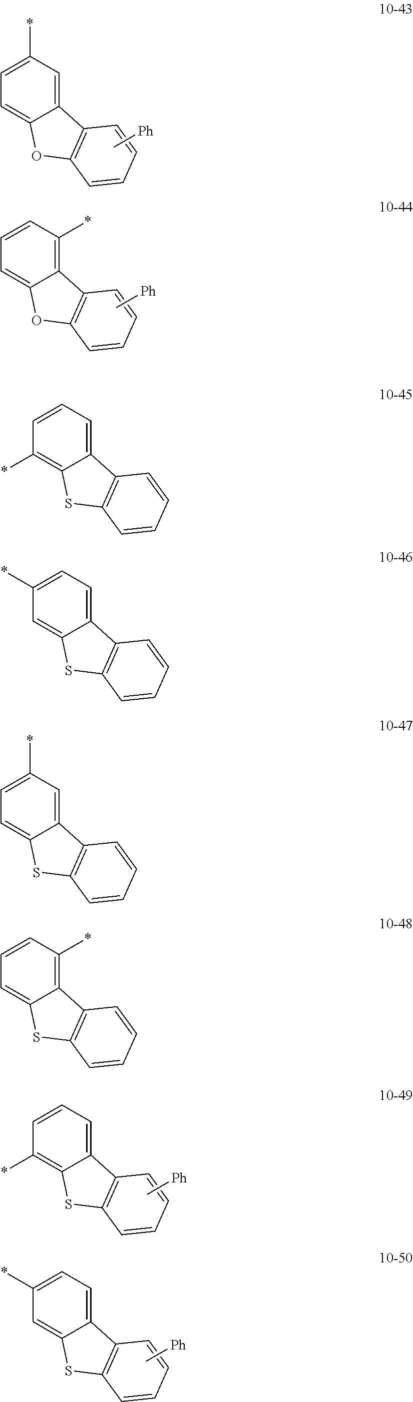

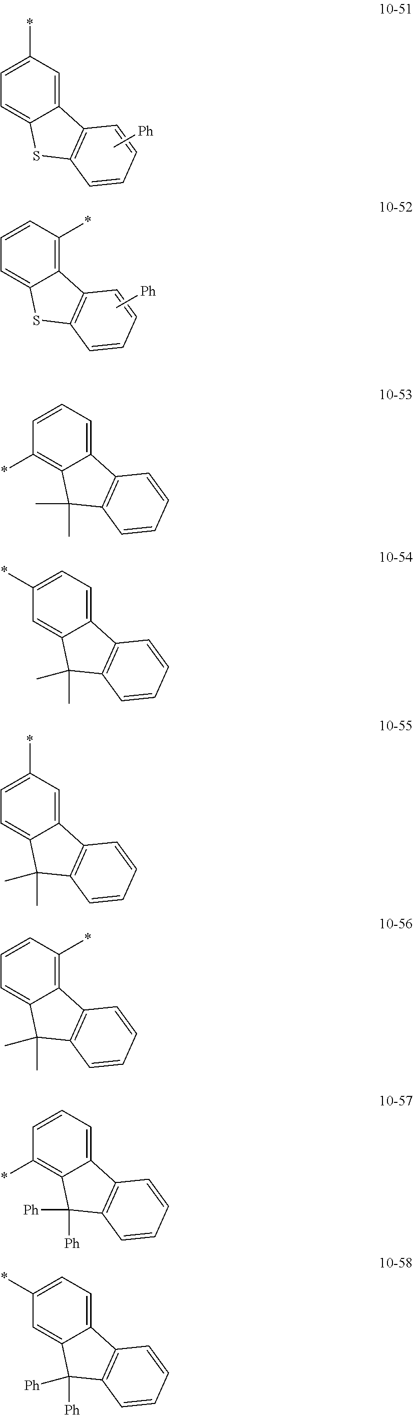

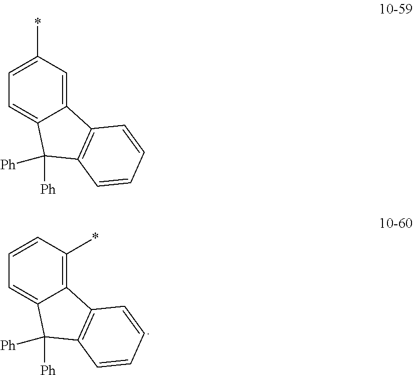 [SMILES: *c1ccc2c(c1)-c1ccccc1C2(c1ccccc1)c1ccccc1 ; *c1cccc2c1-c1ccccc1C2(c1ccccc1)c1ccccc1]

In Formulae 9-1 to 9-19 and 10-1 to 10-60, Ph indicates a phenyl group, TMS indicates a trimethylsilyl group, and * indicates a binding site to a neighboring atom.

In Formulae 2-1 and 2-2, c1 and c2 may each independently be an integer of 0 to 5.

Q₄₀₁ to Q₄₀₉ as used herein may each independently be selected from hydrogen, deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, and a tetraphenyl group.

* as used herein indicates a binding site to a neighboring atom.

In Formula 1, i) at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 may be equal to or greater than one (for example, 1, 2, 3, 4, 5 or 6). In an embodiment, the auxiliary dopant may include a compound represented by one selected from Formulae 1-1 to 1-7:

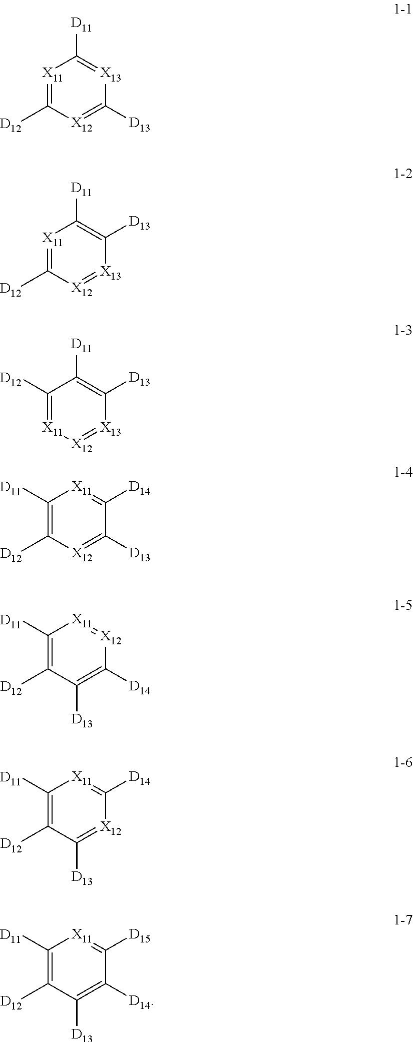

In Formulae 1-1 to 1-7,

D₁₁ to D₁₅ may each independently be a group represented by Formula 2-1 or 2-2,

X₁₁ may be C(CN), C(F), C(R₁₄), N, or C(R₁₁),

X₁₂ may be C(CN), C(F), C(R₁₄), N, or C(R₁₂),

X₁₃ may be C(CN), C(F), C(R₁₄), N, or C(R₁₃),

R₁₁ to R₁₃ may be the same as described in connection with R₁₀,

R₁₄ may be selected from a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, and a tetraphenyl group, each substituted with at least one selected from a cyano group (—CN) and a fluoro group (—F),

at least one selected from X₁₁ to X₁₃ in Formulae 1-1 to 1-3 may each independently be C(CN), C(F), C(R₁₄), or N, at least one selected from X₁₁ and X₁₂ in Formulae 3 1-4 to 1-6 may each independently be C(CN), C(F), C(R₁₄), or N, and X₁₁ in Formula 1-7 may be C(CN), C(F), C(R₁₄), or N.

In one or more embodiments, in Formulae 2-1 and 2-2, the core represented by

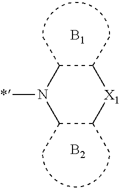

may be represented by one selected from Formulae 3-1 to 3-35:

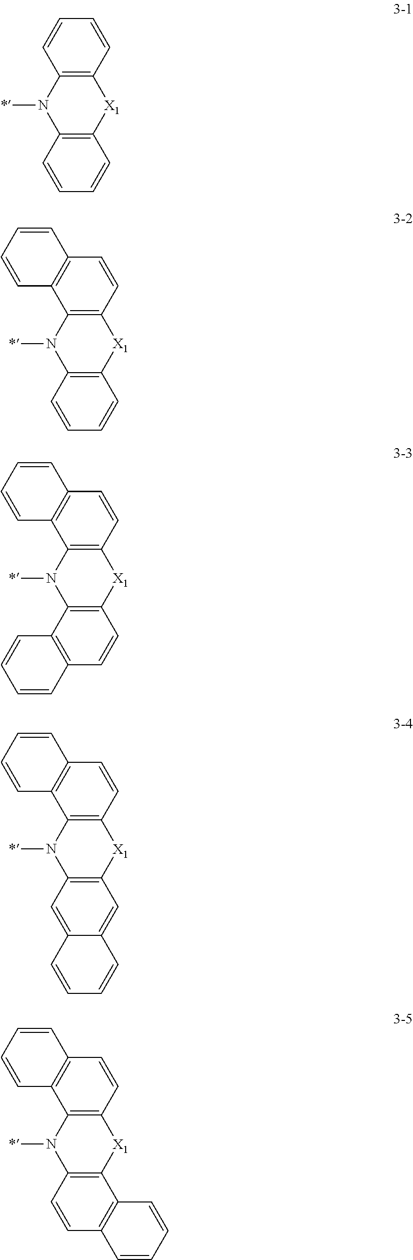

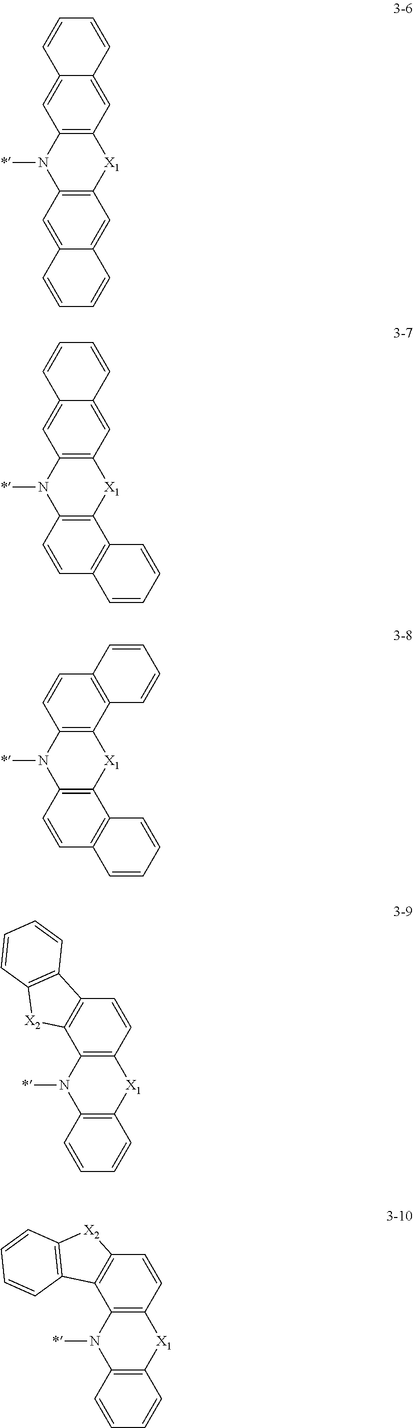

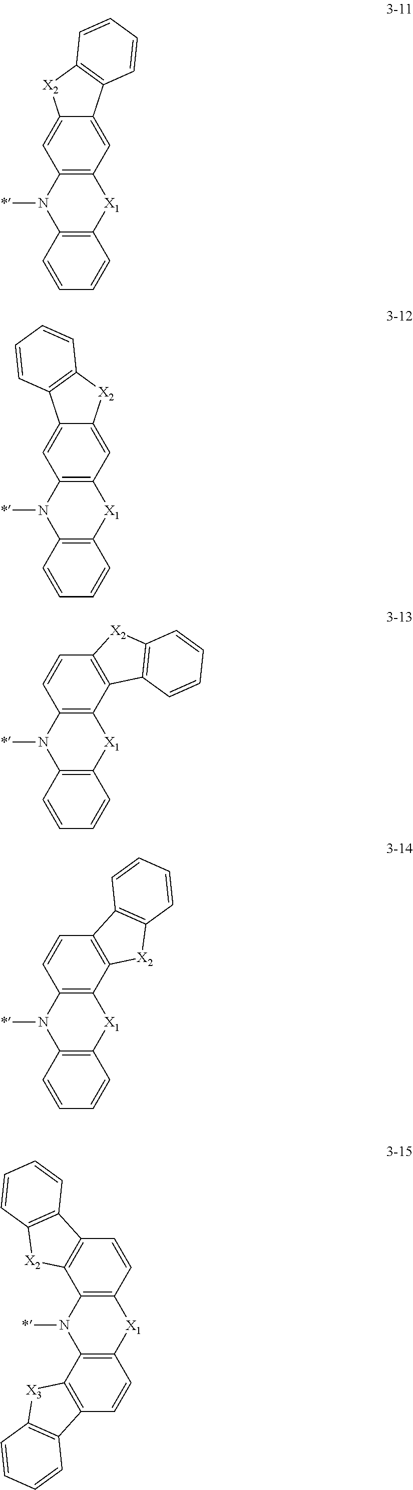

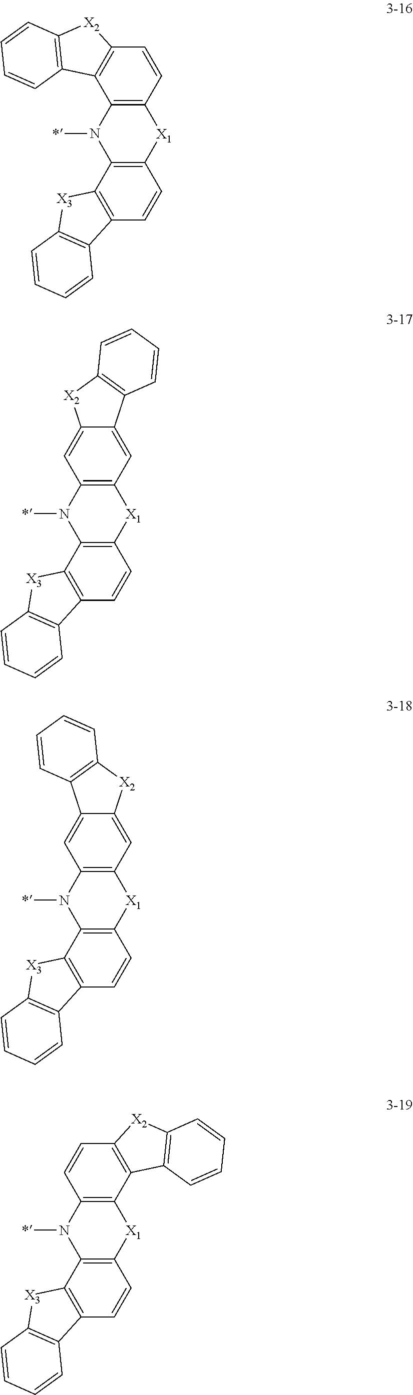

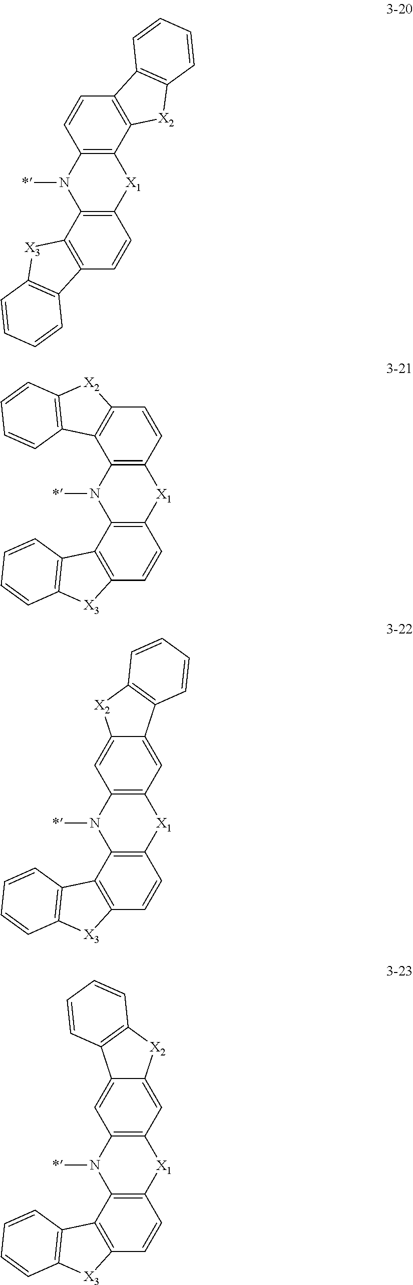

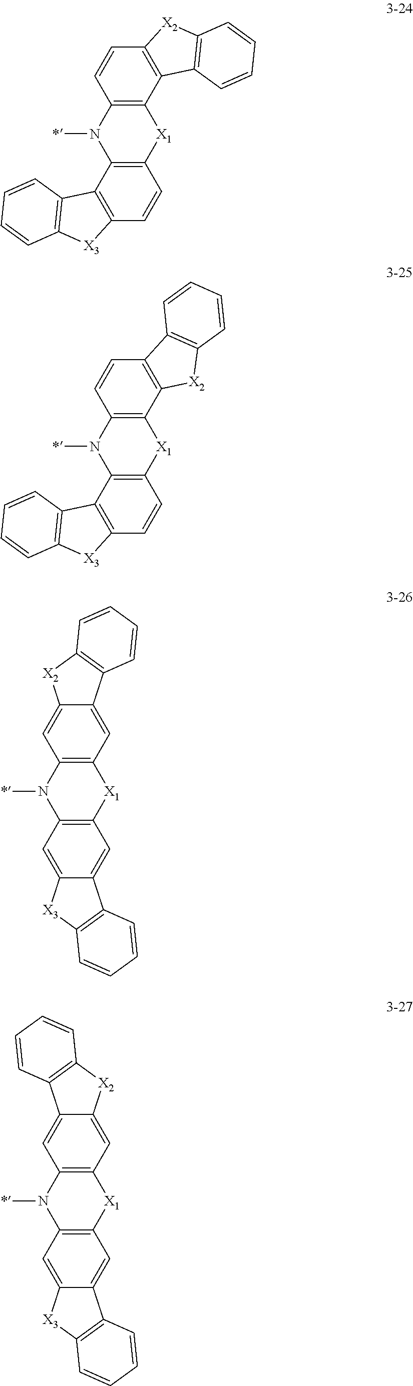

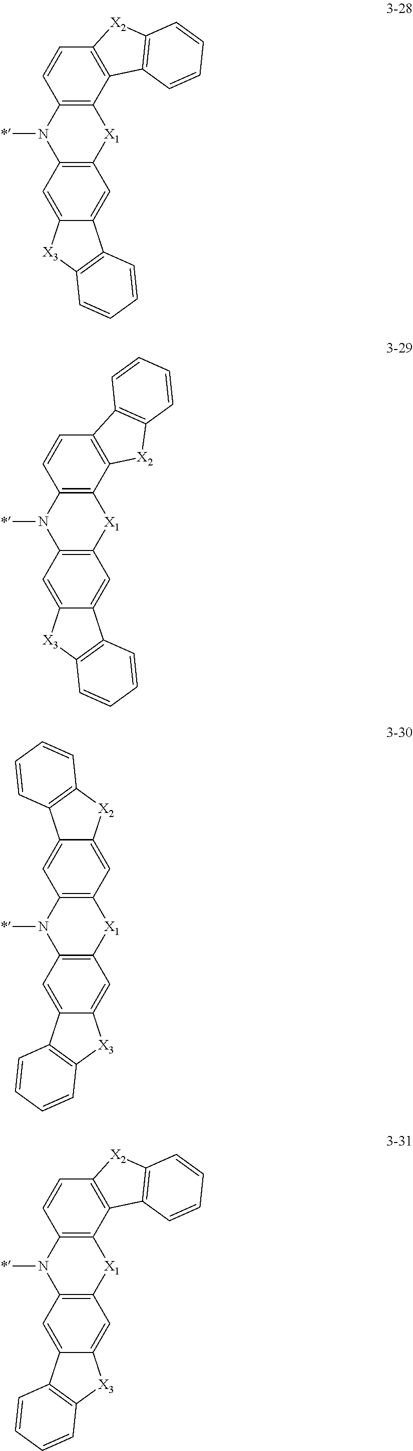

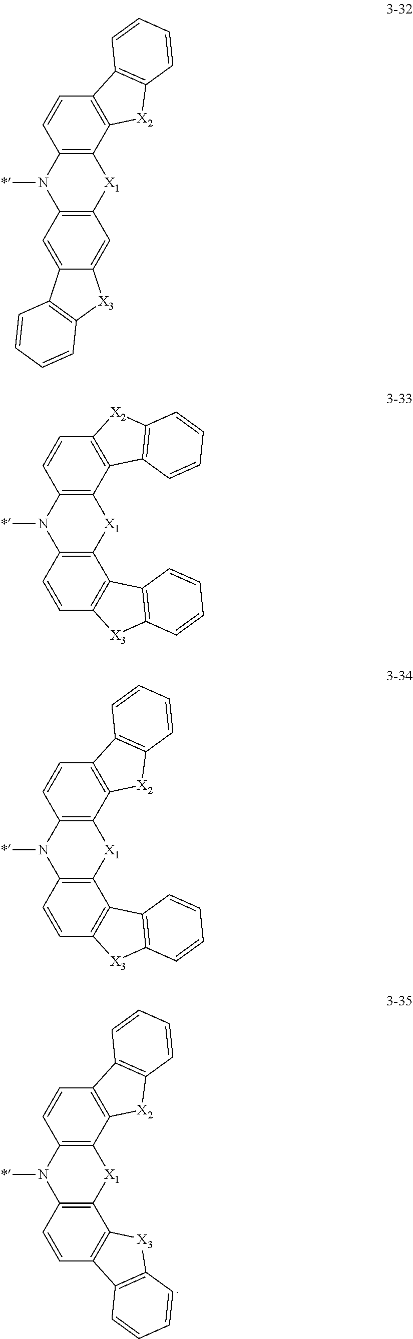

In Formulae 3-1 to 3-35,

X₁ may be the same as described above,

X₂ may be C(R₆)(R₇), Si(R₆)(R₇), N(R₆), O, or S,

X₃ may be C(R₈)(R₉), Si(R₈)(R₉), N(R₈), O, or S,

R₆ to R₉ may each independently be the same as described in connection with R₃, and

* indicates a binding site to a neighboring atom.

In one or more embodiments, in Formulae 2-1 and 2-2, the core represented by

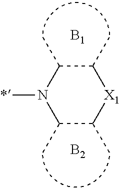

may be represented by Formula 3-1 and the sum of c1 and c2 in Formulae 2-1 and 2-2 may be equal to or greater than one (for example, 1, 2, 3, 4, 5 or 6).

In one or more embodiments, in Formulae 2-1 and 2-2, the core represented by

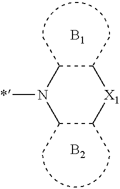

may be represented by one selected from Formulae 3-2 to 3-35.

In one or more embodiments, in Formulae 2-1 and 2-2, the core represented by

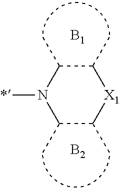

may be represented by one selected from Formulae 3-2 to 3-35 and the sum of c1 and c2 in Formulae 2-1 and 2-2 may be 0.

In one or more embodiments, D₁ in Formula 1 may be selected from groups represented by Formulae 2-1(1) to 2-1(82):

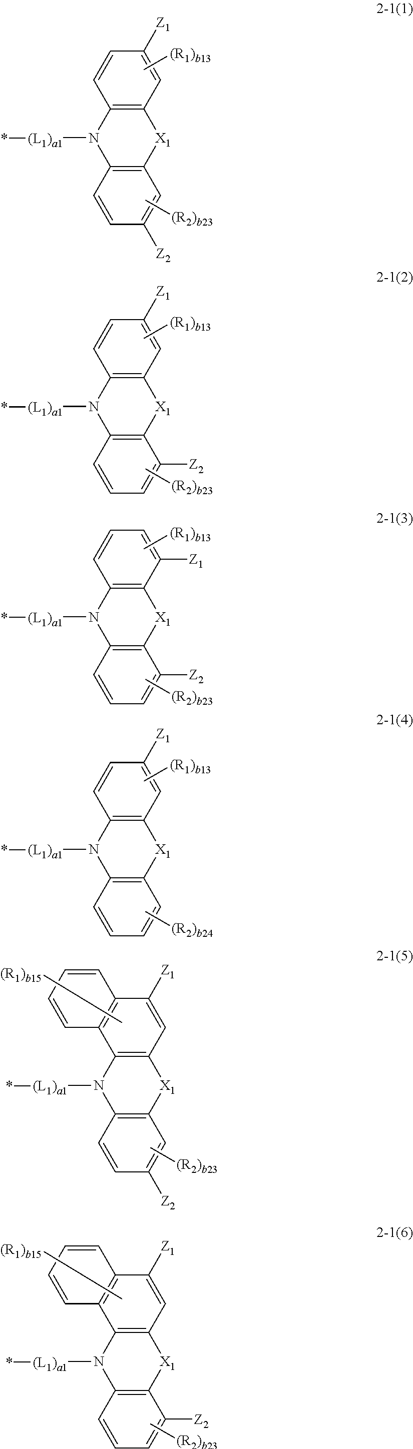

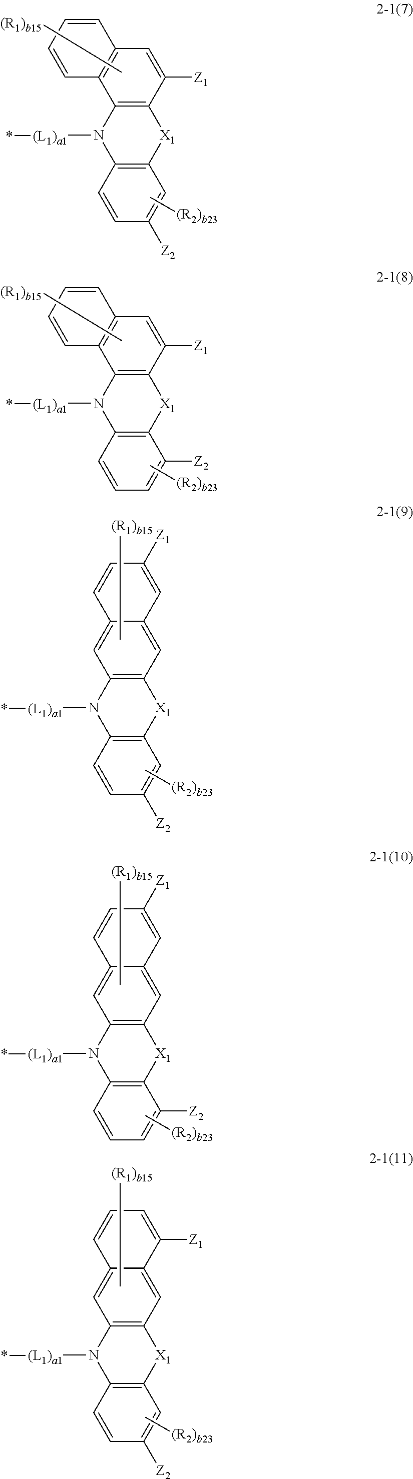

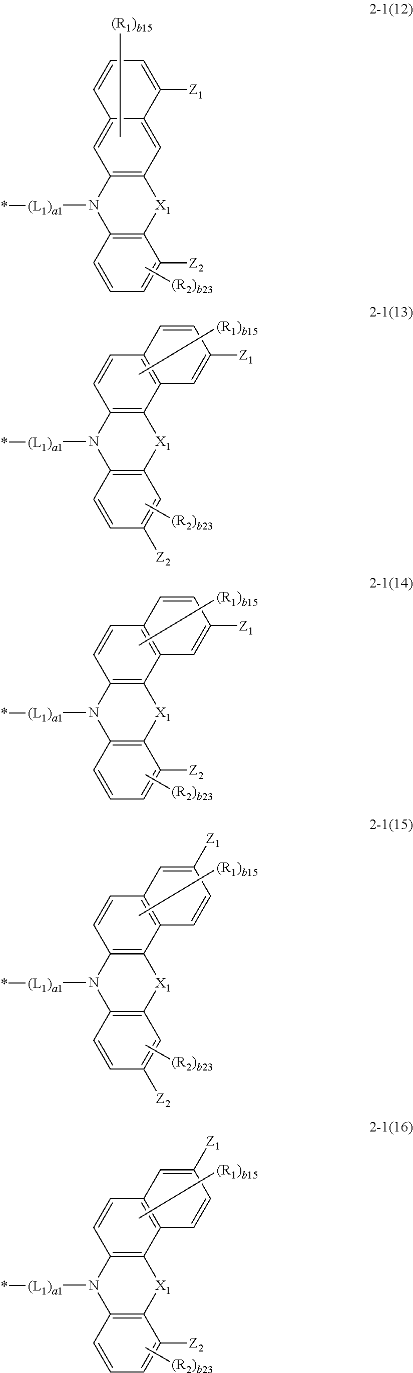

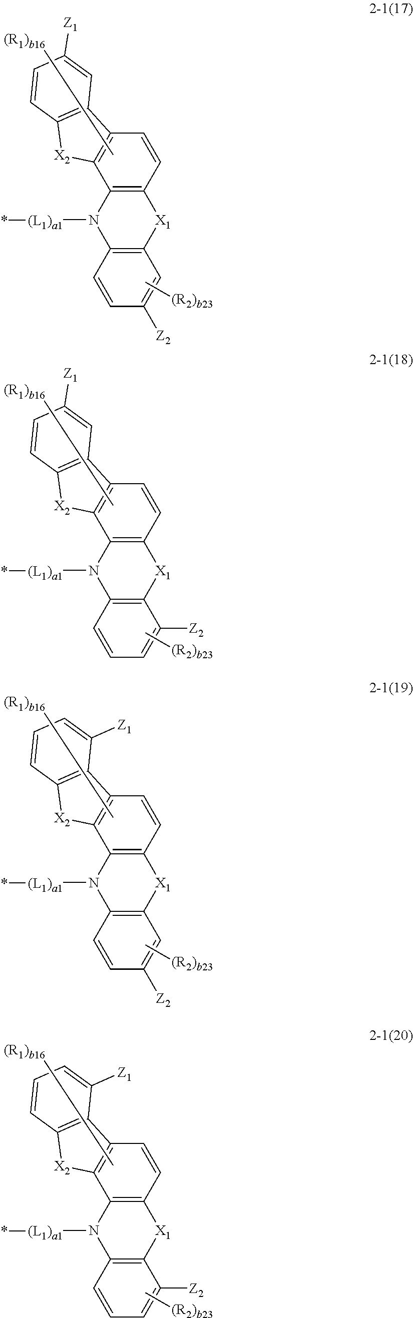

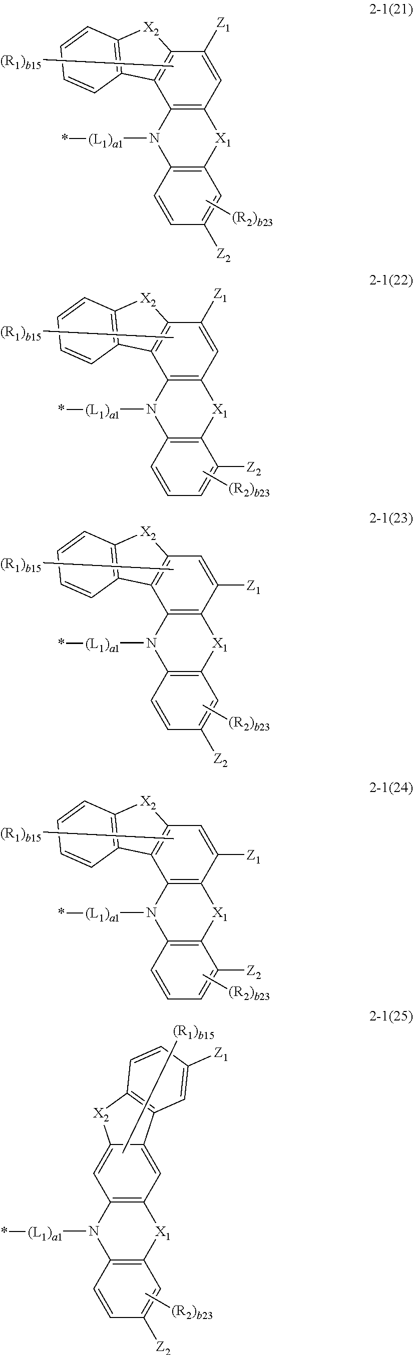

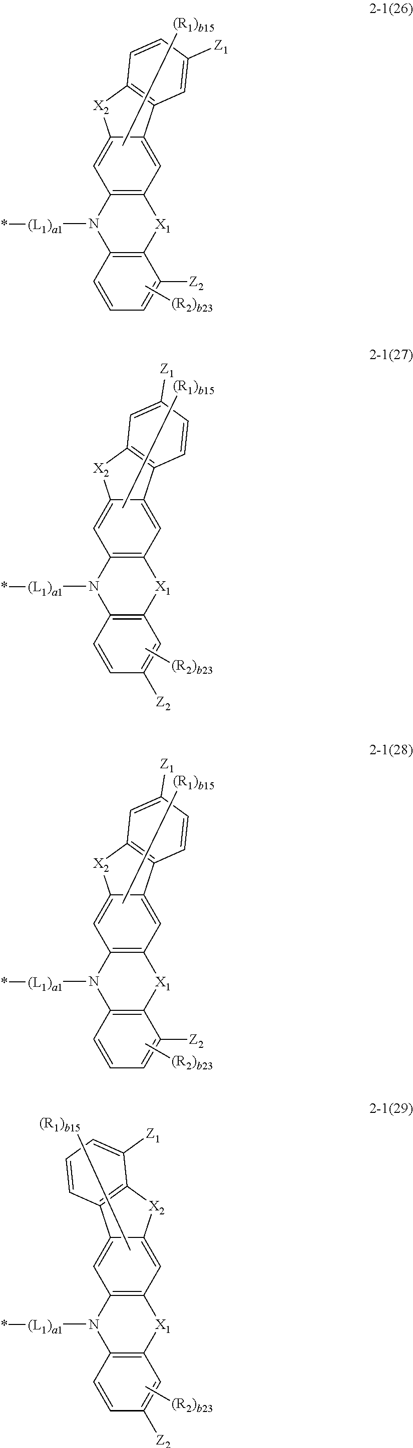

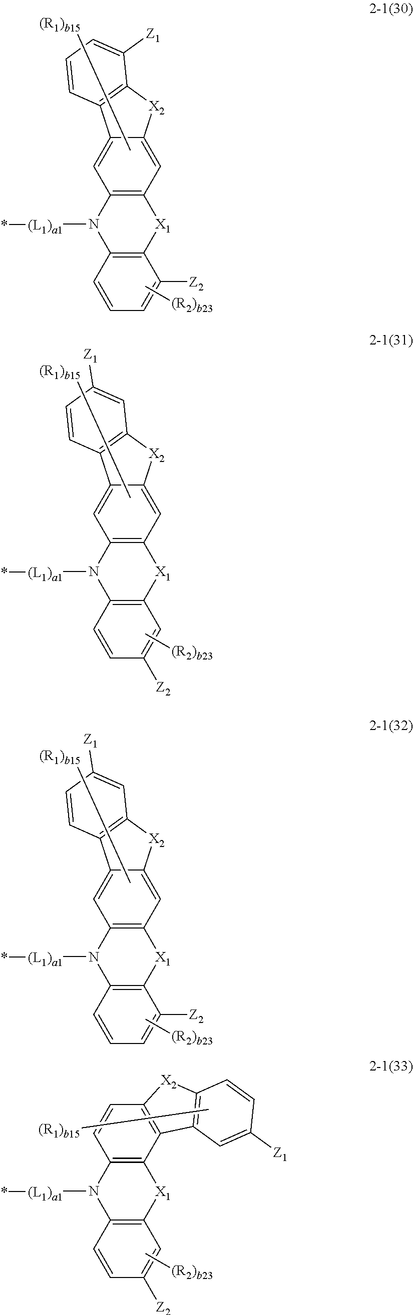

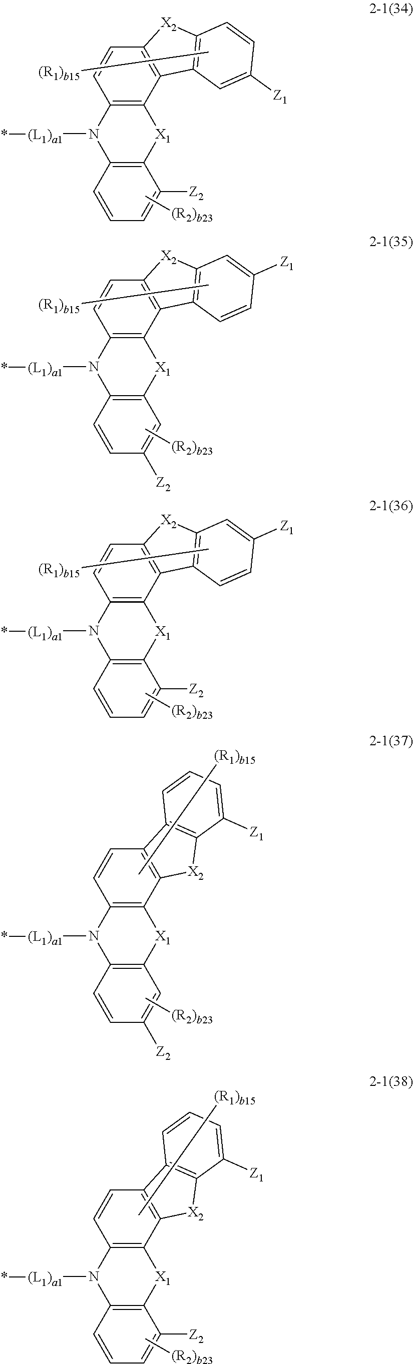

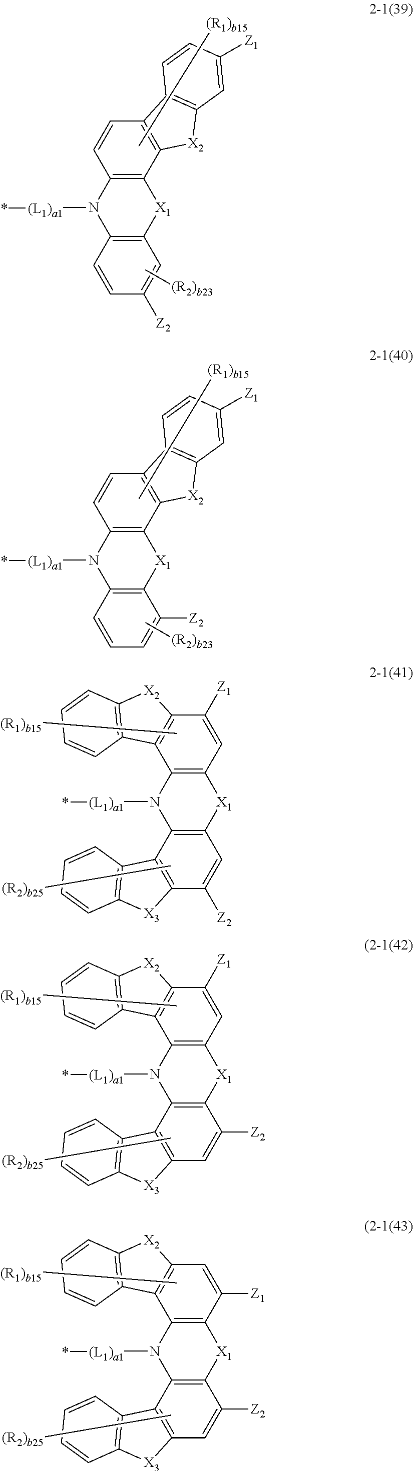

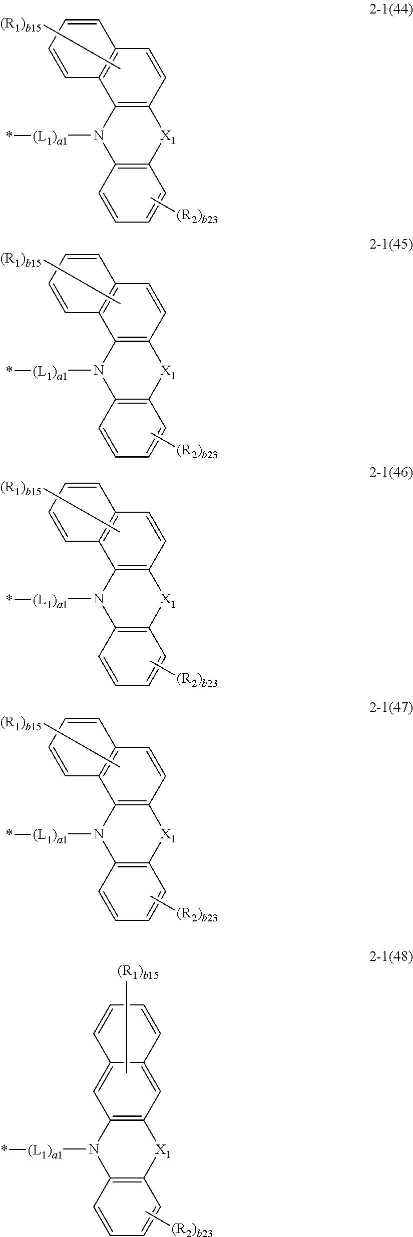

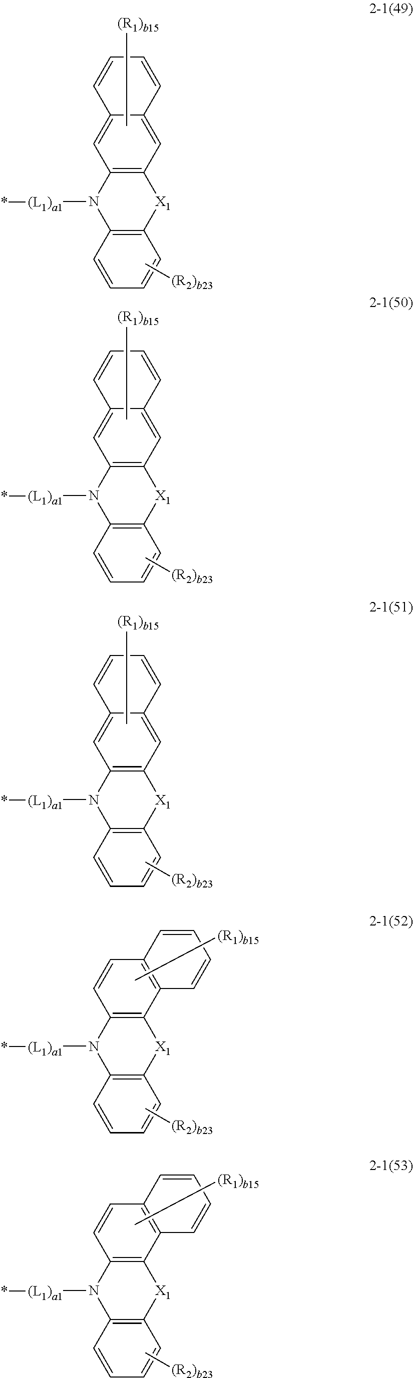

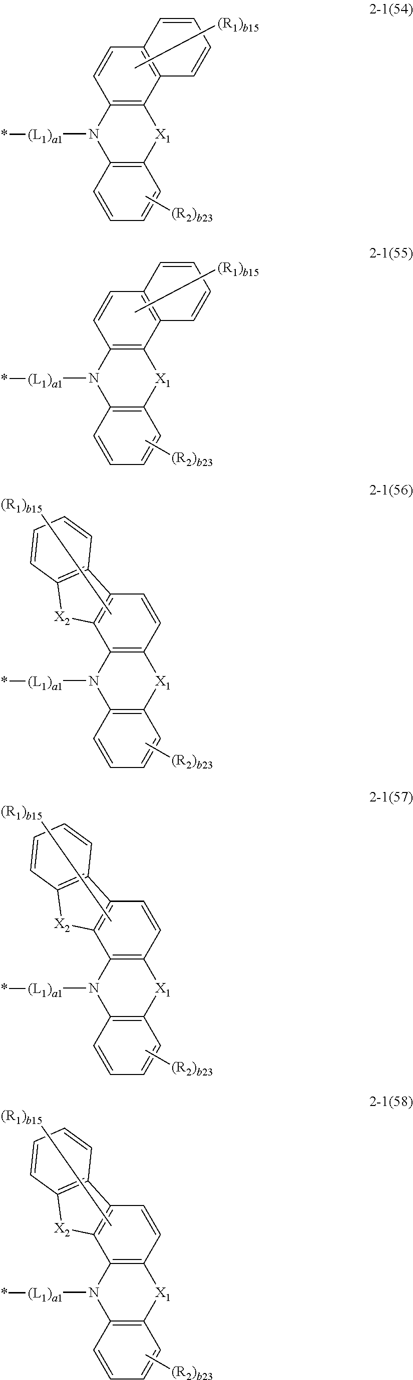

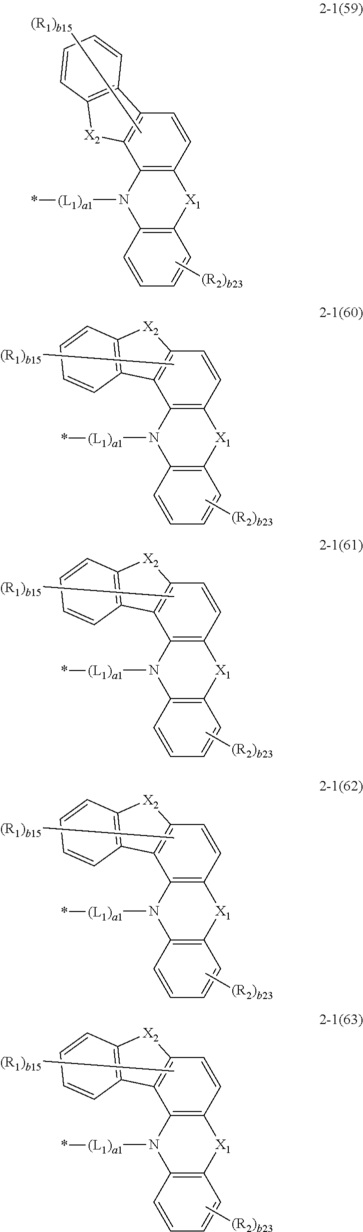

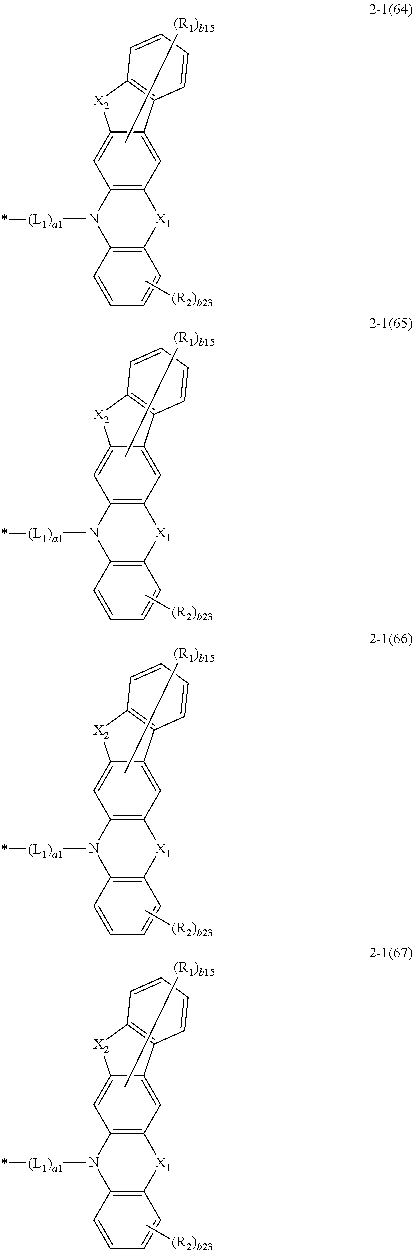

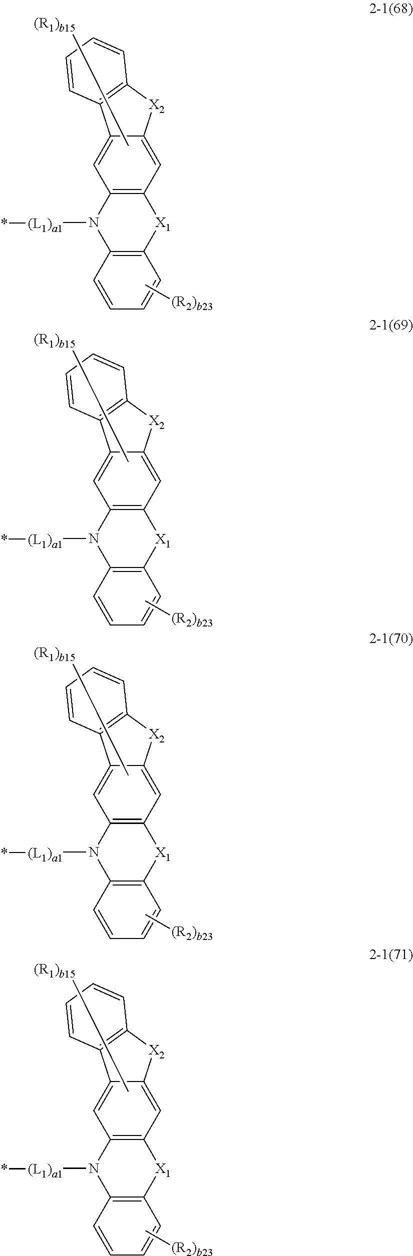

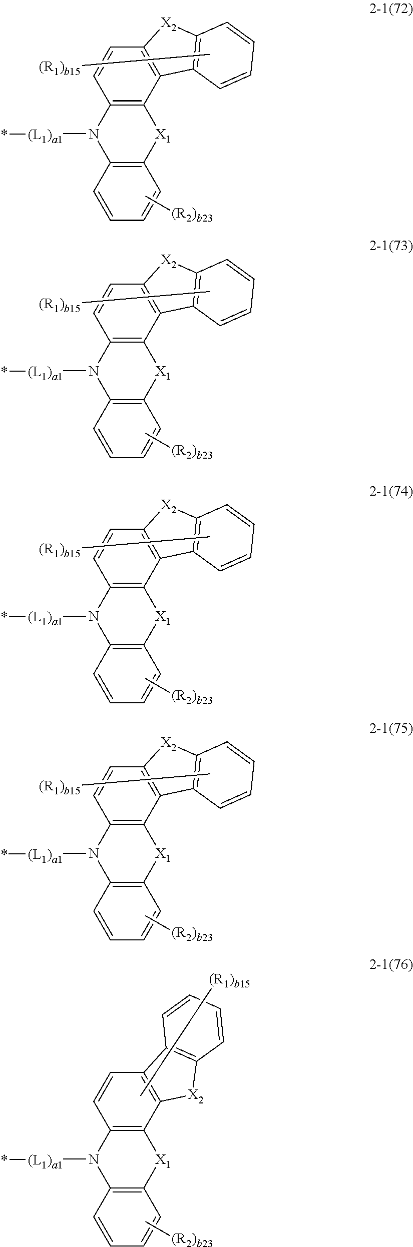

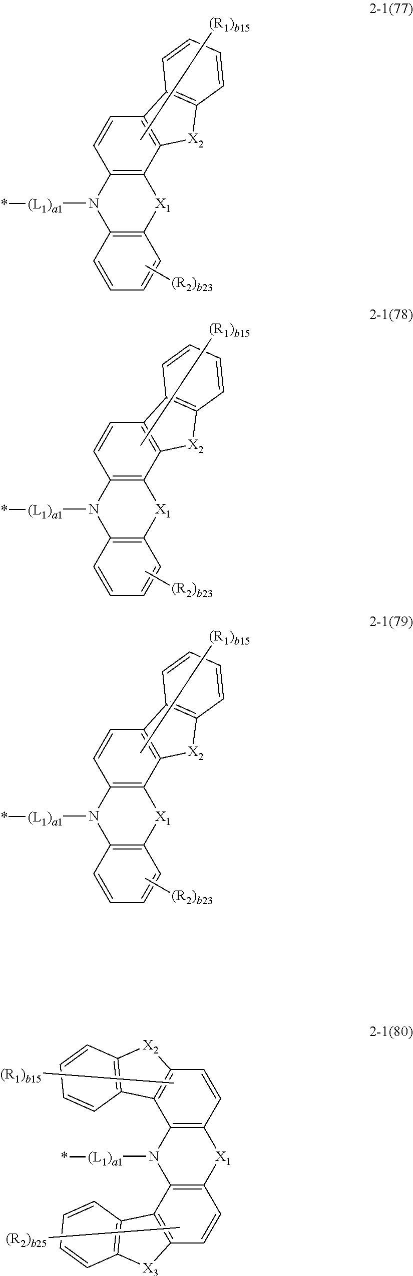

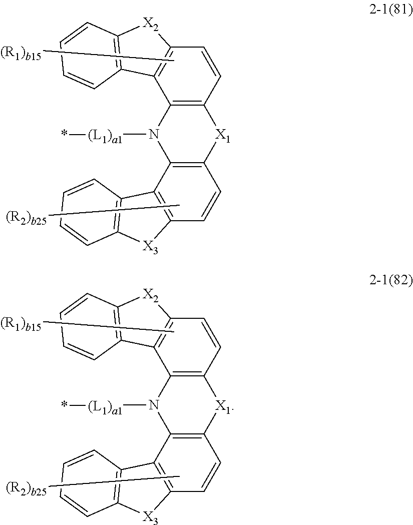

In Formulae 2-1(1) to 2-1(82),

X₁, L₁, a1, R₁, R₂, Z₁, and Z₂ are the same as described herein,

X₂ may be C(R₆)(R₇), Si(R₆)(R₇), N(R₆), O, or S,

X₃ may be C(R₈)(R₉), Si(R₈)(R₉), N(R₈), O, or S,

R₆ to R₉ are the same as described in connection with R₁,

b13 and b23 may each independently be an integer from 0 to 3,

b24 may be an integer from 0 to 4,

b15 and b25 may each independently be an integer from 0 to 5, and

* indicates a binding site to a neighboring atom.

In one or more embodiments, a difference between a singlet energy level (electron volts, eV) and a triplet energy level (eV) of the auxiliary dopant may be 0.5 eV or less. Therefore, triplet exciton of the auxiliary dopant may be easily transferred to a singlet state of the auxiliary dopant through reverse intersystem crossing (RISC).

The singlet energy level and the triplet energy level described above were calculated by using Gaussian 09 program based on a quantum chemical calculation method based on density functional theory (DFT) using a 6-311+G(d,p) basis set.

The auxiliary dopant may include at least one of Compounds AD1 to AD22, but embodiments of the present disclosure are not limited thereto:

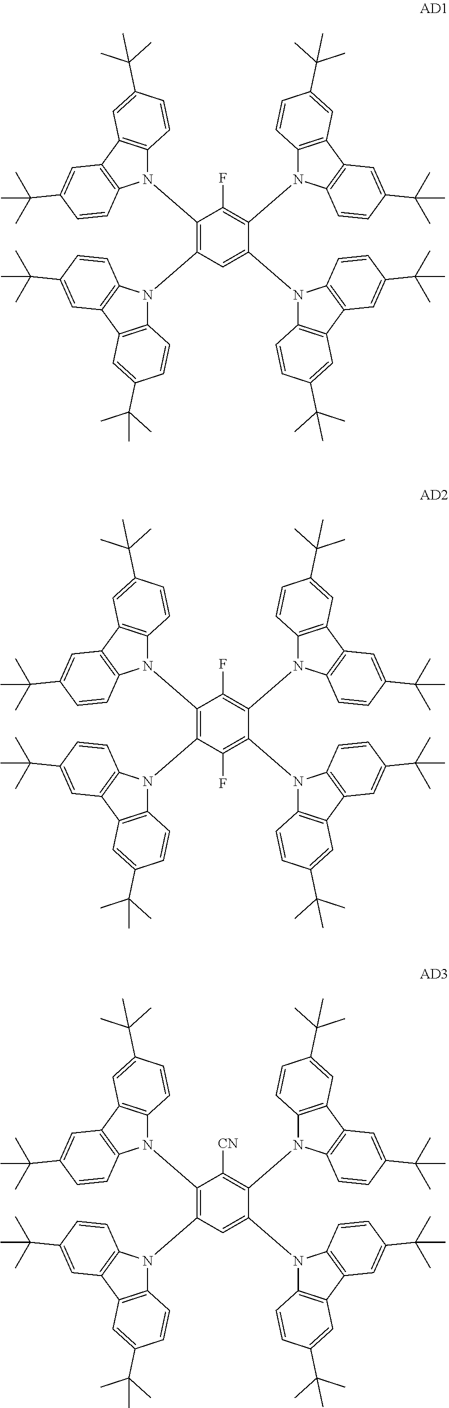

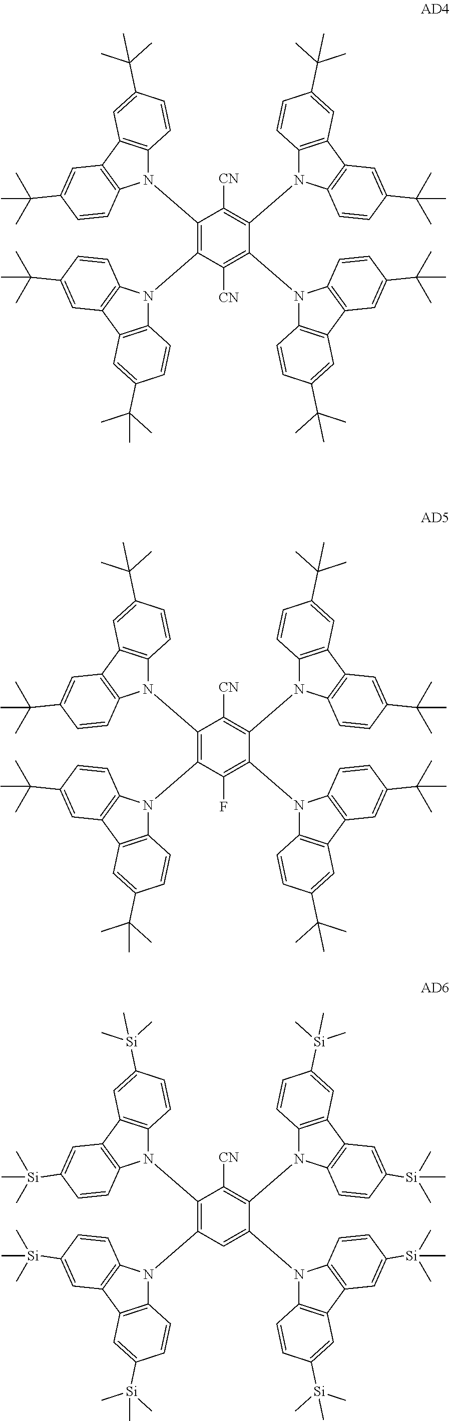

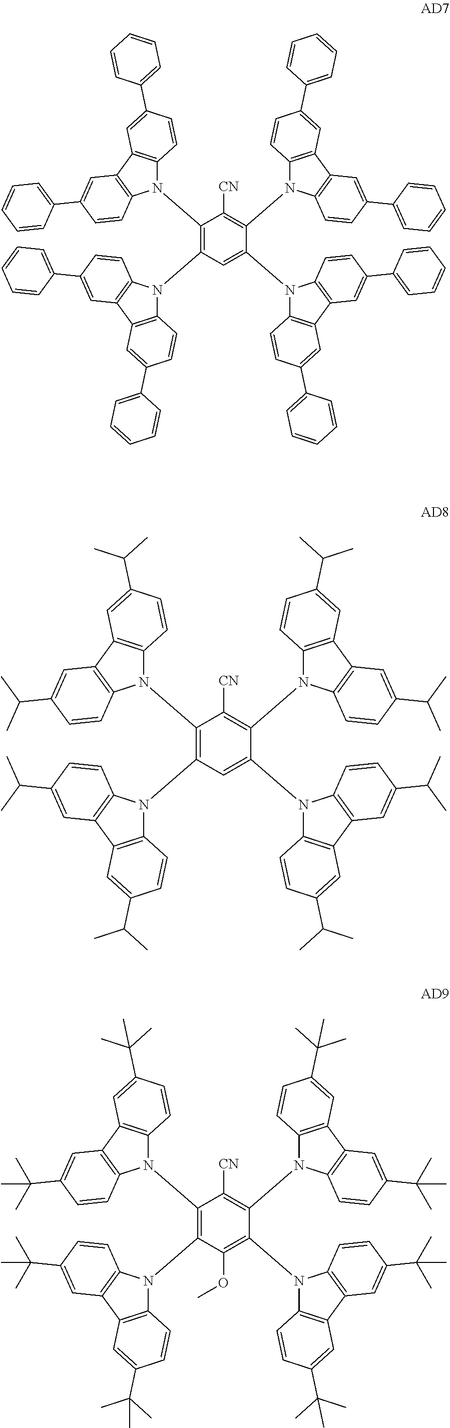

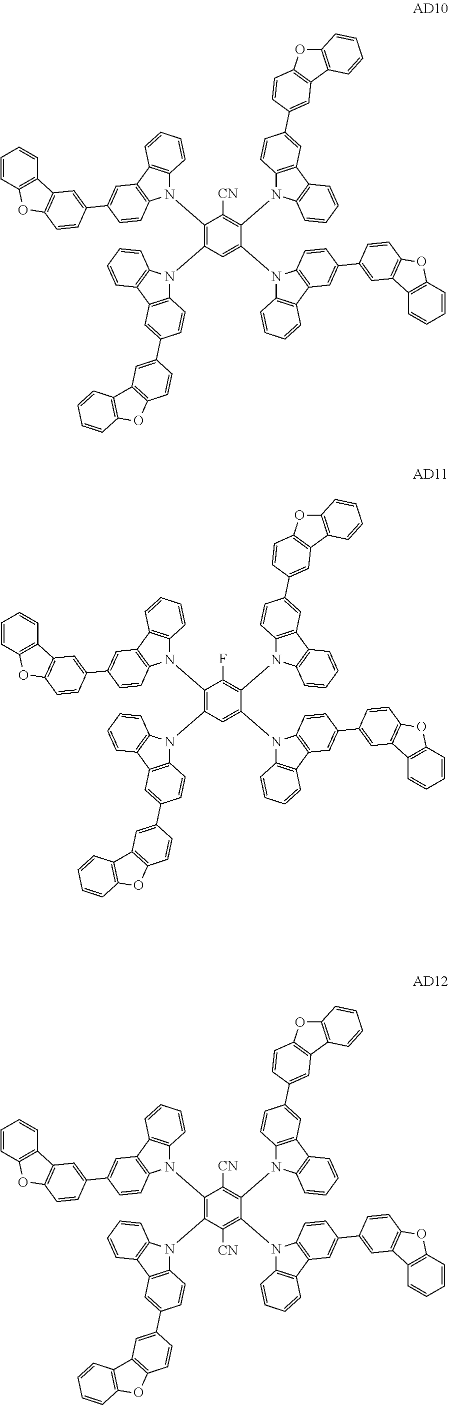

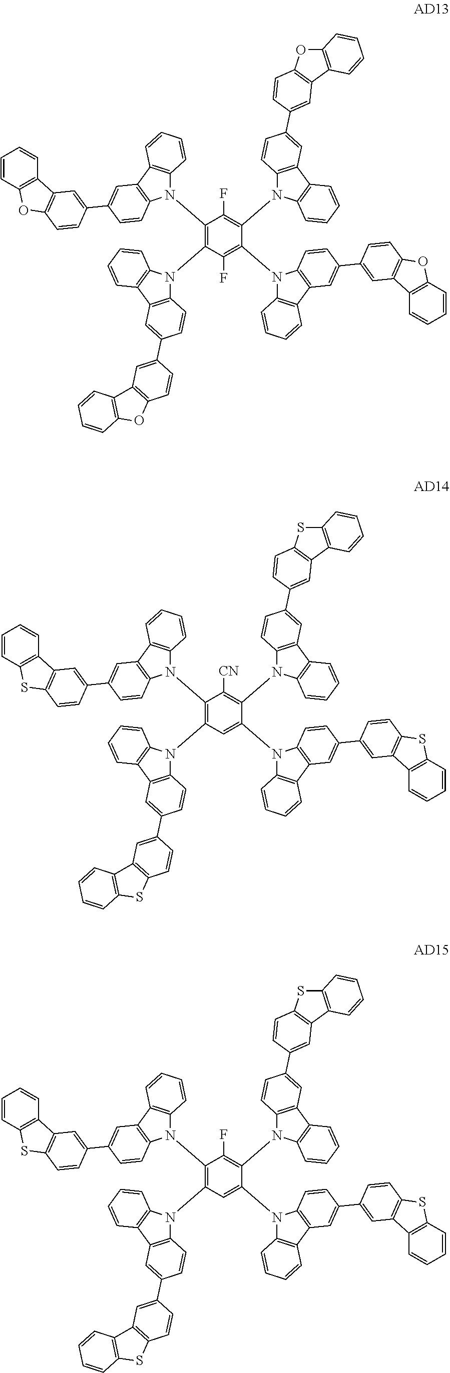

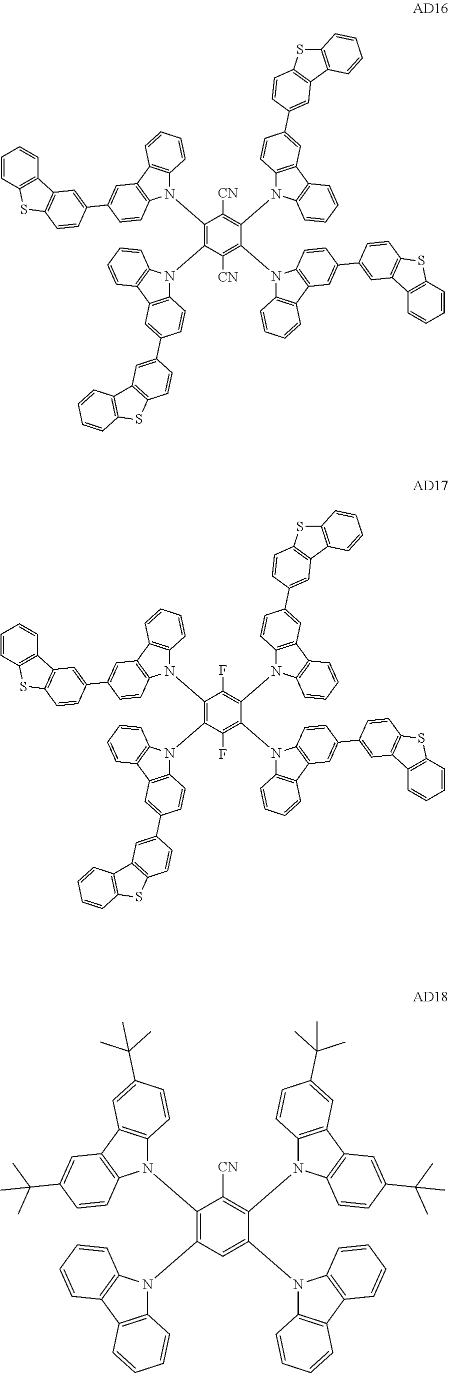

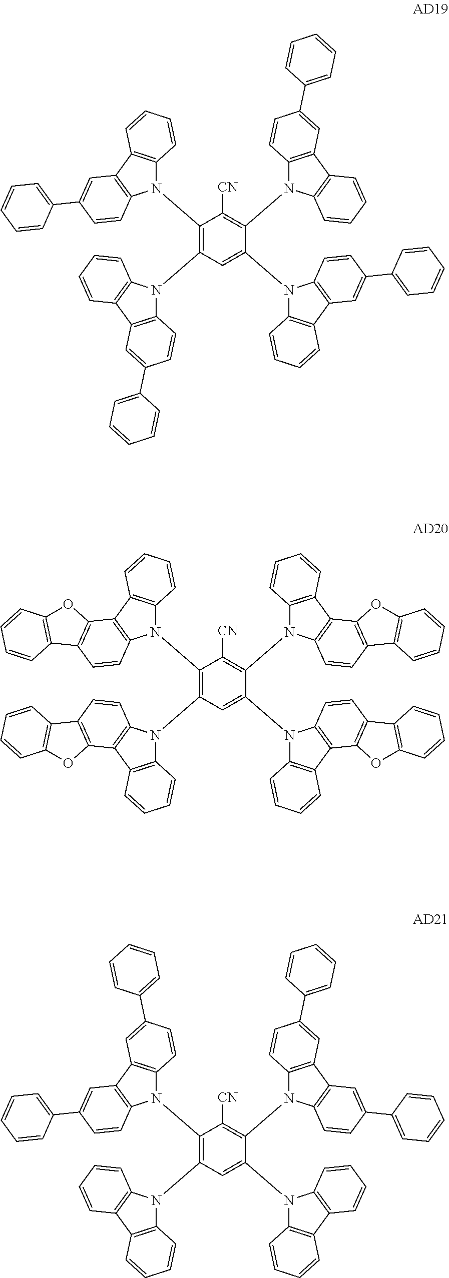 [SMILES: N#Cc1c(-n2c3ccccc3c3cc(-c4ccccc4)ccc32)c(-n2c3ccccc3c3cc(-c4ccccc4)ccc32)cc(-n2c3ccccc3c3cc(-c4ccccc4)ccc32)c1-n1c2ccccc2c2cc(-c3ccccc3)ccc21 ; N#Cc1c(-n2c3ccccc3c3c4oc5ccccc5c4ccc32)c(-n2c3ccccc3c3c4oc5ccccc5c4ccc32)cc(-n2c3ccccc3c3c4oc5ccccc5c4ccc32)c1-n1c2ccccc2c2c3oc4ccccc4c3ccc21 ; N#Cc1c(-n2c3ccc(-c4ccccc4)cc3c3cc(-c4ccccc4)ccc32)c(-n2c3ccccc3c3ccccc32)cc(-n2c3ccccc3c3ccccc32)c1-n1c2ccc(-c3ccccc3)cc2c2cc(-c3ccccc3)ccc21]

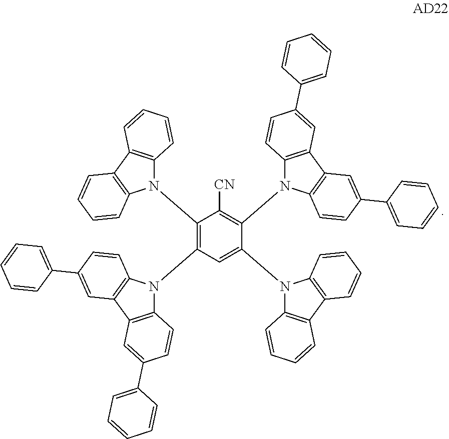 [SMILES: N#Cc1c(-n2c3ccccc3c3ccccc32)c(-n2c3ccc(-c4ccccc4)cc3c3cc(-c4ccccc4)ccc32)cc(-n2c3ccccc3c3ccccc32)c1-n1c2ccc(-c3ccccc3)cc2c2cc(-c3ccccc3)ccc21]

The fluorescent dopant is a material that emits prompt fluorescence.

For example, the fluorescent dopant may be selected from fluorescence materials that does not include a cyano group (—CN) and a fluoro group (—F).

In an embodiment, the fluorescent dopant may be selected from a condensed cyclic group-containing compound, an amino group-containing compound, a styryl group-containing compound, and a boron-containing compound.

In an embodiment, the fluorescent dopant may include at least one compound selected from a naphthalene-containing compound, a fluorene-containing compound, a spiro-bifluorene-containing compound, a benzofluorene-containing compound, a dibenzofluorene-containing compound, a phenanthrene-containing compound, an anthracene-containing compound, a fluoranthene-containing compound, a triphenylene-containing compound, a pyrene-containing compound, a chrysene-containing compound, a naphthacene-containing compound, a picene-containing compound, a perylene-containing compound, a pentaphene-containing compound, an indenoanthracene-containing compound, a tetracene-containing compound, a bisanthracene-containing compound, and a compound including one of groups represented by Formulae 501-1 to 501-21, but embodiments of the present disclosure are not limited thereto:

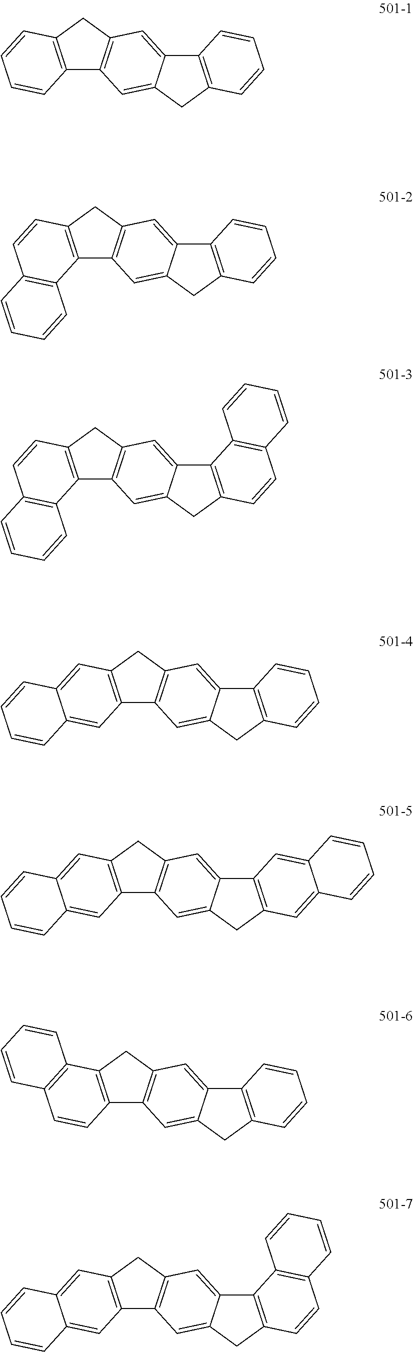

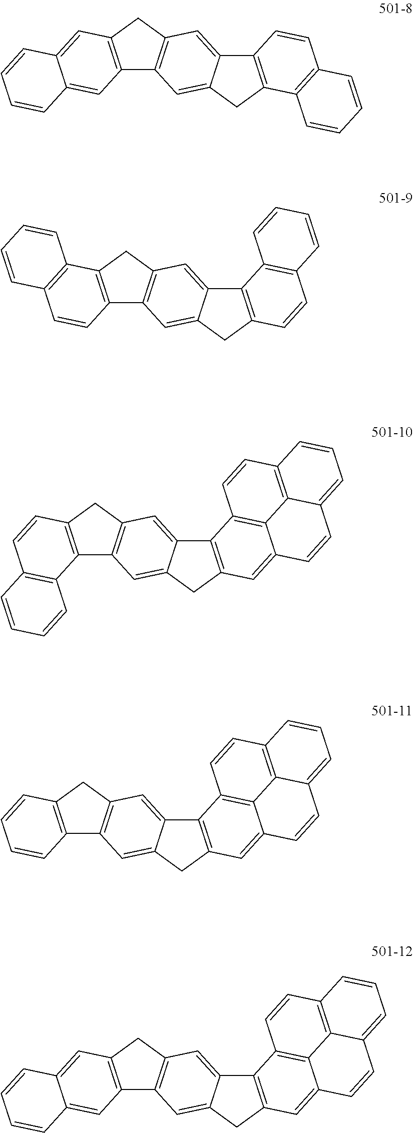

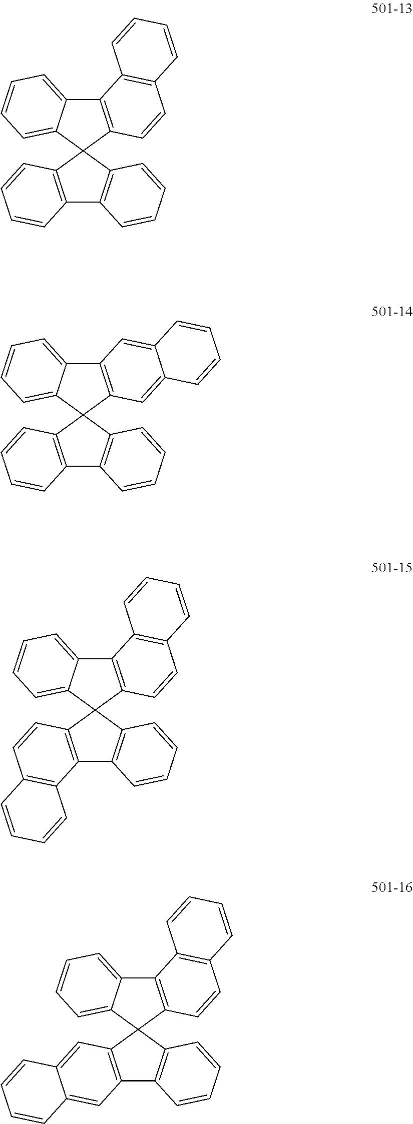

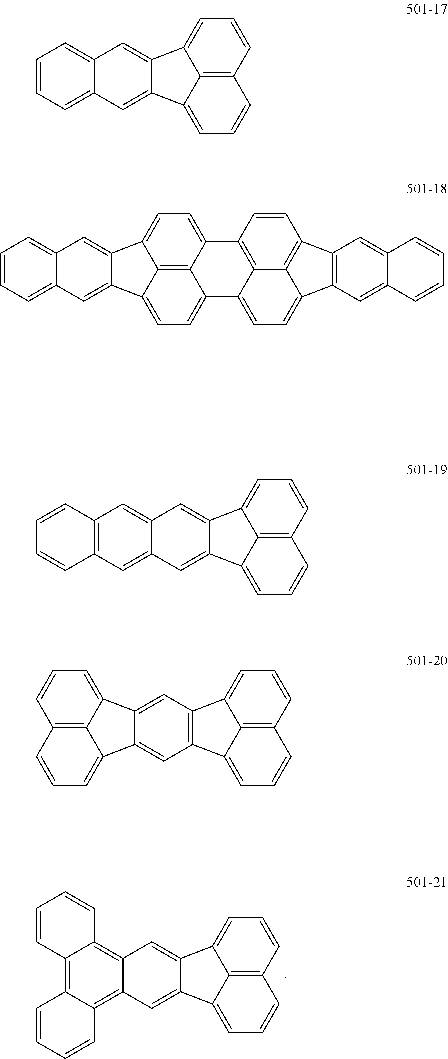

In one or more embodiments, the fluorescent dopant may include a compound represented by Formula 501A or 501B, but embodiments of the present disclosure are not limited thereto:

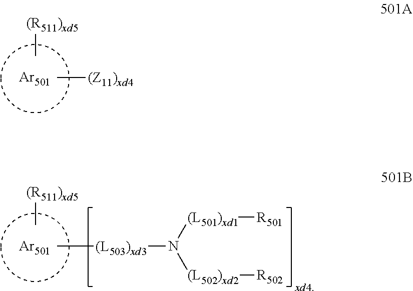

In Formulae 501A and 501B,

Ar₅₀₁ may be selected from a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group, a picene group, a perylene group, a pentaphene group, an indenoanthracene group, a tetracene group, a bisanthracene group, and groups represented by Formulae 501-1 to 501-21,

R₅₁₁ may be selected from hydrogen, deuterium, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₅₀₁)(Q₅₀₂)(Q₅₀₃),

xd5 may be an integer of 0 to 10,

L₅₀₁ to L₅₀₃ may each independently be selected from:

a single bond; and

a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group, each unsubstituted or substituted with at least one selected from deuterium, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₅₀₁)(Q₅₀₂)(Q₅₀₃),

xd1 to xd3 may each independently be 1, 2, and 3,

R₅₀₁ and R₅₀₂ may each independently be selected from a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, a dibenzothiophenyl group, and a dibenzosilolyl group, each unsubstituted or substituted with at least one selected from Z₁₁, deuterium, a C₁-C₂₀ alkoxy group, a pyridinyl group, a pyrimidinyl group, a pyridazinyl group, a pyrazinyl group, a triazinyl group, a quinolinyl group, an isoquinolinyl group, a quinoxalinyl group, a quinazolinyl group, and a phenanthrolinyl group,

Z₁₁ may be the same as described in connection with Z₁,

xd4 may be selected from 1, 2, 3, 4, 5, and 6, and

Q₅₀₁ to Q₅₀₃ may each independently be selected from hydrogen, C₁-C₆₀ alkyl group, a C₁-C₆₀ alkoxy group, a C₆-C₆₀ aryl group, a C₁-C₆₀ heteroaryl group, a monovalent non-aromatic condensed polycyclic group, and a monovalent non-aromatic condensed heteropolycyclic group.

In one or more embodiments, the fluorescent dopant may include a compound represented by Formula 501A or 501B,

xd4 in Formula 501A may be 3, 4, 5, or 6,

xd4 in Formula 501B may be 2, 3, or 4, and

R₅₀₁ and R₅₀₂ in Formula 501B may each be selected from a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, a dibenzothiophenyl group, and a dibenzosilolyl group, each substituted with at least one Z₁₁, but embodiments of the present disclosure are not limited thereto.

In one or more embodiments, the fluorescent dopant may include at least one selected from Compounds FD(1) to FD(16) and FD1 to FD13:

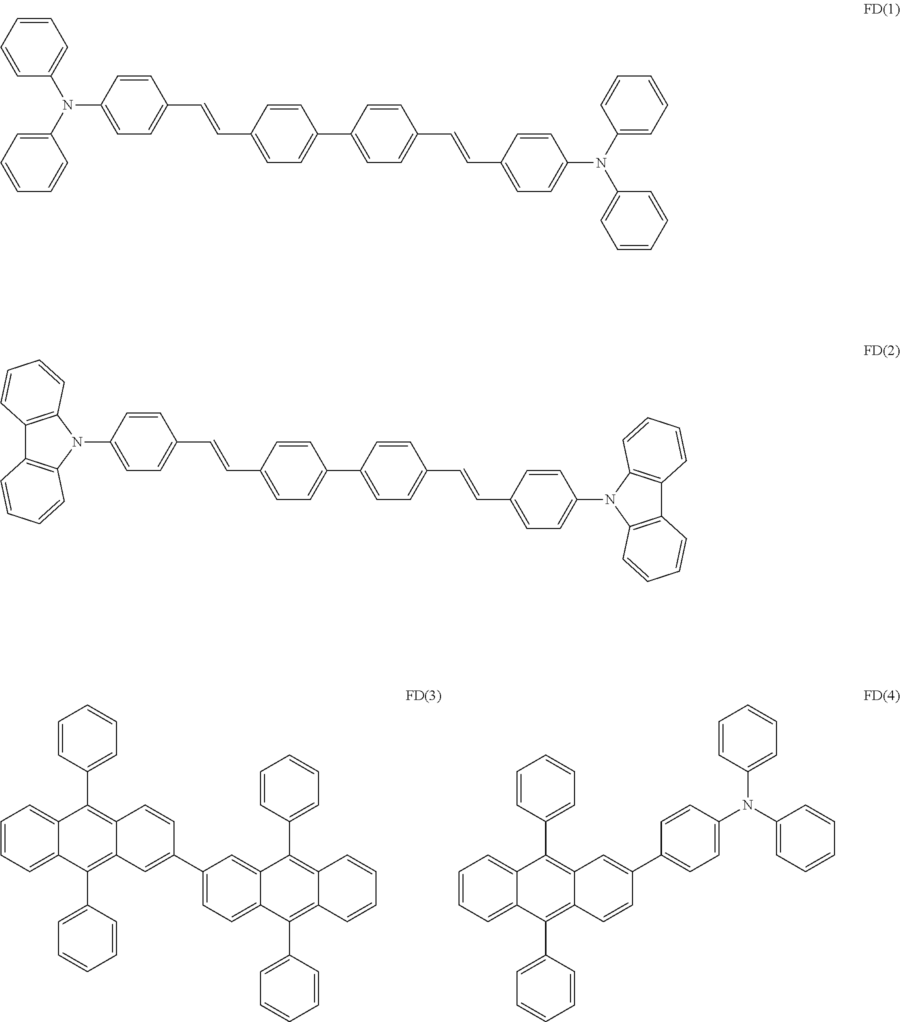

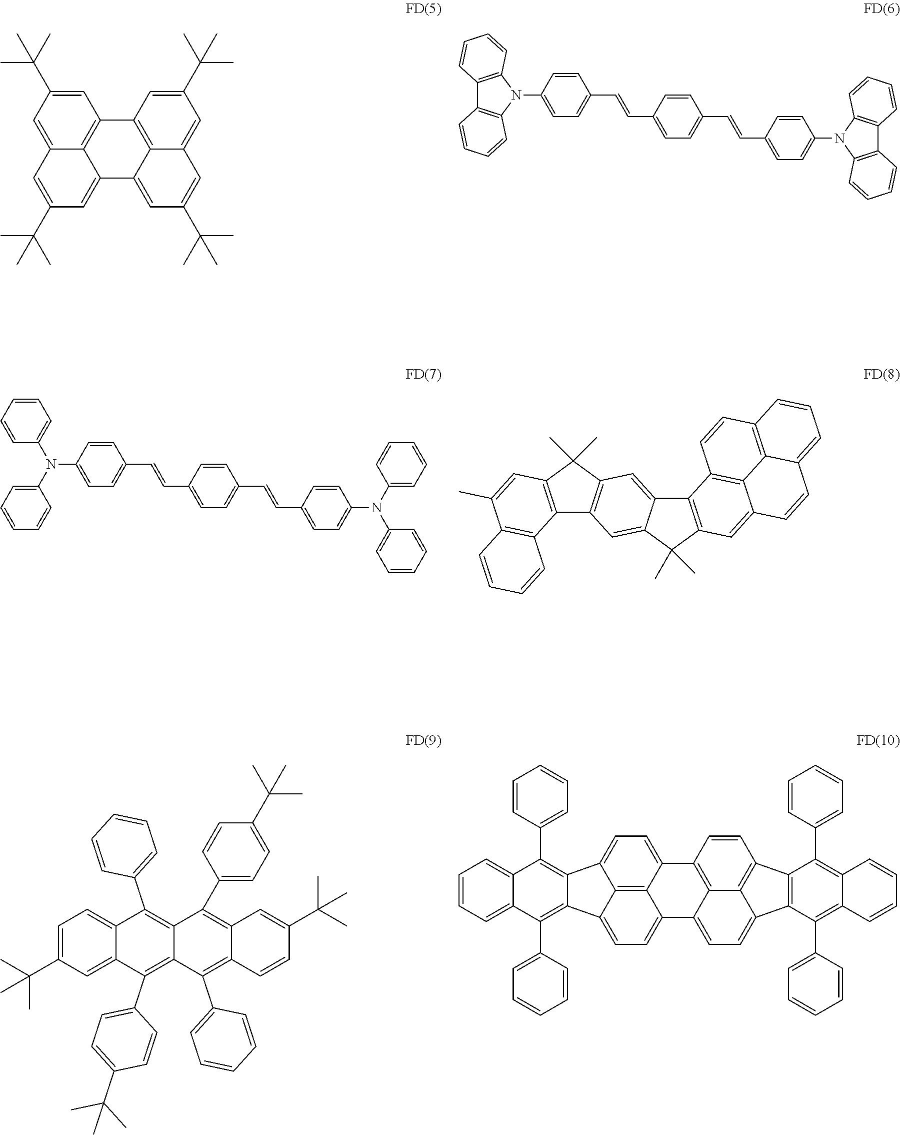

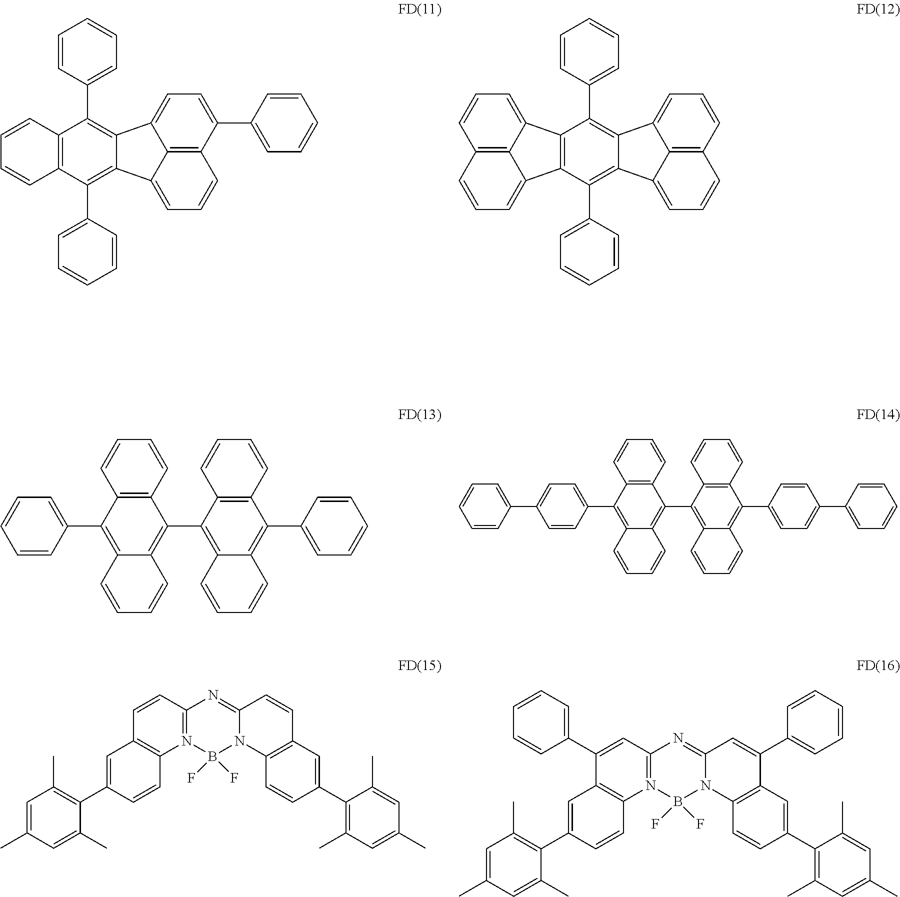

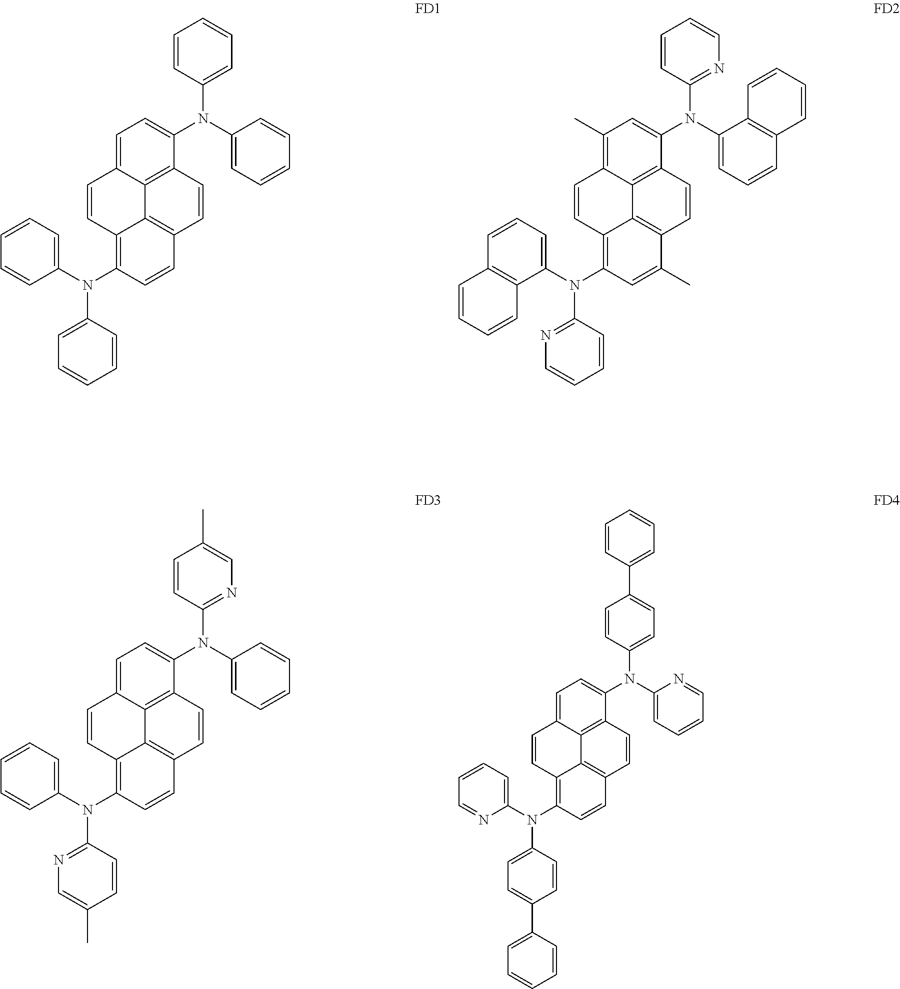 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1 ; c1ccc(-c2ccc(N(c3ccccn3)c3ccc4ccc5c(N(c6ccc(-c7ccccc7)cc6)c6ccccn6)ccc6ccc3c4c65)cc2)cc1]

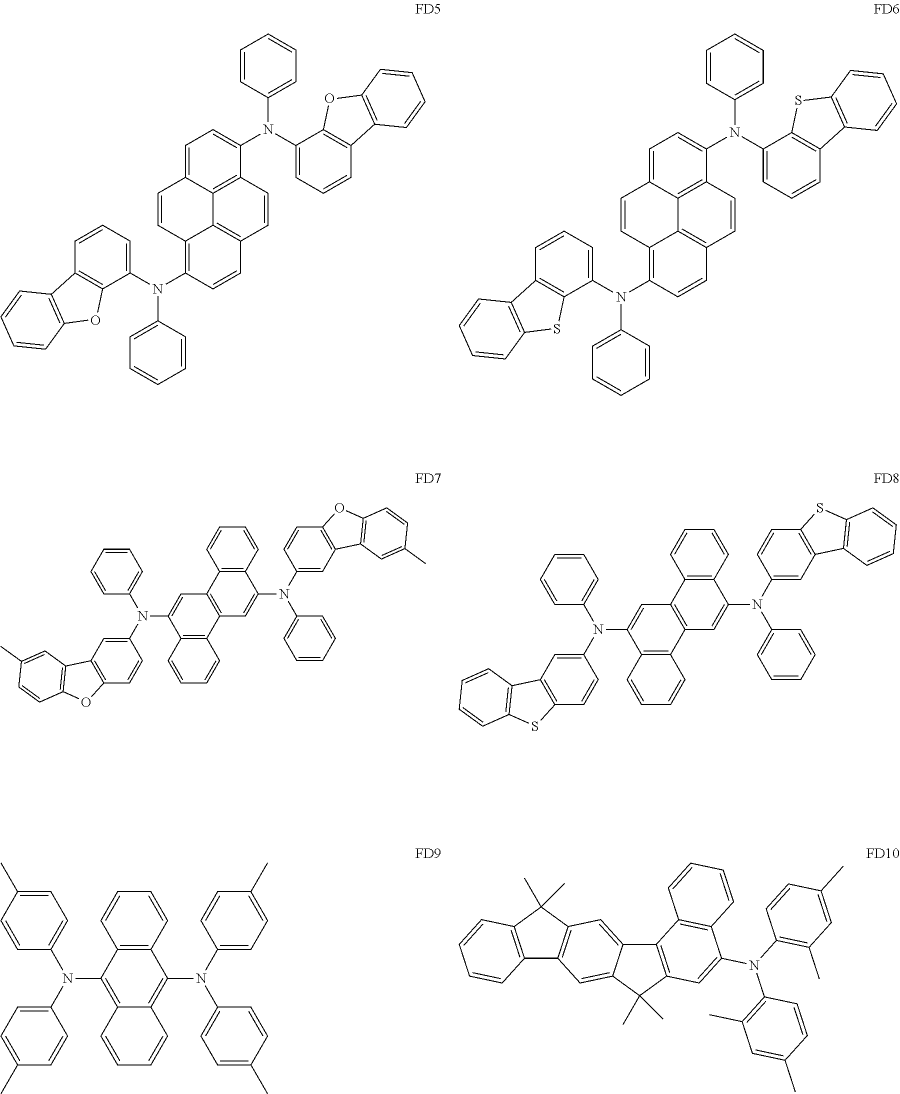

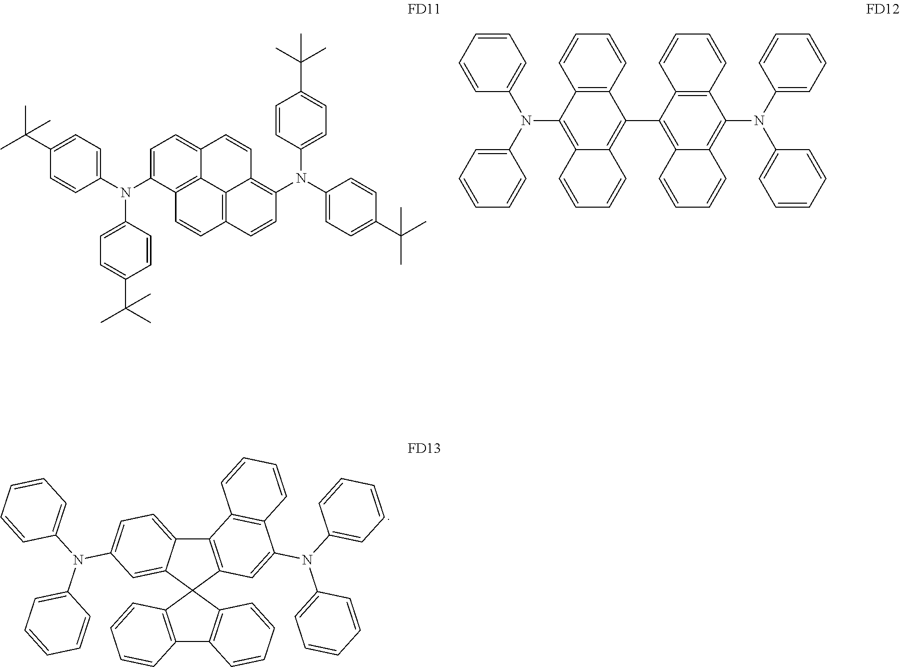 [SMILES: CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1 ; c1ccc(N(c2ccccc2)c2c3ccccc3c(-c3c4ccccc4c(N(c4ccccc4)c4ccccc4)c4ccccc34)c3ccccc23)cc1 ; c1ccc(N(c2ccccc2)c2ccc3c(c2)C2(c4ccccc4-c4ccccc42)c2cc(N(c4ccccc4)c4ccccc4)c4ccccc4c2-3)cc1]

The host may be selected from arbitrary hosts.

The host may have a triplet energy level of about 2.9 eV or more, for example, a triplet energy level of about 2.9 eV to about 4.5 eV. Therefore, energy transfer from the host to the auxiliary dopant and the fluorescent dopant may be effectively achieved, and the organic light-emitting device may have high efficiency.

The host may be a single compound or a mixture of two or more different compounds.

For example, the host may include at least one compound selected from a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, and a sulphonyl-containing compound.

In an embodiment, the host may include a first material and a second material.

The first material may be a hole transport host that does not include an electron transport moiety, and the second material may be an electron transport host that includes at least one electron transport moiety.

For example, the first material may include at least one π electron-depleted nitrogen-free cyclic group and may not include an electron transport moiety, and the second material may include at least one π electron-depleted nitrogen-free cyclic group and at least one electron transport moiety. The electron transport moiety may be selected from a cyano group, a π electron-depleted nitrogen-containing cyclic group, and groups represented by formulae illustrated below:

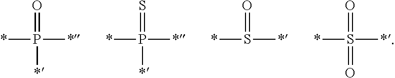

In the formulae above, *, *′, and *″ each indicate a binding site to a neighboring atom.

The term “π electron-depleted nitrogen-containing (C₁-C₃₀) cyclic group” as used herein refers to a cyclic group having, for example, 1 to 30 carbon atoms, with at least one *—N═″ moiety. Examples of the π electron-depleted nitrogen-containing (C₁-C₃₀) cyclic group include from an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinolic, a phthalazine group, a naphthyridine group, a quinoxaline group, a benzoquinoxaline group, a quinazoline group, a cinnoline group, a phenanthridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, an azadibenzosilole group, or a condensed cyclic group in which at least one selected from the groups above is condensed with any cyclic group.

The π electron-depleted nitrogen-free (C₅-C₃₀) cyclic group may be, for example, a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a benzosilolocarbazole group, a triindolobenzene group, an acridine group, or a dihydroacridine group. For example, the π electron-depleted nitrogen-free (C₅-C₃₀) cyclic group may have 5 to 30 carbon atoms, but embodiments of the present disclosure are not limited thereto.

In an embodiment, the first material may include at least one selected from a compound represented by Formula H-1(1), a compound represented by Formula H-1(2), and a compound represented by Formula H-1(3):

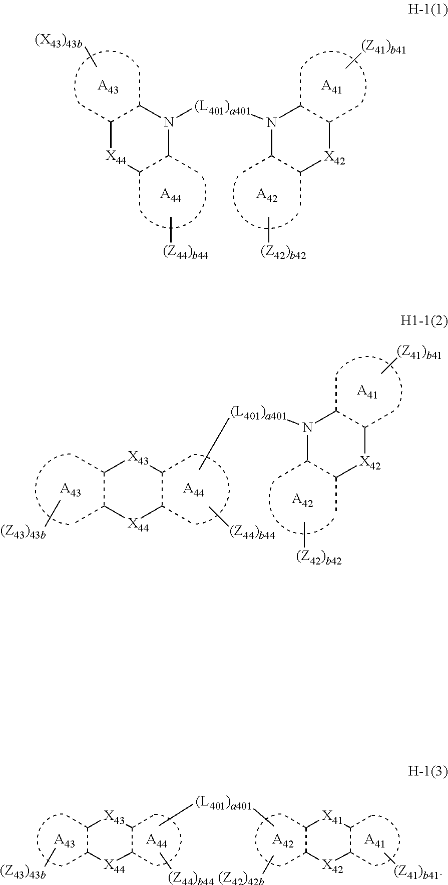

In Formulae H-1(1) to H-1(3), ring A₄₁ to A₄₄ may each independently be a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group.

For example, ring A₄₁ to A₄₄ may each independently be a benzene group, a fluorene group, a carbazole group, a dibenzofuran group, a dibenzothiophene group, or a dibenzosilole group, wherein at least one selected from ring A₄₁ and A₄₂ may be a benzene group, and at least one selected from ring A₄₃ and A₄₄ may be a benzene group.

In Formulae H-1(1) to H-1(3),

X₄₁ may be N-[(L₄₁₁)_{c411}-Z₄₁₁], C(Z₄₁₅)(Z₄₁₆), O, or S,

X₄₂ may be a single bond, N-[(L₄₁₂)_{c412}-Z₄₁₂], C(Z₄₁₇)(Z₄₁₈), O, or S,

X₄₃ may be N-[(L₄₁₃)_{c413}-Z₄₁₃], C(Z₄₁₉)(Z₄₂₀), O, or S, and

X₄₄ may be a single bond, N-[(L₄₁₄)_{c414}-Z₄₁₄], C(Z₄₂₁)(Z₄₂₂), O, or S.

L₄₀₁ and L₄₁₁ to L₄₁₄ may each independently be selected from:

a single bond; and

a π electron-depleted nitrogen-free cyclic group unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, and —Si(Q₄₀₁)(Q₄₀₂)(Q₄₀₃) (for example, a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentacene group, a rubicene group, a corozene group, an ovalene group, a pyrrole group, an isoindole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a benzosilolocarbazole group, a triindolobenzene group, an acridine group, or a dihydroacridine group, each unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, and —Si(Q₄₀₁)(Q₄₀₂)(Q₄₀₃)).

a401 and c411 to c414 may each independently indicate the number of L₄₀₁ and L₄₁₁ to L₄₁₄, respectively, and may each independently be an integer of 1 to 10. When a401 is two or more, two or more groups L₄₀₁ may be identical to or different from each other, when c411 is two or more, two or more groups L₄₁₁ may be identical to or different from each other, wherein, when c412 is two or more, two or more groups L₄₁₂ may be identical to or different from each other, when c413 is two or more, two or more groups L₄₁₃ may be identical to or different from each other, and when c414 is two or more, two or more groups L₄₁₄ may be identical to or different from each other.

For example, a401 and c411 to c414 may each independently 1, 2, or 3.

Z₄₁ to Z₄₄ and Z₄₁₁ to Z₄₂₂ may each independently be selected from:

hydrogen, deuterium, a C₁-C₁₀ alkyl group, and a C₁-C₁₀ alkoxy group; and

a π electron-depleted nitrogen-free cyclic group unsubstituted or substituted with at least one selected from deuterium, a C₁₀-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, and —Si(Q₄₀₁)(Q₄₀₂)(Q₄₀₃) (for example, a phenyl group, a biphenyl group, a terphenyl group, a tetraphenyl group, a naphthyl group, a fluorenyl group, a spiro-bifluorenyl group, a benzofluorenyl group, a dibenzofluorenyl group, a phenanthrenyl group, an anthracenyl group, a triphenylenyl group, a pyrenyl group, a chrysenyl group, a pyrrolyl group, an isoindolyl group, an indolyl group, a furanyl group, a thiophenyl group, a benzofuranyl group, a benzothiophenyl group, a benzosilolyl group, a benzocarbazolyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, and —Si(Q₄₀₁)(Q₄₀₂)(Q₄₀₃).

b41 to b44 may each independently indicate the number of Z₄₁ to Z₄₄, respectively, and may each independently be 1, 2, 3, or 4. When b41 is two or more, two or more groups Z₄₁ may be identical to or different from each other, when b42 is two or more, two or more groups Z₄₂ may be identical to or different from each other, when b43 is two or more, two or more groups Z₄₃ may be identical to or different from each other, and when b44 is two or more, two or more groups Z₄₄ may be identical to or different from each other.

For example, b41 to b44 may each independently be 1 or 2, but embodiments of the present disclosure are not limited thereto.

Q₄₀₁ to Q₄₀₃ may each independently be hydrogen, deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

In an embodiment, L₄₀₁ and L₄₁₁ to L₄₁₄ may each independently be selected from:

a single bond; and

a benzene group, a fluorene group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, an acridine group, or a dihydroacridine group, each unsubstituted or substituted with at least one selected from deuterium, a C₁-C₁₀ alkyl group, a C₁-C₁ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, and a tetraphenyl group, and

Z₄₁ to Z₄₄ and Z₄₁₁ to Z₄₂₂ may each independently be selected from:

hydrogen, deuterium, a C₁-C₁₀ alkyl group, and a C₁-C₁₀ alkoxy group; and

a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, and a tetraphenyl group,

but embodiments of the present disclosure are not limited thereto.

In an embodiment, the first material may include at least one selected from Compounds H1 to H32, but embodiments of the present disclosure are not limited thereto:

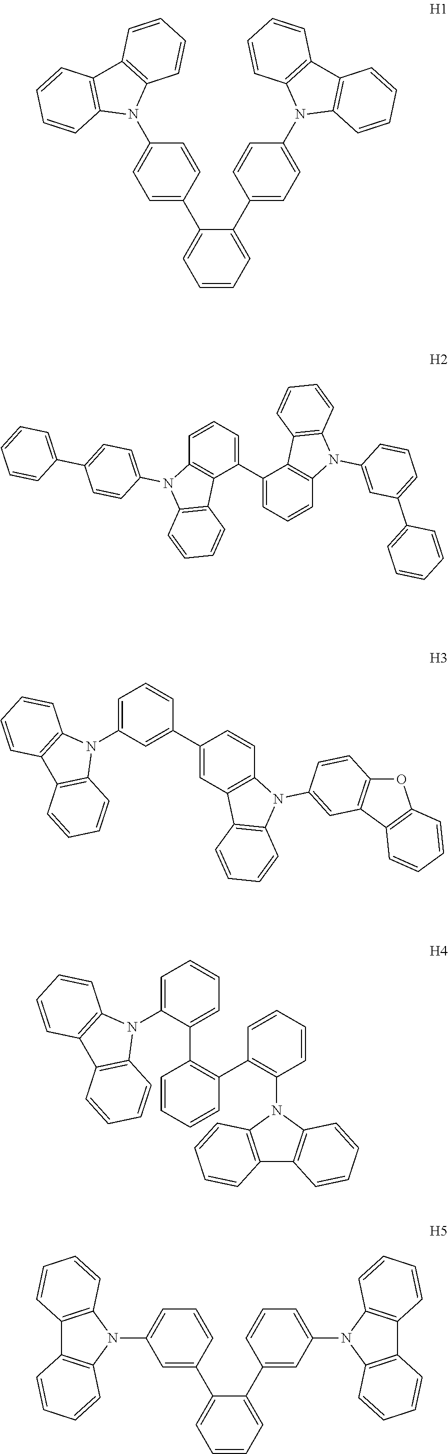 [SMILES: c1ccc(-c2ccc(-n3c4ccccc4c4ccccc43)cc2)c(-c2ccc(-n3c4ccccc4c4ccccc43)cc2)c1 ; c1ccc(-c2ccc(-n3c4ccccc4c4c(-c5cccc6c5c5ccccc5n6-c5cccc(-c6ccccc6)c5)cccc43)cc2)cc1 ; c1cc(-c2ccc3c(c2)c2ccccc2n3-c2ccc3oc4ccccc4c3c2)cc(-n2c3ccccc3c3ccccc32)c1 ; c1ccc(-c2ccccc2-n2c3ccccc3c3ccccc32)c(-c2ccccc2-n2c3ccccc3c3ccccc32)c1 ; c1cc(-c2ccccc2-c2cccc(-n3c4ccccc4c4ccccc43)c2)cc(-n2c3ccccc3c3ccccc32)c1]

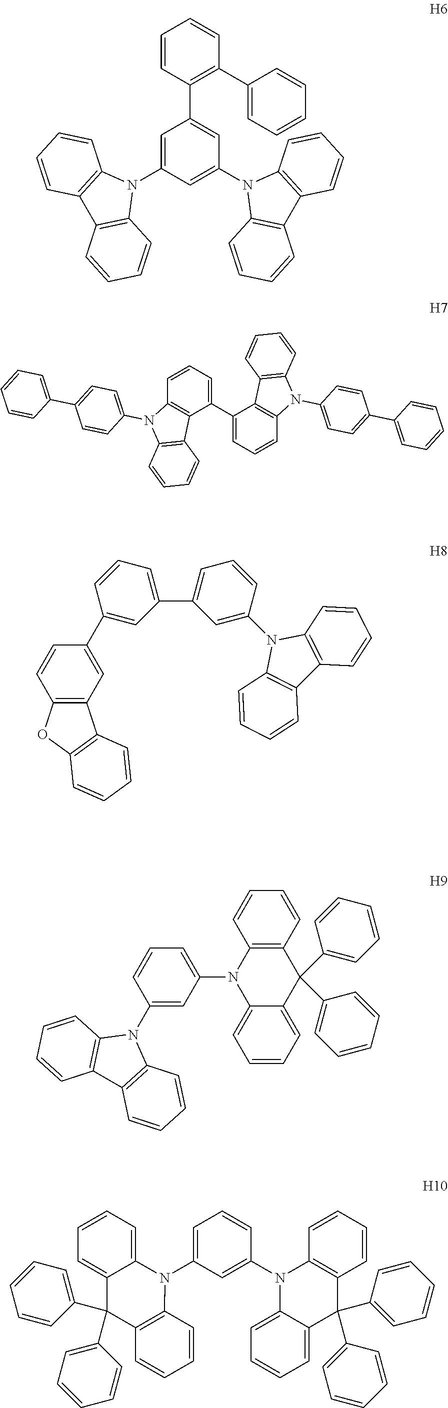 [SMILES: c1ccc(-c2ccccc2-c2cc(-n3c4ccccc4c4ccccc43)cc(-n3c4ccccc4c4ccccc43)c2)cc1 ; c1ccc(-c2ccc(-n3c4ccccc4c4c(-c5cccc6c5c5ccccc5n6-c5ccc(-c6ccccc6)cc5)cccc43)cc2)cc1 ; c1cc(-c2cccc(-n3c4ccccc4c4ccccc43)c2)cc(-c2ccc3oc4ccccc4c3c2)c1 ; c1ccc(C2(c3ccccc3)c3ccccc3N(c3cccc(-n4c5ccccc5c5ccccc54)c3)c3ccccc32)cc1 ; c1ccc(C2(c3ccccc3)c3ccccc3N(c3cccc(N4c5ccccc5C(c5ccccc5)(c5ccccc5)c5ccccc54)c3)c3ccccc32)cc1]

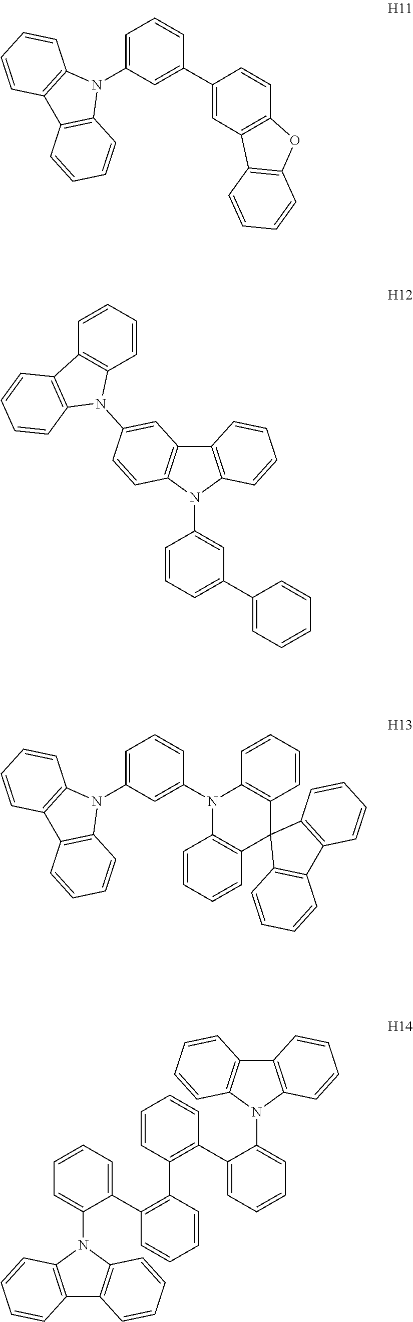

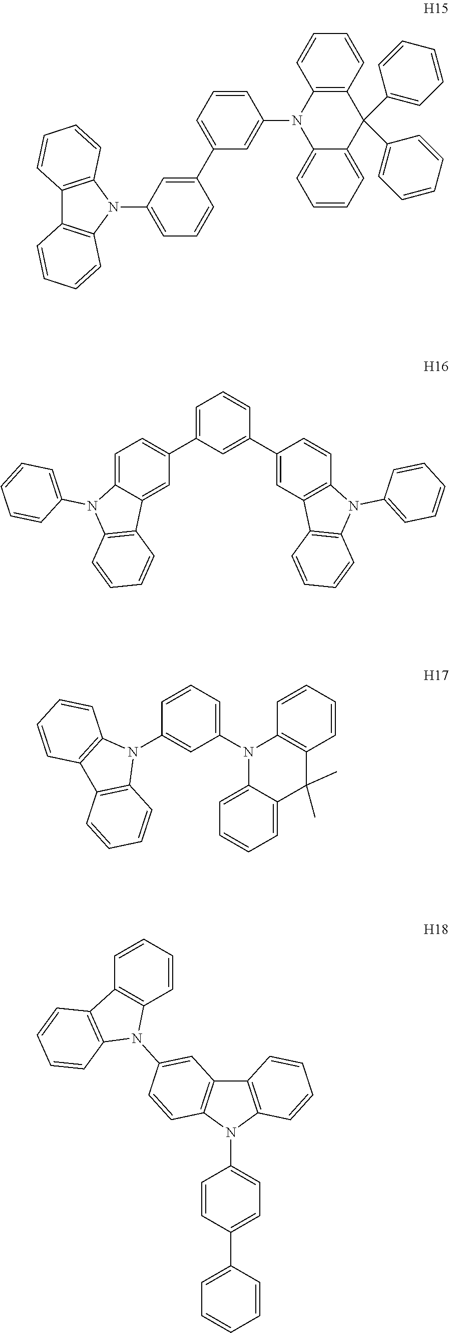

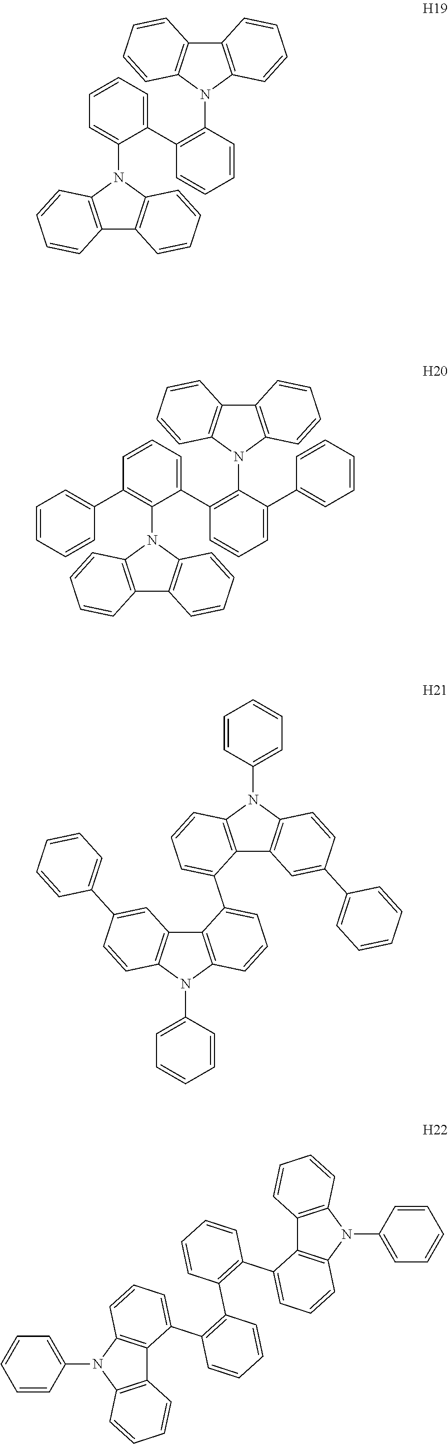 [SMILES: c1ccc(-n2c3ccccc3c3ccccc32)c(-c2ccccc2-n2c3ccccc3c3ccccc32)c1 ; c1ccc(-c2cccc(-c3cccc(-c4ccccc4)c3-n3c4ccccc4c4ccccc43)c2-n2c3ccccc3c3ccccc32)cc1 ; c1ccc(-c2ccc3c(c2)c2c(-c4cccc5c4c4cc(-c6ccccc6)ccc4n5-c4ccccc4)cccc2n3-c2ccccc2)cc1 ; c1ccc(-n2c3ccccc3c3c(-c4ccccc4-c4ccccc4-c4cccc5c4c4ccccc4n5-c4ccccc4)cccc32)cc1]

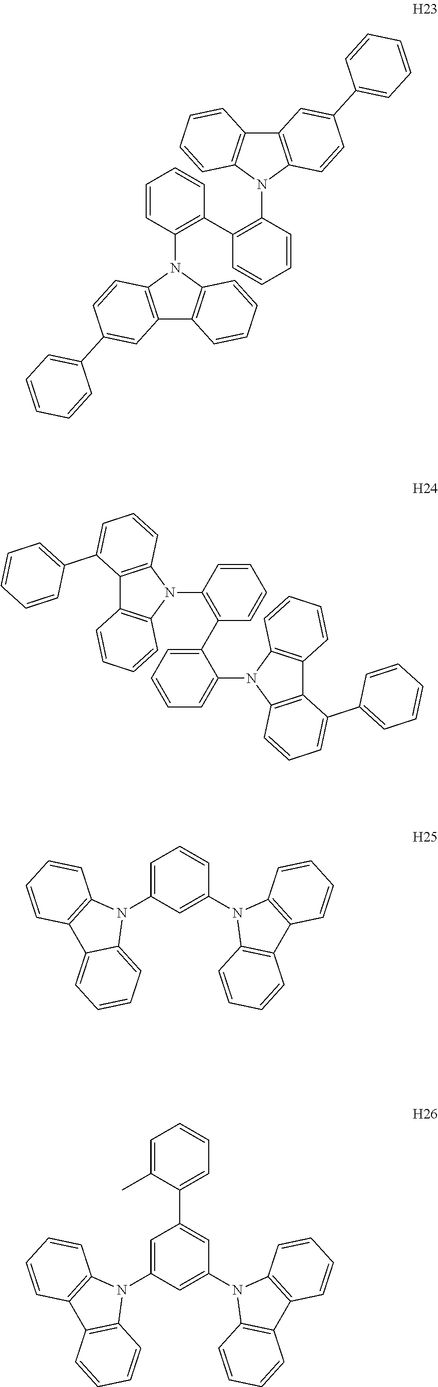 [SMILES: c1ccc(-c2ccc3c(c2)c2ccccc2n3-c2ccccc2-c2ccccc2-n2c3ccccc3c3cc(-c4ccccc4)ccc32)cc1 ; c1ccc(-c2cccc3c2c2ccccc2n3-c2ccccc2-c2ccccc2-n2c3ccccc3c3c(-c4ccccc4)cccc32)cc1 ; c1cc(-n2c3ccccc3c3ccccc32)cc(-n2c3ccccc3c3ccccc32)c1 ; Cc1ccccc1-c1cc(-n2c3ccccc3c3ccccc32)cc(-n2c3ccccc3c3ccccc32)c1]

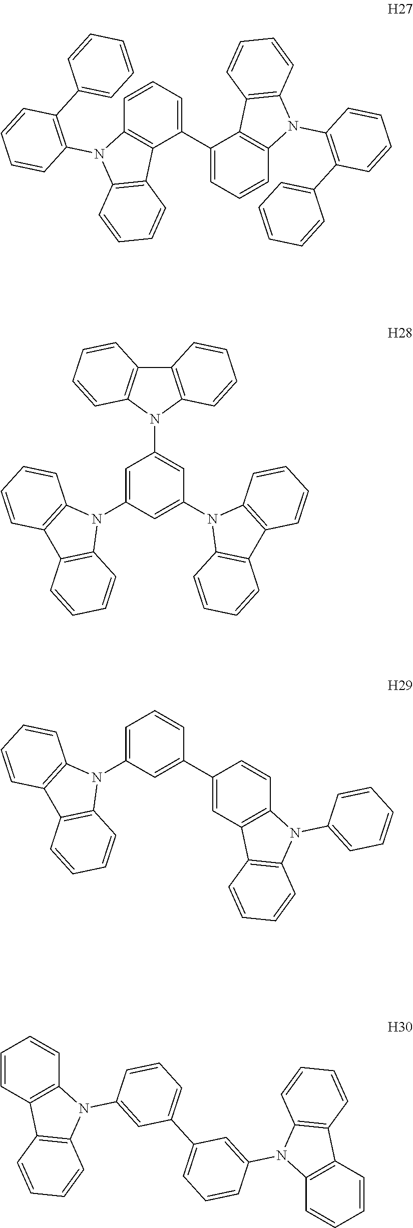

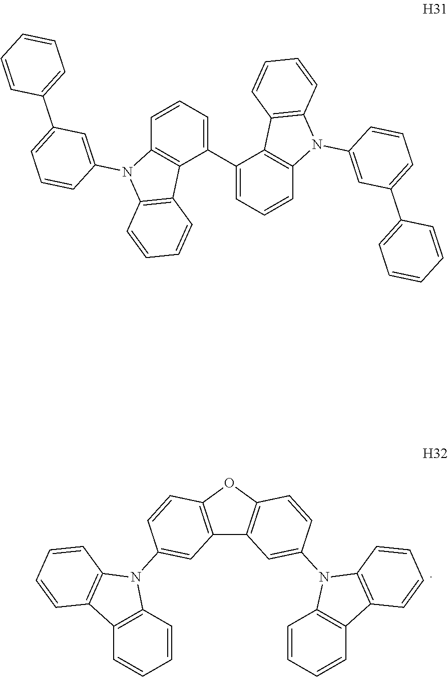 [SMILES: c1ccc(-c2cccc(-n3c4ccccc4c4c(-c5cccc6c5c5ccccc5n6-c5cccc(-c6ccccc6)c5)cccc43)c2)cc1 ; c1ccc2c(c1)c1ccccc1n2-c1ccc2oc3ccc(-n4c5ccccc5c5ccccc54)cc3c2c1 ; "."]

In an embodiment, the second material may include at least one cyano group.

In one or more embodiments, the second material may include at least one cyano group and at least one carbazole ring.

In one or more embodiments, the second material may include a compound represented by Formula E-1:

[Ar₃₀₁]_{xb11}-[(L₃₀₁)_{xb1}-R₃₀₁]_{xb21}. Formula E-1

In Formula E-1,

Ar₃₀₁ may be selected from a substituted or unsubstituted C₅-C₆₀ carbocyclic group and a substituted or unsubstituted C₁-C₆₀ heterocyclic group,

xb11 may be 1, 2, or 3, and

L₃₀₁ may be selected from a single bond, a group represented by one of the formulae illustrated below, a substituted or unsubstituted C₅-C₆₀ carbocyclic group, and a substituted or unsubstituted C₁-C₆₀ heterocyclic group, and *, *′, and *″ in the formulae each indicate a binding site to a neighboring atom:

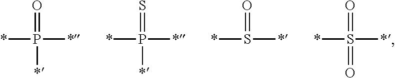

xb1 may be an integer from 1 to 5,

R₃₀₁ may be selected from hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃₋C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), —S(═O)(Q₃₀₁), —P(═O)(Q₃₀₁)(Q₃₀₂), and —P(═S)(Q₃₀₁)(Q₃₀₂),

xb21 may be an integer from 1 to 5,

Q₃₀₁ to Q₃₀₃ may each independently be selected from a C₁-C₁₀ alkyl group, a C₁-C₁₀ alkoxy group, a phenyl group, a biphenyl group, a terphenyl group, and a naphthyl group, and

at least one of Condition 1 to Condition 3 is satisfied:

Condition 1

at least one of Ar₃₀₁, L₃₀₁, and R₃₀₁ in Formula E-1 each independently includes a π electron-depleted nitrogen-containing cyclic group;

Condition 2

at least one of L₃₀₁ in Formula E-1 is a group represented by one of formulae illustrated below; and

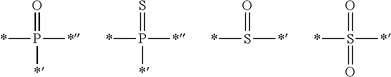

Condition 3

at least one of R₃₀₁ in Formula E-1 is selected from a cyano group, —S(═O)₂(Q₃₀₁), —S(═O)(Q₃₀₁), —P(═O)(Q₃₀₁)(Q₃₀₂), and —P(═S)(Q₃₀₁)(Q₃₀₂).

In one or more embodiments, the second material may include at least one of a compound represented by Formula E-1(1), a compound represented by Formula E-1(2), and a compound represented by Formula E-1(3):

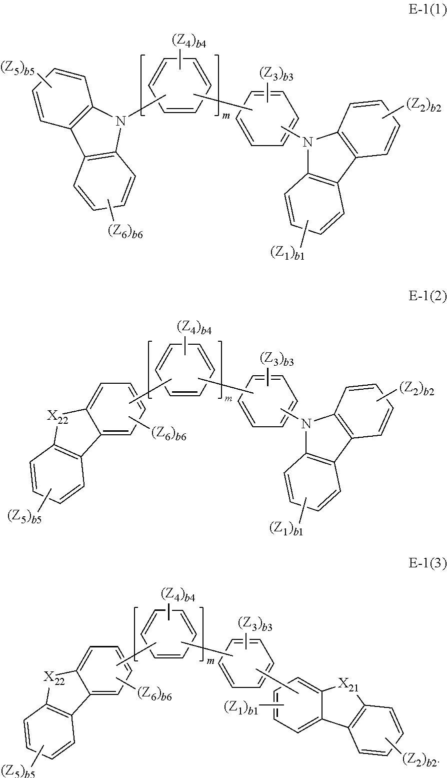

In Formulae E-1(1) to E-1(3), X₂₁ may be N(Z₇), O, or S, and X₂₂ may be N(Z₈), O, or S.

Z₁ to Z₈ may each independently be selected from:

hydrogen, deuterium, or a cyano group (CN); or

a C₁-C₂₀ alkyl group, a phenyl group, a biphenyl group, a terphenyl group, a dibenzofuranyl group, or a dibenzothiophenyl group, each unsubstituted or substituted with at least one selected from deuterium, a cyano group, a C₁-C₂₀ alkyl group, a phenyl group, and a biphenyl group.

For example, Z₁ to Z₈ in Formulae E-1(1) to E-1(3) may each independently be selected from:

hydrogen, deuterium, or a cyano group; or

a C₃-C₁₀ alkyl group, a phenyl group, a biphenyl group, a terphenyl group, a dibenzofuranyl group, or a dibenzothiophenyl group, each unsubstituted or substituted with at least one selected from deuterium, a cyano group, a C₃-C₁₀ alkyl group, a phenyl group, and a biphenyl group.

In an embodiment, Z₁ to Z₈ in Formulae E-1(1) to E-1(3) may each independently be selected from:

hydrogen, deuterium, or a cyano group; or

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, a biphenyl group, or a terphenyl group, each unsubstituted or substituted with at least one selected from deuterium, a cyano group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a biphenyl group.

In Formulae E-1(1) to E-1(3), b1 to b6 indicate the number of groups Z₁ to groups Z₆, respectively, and may each independently be 1, 2, or 3. When each of b1 to b6 is two or more, two or more groups Z₁ to groups Z₆ may be identical to or different from each other.

In one or more embodiments, in Formulae E-1 (1) to E-1(3), at least one of groups Z₁ in the number of b1, groups Z₂ in the number of b2, groups Z₃ in the number of b3, groups Z₄ in the number of b4, groups Z₅ in the number of b5, and groups R₆ in the number of b6 may be a cyano group. That is, Formulae E-1(1) to E-1(3) may essentially include at least one cyano group.

For example, the number of cyano groups included in the compound represented by Formula E-1(1), the number of cyano groups included in the compound represented by Formula E-1(2), and the number of cyano groups included in the compound represented by Formula E-1(3) may each independently be 1, 2, or 3, but embodiments of the present disclosure are not limited thereto.

In an embodiment, in Formulae E-1(1) to E-1(3),

at least one of groups Z₁ in the number of b1 and groups Z₂ in the number of b2 may be a cyano group,

at least one of groups Z₃ in the number of b3 and groups Z₄ in the number of b4 may be a cyano group,

at least one of groups Z₅ in the number of b5 and groups Z₆ in the number of b6 may be a cyano group,

at least one of groups Z₁ in the number of b1 and groups Z₂ in the number of b2 may be a cyano group, and at least one of groups Z₃ in the number of b3 and groups Z₄ in the number of b4 may be a cyano group,

at least one of groups Z₁ in the number of b1 and groups Z₂ in the number of b2 may be a cyano group, and at least one of groups Z₅ in the number of b5 and groups Z₆ in the number of b6 may be a cyano group,

at least one of groups Z₃ in the number of b3 and groups Z₄ in the number of b4 may be a cyano group, and at least one of groups Z₅ in the number of b5 and groups Z₆ in the number of b6 may be a cyano group, or

at least one of groups Z₁ in the number of b1 and groups Z₂ in the number of b2 may be a cyano group, and at least one of groups Z₃ in the number of b3 and groups Z₄ in the number of b4 may be a cyano group, and at least one of groups Z₅ in the number of b5 and groups Z₆ in the number of b6 may be a cyano group.

In Formulae E-1(1) to E-1(3), m may be 0 or 1.

In an embodiment, a group represented by in

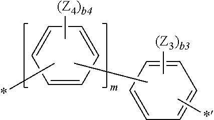

Formulae E-1(1) to E-1(3) may be one of groups represented by Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9:

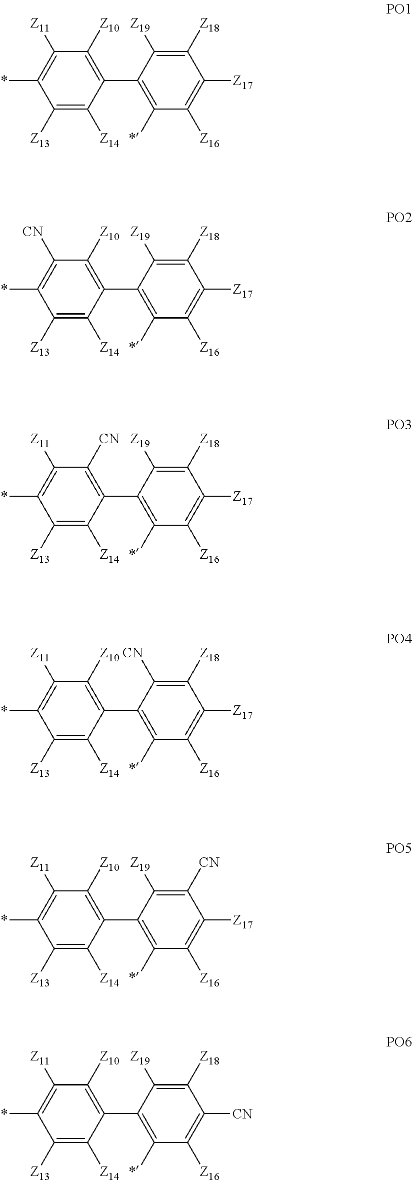

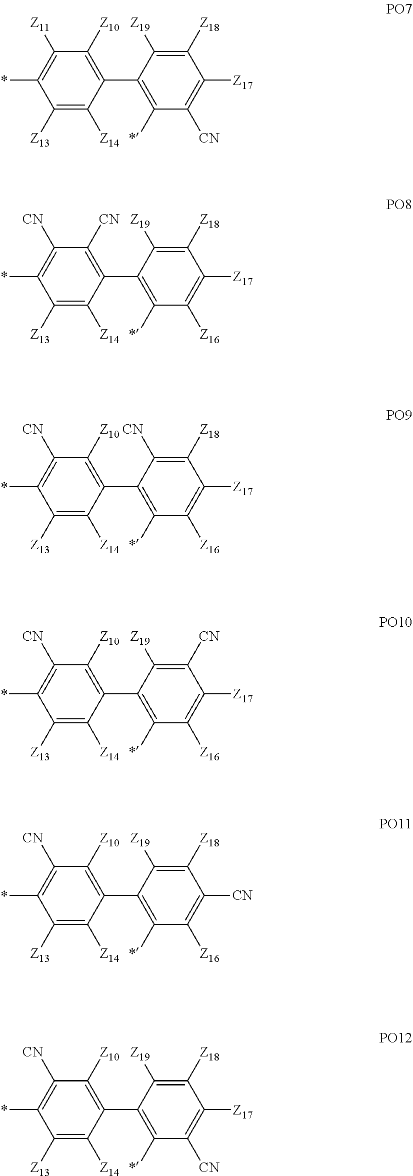

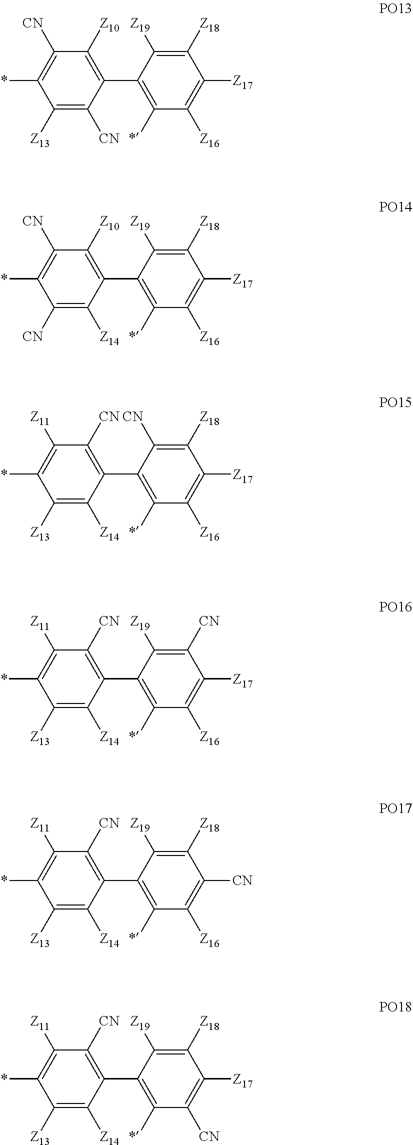

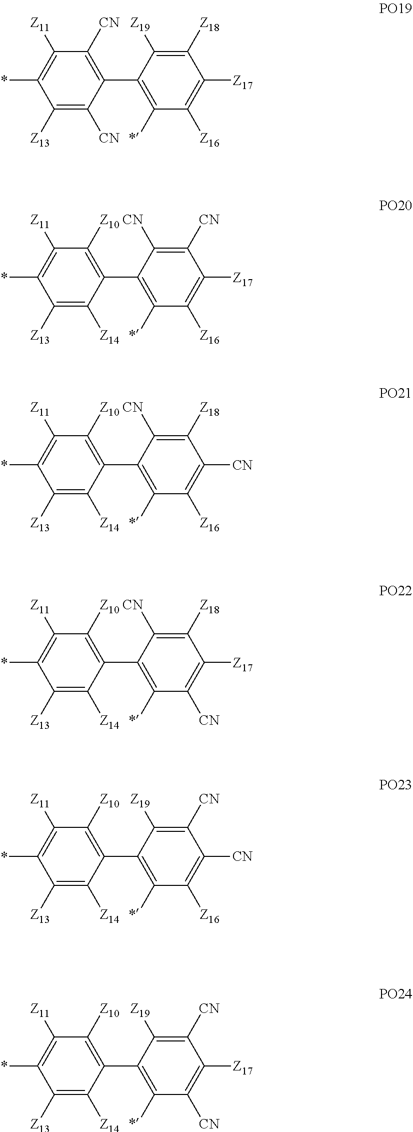

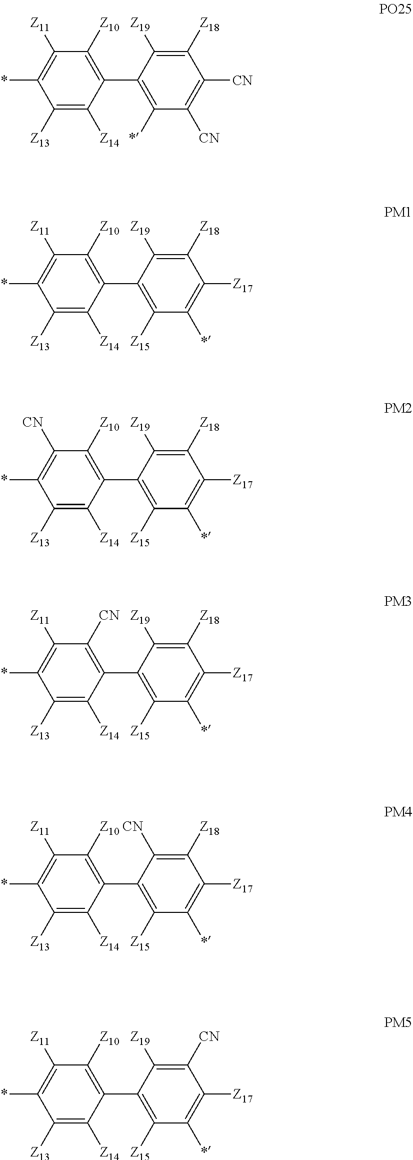

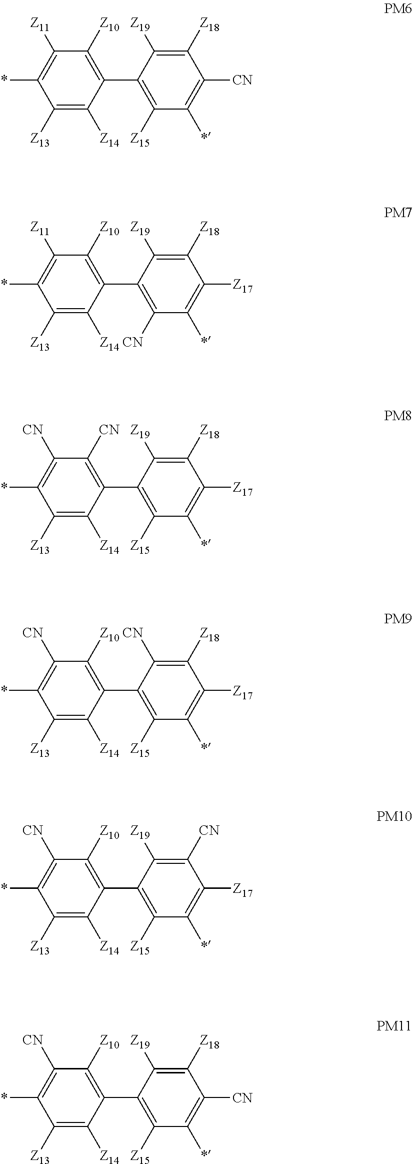

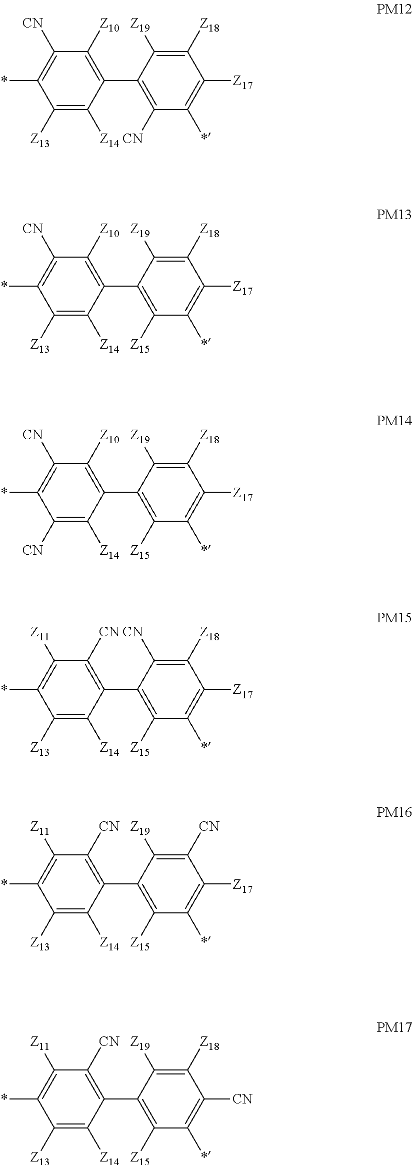

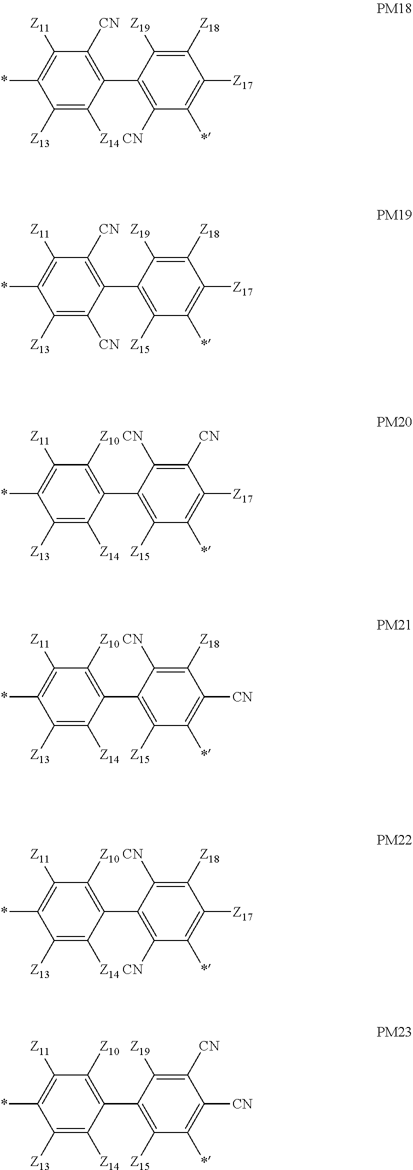

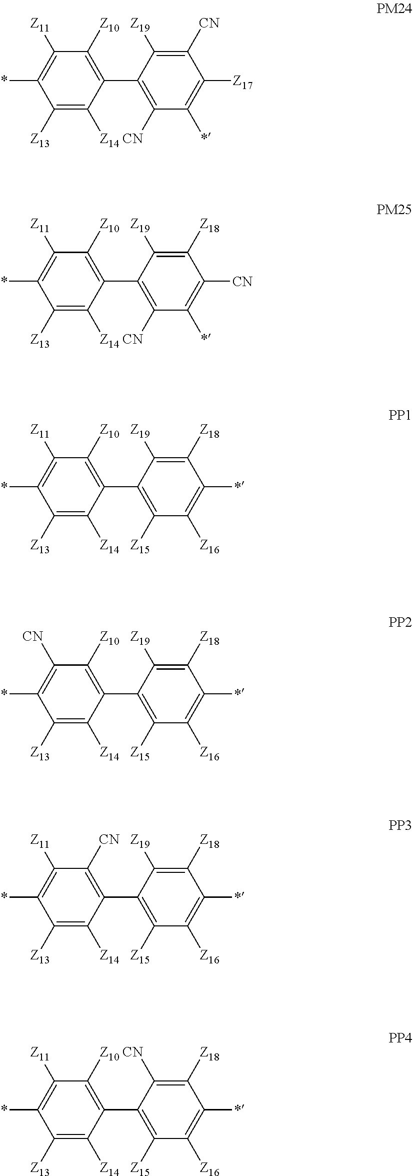

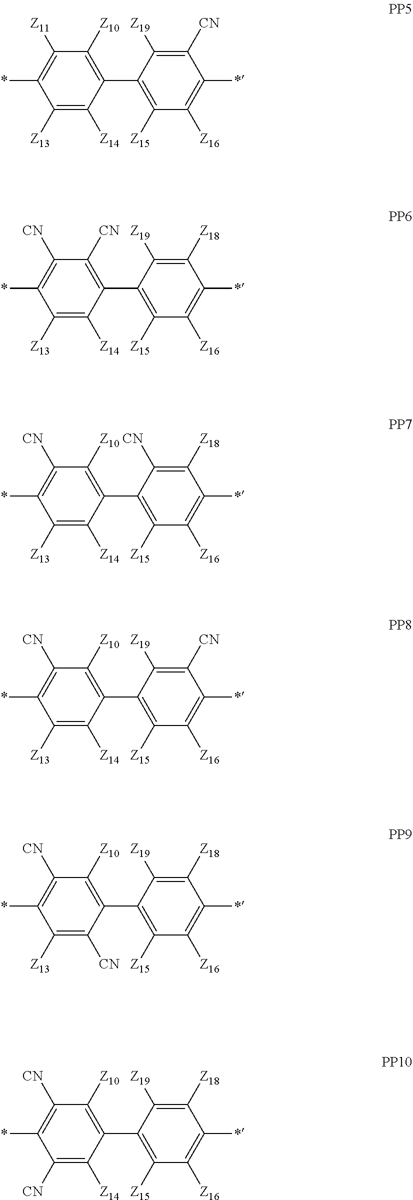

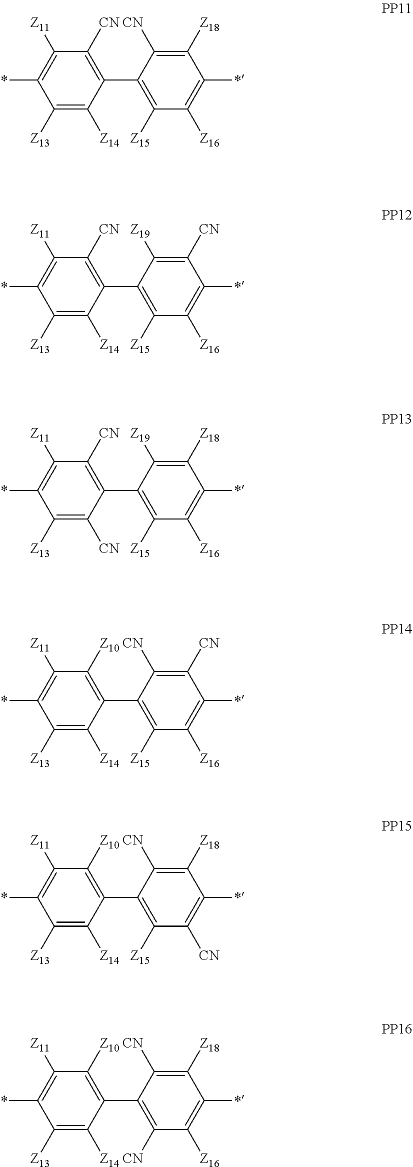

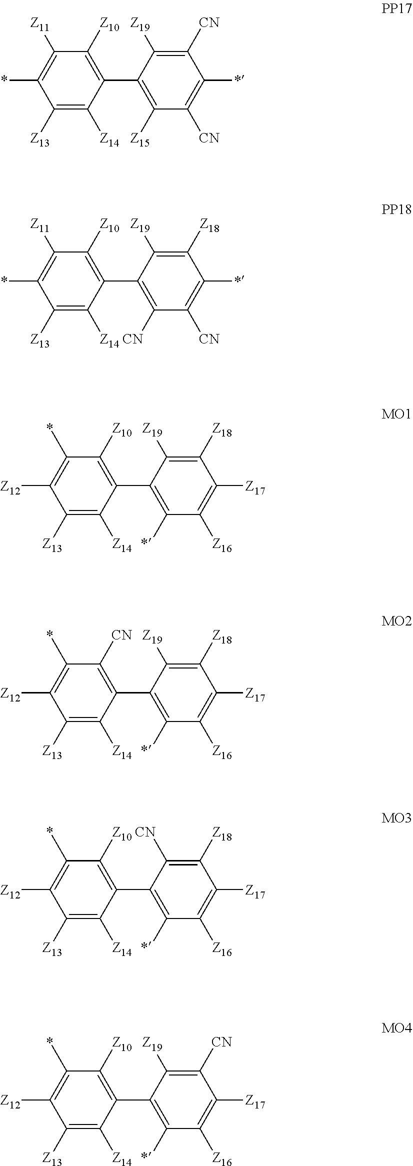

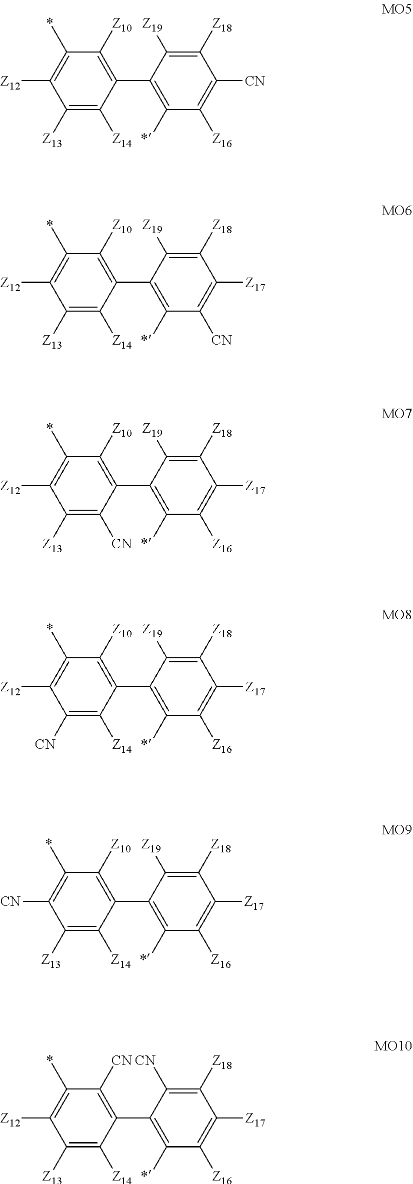

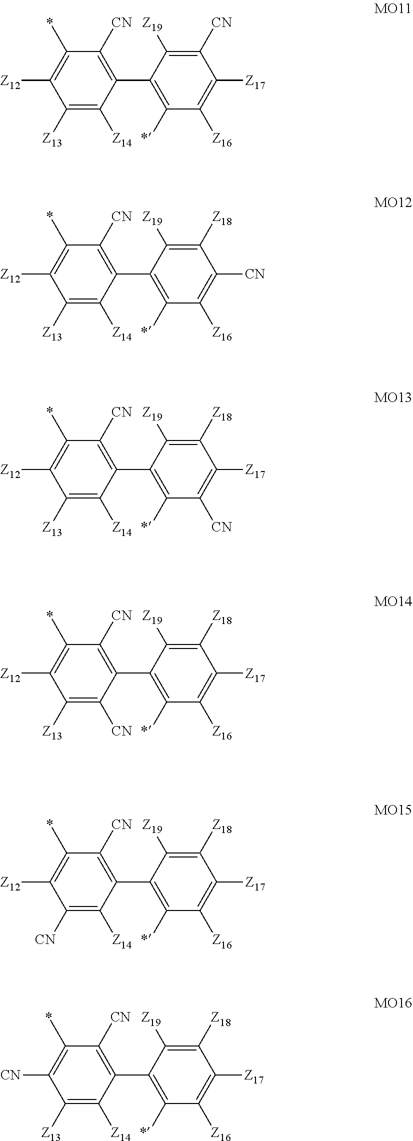

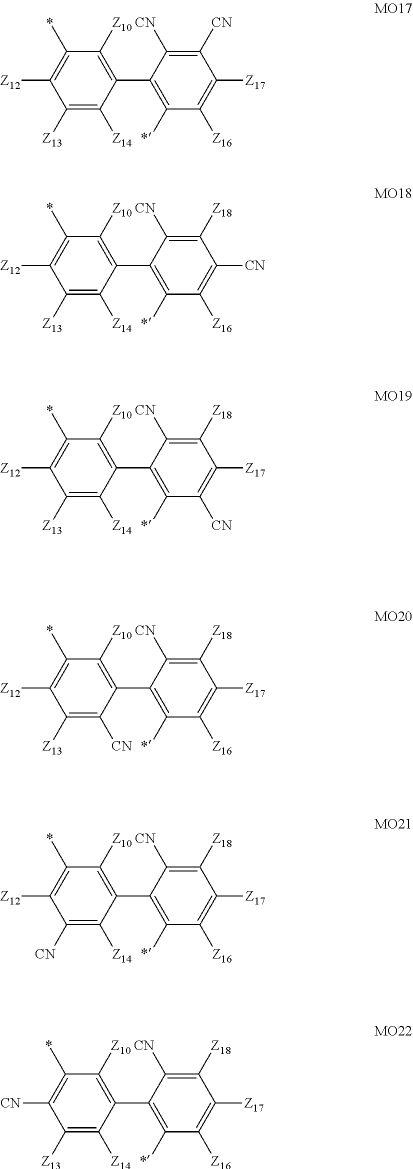

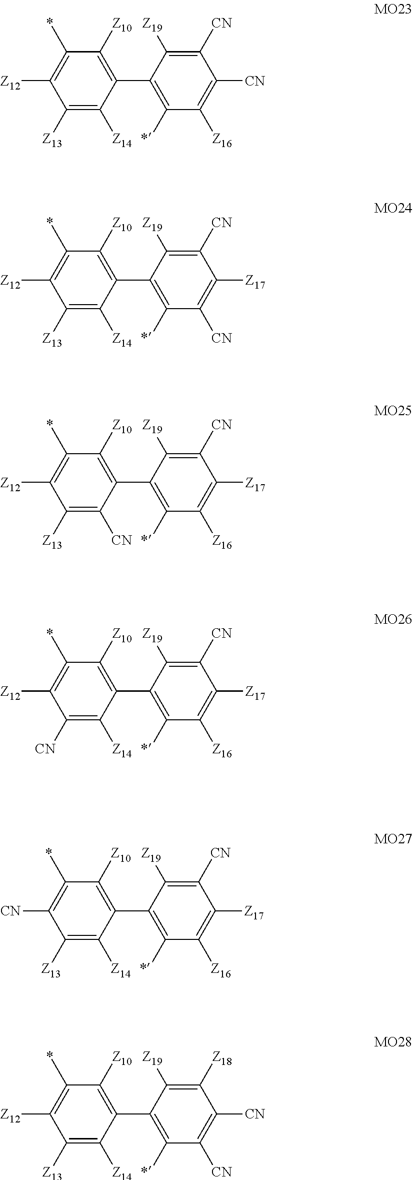

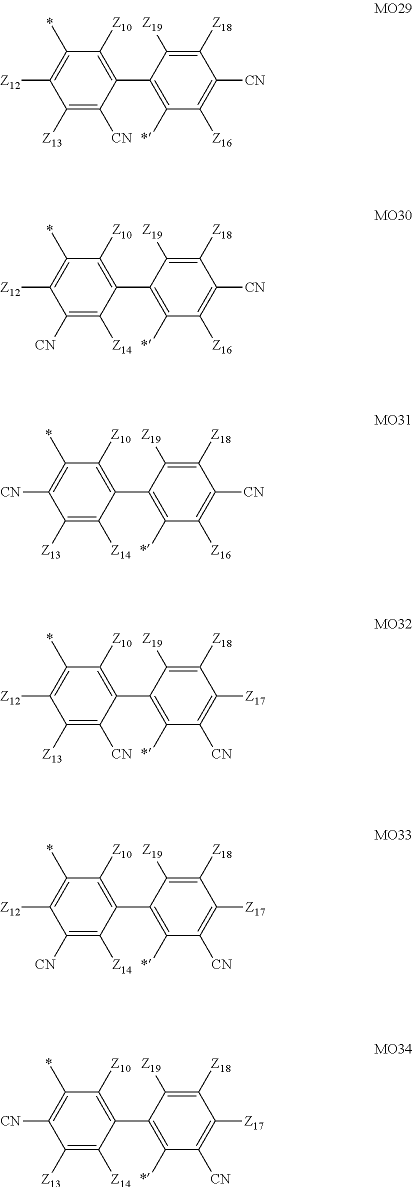

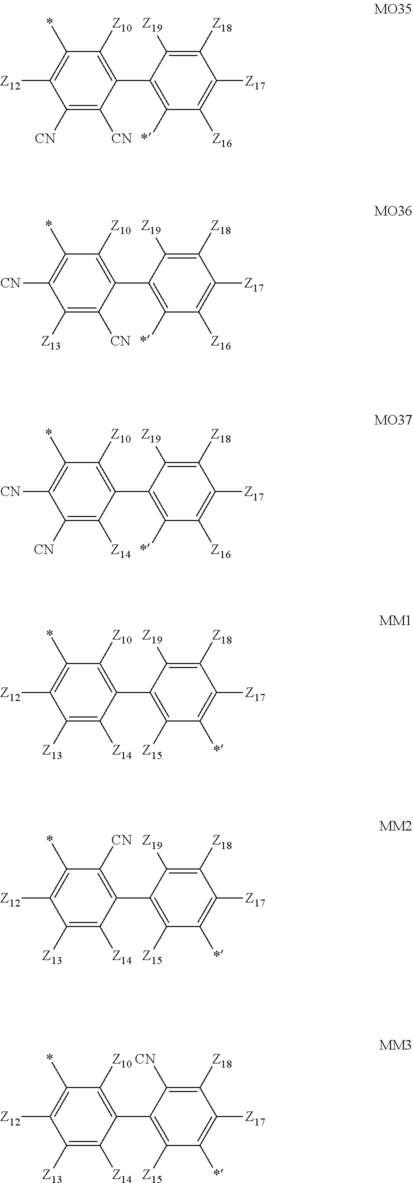

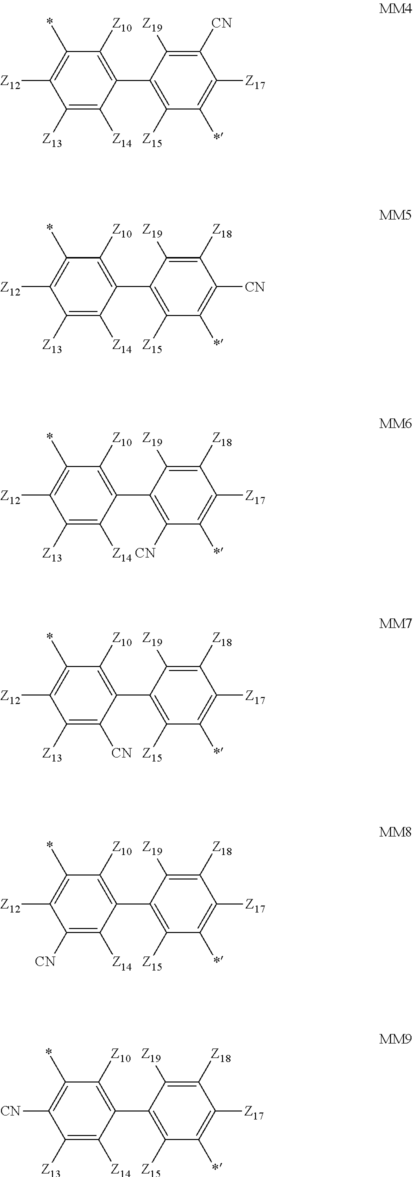

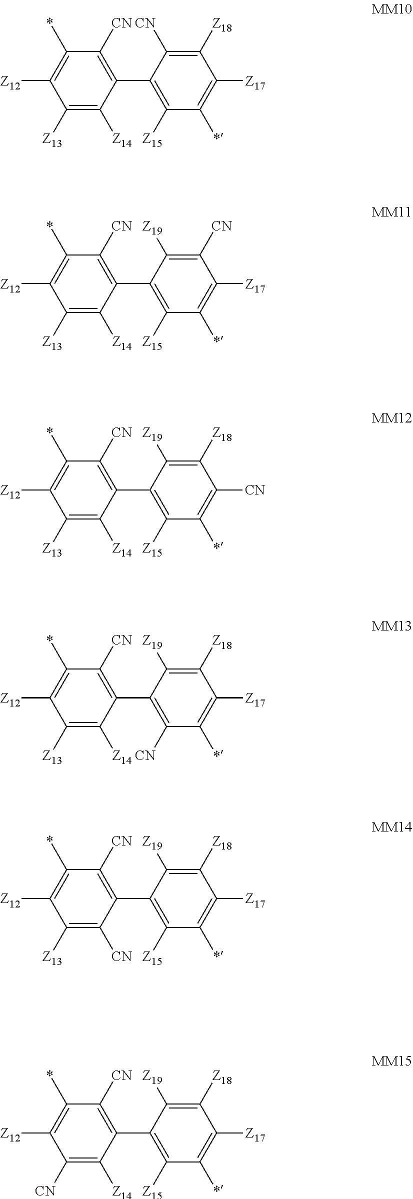

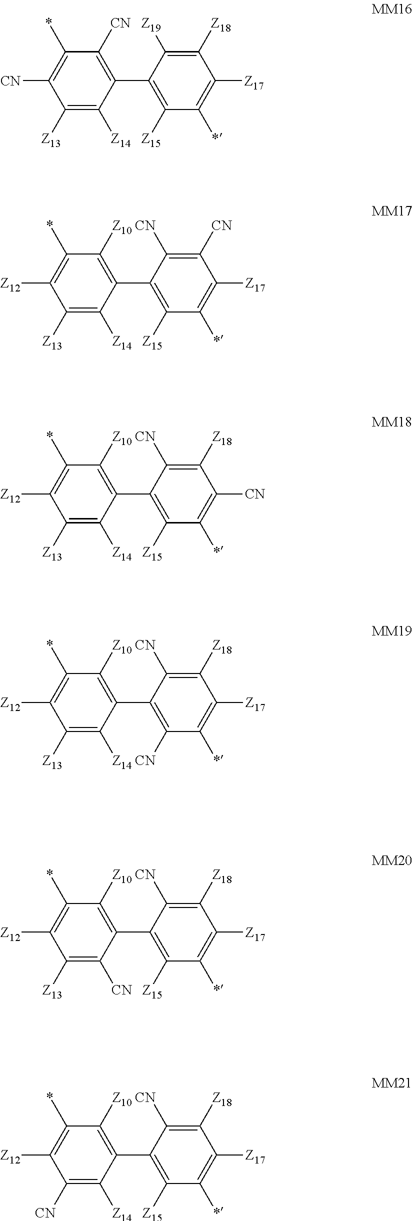

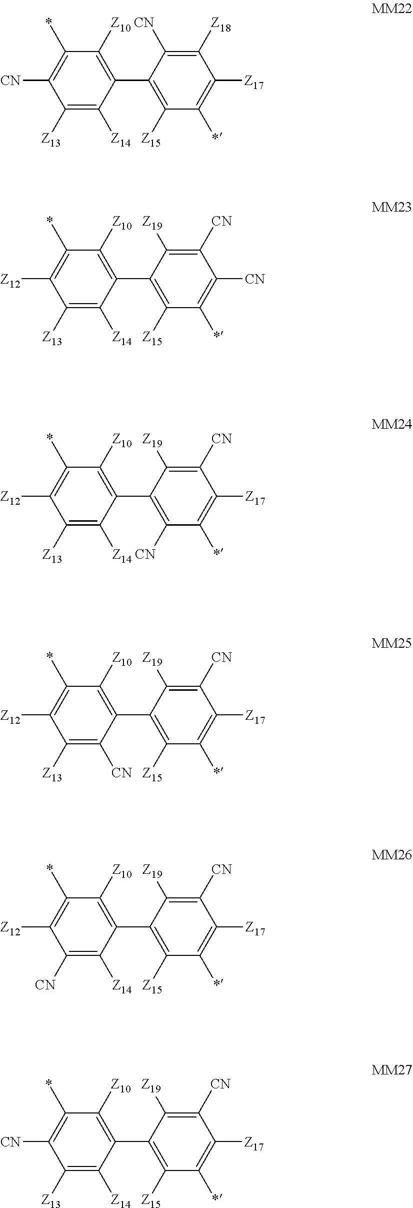

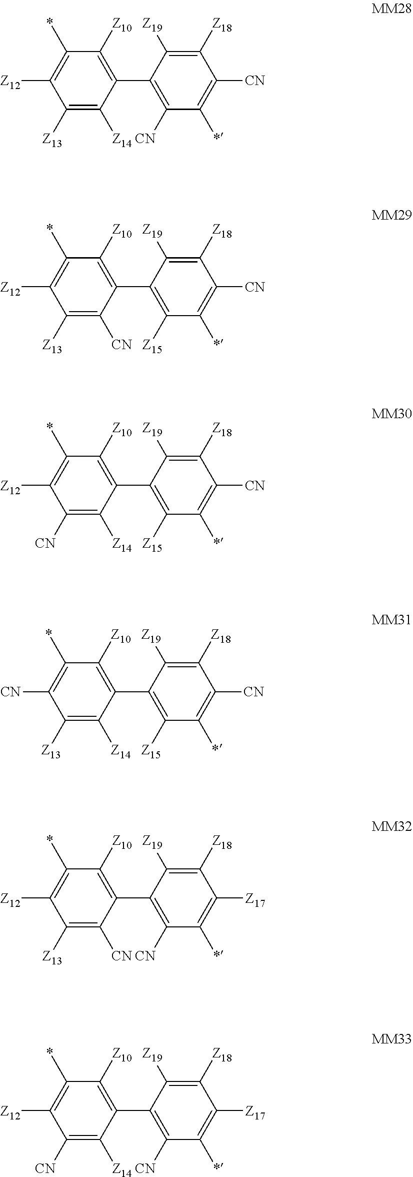

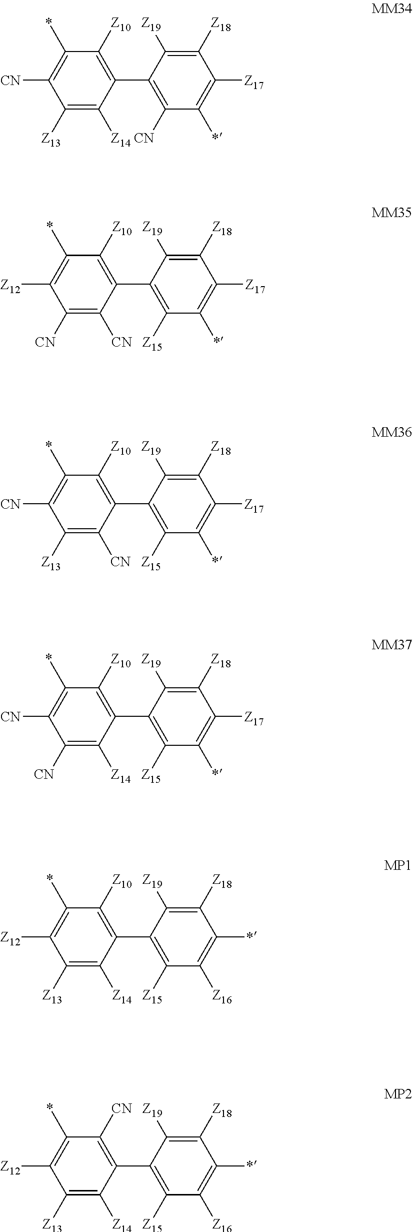

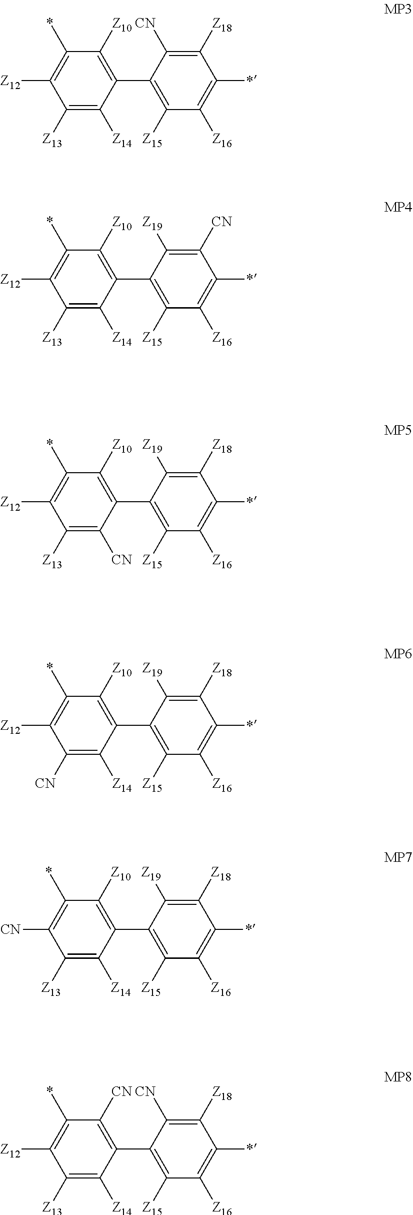

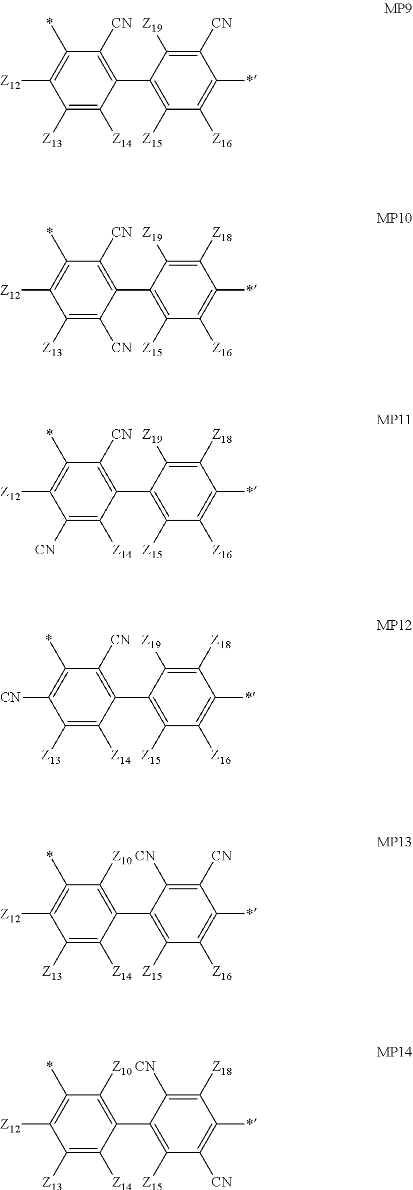

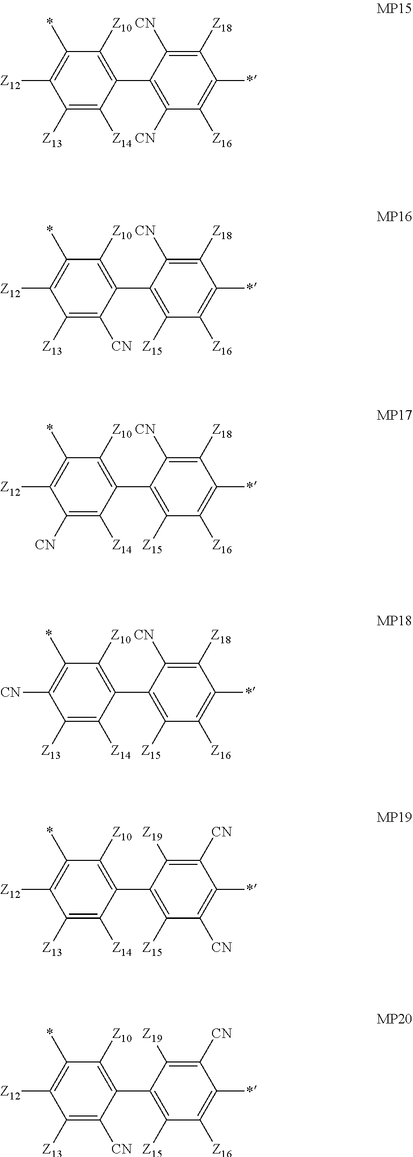

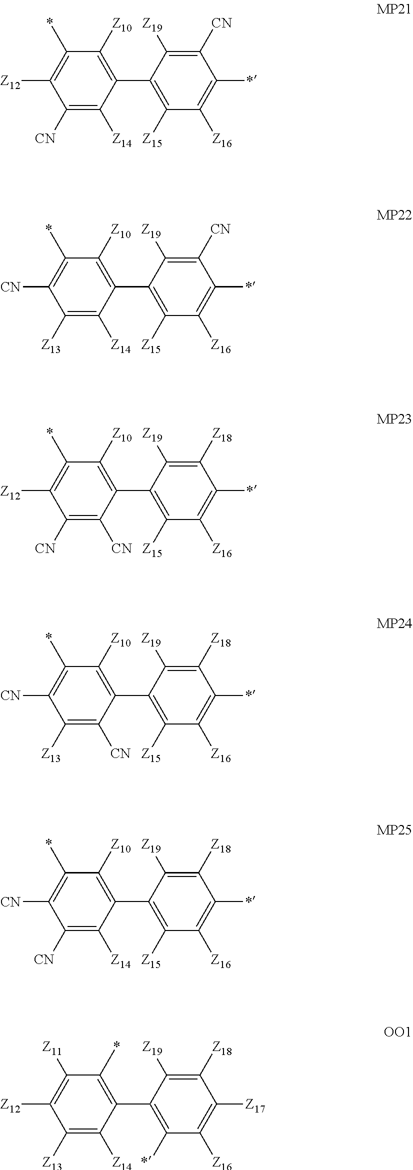

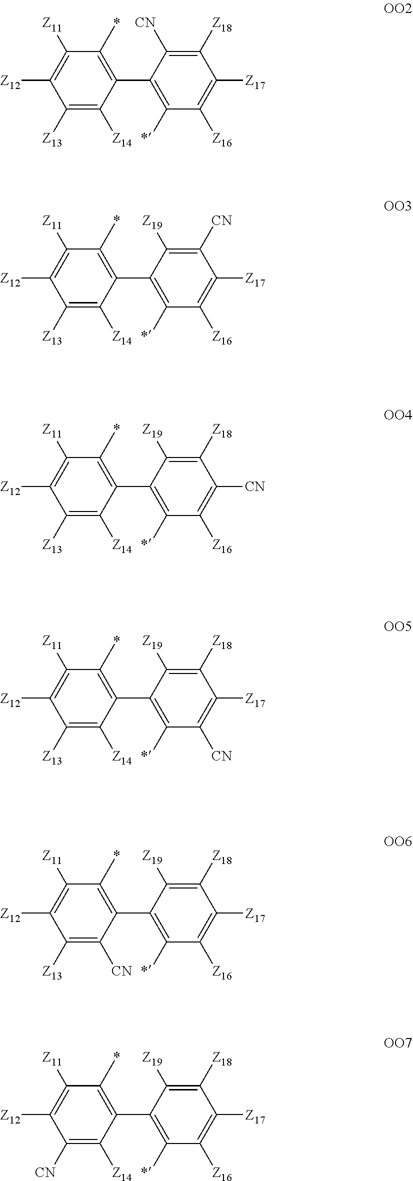

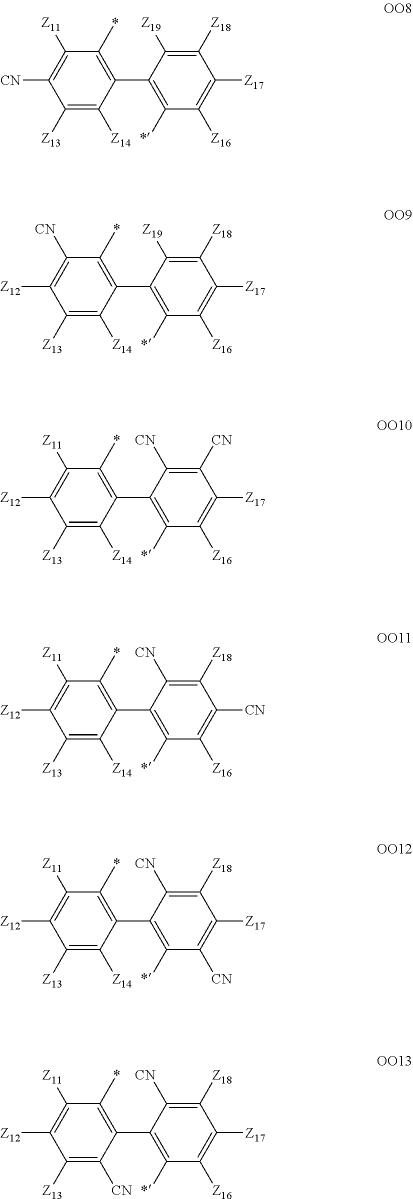

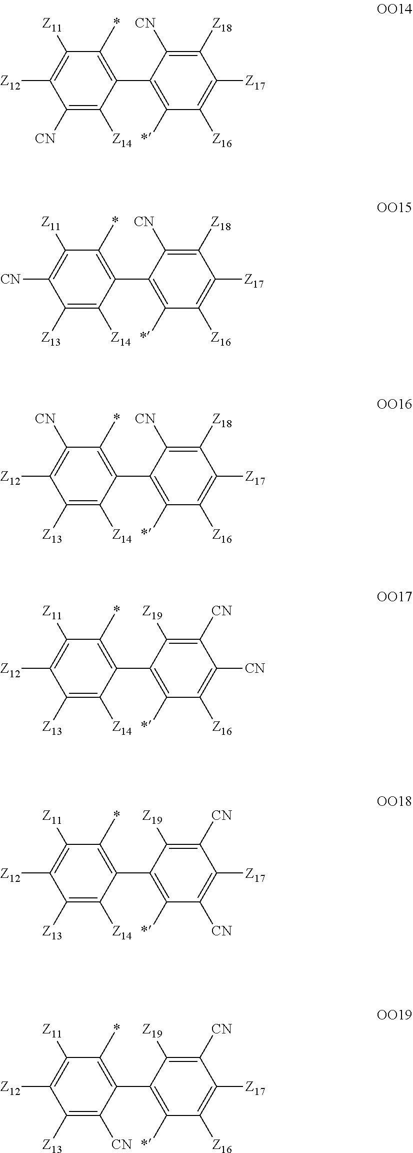

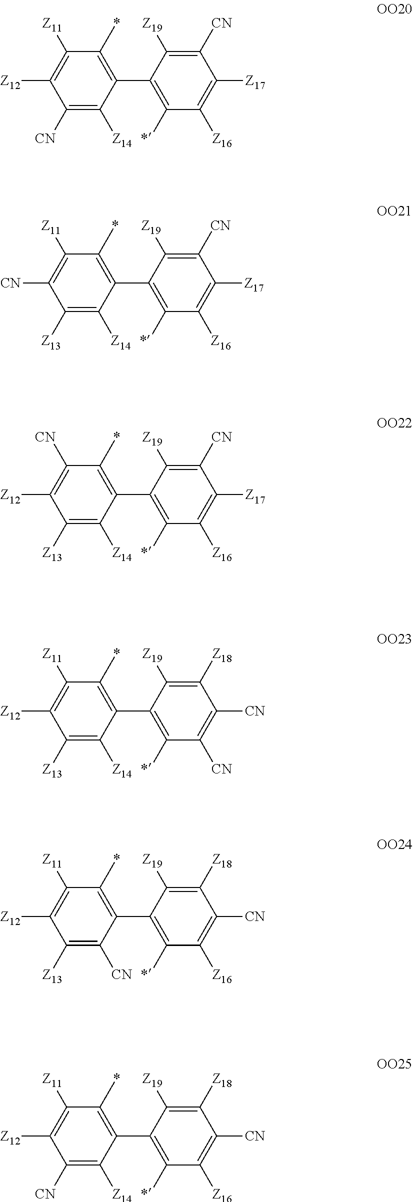

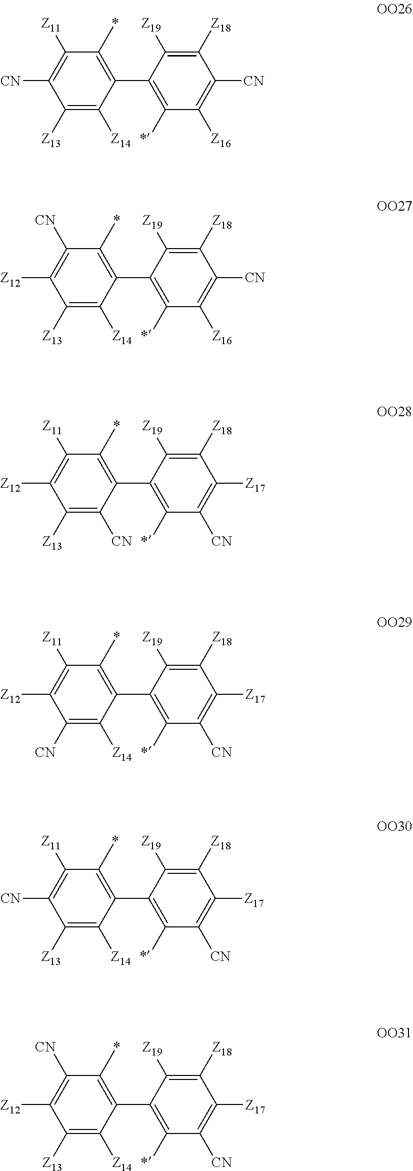

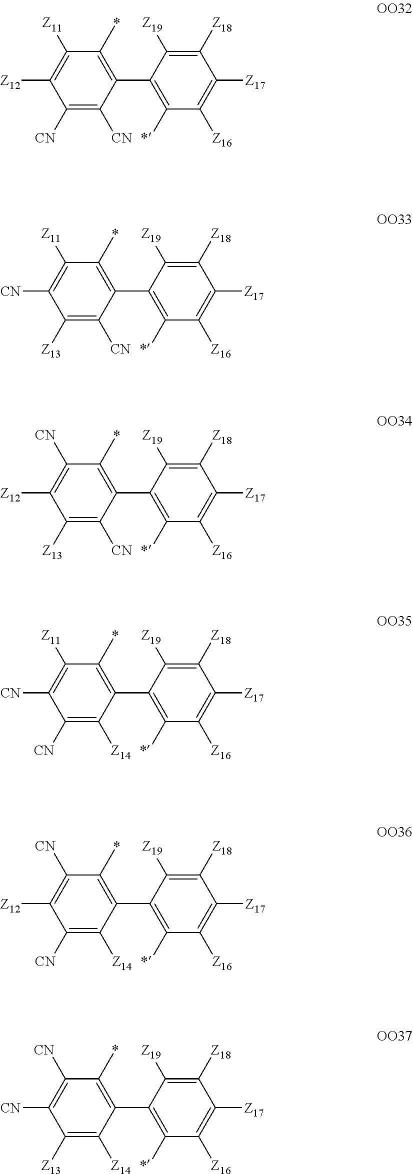

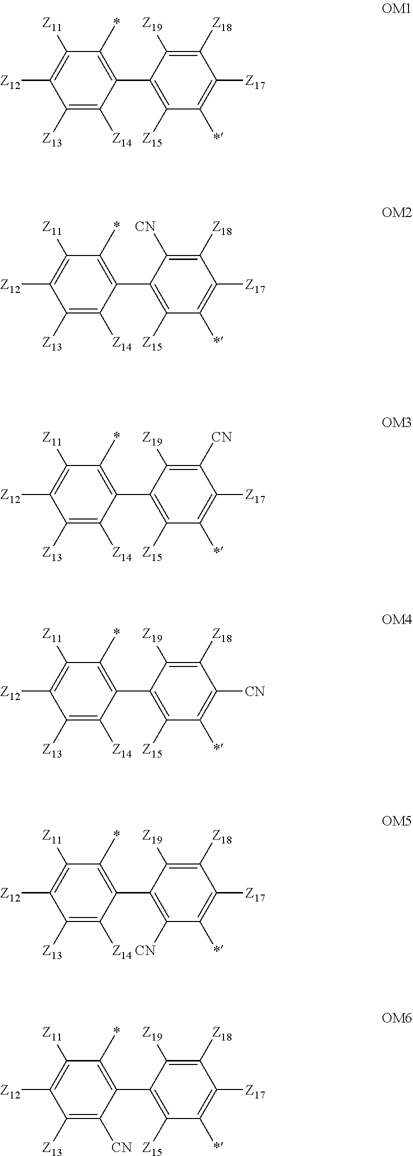

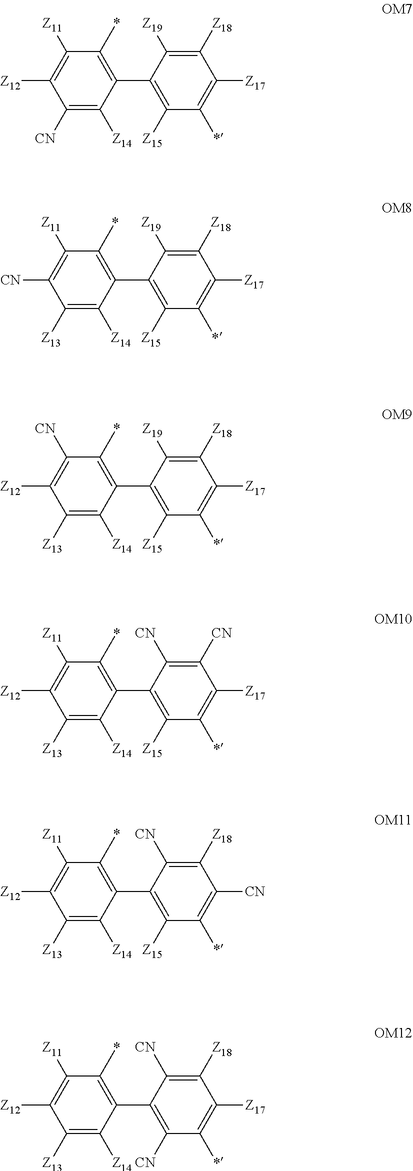

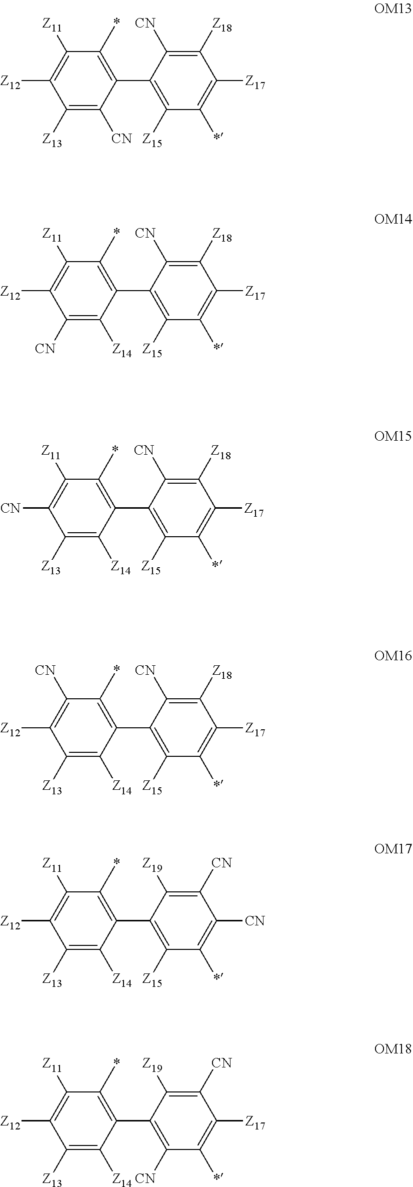

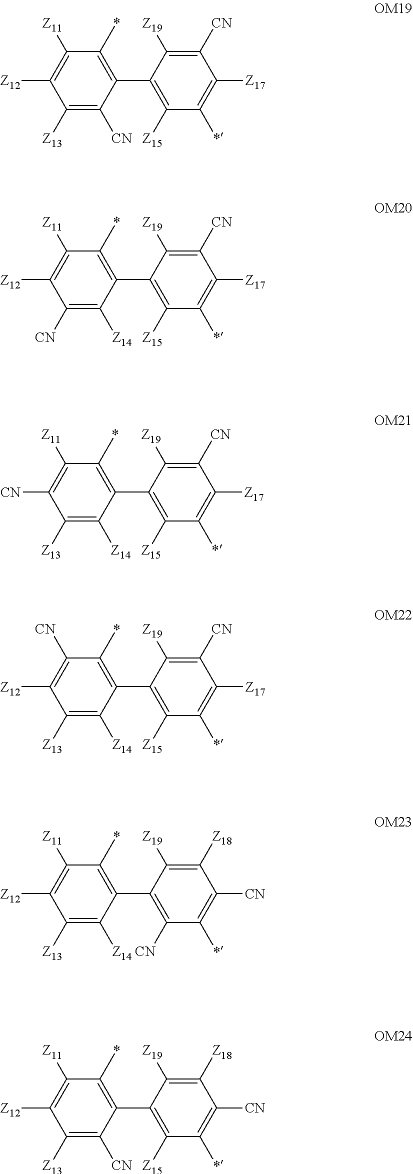

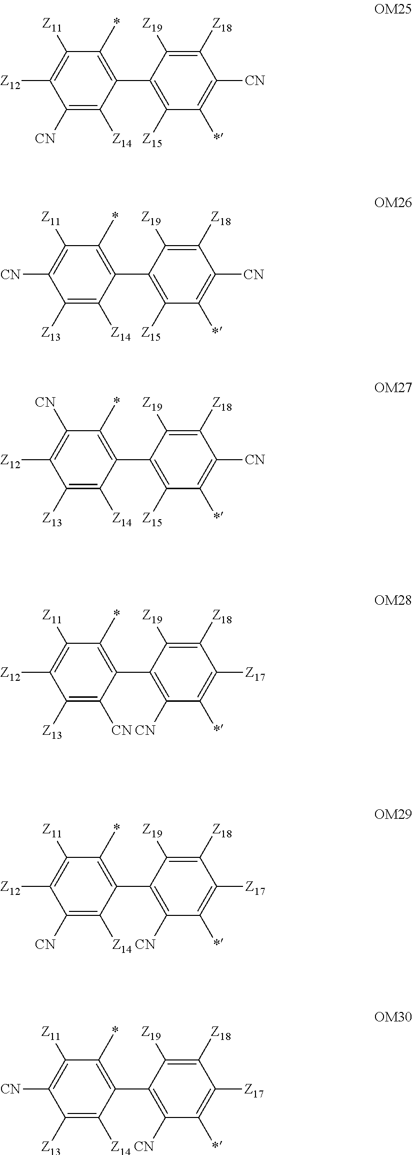

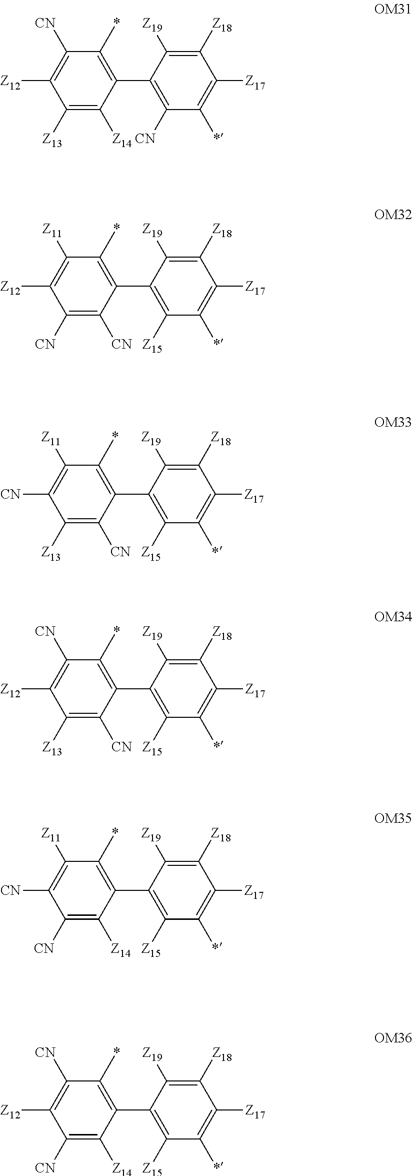

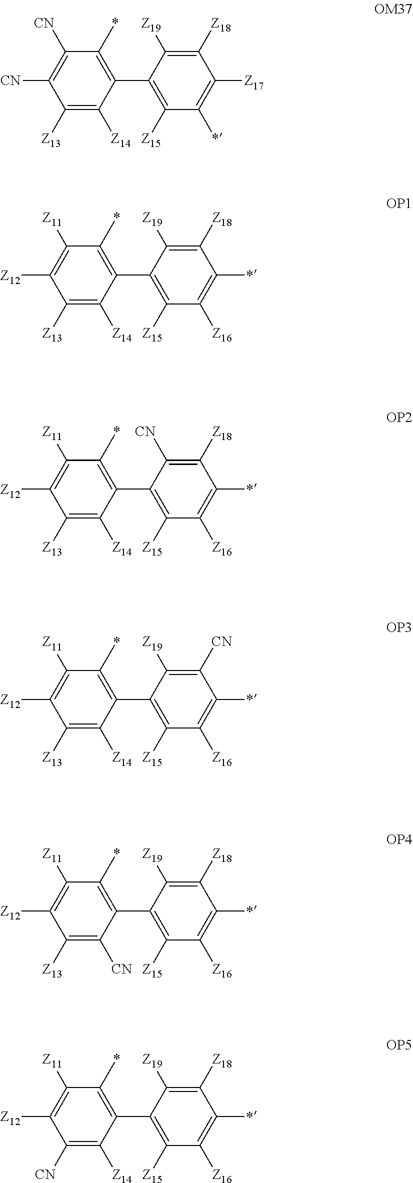

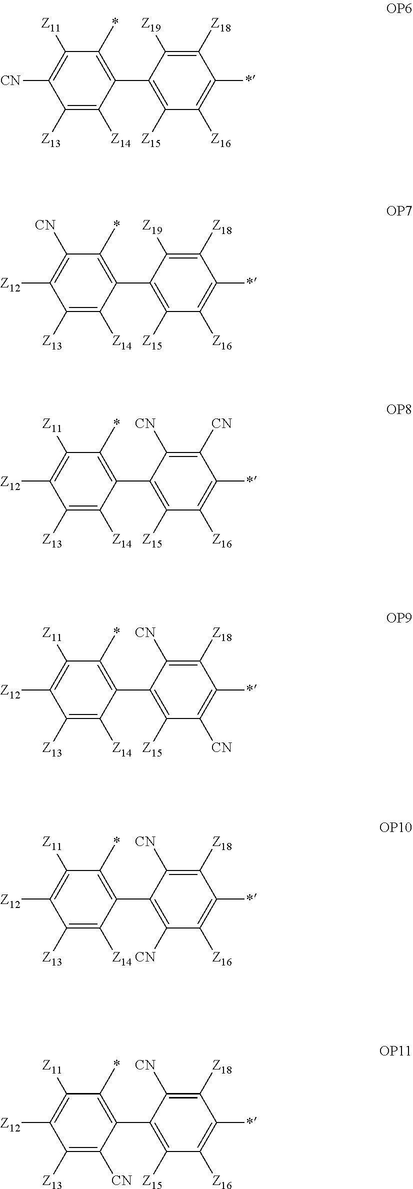

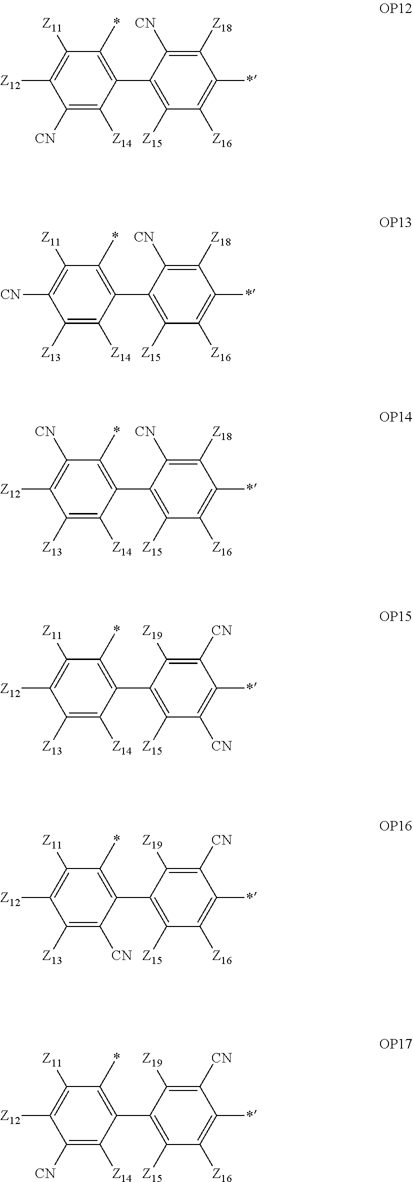

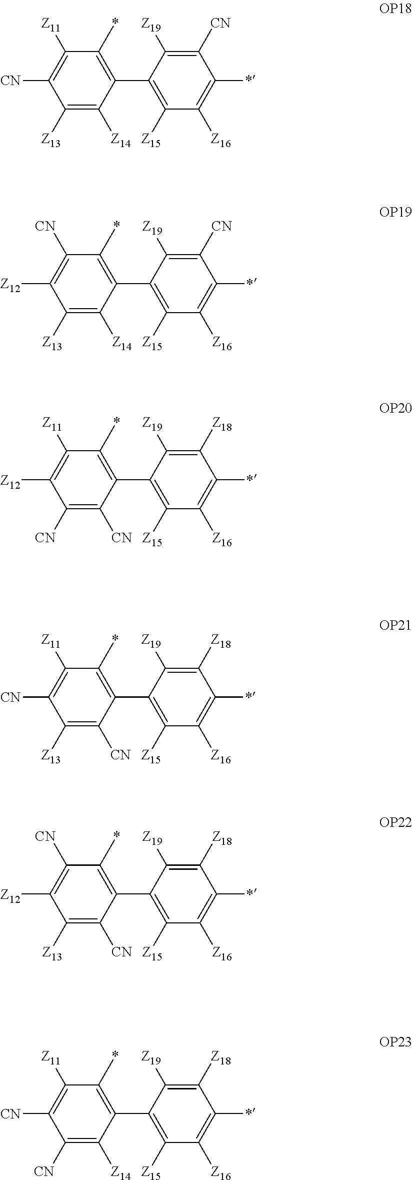

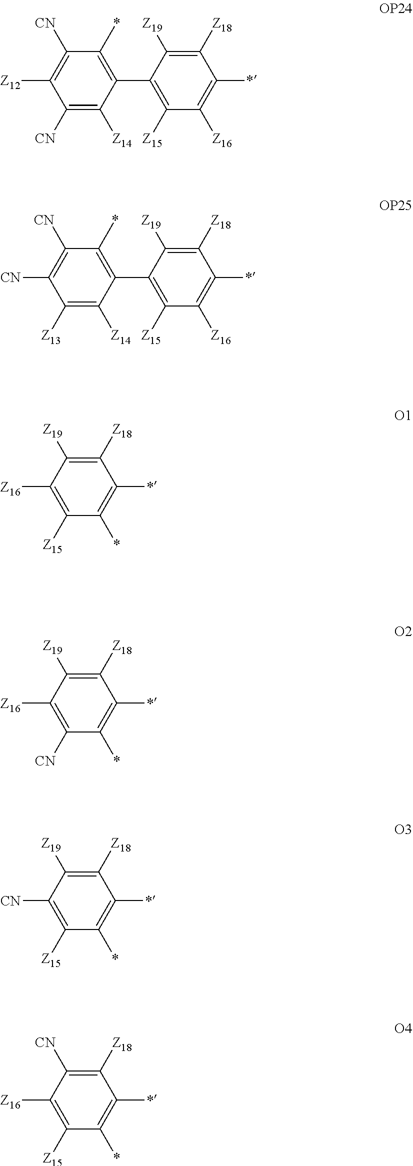

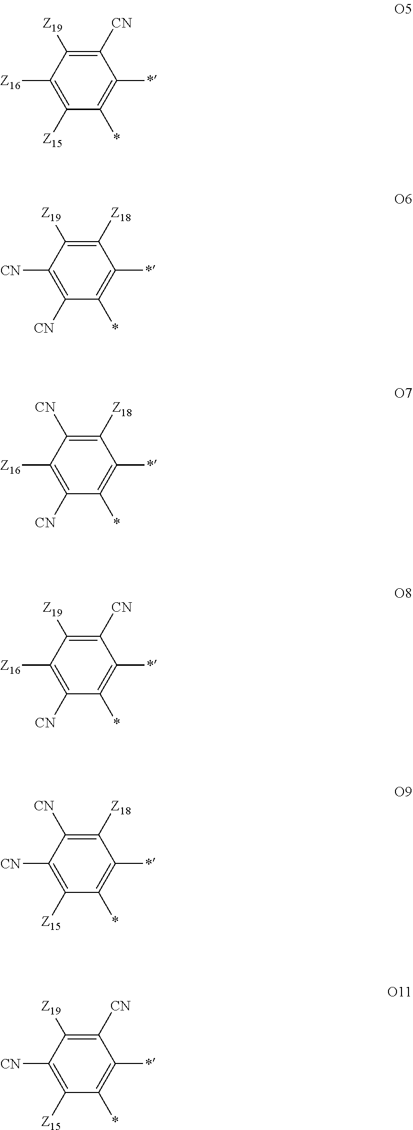

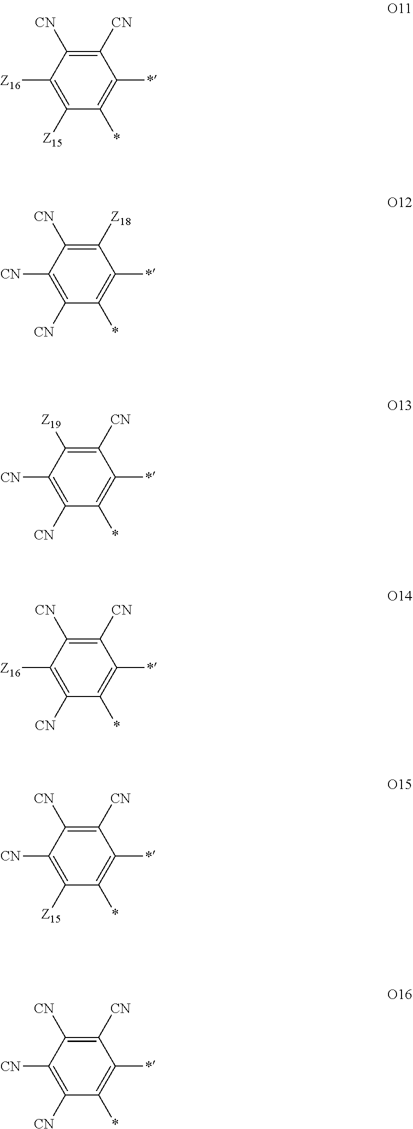

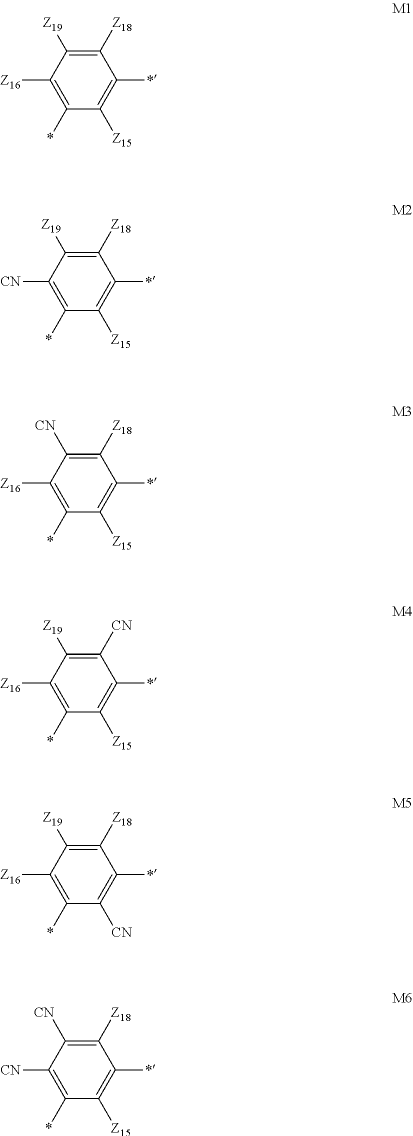

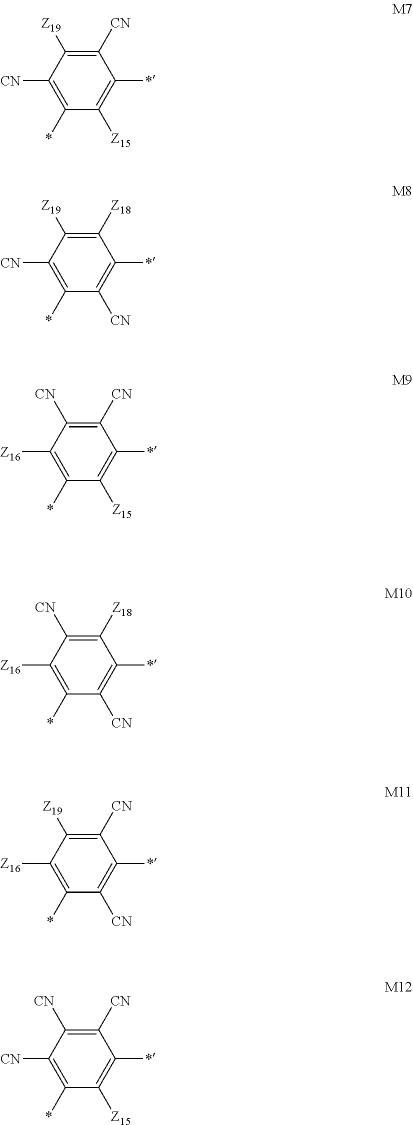

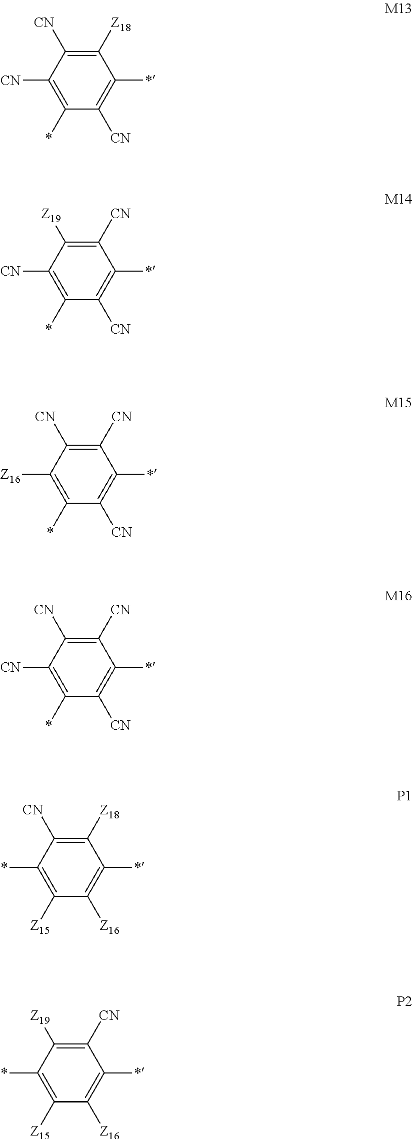

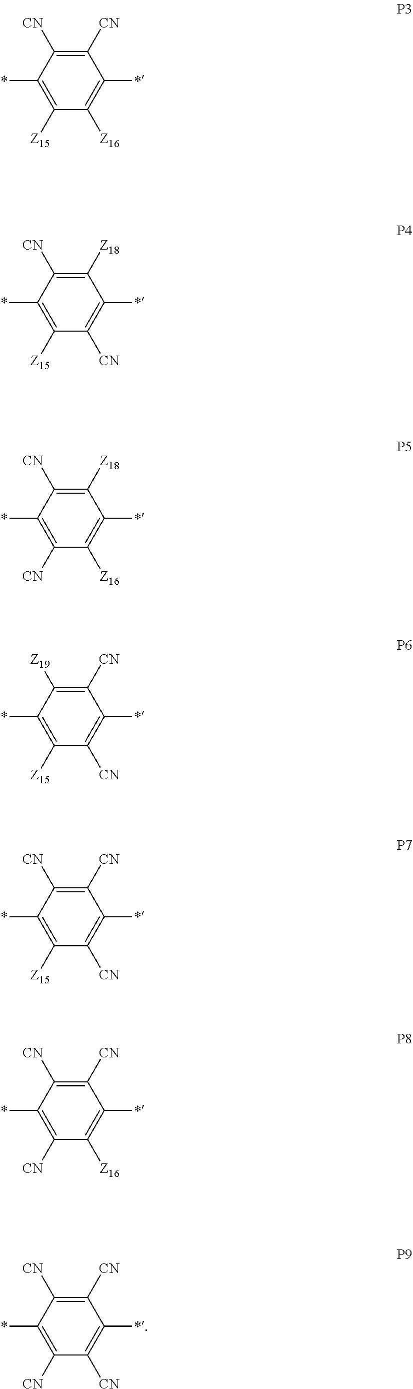

In Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9, Z₁₀ to Z₁₉ are the same as described in connection with Z₃ and Z₄, and * and *′ each indicate a binding site to a neighboring atom.

In an embodiment, in Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9, Z₁₀ to Z₁₉ may not be a cyano group.

In one or more embodiments, in Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9, Z₁₀ to Z₁₉ may each independently be selected from:

hydrogen, deuterium, or a cyano group; or

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, a biphenyl group, or a terphenyl group, each unsubstituted or substituted with at least one selected from deuterium, a cyano group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a biphenyl group.

In one or more embodiments, a group represented by

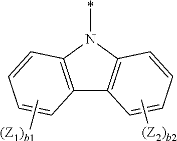

Formulae E-1(1) and E-1(2) may be one of groups represented by Formulae A1-1 to A1-3,
a group represented by

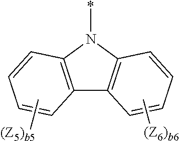

in Formula E-1(1) may be one of groups represented by Formulae A2-1 to A2-3,
a group represented by

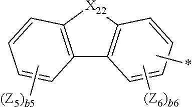

in Formulae E-1(2) and E-1(3) may be one of groups represented by Formulae A2-4 to A2-17, and
a group represented by

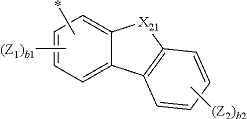

in Formula E-1(3) may be one of groups represented by Formulae A1-4 to A1-17:

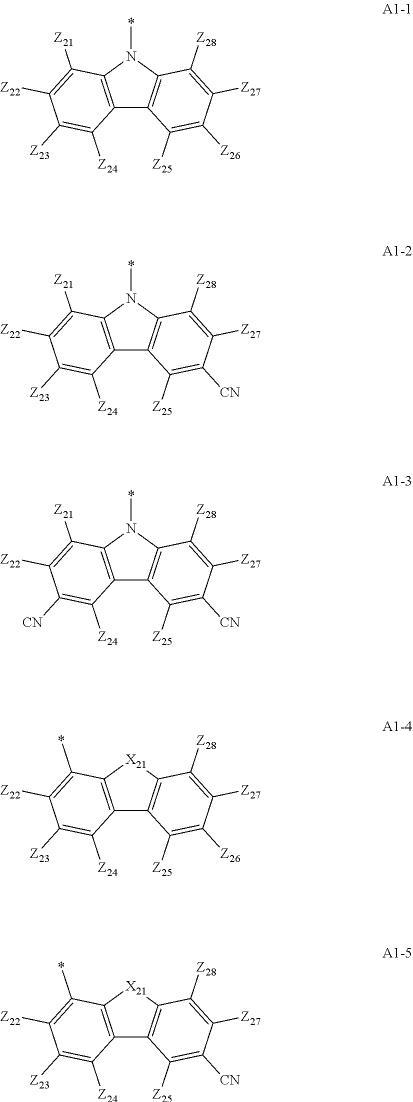

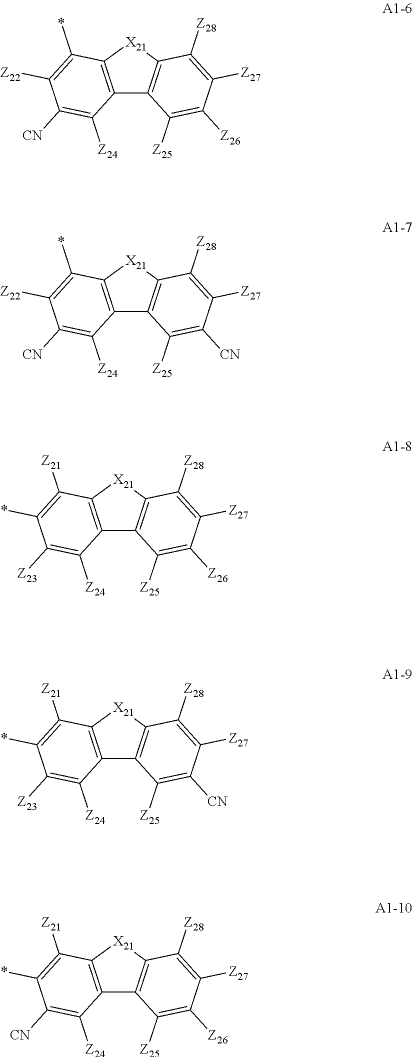

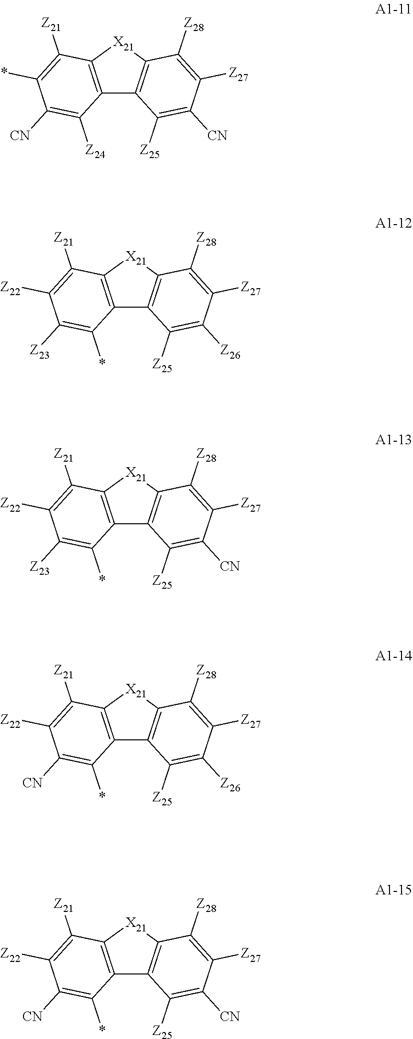

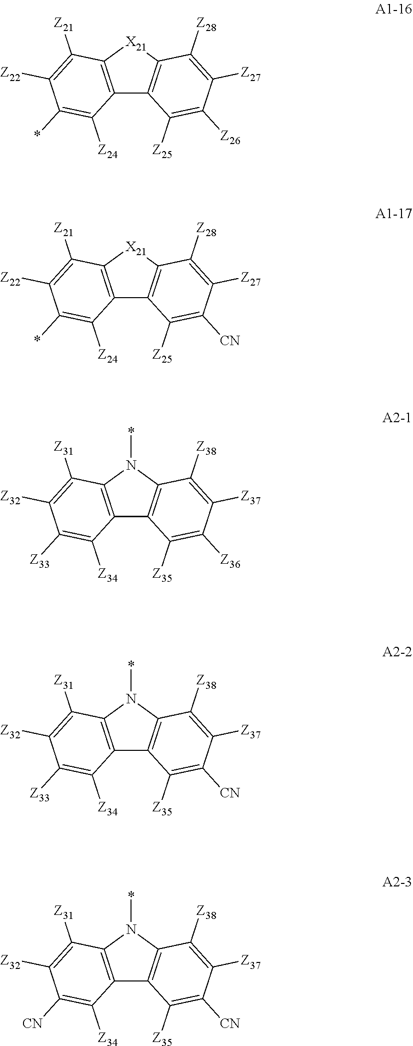

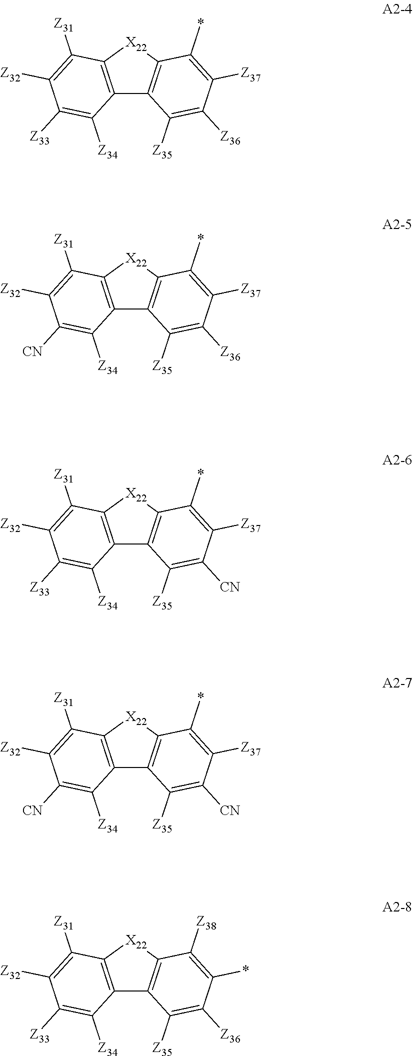

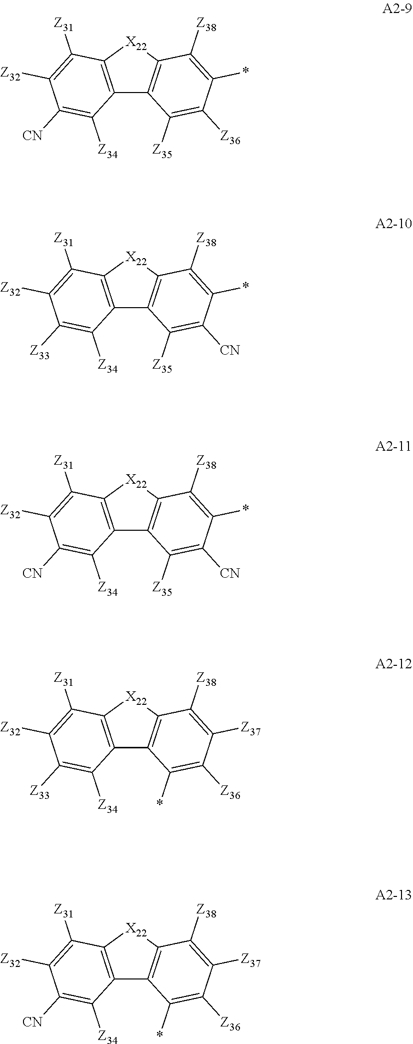

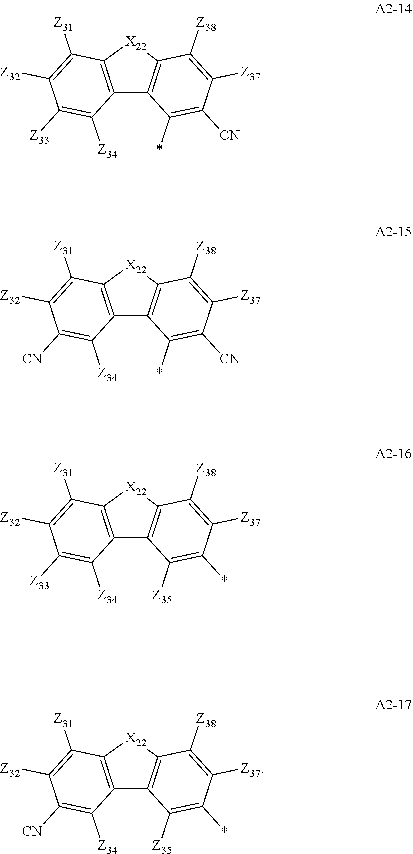

In Formulae A1-1 to A1-17 and A2-1 to A2-17, Z₂₁ to Z₂₈ are the same as described in connection with Z₁ and Z₂, Z₃₁ to Z₃₈ are the same as described in connection with Z₅ and Z₆, and * and *′ each indicate a binding site to a neighboring atom.

In an embodiment, in Formulae A1-1 to A1-17 and A2-1 to A2-17, Z₂₁ to Z₂₈ and Z₃₁ to Z₃₈ may not be a cyano group.

In one or more embodiments, in Formulae A1-1 to A1-17 and A2-1 to A2-17, Z₂₁ to Z₂₈ and Z₃₁ to Z₃₈ may each independently be selected from:

hydrogen, deuterium, or a cyano group; or

an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, a biphenyl group, or a terphenyl group, each unsubstituted or substituted with at least one selected from deuterium, a cyano group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a biphenyl group.

In an embodiment, the second material may include at least one compound selected from Compounds E1 to E9, but embodiments of the present disclosure are not limited thereto:

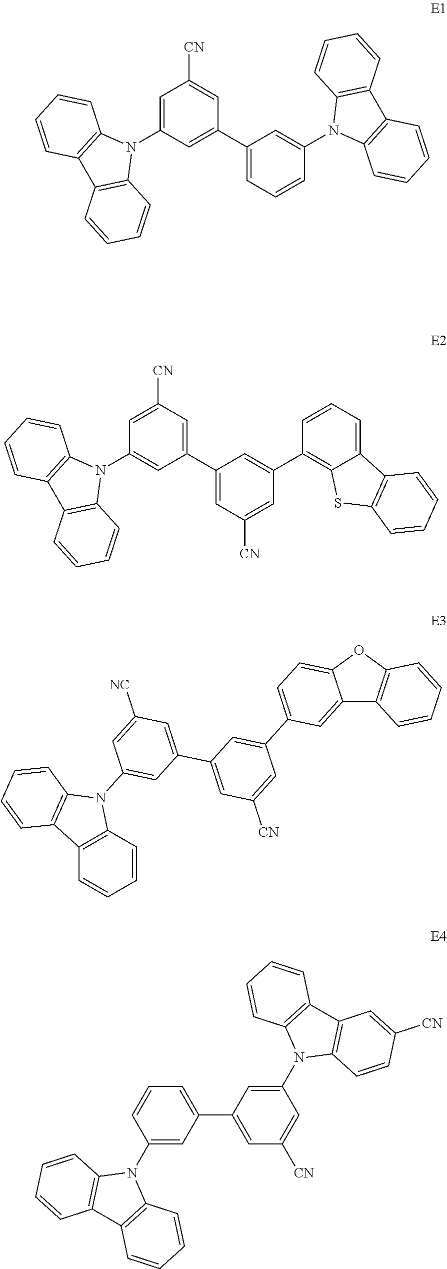 [SMILES: N#Cc1cc(-c2cccc(-n3c4ccccc4c4ccccc43)c2)cc(-n2c3ccccc3c3ccccc32)c1 ; N#Cc1cc(-c2cc(C#N)cc(-n3c4ccccc4c4ccccc43)c2)cc(-c2cccc3c2sc2ccccc23)c1 ; N#Cc1cc(-c2cc(C#N)cc(-n3c4ccccc4c4ccccc43)c2)cc(-c2ccc3oc4ccccc4c3c2)c1 ; N#Cc1cc(-c2cccc(-n3c4ccccc4c4ccccc43)c2)cc(-n2c3ccccc3c3cc(C#N)ccc32)c1]

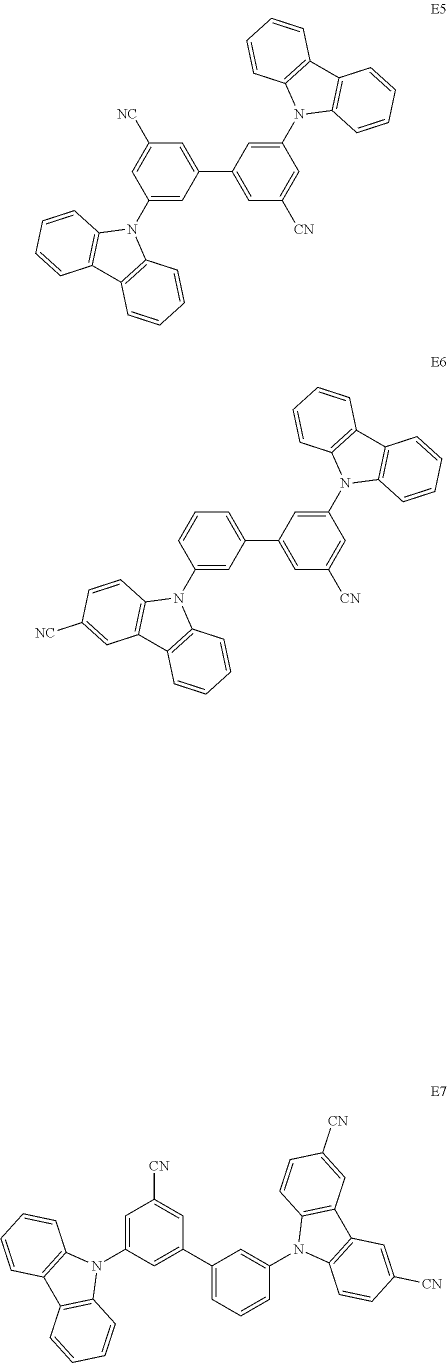 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccc(C#N)cc4c4cc(C#N)ccc43)c2)cc(-n2c3ccccc3c3ccccc32)c1]

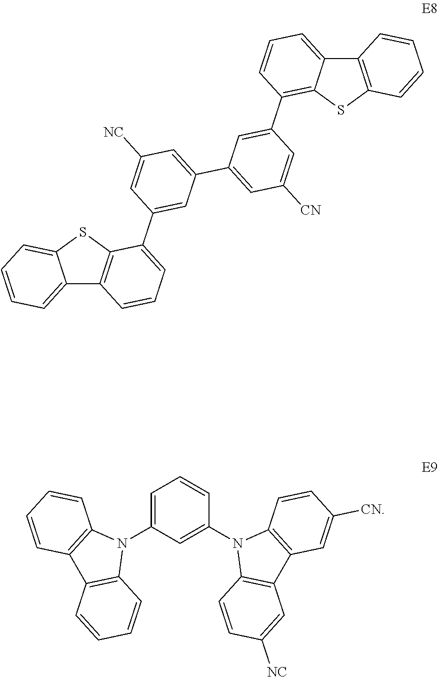

In an embodiment, the second material may satisfy Condition 2. For example, the second material may be a phosphine oxide-containing compound. In an embodiment, the second material may be selected from Compounds E10 and E11, but embodiments of the present disclosure are not limited thereto:

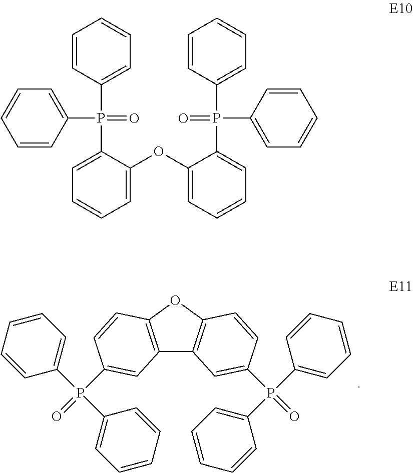 [SMILES: O=P(c1ccccc1)(c1ccccc1)c1ccccc1Oc1ccccc1P(=O)(c1ccccc1)c1ccccc1 ; O=P(c1ccccc1)(c1ccccc1)c1ccc2oc3ccc(P(=O)(c4ccccc4)c4ccccc4)cc3c2c1]

In one or more embodiments, the host may not be CBP.

In one or more embodiments, the host may consist of a single compound. For example, the single compound may be selected from the first material (hole transport host) and the second material (electron transport host).

The organic light-emitting device may satisfy Equation 1 below:

E_{T1(HOST)}−E_{T1(AD)}>0.05 eV. Equation 1

In Equation 1,

E_{T1(HOST)} is triplet energy level (eV) of the host, and

E_{T1(AD)} is triplet energy level (eV) of the auxiliary dopant.

Since the organic light-emitting device satisfies Equation 1 (for example, E_{T1(HOST)}−E_{T1(AD)} is in a range of about 0.10 eV to about 0.65 eV), energy of triplet exciton generated in the auxiliary dopant of the emission layer cannot be transferred to the host of the emission layer, and a probability that the triplet exciton will be lost in a path other than light emission is reduced. Therefore, the organic light-emitting device may have high efficiency.

In one or more embodiments, the organic light-emitting device may satisfy Equation 2:

E_{S1(FD)}−E_{S1(AD)}<0 eV. Equation 2

In Equation 2,

E_{S1(FD)} is singlet energy (eV) of the fluorescent dopant, and

E_{S1(AD)} is singlet energy (eV) of the auxiliary dopant.

Since the organic light-emitting device satisfies Equation 2 (for example, E_{S1(FD)}−E_{S1(AD)} is in a range of about −0.4 eV to about −0.05 eV), energy of singlet exciton generated in the auxiliary dopant of the emission layer may be quickly transferred to the fluorescent dopant. Therefore, light emission substantially occurs only in the fluorescent dopant in the emission layer of the organic light-emitting device, and a fluorescence spectrum having excellent color purity based on the fluorescent dopant may be obtained. In addition, fluorescence having a relatively short exciton lifespan is achieved, and an efficiency reduction phenomenon under high luminance (so-called roll-off phenomenon), which may be caused by interaction between a plurality of excitons (exciton-to-exciton interaction) or interaction between exciton and charge (hole or electron) (exciton-to-polaron interaction) may be suppressed, and an organic light-emitting device having high efficiency may be implemented. Furthermore, since the auxiliary dopant has a short exciton lifespan, a probability of chemical or physical deterioration that may occur in an exciton state of the auxiliary dopant may be reduced. The organic light-emitting device satisfying Equation 2 may have improved durability.

Therefore, a ratio of a fluorescence component emitted from the fluorescent dopant to a total fluorescence component emitted from the emission layer may be about 50% or more, about 60% or more, about 70% or more, about 80% or more, or about 90% or more. That is, a main fluorescence component from the emission layer may be a fluorescence component emitted from the fluorescent dopant. In an embodiment, a ratio of a fluorescence component (for example, a thermally activated delayed fluorescence component) emitted from the auxiliary dopant to a total fluorescence component emitted from the emission layer may be less than about 50%, less than about 40%, less than about 30%, less than about 20%, or less than about 10%. Therefore, the fluorescent dopant in the emission layer substantially contributes to light emission of the emission layer.

In one or more embodiments, an amount of the auxiliary dopant in the organic layer may be larger than an amount of the fluorescent dopant. For example, a weight ratio of the auxiliary dopant to the fluorescent dopant may be in a range of about 10:0.1 to about 20:5, but embodiments of the present disclosure are not limited thereto. On the other hand, a weight ratio of the host to the auxiliary dopant in the organic layer may be in a range of about 60:40 to about 95:5. While not wishing to be bound by theory, it is understood that when the amount is within this range, the organic light-emitting device may have improved luminescent efficiency and/or lifespan characteristics.

The auxiliary dopant is represented by Formula 1, and in Formula 1, i) at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 may be equal to or greater than one. That is, the auxiliary dopant essentially includes i) a group represented by Formula 2-1 or 2-2, in which at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, and/or ii) at least one of Z₁ and Z₂, which are bulky substituents as described herein. In an embodiment, the auxiliary dopant is surrounded by at least one of Z₁ and Z₂, which are bulky substituents as described herein.

Energy transfer from the auxiliary dopant to the fluorescent dopant may be divided into Foster energy transfer from the singlet state of the auxiliary dopant to the singlet state of the fluorescent dopant and Dexter energy transfer from the triplet state of the auxiliary dopant to the triplet state of the fluorescent dopant. When the Dexter energy transfer occurs, light emission is impossible in the triplet of the fluorescent dopant, and thus non-light emission loss may occur in the fluorescent dopant, which may be the cause of the efficiency deterioration of the organic light-emitting device.

However, since i) at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 may be equal to or greater than one (that is, the auxiliary dopant essentially includes at least one of Z₁ and Z₂, which are bulky substituents as described herein), a distance between the auxiliary dopant and the fluorescent dopant in the emission layer may be maintained at a distance (for example, 1 nm or more) capable of effectively suppressing the Dexter energy transfer from the triplet state of the auxiliary dopant to the triplet state of the fluorescent dopant.

Although not limited by a specific theory, a collision diameter of Compound AD-A, which includes a benzene group as B₁ and B₂ and does not include the bulky substituent Z₁, is about 12.7 Angstroms (Å), whereas a collision diameter of Compound AD3, which includes the bulky substituents Z₁ and Z₂, is about 16.9 Å. Therefore, when the emission layer includes Compound AD3 and the fluorescent dopant, Compound AD3 may be included in the emission layer, such that Compound AD3 is spaced apart from the fluorescent dopant by a distance capable of effectively suppressing the Dexter energy transfer from the triplet state of Compound AD3 to the triplet state of the fluorescent dopant.

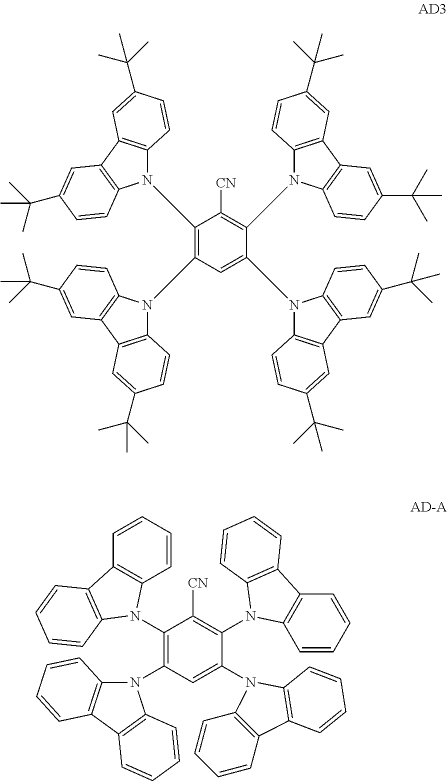 [SMILES: CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccc(C(C)(C)C)cc3c3cc(C(C)(C)C)ccc32)c(C#N)c1-n1c2ccc(C(C)(C)C)cc2c2cc(C(C)(C)C)ccc21 ; N#Cc1c(-n2c3ccccc3c3ccccc32)c(-n2c3ccccc3c3ccccc32)cc(-n2c3ccccc3c3ccccc32)c1-n1c2ccccc2c2ccccc21]

Therefore, an organic light-emitting device employing the emission layer including the auxiliary dopant and the fluorescent dopant effectively suppresses the Dexter energy transfer from the triplet state of the auxiliary dopant to the triplet state of the fluorescent dopant. As a result, the Foster energy transfer from the singlet state of the auxiliary dopant to the singlet state of the fluorescent dopant is relatively dominant and the final fluorescence by the singlet exciton of the fluorescent dopant may be effectively achieved. Therefore, the organic light-emitting device may have high luminescent efficiency and/or a long lifespan.

Furthermore, in an embodiment, a difference between the singlet energy level (eV) and the triplet energy level (eV) of the auxiliary dopant may be 0.5 eV or less. For example, the auxiliary dopant may be a thermally activated delayed fluorescence (TADF) material that may emit delayed fluorescence. Therefore, the triplet exciton of the auxiliary dopant may be easily transferred to the singlet state of the auxiliary dopant through RISC. Therefore, the triplet exciton of the auxiliary dopant is transferred to the singlet state of the auxiliary dopant by RISC and then transferred to the singlet state of the fluorescent dopant through the Foster energy transfer, thus contributing to the final fluorescence in the fluorescent dopant. Therefore, the organic light-emitting device may have more improved luminescent efficiency and/or lifespan.

On the other hand, since i) at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 may be equal to or greater than one (that is, the auxiliary dopant essentially includes at least one of Z₁ and Z₂, which are bulky substituents as described herein), a distance between the auxiliary dopant and the fluorescent dopant in the emission layer may be maintained at a distance (for example, about 1 nm or more) capable of effectively suppressing the Dexter energy transfer from the triplet state of the auxiliary dopant to the triplet state of the fluorescent dopant. Therefore, a separate feature (for example, the use of a very small amount of the auxiliary dopant) capable of a distance between the auxiliary dopant and the fluorescent dopant in the emission layer at more than a predetermined distance may not be substantially considered. In order to improve luminescent efficiency and/or lifespan, the emission layer may be configured relatively freely. In consideration of this, an amount of the auxiliary dopant in the emission layer may be adjusted to be larger than an amount of the fluorescent dopant. i) Even when the amount of the auxiliary dopant is larger than the amount of the fluorescent dopant, the distance between the auxiliary dopant and the fluorescent dopant may be effectively maintained at a distance capable of effectively suppressing the Dexter energy transfer since i) at least one of B₁ and B₂ in Formulae 2-1 and 2-2 may each independently be a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 may be equal to or greater than one (that is, the auxiliary dopant essentially includes at least one of Z₁ and Z₂, which are bulky substituents as described herein), and ii) as the amount of the auxiliary dopant increases, the triplet exciton and the singlet exciton of the auxiliary dopant, which may contribute to the final fluorescence in the fluorescent dopant, increases through the RISC in the auxiliary dopant and/or the Foster energy transfer between the auxiliary dopant and the fluorescent dopant. Therefore, the organic light-emitting device may have more improved luminescent efficiency and/or lifespan.

In addition, d1 in Formula 1 may be an integer from 3 to 10. That is, in Formula 1, the number of groups D₁ represented by Formula 2-1 or 2-2 is three or more. Therefore, an acceptor A₁ in Formula 1 is effectively surrounded by three or more groups D₁, and the damage to A₁ due to the charge transferred to the emission layer in driving the organic light-emitting device may be minimized. Therefore, the organic light-emitting device may further improve efficiency and/or lifespan.

Furthermore, the fluorescent dopant may be a material that is dominant in prompt fluorescence rather than delayed fluorescence and emits prompt fluorescence (for example, a fluorescence material that rarely emits delayed fluorescence). The fluorescent dopant is different from a delayed fluorescence emitter (for example, a TADF emitter) that emits delayed fluorescence more dominantly than prompt fluorescence. In the organic light-emitting device, the final light emission is achieved from the fluorescent dopant that emits prompt fluorescence, and the emission layer may emit prompt fluorescence having a relatively small full width at half maximum and excellent color purity.

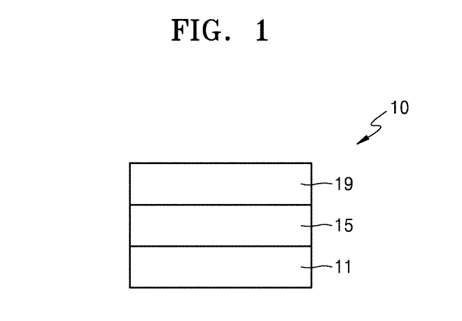

FIG. 1 is a schematic view of an organic light-emitting device 10 according to an embodiment. Hereinafter, the structure of an organic light-emitting device according to an embodiment and a method of manufacturing an organic light-emitting device according to an embodiment will be described in connection with FIG. 1. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode may be, for example, indium tin oxide (ITO), indium zinc oxide (IZO), tin oxide (SnO₂), and zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode.

The first electrode 11 may have a single-layered structure or a multi-layered structure including two or more layers. For example, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include at least one selected from a hole injection layer, a hole transport layer, an electron blocking layer, and a buffer layer.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

A hole injection layer may be formed on the first electrode 11 by using one or more suitable methods selected from vacuum deposition, spin coating, casting, or Langmuir-Blodgett (LB) deposition.

When a hole injection layer is formed by vacuum deposition, the deposition conditions may vary according to a compound that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec, but embodiments of the present disclosure are not limited thereto.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include at least one selected from m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrene sulfonate) (PEDOT/PSS), polyaniline/camphor sulfonic acid (PANI/CSA), polyaniline/poly(4-styrene sulfonate) (PANI/PSS), a compound represented by Formula 201 below, and a compound represented by Formula 202 below:

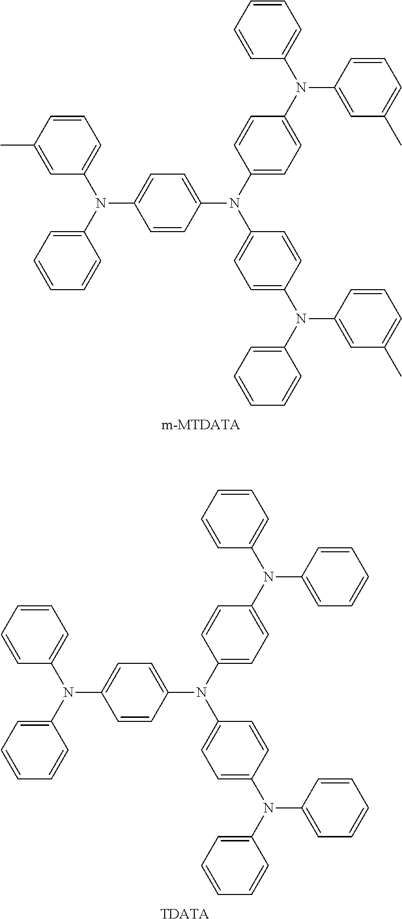

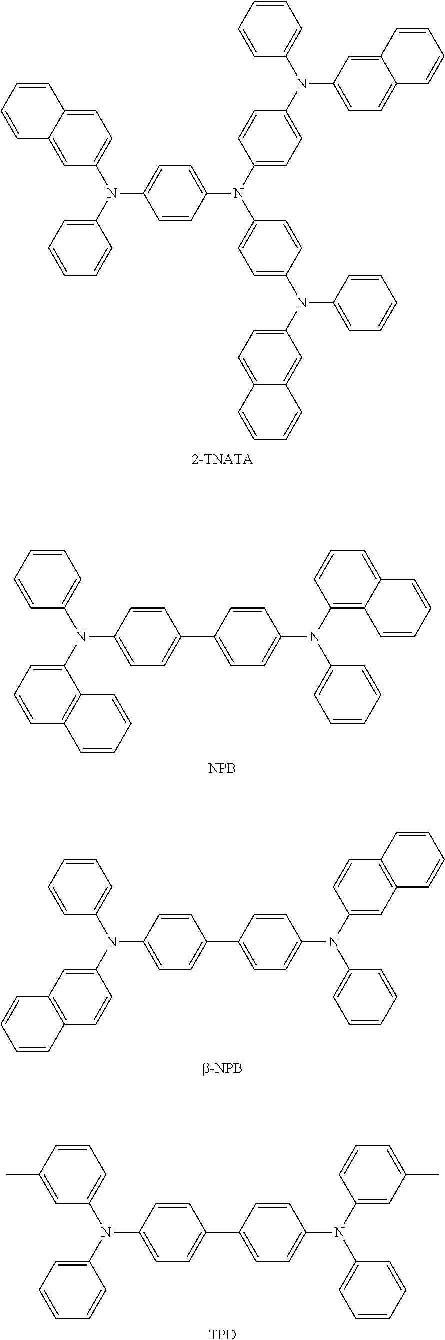

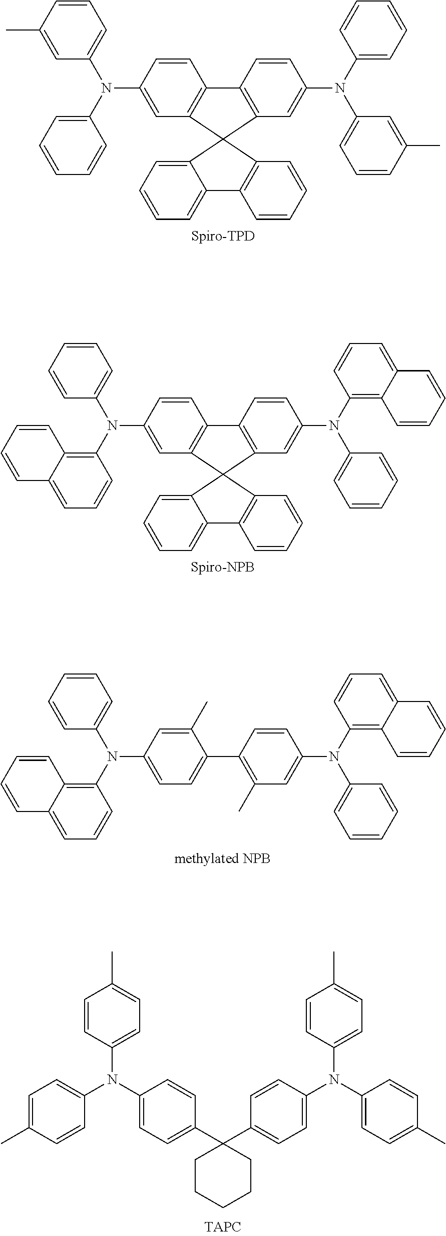

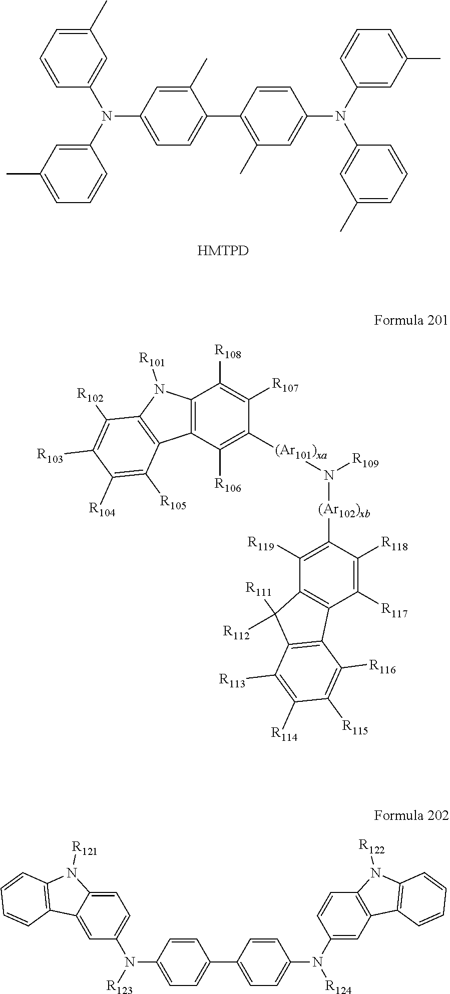

Ar₁₀₁ and Ar₁₀₂ in Formula 201 may each independently be selected from:

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arythio group, a C₁-C₆₀ heteroaryl group, a monovalent non-aromatic condensed polycyclic group, and a monovalent non-aromatic condensed heteropolycyclic group.

In Formula 201, xa and xb may each independently be an integer from 0 to 5, or 0, 1, or 2. For example, xa is 1 and xb is 0, but xa and xb are not limited thereto.

R₁₀₁ to R₁₀₈, R₁₁₁ to R₁₁₉, and R₁₂₁ to R₁₂₄ in Formulae 201 and 202 may each independently be selected from:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, and a C₁-C₁₀ alkyl group (for example, a methyl group, an ethyl group, a propyl group, a butyl group, a pentyl group, a hexyl group, and so on), or a C₁-C₁ alkoxy group (for example, a methoxy group, an ethoxy group, a propoxy group, a butoxy group, a pentoxy group, and so on);

a C₁-C₁₀ alkyl group or a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, an anthracenyl group, a fluorenyl group, and a pyrenyl group; and

a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, or a C₁-C₁₀ alkoxy group,

but embodiments of the present disclosure are not limited thereto.

R₁₀₉ in Formula 201 may be selected from:

a phenyl group, a naphthyl group, an anthracenyl group, and a pyridinyl group; and

a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, and a pyridinyl group.

According to an embodiment, the compound represented by Formula 201 may be represented by Formula 201A, but embodiments of the present disclosure are not limited thereto:

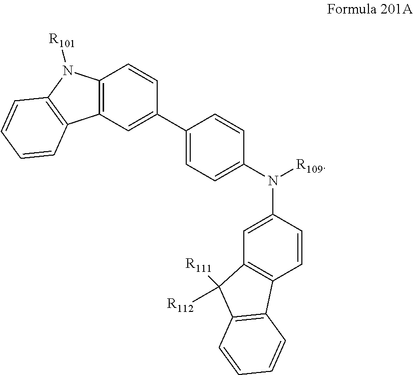

R₁₀₁, R₁₁₁, R₁₁₂, and R₁₀₉ in Formula 201A may be understood by referring to the description provided herein.

For example, the compound represented by Formula 201, and the compound represented by Formula 202 may include compounds HT1 to HT20 illustrated below, but are not limited thereto.

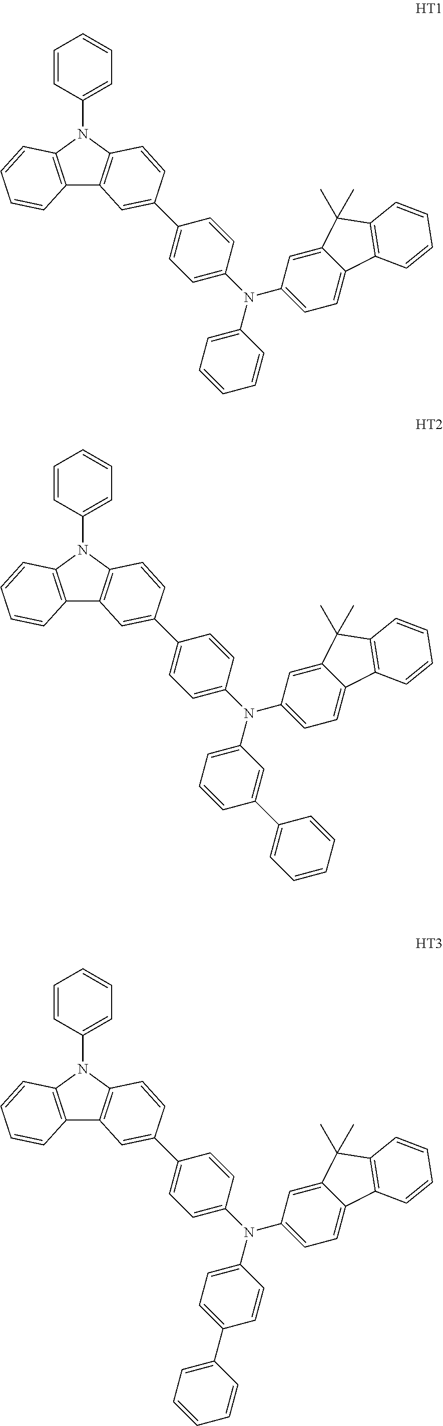 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

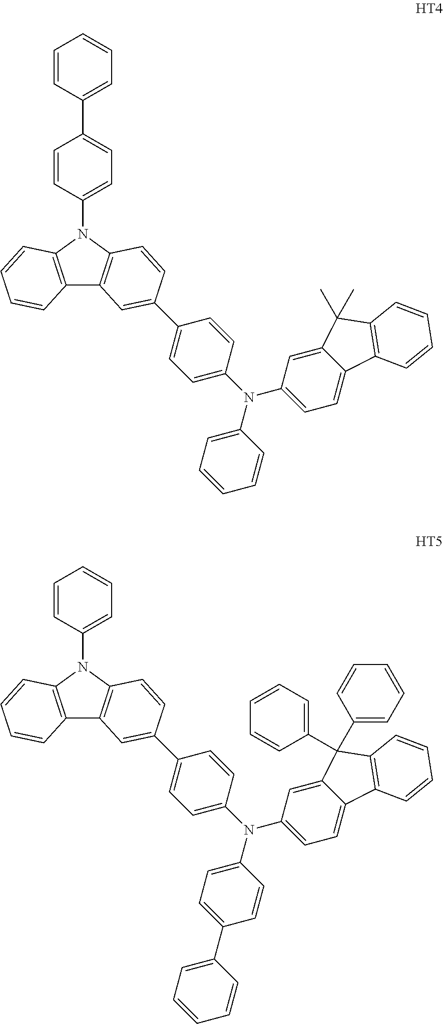 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

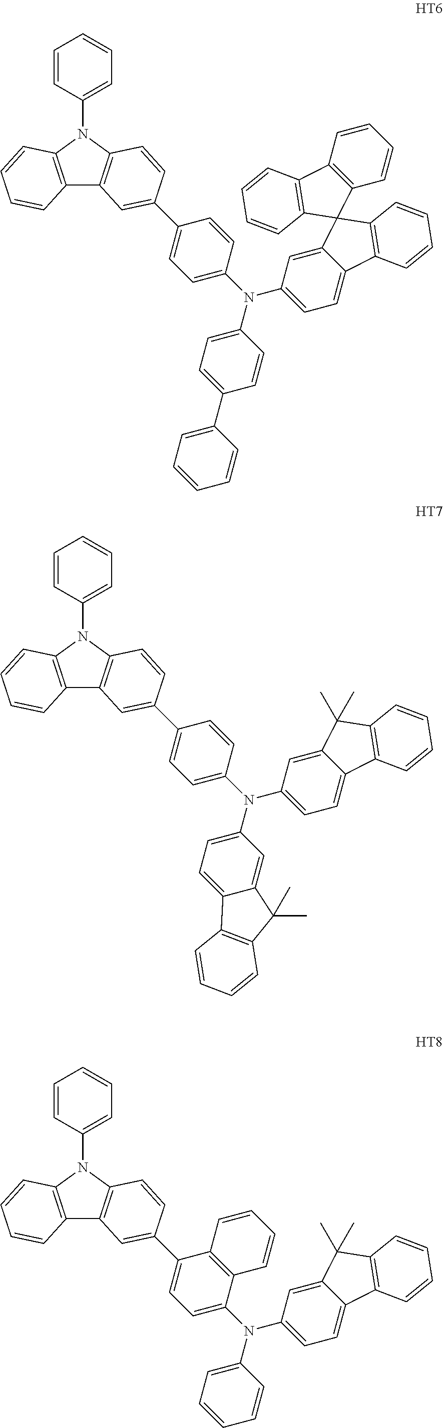 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

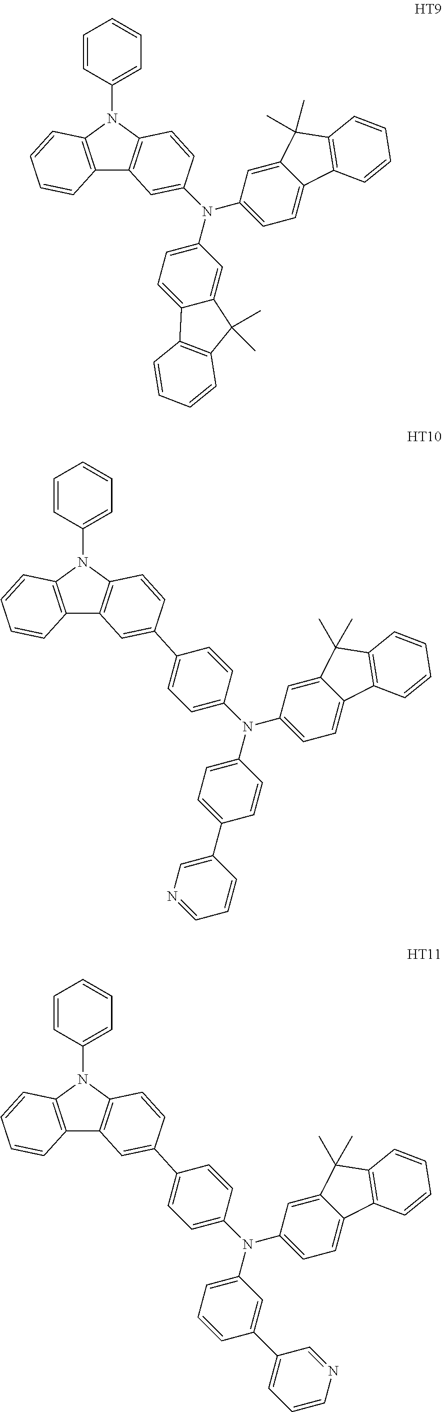 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

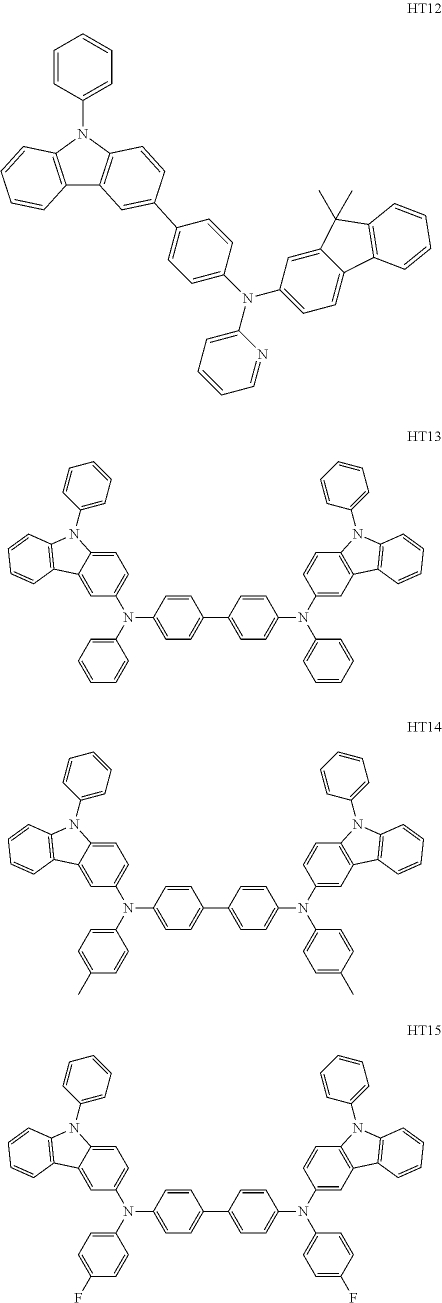 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

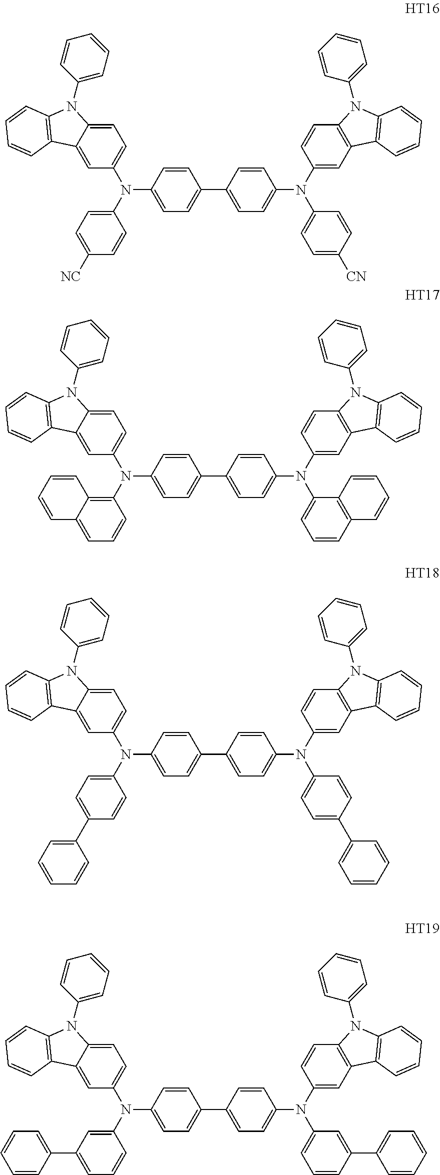 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

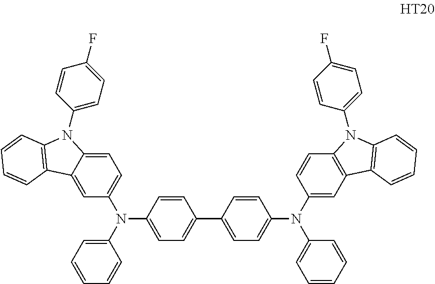 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes a hole injection layer and a hole transport layer, the thickness of the hole injection layer may be in a range of about 100 Å to about 10,000 Å, and for example, about 100 Å to about 1,000 Å, and the thickness of the hole transport layer may be in a range of about 50 Å to about 2,000 Å, and for example, about 100 Å to about 1,500 Å. While not wishing to be bound by theory, it is understood that when the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenium oxide; and a cyano group-containing compound, such as Compound HT-D1 or Compound HT-D2 below, but are not limited thereto.

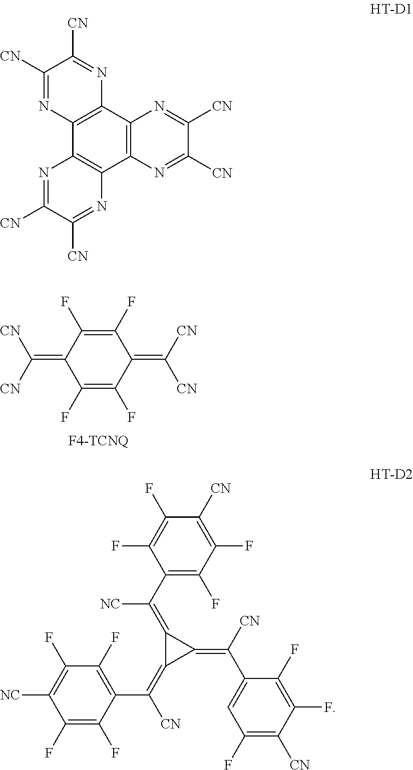

The hole transport region may include a buffer layer.

Also, the buffer layer may compensate for an optical resonance distance according to a wavelength of light emitted from the emission layer, and thus, efficiency of a formed organic light-emitting device may be improved.

The hole transport region may further include an electron blocking layer. The electron blocking layer may include, for example, mCP, but a material therefor is not limited thereto:

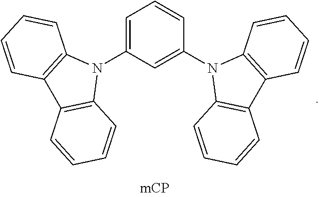 [SMILES: c1cc(-n2c3ccccc3c3ccccc32)cc(-n2c3ccccc3c3ccccc32)c1]

Then, an emission layer (EML) may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

The emission layer may include an auxiliary dopant, a fluorescent dopant, and a host, wherein the auxiliary dopant, the fluorescent dopant, and the host may be the same as described above.

A thickness of the emission layer may be in a range of about 100 Å to about 1,000 Å, for example, about 200 Å to about 600 Å. While not wishing to be bound by theory, it is understood that when the thickness of the emission layer is within this range, excellent light-emission characteristics may be obtained without a substantial increase in driving voltage.

Next, the electron transport region may be disposed on the emission layer.

The electron transport region may include at least one selected from a hole blocking layer, an electron transport layer, and an electron injection layer.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP and Bphen, but may also include other materials.

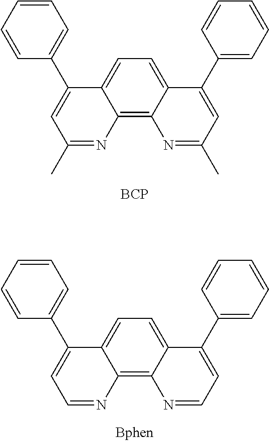

In an embodiment, the hole blocking layer may include at least one selected from the examples of the host.

A thickness of the hole blocking layer may be in a range of about 20 Å to about 1,000 Å, for example, about 30 Å to about 300 Å. While not wishing to be bound by theory, it is understood that when the thickness of the hole blocking layer is within these ranges, the hole blocking layer may have improved hole blocking ability without a substantial increase in driving voltage.

The electron transport layer may include at least one selected from BCP, Bphen, Alq₃, BAlq, TAZ, and NTAZ:

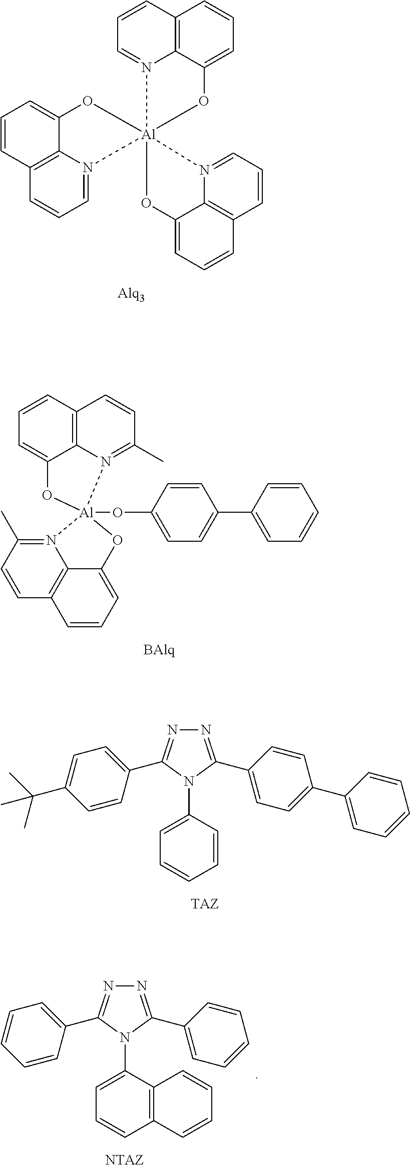

In one or more embodiments, the electron transport layer may include at least one of ET1 to ET25, but are not limited thereto:

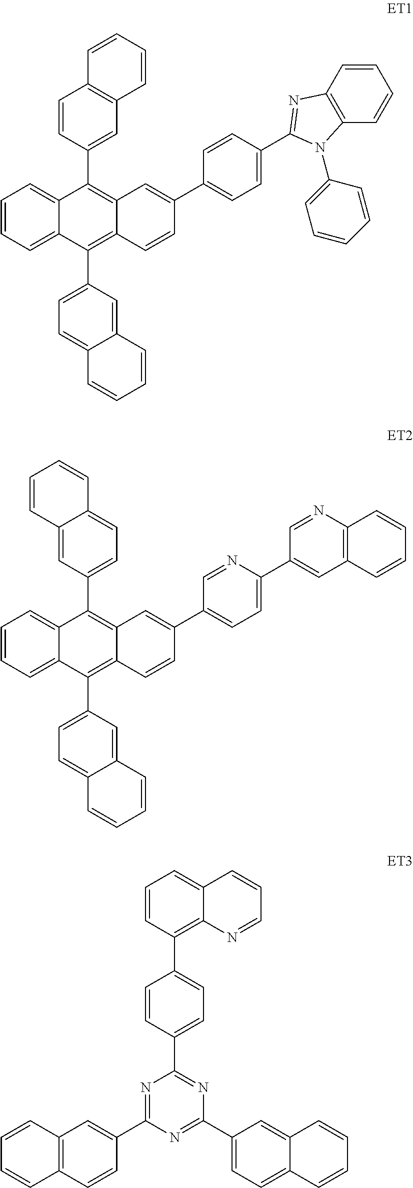 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

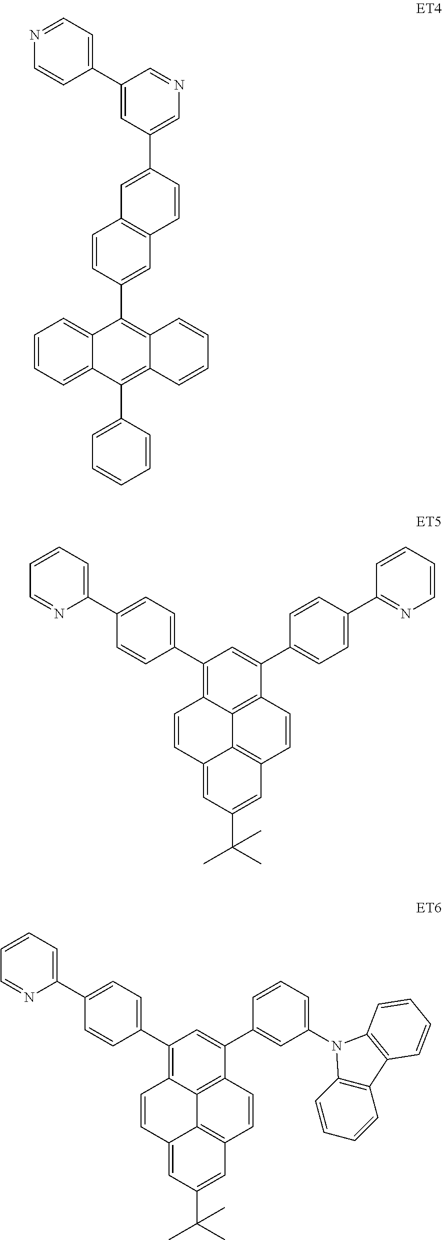 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

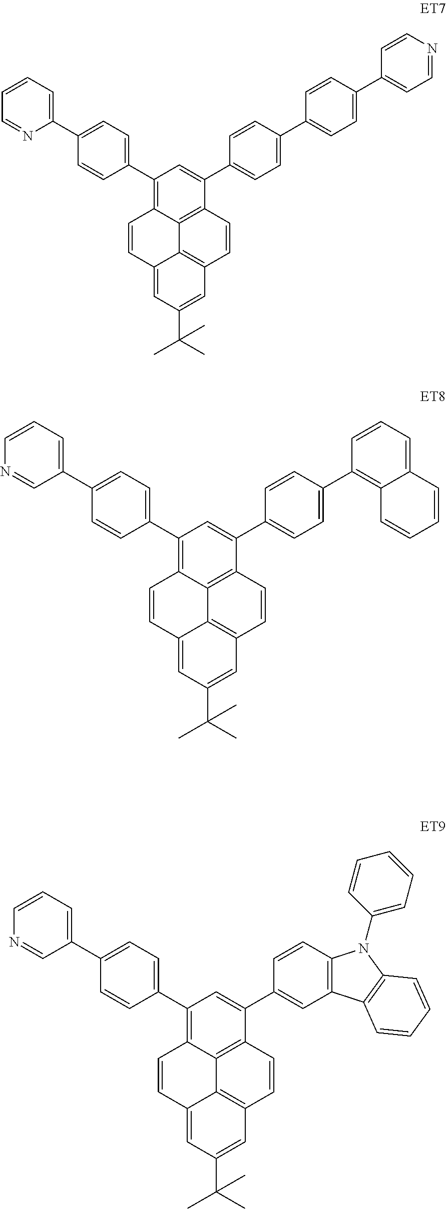 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

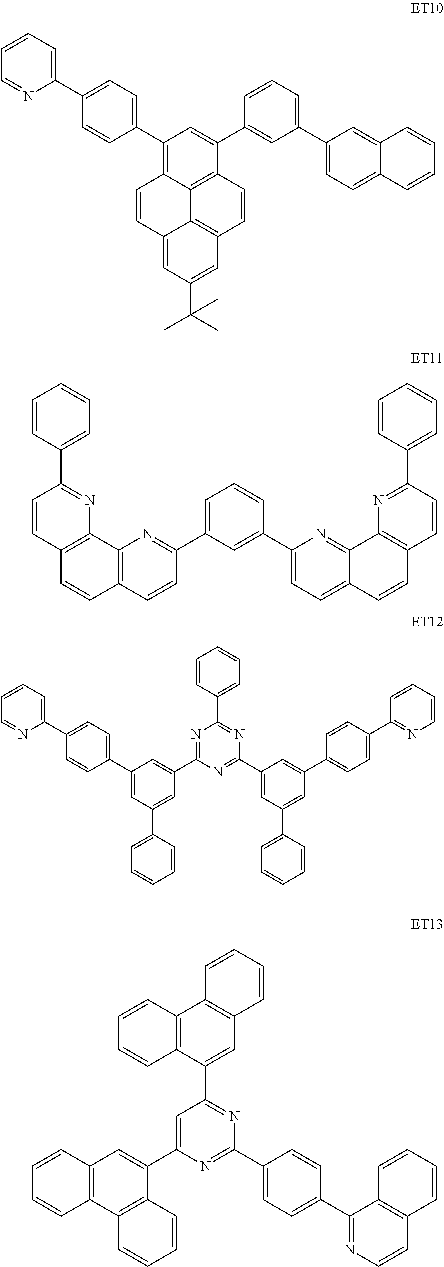 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

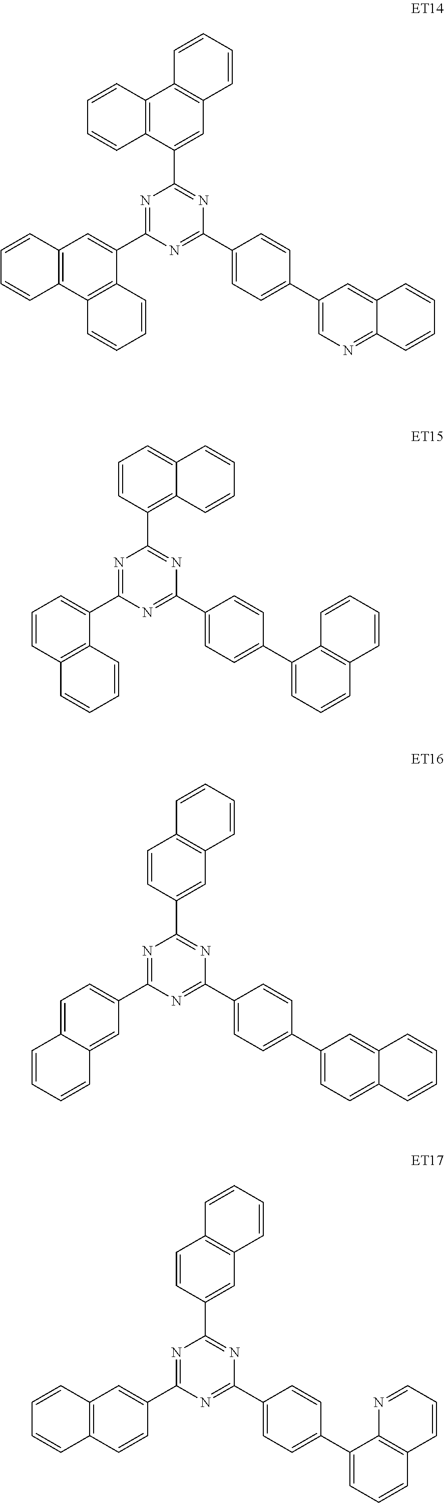 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

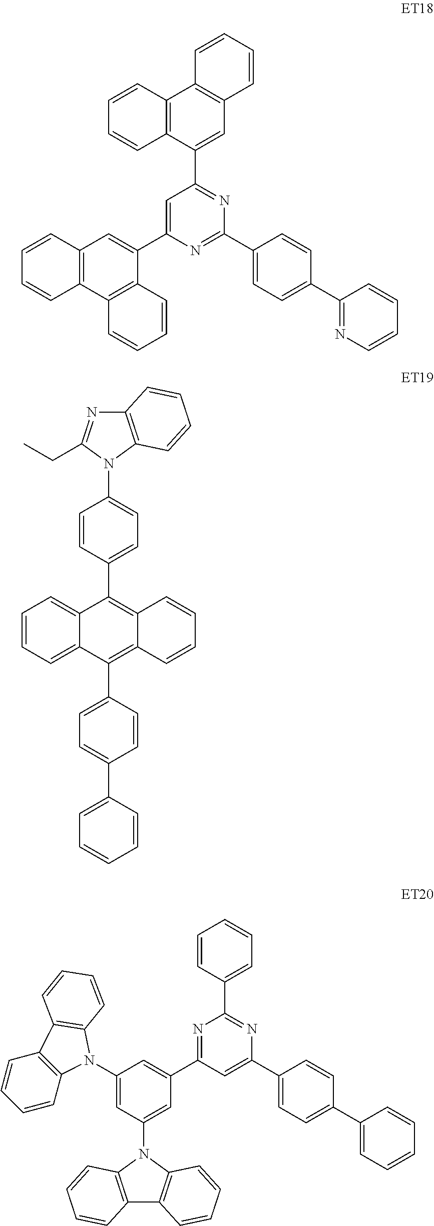

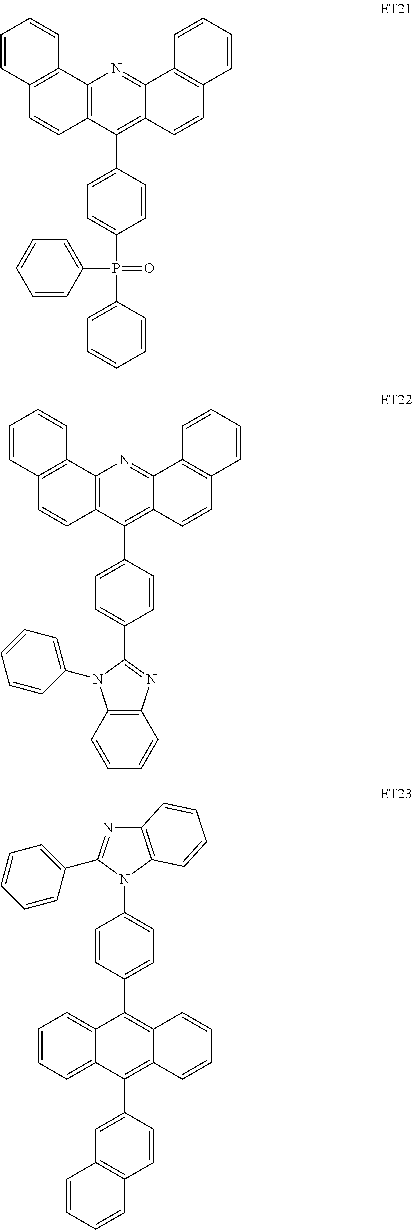

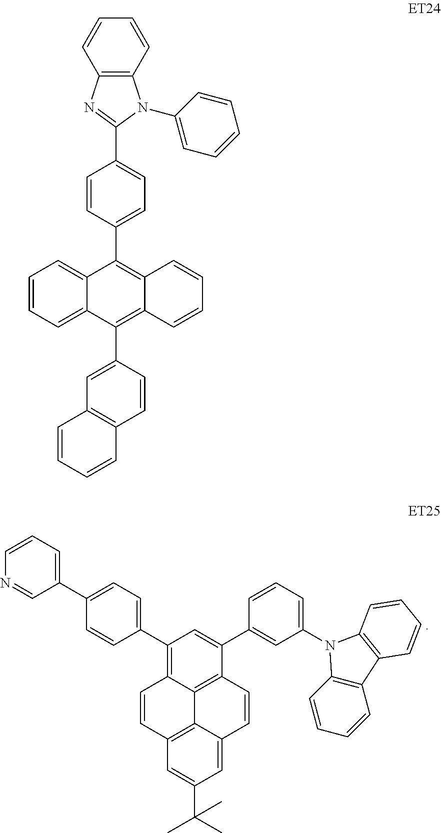 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. While not wishing to be bound by theory, it is understood that when the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a L₁ complex. The L₁ complex may include, for example, Compound ET-D₁ (lithium 8-hydroxyquinolate, LiQ) or ET-D₂.

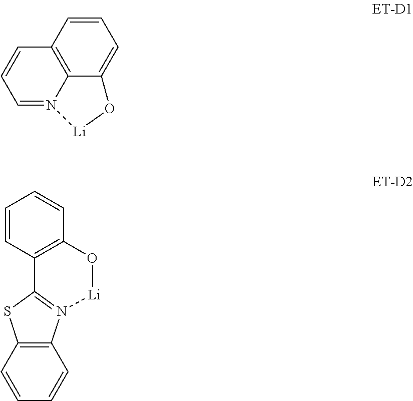

The electron transport region may include an electron injection layer that promotes flow of electrons from the second electrode 19 thereinto.

The electron injection layer may include at least one selected from LiF, NaCl, CsF, Li₂O, and BaO.

A thickness of the electron injection layer may be in a range of about 1 Å to about 100 Å, for example, about 3 Å to about 90 Å. While not wishing to be bound by theory, it is understood that when the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be selected from metal, an alloy, an electrically conductive compound, and a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIG. 1, but embodiments of the present disclosure are not limited thereto.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an iso-butyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, and an iso-propyloxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a carbocyclic aromatic system that has at least one heteroatom selected from N, O, P, Si, and S as a ring-forming atom, and 1 to 60 carbon atoms. The term “C₁-C₆₀ heteroarylene group” as used herein refers to a divalent group having a carbocyclic aromatic system that has at least one heteroatom selected from N, O, P, and S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₆-C₆₀ aryloxy group” used herein indicates —OA₁₀₂ (wherein A₁₀₂ is the C₆-C₆₀ aryl group), and a C₆-C₆₀ arylthio group used herein indicates —SA₁₀₃ (wherein A₁₀₃ is the C₆-C₆₀ aryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, and S, other than carbon atoms, as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₆₀ carbocyclic group” as used herein refers to a saturated or unsaturated cyclic group having, as a ring-forming atom, 5 to 60 carbon atoms only. The C₅-C₆₀ carbocyclic group may be a monocyclic group or a polycyclic group.

The term “C₁-C₆₀ heterocyclic group” as used herein refers to a saturated or unsaturated cyclic group having, as a ring-forming atom, at least one heteroatom selected from N, O, Si, P, and S other than 1 to 60 carbon atoms. The C₁-C₆₀ heterocyclic group may be a monocyclic group or a polycyclic group.

At least one substituent of the substituted C₅-C₆₀ carbocyclic group, the substituted C₁-C₆₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇) and —P(═O)(Q₁₈)(Q₁₉);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇) and —P(═O)(Q₂₈)(Q₂₉); and

—N(Q₃₁)(Q₃₂),—Si(Q₃₃)(Q₃₄)(Q₃₅),—B(Q₃₆)(Q₃₇), and —P(═O)(Q₃₈)(Q₃₉), and

Q₁ to Q₉, Q₁₁ to Q₁₉, Q₂₁ to Q₂₉, and Q₃₁ to Q₃₉ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one selected from a C₁-C₆₀ alkyl group, and a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group.

Hereinafter, a compound and an organic light-emitting device according to embodiments are described in detail with reference to Synthesis Example and Examples. However, the organic light-emitting device is not limited thereto. The wording “B was used instead of A” used in describing Synthesis Examples means that an amount of A used was identical to an amount of B used, in terms of a molar equivalent.

The term “room temperature” as used herein refers to about 25° C.

### EXAMPLES

Manufacture of Organic Light-Emitting Device

A glass substrate, on which an ITO electrode (first electrode, anode) having a thickness of 1,500 Å was formed, was washed by using distilled water. When the washing with distilled water was completed, sonification washing was performed by using a solvent, such as iso-propyl alcohol, acetone, or methanol. The result was dried and then transferred to a plasma washer, and the resultant substrate was washed with oxygen plasma for 5 minutes and then transferred to a vacuum depositing device.

Compound HT3 and Compound HT-D₂ were co-deposited on the ITO electrode of the glass substrate to form a hole injection layer having a thickness of 100 Å, Compound HT3 was deposited on the hole injection layer to form a hole transport layer having a thickness of 1,300 Å, and mCP was deposited on the hole transport layer to form an electron blocking layer having a thickness of 150 Å, thereby forming a hole transport region.

Compound E1 (host), Compound AD3 (auxiliary dopant), and Compound FD(5) (fluorescent dopant) were co-deposited on the hole transport region at a volume ratio of 85:15:0.3 to form an emission layer having a thickness of 300 Å.

BCP was vacuum-deposited on the emission layer to form a hole blocking layer having a thickness of 100 Å, Compound ET3 and LiQ were vacuum-deposited on the hole blocking layer to form an electron transport layer having a thickness of 250 Å, LiQ was deposited on the electron transport layer to form an electron injection layer having a thickness of 5 Å, and Al was deposited on the electron injection layer to form an Al second electrode (cathode) having a thickness of 1,000 Å, thereby manufacturing an OLED 1-2.

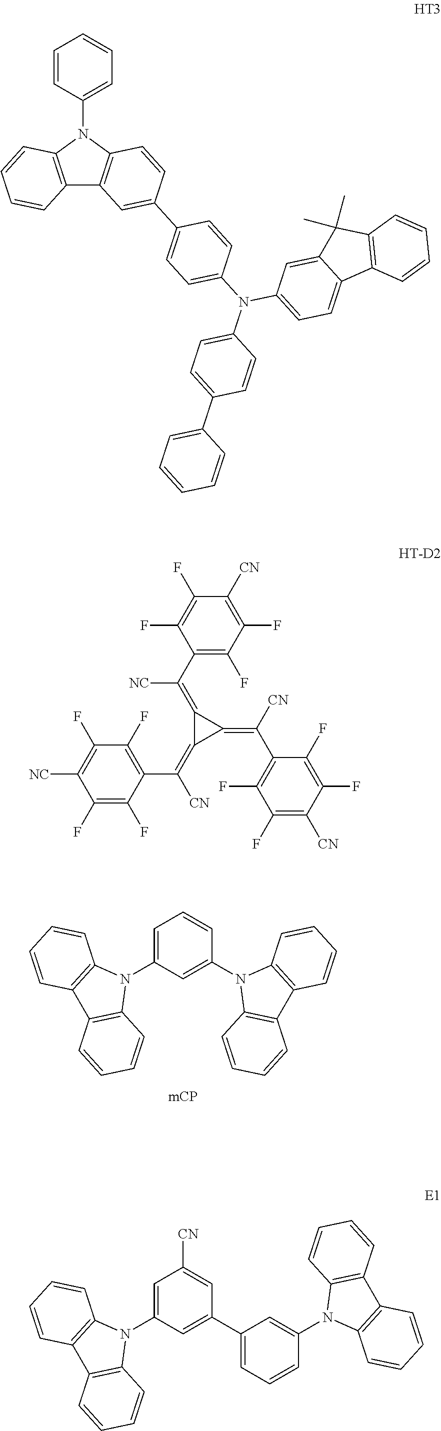 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1cc(-n2c3ccccc3c3ccccc32)cc(-n2c3ccccc3c3ccccc32)c1 ; "mCP" ; N#Cc1cc(-c2cccc(-n3c4ccccc4c4ccccc43)c2)cc(-n2c3ccccc3c3ccccc32)c1]

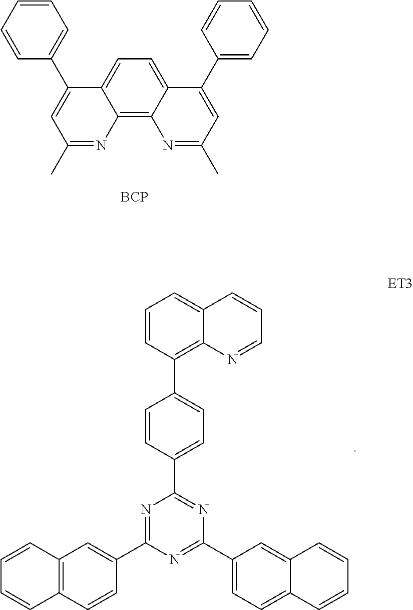

The other OLEDs were manufactured in the same manner as described above, except that a configuration of an emission layer was changed as shown in Table 1. A volume ratio of Table 1 represents a volume ratio of host: auxiliary dopant: fluorescent dopant, and host: auxiliary dopant or host: fluorescent dopant. As the host of OLED 5, mixture of Compound H19 (hole transport host) and Compound E1 (electron transport host) were used at a volume ratio of 3:7.

TABLE 1

| | | Auxiliary | Fluorescent | |
|---|---|---|---|---|
| OLED No. | Host | dopant | dopant | Volume ratio |
| OLED 1-1 | E1 | AD3 | — | 85:15 |
| (Comparative | | | | |
| Example) | | | | |
| OLED 1-2 | E1 | AD3 | FD(5) | 85:15:0.3 |
| (Example) | | | | |
| OLED 1-3 | E1 | — | FD(5) | 99:1 |
| (Comparative | | | | |
| Example) | | | | |
| OLED 2-1 | E1 | AD3 | — | 85:15 |
| (Comparative | | | | |
| Example) | | | | |
| OLED 2-2 | E1 | AD3 | FD11 | 85:15:0.3 |
| (Example) | | | | |
| OLED 2-3 | E1 | — | FD11 | 97:3 |
| (Comparative | | | | |
| Example) | | | | |
| OLED 3-1 | E1 | AD-A | — | 85:15 |
| (Comparative | | | | |
| Example) | | | | |
| OLED 3-2 | E1 | AD-A | FD11 | 85:15:0.3 |
| (Comparative | | | | |
| Example) | | | | |
| OLED 4-1 | E10 | AD-B | — | 85:15 |
| (Comparative | | | | |
| Example) | | | | |
| OLED 4-2 | E10 | AD-B | FD(7) | 85:15:0.3 |
| (Comparative | | | | |
| Example) | | | | |
| OLED 5 | H19:E1 | AD3 | FD11 | 85:15:0.3 |
| (Example) | (3:7) | | | |
| OLED 6 | H19:E1 | AD3 | FD11 | 85:15:0.3 |
| (Example) | (1:9) | | | |
| OLED 7 | H19:E1 | AD18 | FD11 | 85 15:0.3 |
| (Example) | (1:7) | | | |

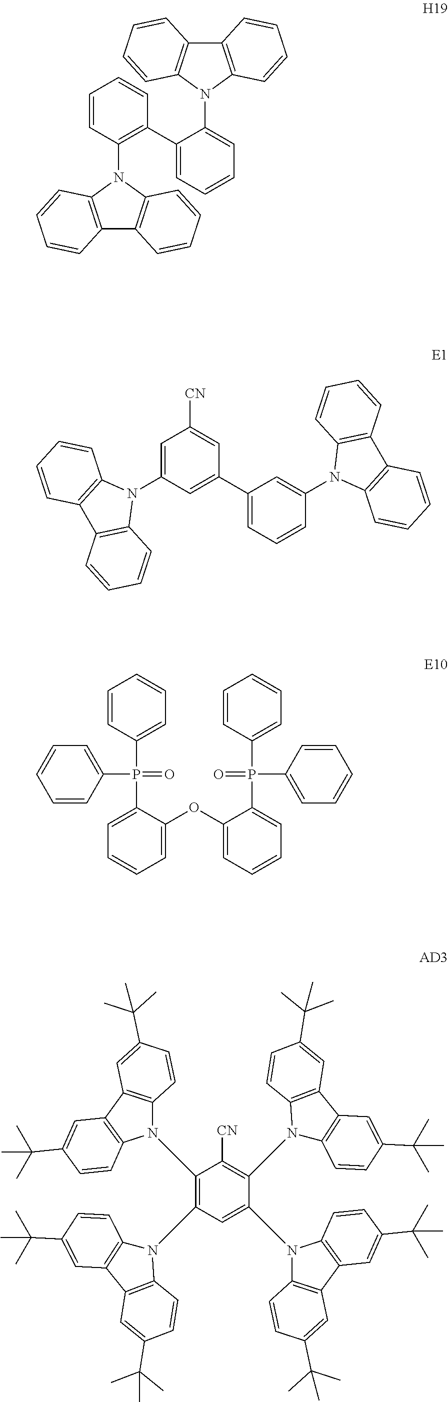 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3ccccc32)c1 ; O=P(c1ccccc1)(c1ccccc1)c1ccccc1Oc1ccccc1P(=O)(c1ccccc1)c1ccccc1 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccc(C(C)(C)C)cc3c3cc(C(C)(C)C)ccc32)c(C#N)c1-n1c2ccc(C(C)(C)C)cc2c2cc(C(C)(C)C)ccc21]

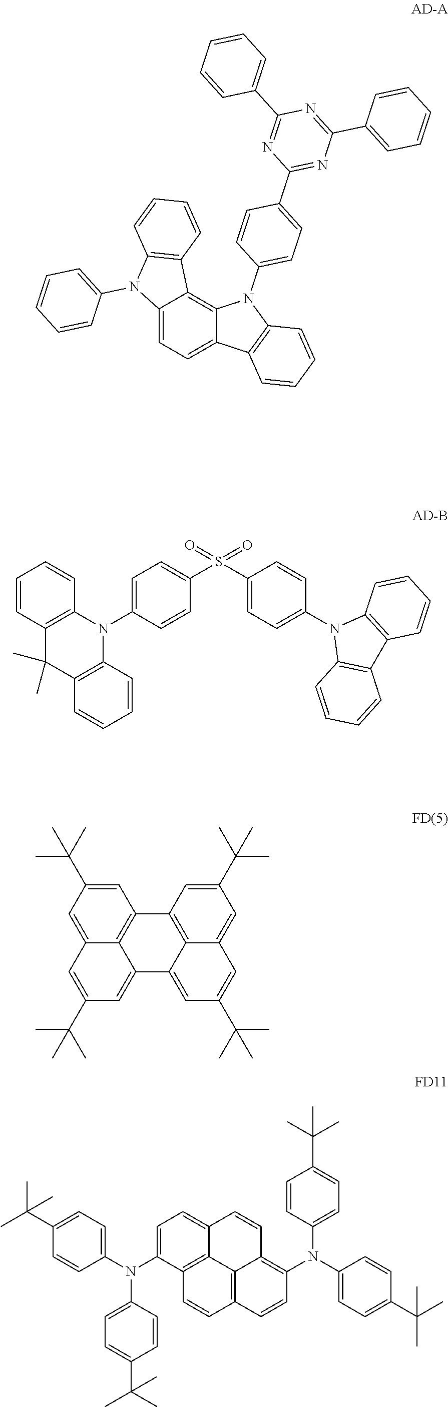

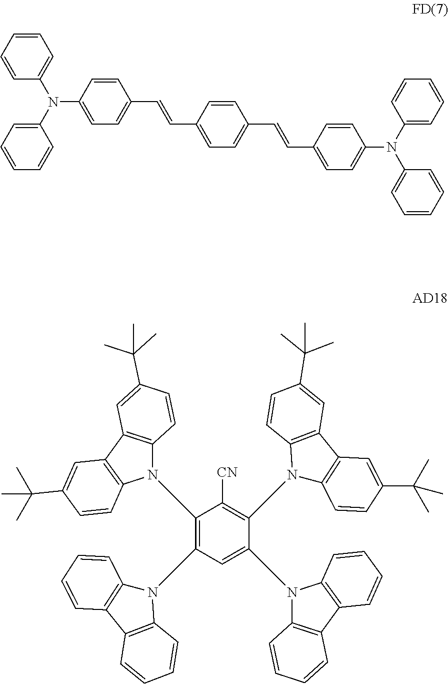 [SMILES: C(=C\c1ccc(N(c2ccccc2)c2ccccc2)cc1)/c1ccc(/C=C/c2ccc(N(c3ccccc3)c3ccccc3)cc2)cc1 ; CC(C)(C)c1ccc2c(c1)c1cc(C(C)(C)C)ccc1n2-c1c(-n2c3ccccc3c3ccccc32)cc(-n2c3ccccc3c3ccccc32)c(-n2c3ccc(C(C)(C)C)cc3c3cc(C(C)(C)C)ccc32)c1C#N]

### Evaluation Example 1

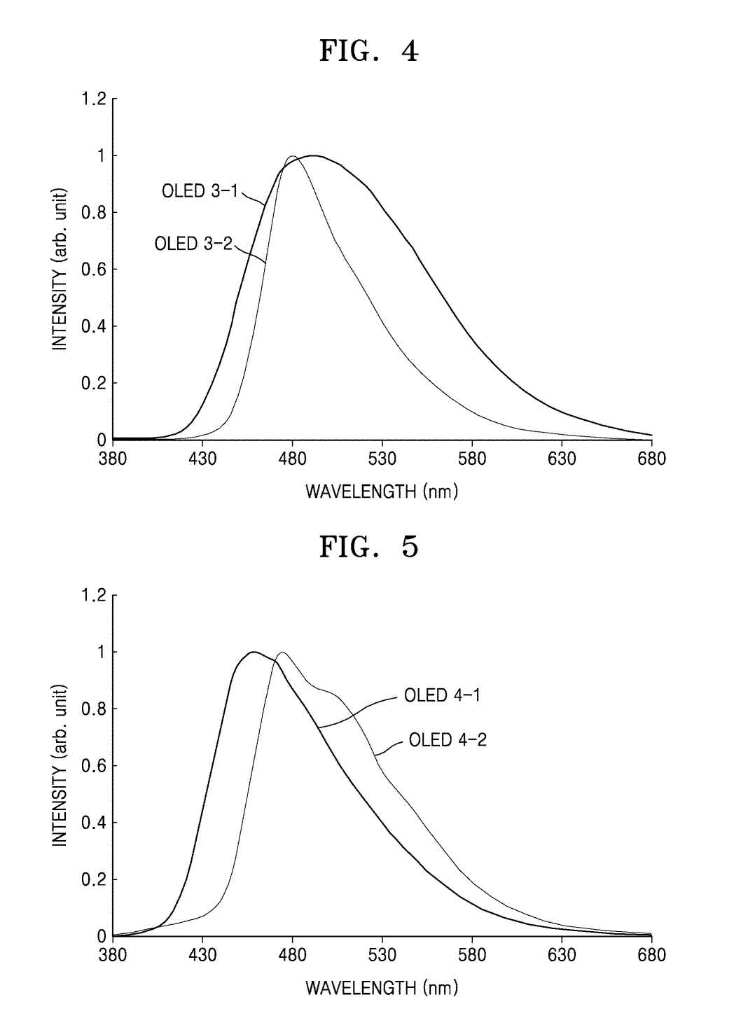

EL spectra of OLEDs 1-1, 1-2, and 1-3, EL spectra of OLEDs 2-1, 2-2, and 2-3, EL spectra of OLEDs 3-1 and 3-2, and EL spectra of OLEDs 4-1 and 4-2 were evaluated by using a luminance meter (Minolta Cs-1000A) (at 500 cd/m²), and results thereof are shown in FIGS. 4 to 7.

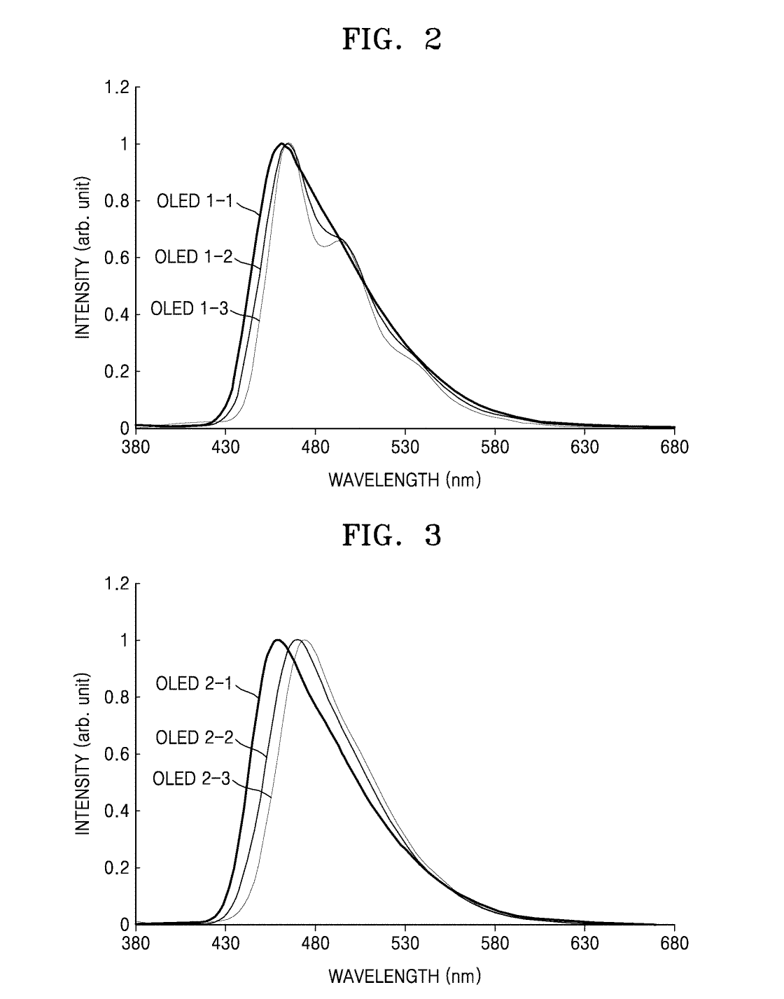

Referring to FIGS. 2 and 3, it is confirmed that maximum emission wavelengths of OLEDs 1-2 and 2-2 are substantially the same as maximum emission wavelengths of OLEDs 1-3 and 2-3, not maximum emission wavelengths of OLEDs 1-1 and 2-1, and OLEDs 1-2 and 2-2 substantially finally emit light from the fluorescent dopant, not the auxiliary dopant. On the other hand, referring to FIGS. 4 and 5, it is confirmed that maximum emission wavelengths of OLEDs 3-2 and 4-2 are different from maximum emission wavelengths of OLEDs 3-1 and 4-1, and OLEDs 3-2 and 4-2 substantially finally emit light from the fluorescent dopant, not the auxiliary dopant.

### Evaluation Example 2

After a quartz substrate washed by chloroform and pure water was prepared, and Films 1 to 4 having a thickness of 50 nm were prepared by vacuum-depositing (co-depositing) predetermined materials shown in Table 2 at a vacuum degree of 10⁻⁷ torr.

TABLE 2

| | | | Fluorescent | |
|---|---|---|---|---|
| | Host | Auxiliary dopant | dopant | Volume ratio |
| Film 1 | E1 | AD3 | FD(5) | 85:15:0.3 |
| Film 2 | E1 | AD3 | FD11 | 85:15:0.3 |
| Film 3 | E1 | — | FD11 | 97:3 |
| Film 4 | E1 | AD-A | FD11 | 85:15:0.3 |

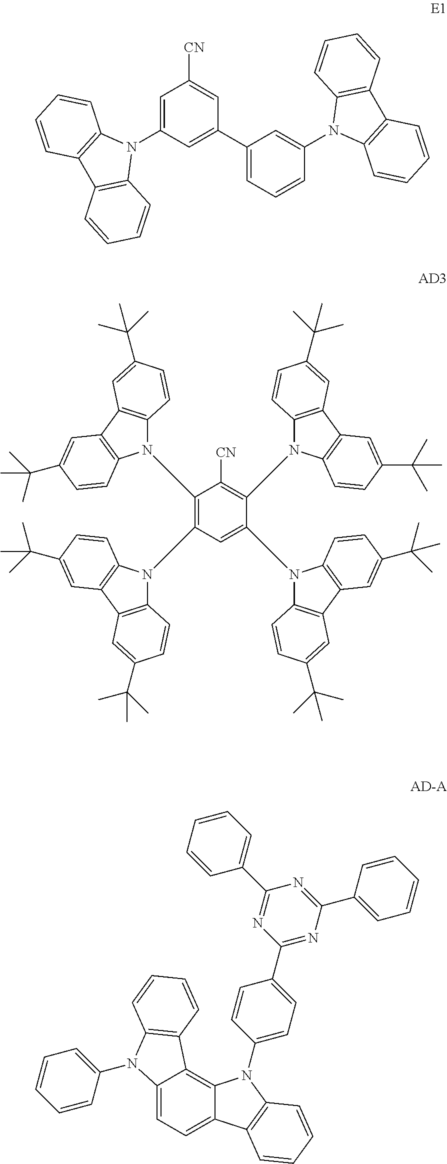 [SMILES: N#Cc1cc(-c2cccc(-n3c4ccccc4c4ccccc43)c2)cc(-n2c3ccccc3c3ccccc32)c1 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccc(C(C)(C)C)cc3c3cc(C(C)(C)C)ccc32)c(C#N)c1-n1c2ccc(C(C)(C)C)cc2c2cc(C(C)(C)C)ccc21 ; c1ccc(-c2nc(-c3ccccc3)nc(-c3ccc(-n4c5ccccc5c5ccc6c(c7ccccc7n6-c6ccccc6)c54)cc3)n2)cc1]

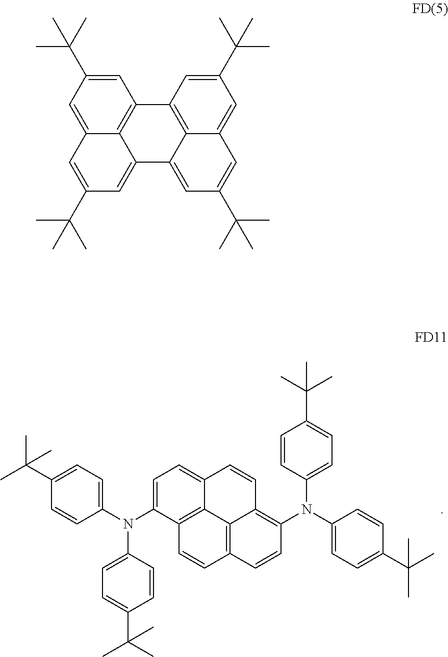

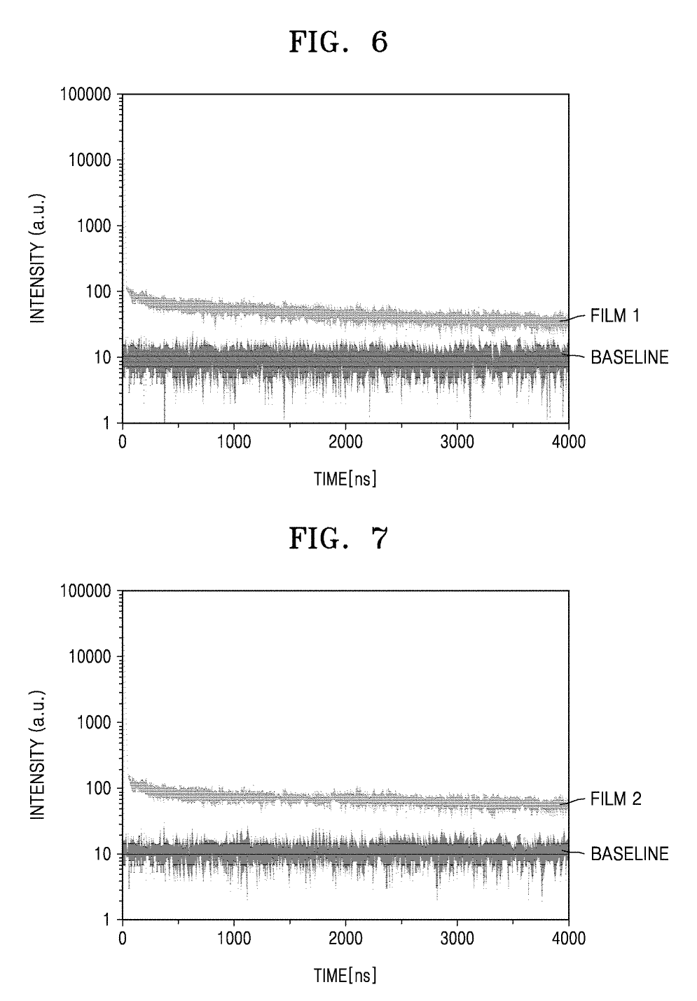

Then, PL spectra of Films 1 to 4 were evaluated at room temperature by using a TRPL measurement system FluoTime 300 (manufactured by PicoQuant) and a pumping source PLS340 (excitation wavelength=340 nanometers, spectral width=20 nanometers) (manufactured by PicoQuant), wavelengths of main peaks of the spectra were determined, and TRPL curves in which fitting was sufficiently possible are obtained by repeating measurement of the number of photons emitted at a wavelength of a main peak from each film according to the time based on time-correlated single photon counting (TCSPC) by a photon pulse (pulse width=500 picoseconds) which PLS340 applied to the films, and the TRPL curves are shown in FIGS. 6 to 9.

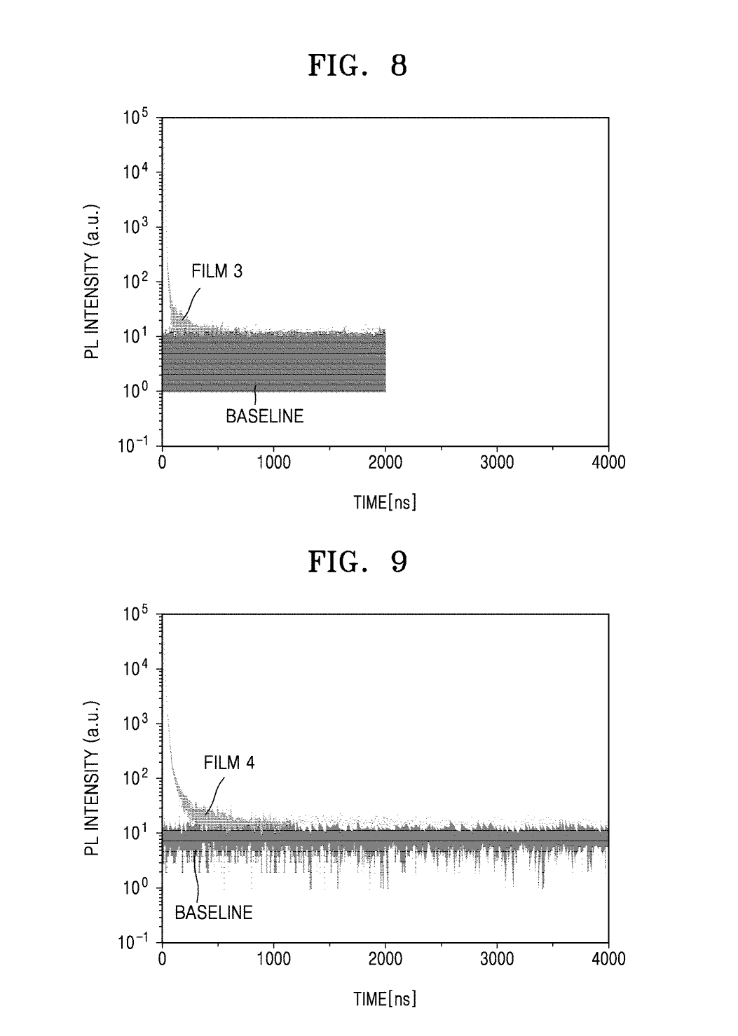

Referring to FIGS. 6, 7, and 9, it is confirmed that in the Films 1, 2, and 4, the final light emission occurs in the fluorescent dopant by occurring delayed fluorescence in the auxiliary dopant and then transferring energy from the auxiliary dopant to the fluorescent dopant. Referring to FIG. 8, it is confirmed that delayed fluorescence component was not observed at all in Film 3.

### Evaluation Example 3

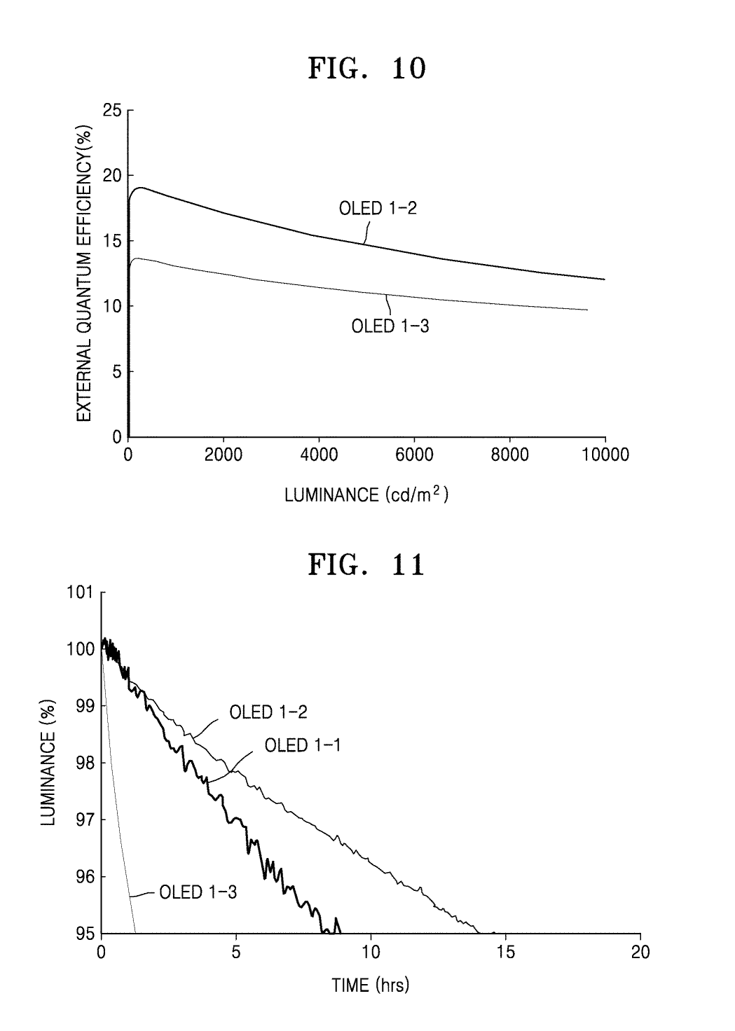

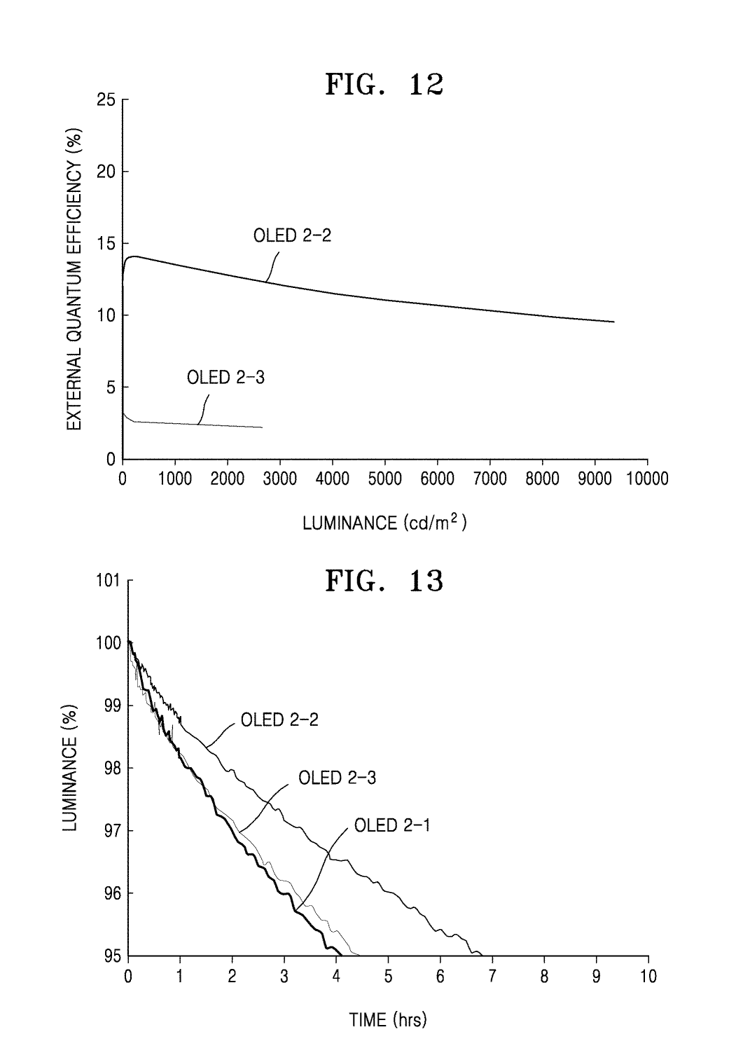

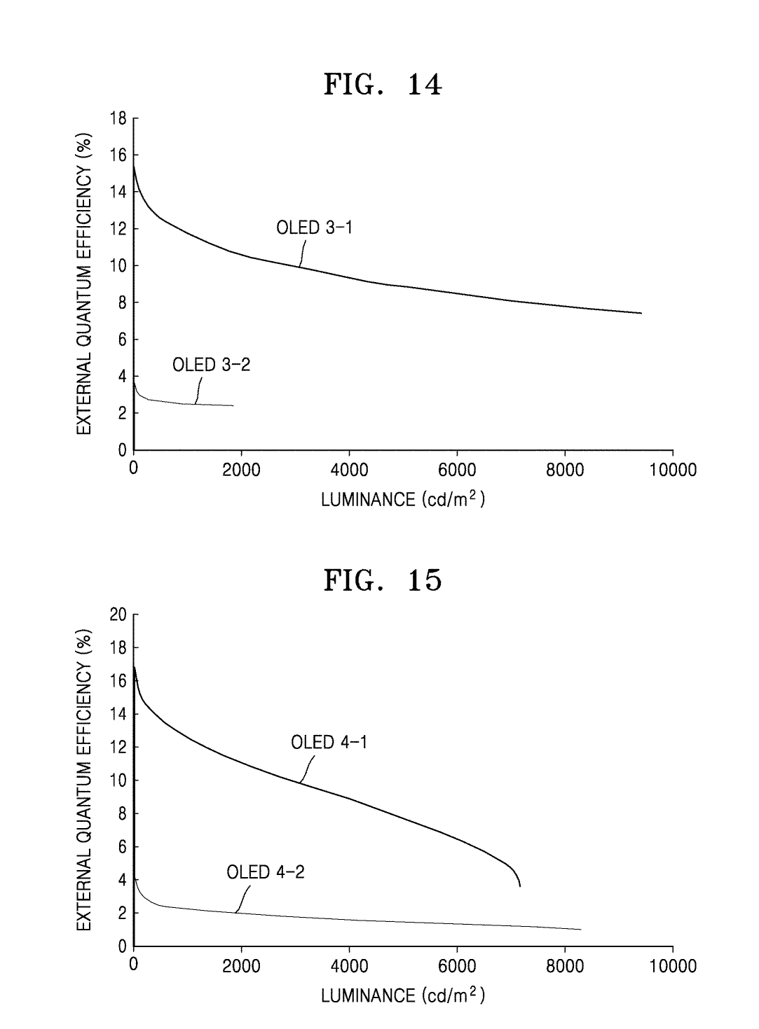

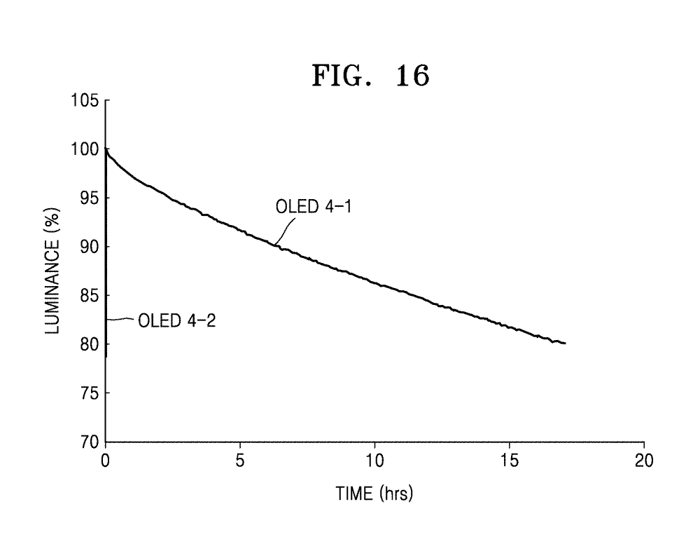

The driving voltage, current density, external quantum efficiency (EQE), and/or lifespan of OLEDs 1-1 to 1-3, 2-1 to 2-3, 3-1, 3-2, 4-1, 4-2, and 5 were measured by using a current-voltage meter (Keithley 2400) and a luminance meter (Minolta Cs-1000A), and results thereof are shown in Table 3, Table 4, and FIGS. 10 to 17. Data other than the maximum value of the external quantum efficiency were measured at 500 candelas per square meter (cd/m²). The lifespan (T₉₅) data (at 500 cd/m²) of Table 4 indicates an amount of time (hr) that lapsed when luminance was 95% of initial luminance (100%). In addition to Tables 3 and 4, a luminance-EQE graph of OLEDs 1-2 and 1-3 is shown in FIG. 10, a time-luminance graph of OLEDs 1-1, 1-2, and 1-3 is shown in FIG. 11, a luminance-EQE graph of OLEDs 2-2 and 2-3 is shown in FIG. 12, a time-luminance graph of OLEDs 2-1, 2-2, and 2-3 is shown in FIG. 13, a luminance-EQE graph of OLEDs 3-1 and 3-2 is shown in FIG. 14, a luminance-EQE graph of OLEDs 4-1 and 4-2 is shown in FIG. 15, and a time-luminance graph of OLEDs 4-1 and 4-2 is shown in FIG. 16.

TABLE 3

| | | | External quantum | |
|---|---|---|---|---|
| | Driving | | efficiency (%) | |
| | voltage | Current density | @ | Maximum |
| No. | (V) | (mA/cm²) | 500 cd/m² | value |
| OLED 1-2 | 4.31 | 3.09 | 9.1 | 9.4 |
| OLED 1-3 | 5.71 | 12.04 | 2.5 | 2.9 |
| OLED 2-2 | 4.17 | 2.36 | 12.1 | 12.2 |
| OLED 2-3 | 5.4 | 10.3 | 2.5 | 3.3 |
| OLED 3-2 | 5.47 | 9.7 | 2.7 | 3.6 |
| OLED 4-2 | 7.68 | 14.04 | 1.6 | 4.1 |
| OLED 5 | 4.28 | 2.09 | 13.9 | 14.0 |
| OLED 6 | 4.57 | 2.80 | 10.8 | 10.9 |
| OLED 7 | 4.80 | 2.60 | 11.4 | 11.5 |

TABLE 4

| | LT₉₅@500 cd/m² |
|---|---|
| No. | (hr) |
| OLED 1-2 | 4.49 |
| OLED 1-3 | 1.23 |
| OLED 2-2 | 5.07 |
| OLED 2-3 | 0.86 |
| OLED 4-2 | 0.02 |
| OLED 5 | 3.47 |
| OLED 6 | 9.29 |
| OLED 7 | 9.76 |

Referring to FIGS. 10 to 17 and Tables 3 and 4, it is confirmed that OLEDs 1-2, 2-2, and 5 to 7 have excellent external quantum efficiency and lifespan characteristics, as compared with those of OLEDs 1-3, 2-3, 3-2, and 4-2.

The organic light-emitting device may emit fluorescence having a relatively small full width at half maximum and have high efficiency and a long lifespan.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. An organic light-emitting device comprising:
a first electrode;
a second electrode facing the first electrode; and
an organic layer disposed between the first electrode and the second electrode,
wherein
the organic layer comprises an emission layer,
the emission layer comprises an auxiliary dopant, a fluorescent dopant, and a host,
the auxiliary dopant comprises a compound represented by Formula 1, and
the fluorescent dopant emits prompt fluorescence: 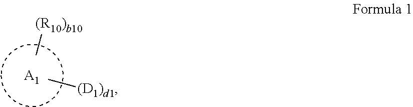
wherein A₁ in Formula 1 is i) a C₅-C₆₀ carbocyclic group comprising at least one of a cyano group (—CN) and a fluoro group (—F), ii) a C₅-C₆₀ heterocyclic group comprising at least one of a cyano group and a fluoro group, or iii) a π electron-depleted nitrogen-containing cyclic group, and
D₁ in Formula 1 is a group represented by Formula 2-1 or 2-2: 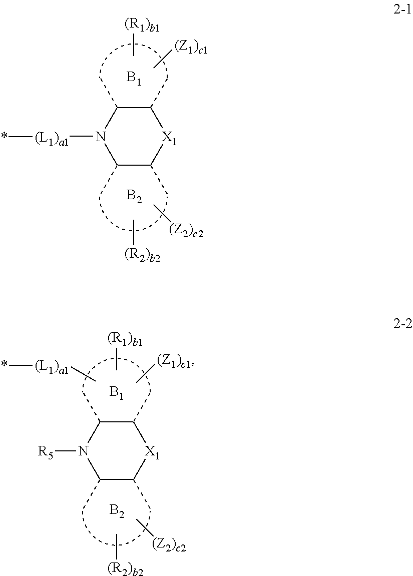
wherein, in Formula 1, d1 is an integer from 3 to 10, and groups D₁ in the number of d1 are identical to or different from each other,
B₁ and B₂ in Formulae 2-1 and 2-2 are each independently a benzene group, a naphthalene group, an anthracene group, a phenanthrene group, a triphenylene group, a fluorene group, a dibenzosilole group, a carbazole group, a dibenzofuran group, or a dibenzothiophene group,
X₁ in Formulae 2-1 and 2-2 is a single bond, C(R₃)(R₄), Si(R₃)(R₄), N(R₃), O, or S,
L₁ in Formulae 2-1 and 2-2 is selected from:
a single bond; and
a π electron-depleted nitrogen-free cyclic group, which is unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃),
a1 in Formulae 2-1 and 2-2 is an integer from 1 to 5,
R₁ to R₅ and R₁₀ in Formulae 1, 2-1, and 2-2 are each independently selected from:
hydrogen and deuterium;
a C₁-C₂₀ alkyl group and a C₁-C₂₀ alkoxy group, each unsubstituted or substituted with at least one selected from deuterium, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃);
a π electron-depleted nitrogen-free cyclic group, which is unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃); and
—Si(Q₄₀₄)(Q₄₀₅)(Q₄₀₆),
b1, b2, and b10 in Formulae 1, 2-1, and 2-2 are each independently an integer from 0 to 10,
Z₁ and Z₂ in Formulae 2-1 and 2-2 are each independently selected from:
—C(Q₄₀₇)(Q₄₀₈)(Q₄₀₉) and —Si(Q₄₀₇)(Q₄₀₈)(Q₄₀₉); and
a π electron-depleted nitrogen-free cyclic group, which is unsubstituted or substituted with at least one selected from deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, a tetraphenyl group, and —Si(Q₄₀₁)(Q₄₀₂)(Q₄₀₃),
c1 and c2 in Formulae 2-1 and 2-2 are each independently an integer from 0 to 5,
Q₄₀₁ to Q₄₀₉ are each independently selected from hydrogen, deuterium, a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, and a tetraphenyl group,
i) at least one of B₁ and B₂ in Formulae 2-1 and 2-2 are each independently a naphthalene group, an anthracene group, a phenanthrene group, a triphenylene group, a fluorene group, a dibenzosilole group, a carbazole group, a dibenzofuran group, or a dibenzothiophene group, or ii) the sum of c1 and c2 in Formulae 2-1 and 2-2 is equal to or greater than 1, and
* indicates a binding site to a neighboring atom.

2. The organic light-emitting device of claim 1, wherein
Z₁ to Z₂ are each independently selected from:
—C(Q₄₀₀₇)(Q₄₀₀₈)(Q₄₀₉) and —Si(Q₄₀₀₇)(Q₄₀₀₈)(Q₄₀₉); and
a phenyl group, a naphthyl group, a fluorenyl group, a dibenzosilolyl group, a carbazolyl group, a dibenzofuranyl group, a dibenzothiophenyl group, a biphenyl group, a terphenyl group, and a tetraphenyl group, each unsubstituted or substituted with at least one selected from deuterium, a C₁-C₂₀ alkyl group, a C₁-C₂₀ alkoxy group, a phenyl group, and —Si(Q₄₀₁)(Q₄₀₂)(Q₄₀₃).

3. The organic light-emitting device of claim 1, wherein
Z₁ and Z₂ are each independently selected from —CH₃, —CD₃, —CD₂H, —CDH₂, groups represented by Formulae 9-1 to 9-19, groups represented by Formulae 10-1 to 10-60, and —Si(Q₄₀₇)(Q₄₀₈)(Q₄₀₉), and
Q₄₀₇ to Q₄₀₉ are each independently selected from hydrogen, —CH₃, —CD₃, —CD₂H, —CDH₂, and groups represented by Formulae 9-1 to 9-19: 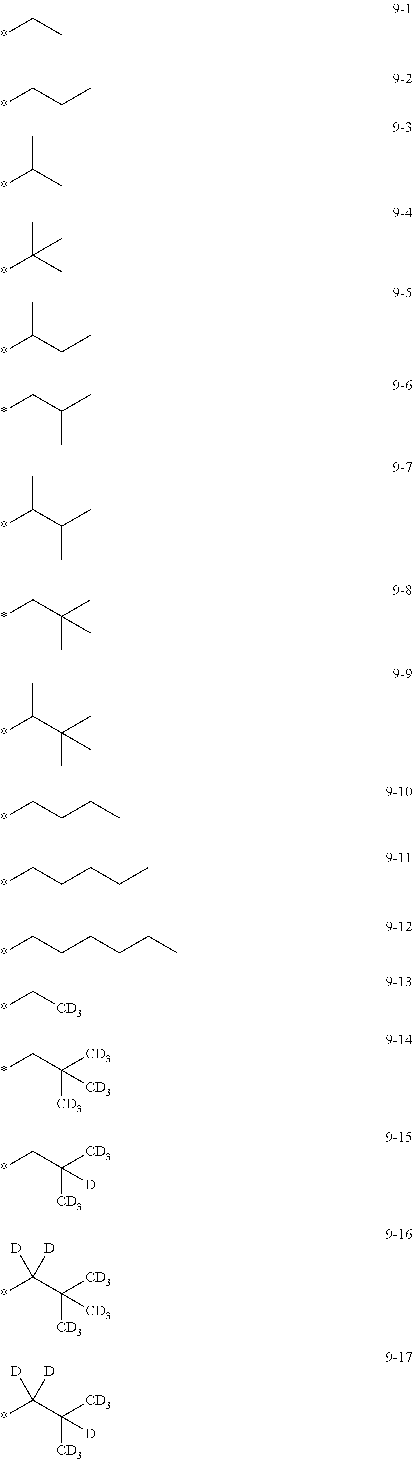 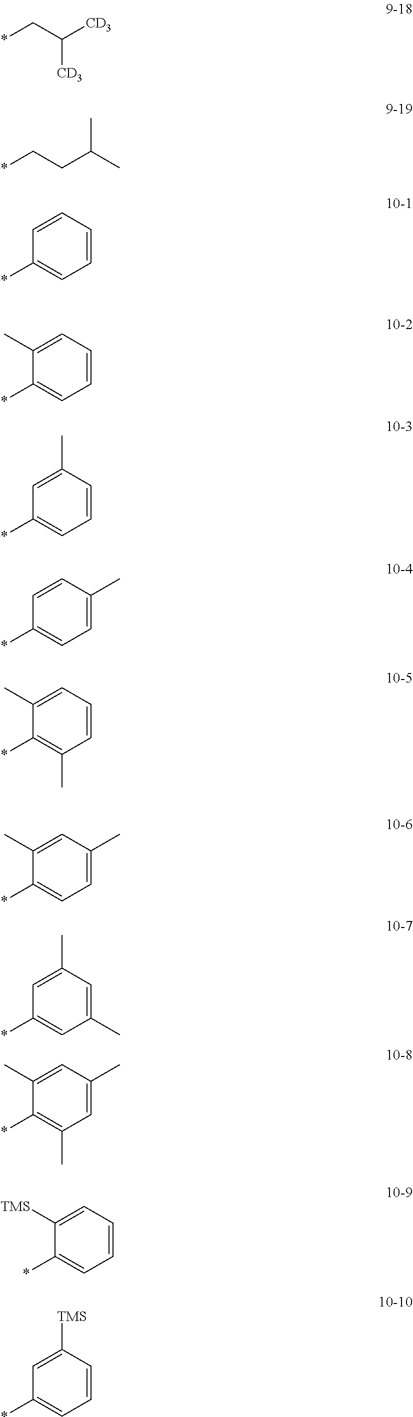 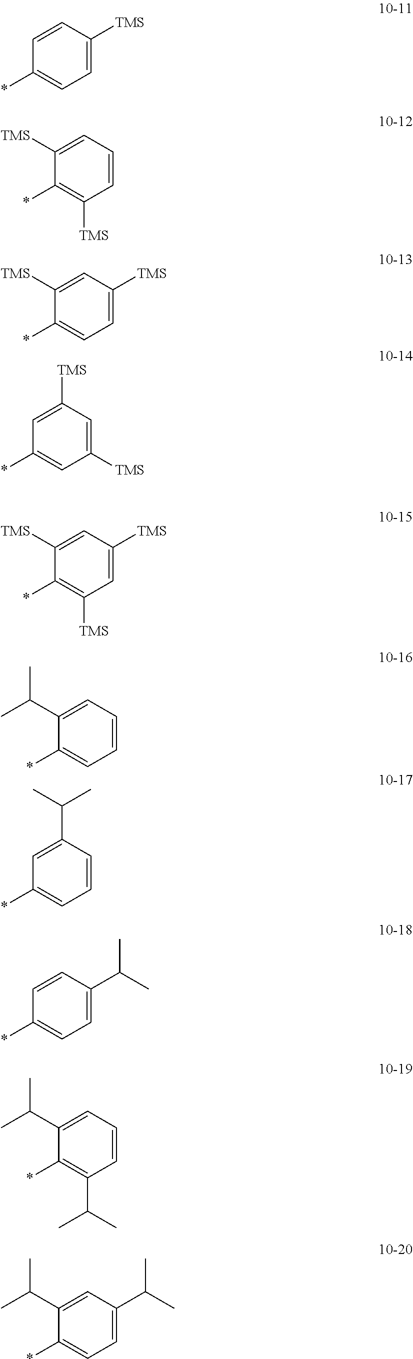 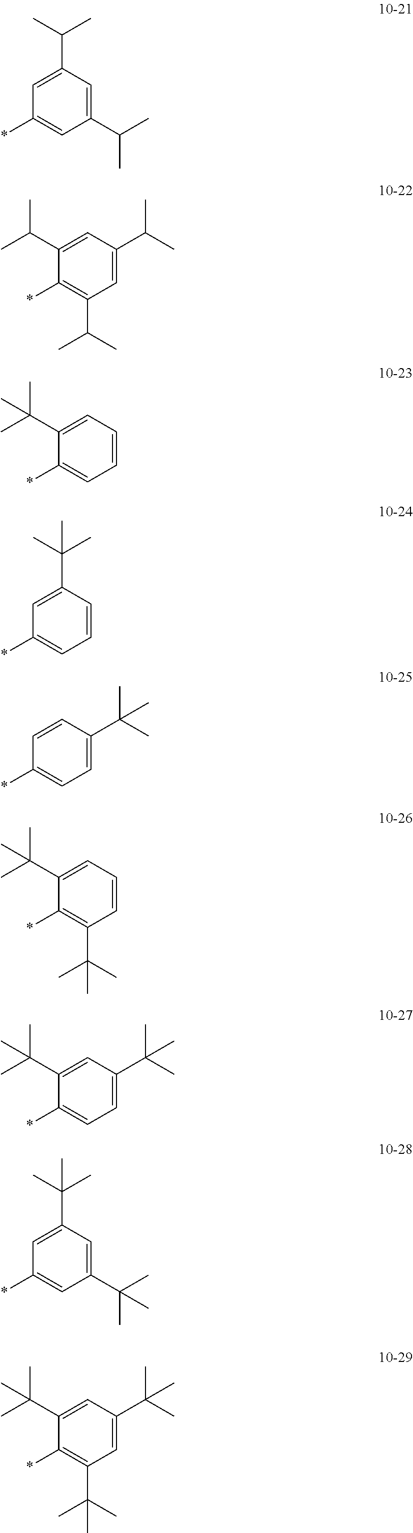 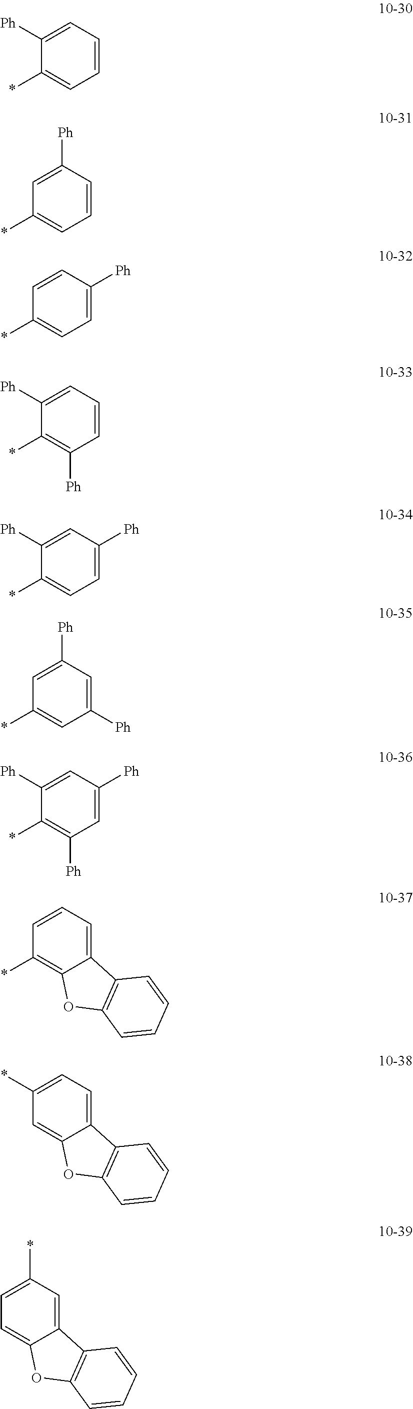 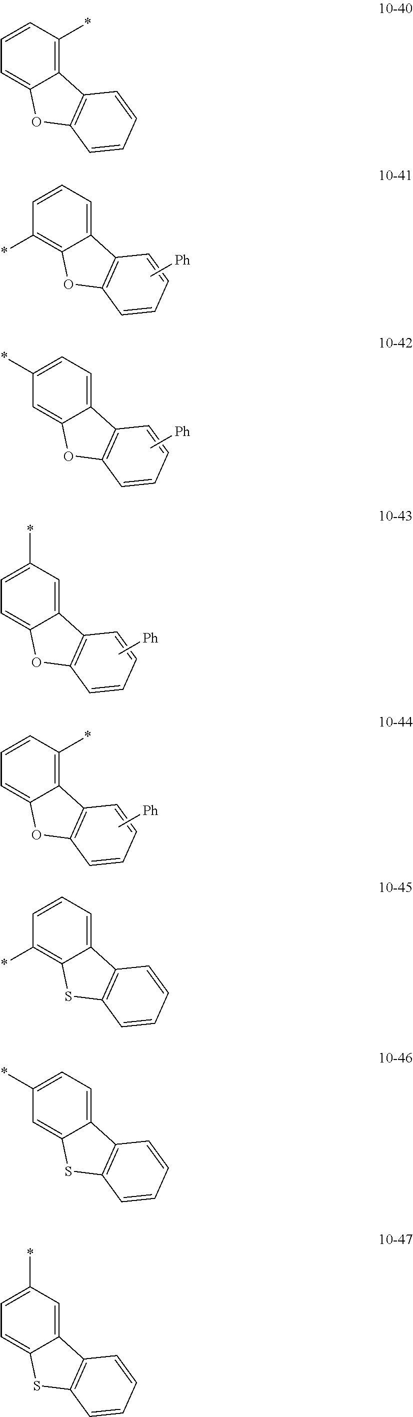 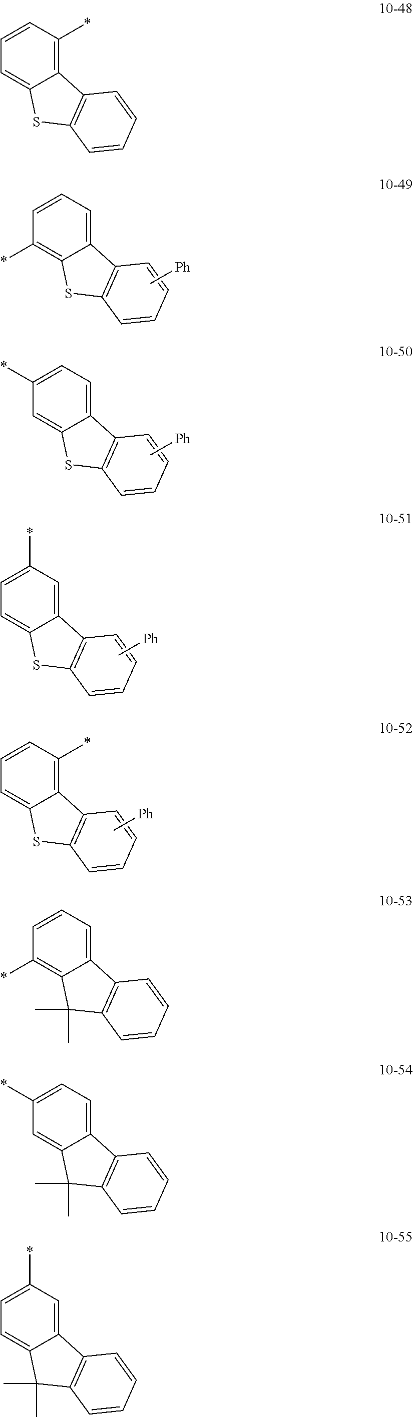 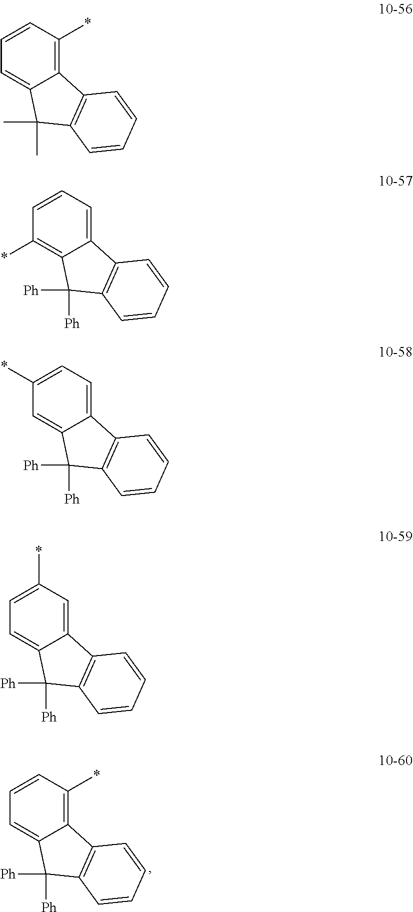
wherein, in Formulae 9-1 to 9-19 and 10-1 to 10-60, Ph indicates a phenyl group, TMS indicates a trimethylsilyl group, and * indicates a binding site to a neighboring atom.

4. The organic light-emitting device of claim 1, wherein
the sum of c1 and c2 is 1, 2, or 3.

5. The organic light-emitting device of claim 1, wherein
the auxiliary dopant comprises a compound represented by one of Formulae 1-1 to 1-7: 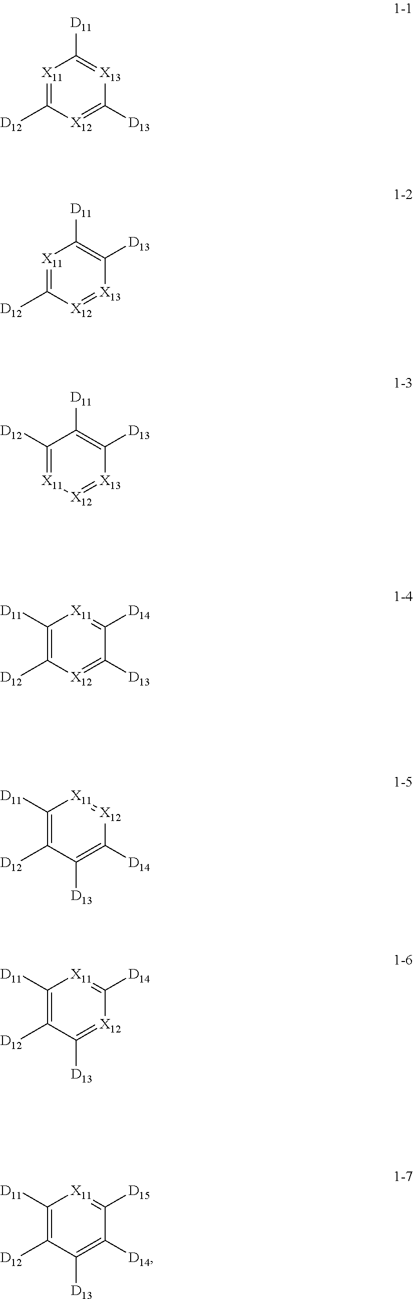
wherein, in Formulae 1-1 to 1-7,
D₁₁ to D₁₅ are each independently a group represented by Formula 2-1 or 2-2,
X₁₁ is C(CN), C(F), C(R₁₄), N, or C(R₁₁),
X₁₂ is C(CN), C(F), C(R₁₄), N, or C(R₁₂),
X₁₃ is C(CN), C(F), C(R₁₄), N, or C(R₁₃),
R₁₁ to R₁₃ are the same as described in connection with R₁₀ in claim 1,
R₁₄ is selected from a C₁-C₂₀ alkyl group, a C₁-C₂₀ alkoxy group, a phenyl group, a naphthyl group, an anthracenyl group, a phenanthrenyl group, a triphenylenyl group, a fluorenyl group, a di(C₁-C₁₀ alkyl)fluorenyl group, a di(C₆-C₆₀ aryl)fluorenyl group, a dibenzosilolyl group, a di(C₁-C₁₀ alkyl)dibenzosilolyl group, a di(C₆-C₆₀ aryl)dibenzosilolyl group, a carbazolyl group, a (C₁-C₁₀ alkyl)carbazolyl group, a (C₆-C₆₀ aryl)carbazolyl group, a dibenzofuranyl group, a dibenzothiophenyl group, a biphenyl group, a terphenyl group, and a tetraphenyl group, each substituted with at least one selected from a cyano group (—CN) and a fluoro group(—F), and
at least one of X₁₁ to X₁₃ in Formulae 1-1 to 1-3 is C(CN), C(F), C(R₁₄), or N, at least one of X₁₁ and X₁₂ in Formulae 1-4 to 1-6 is C(CN), C(F), C(R₁₄), or N, and X₁₁ in Formula 1-7 is C(CN), C(F), C(R₁₄), or N.

6. The organic light-emitting device of claim 1, wherein
a core represented by 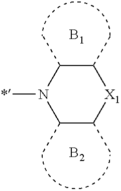
in Formulae 2-1 and 2-2 is represented by one of Formulae 3-1 to 3-35: 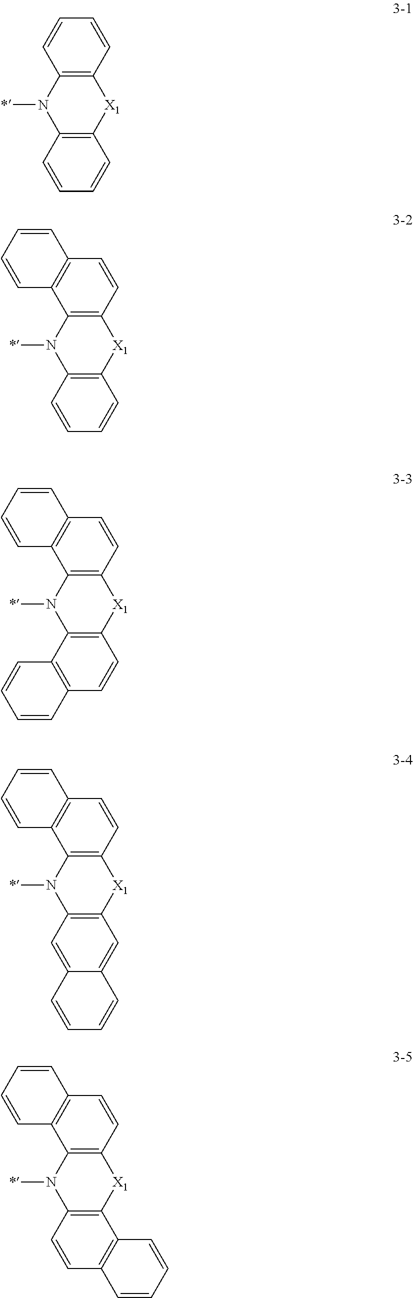 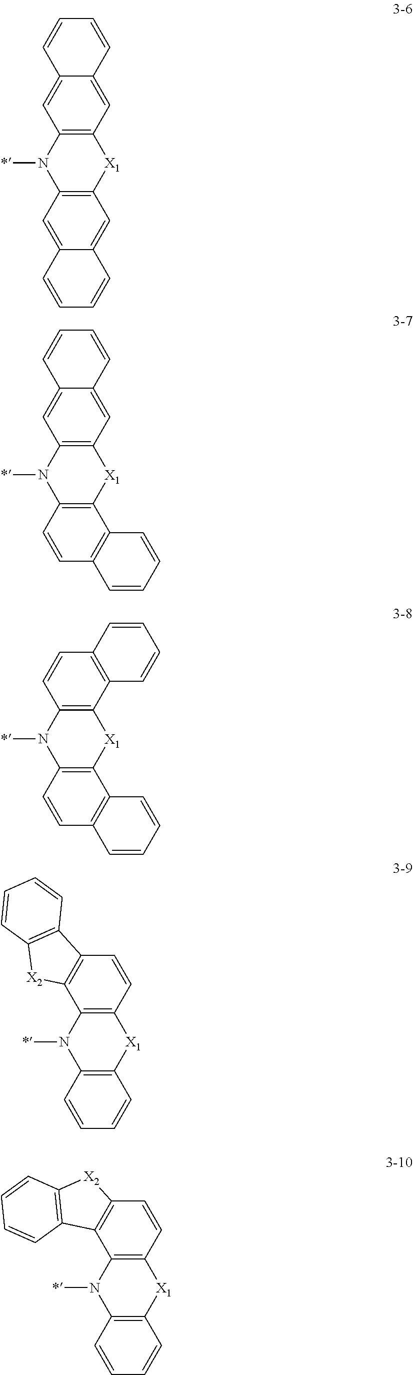 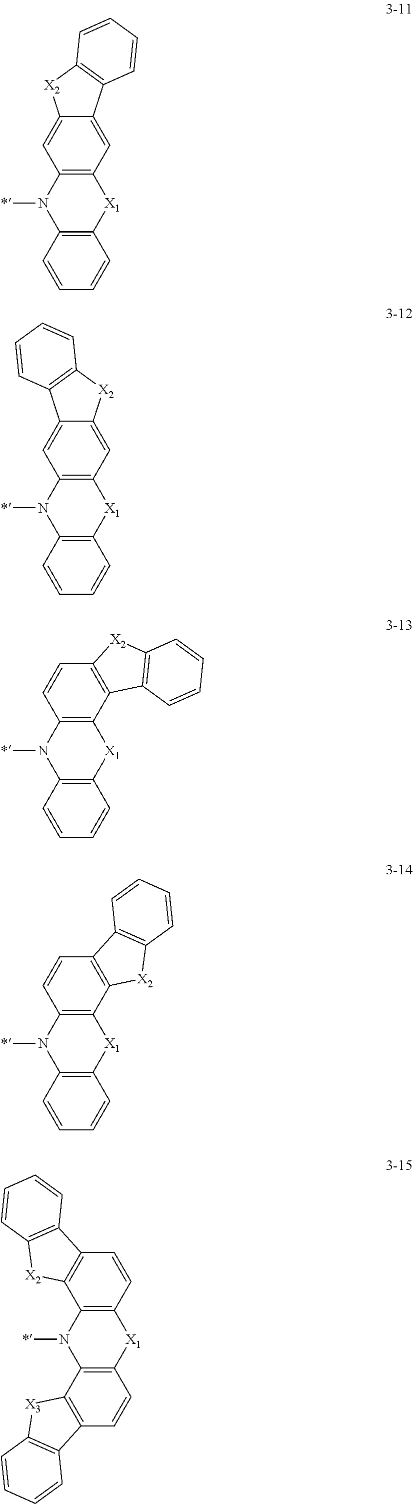 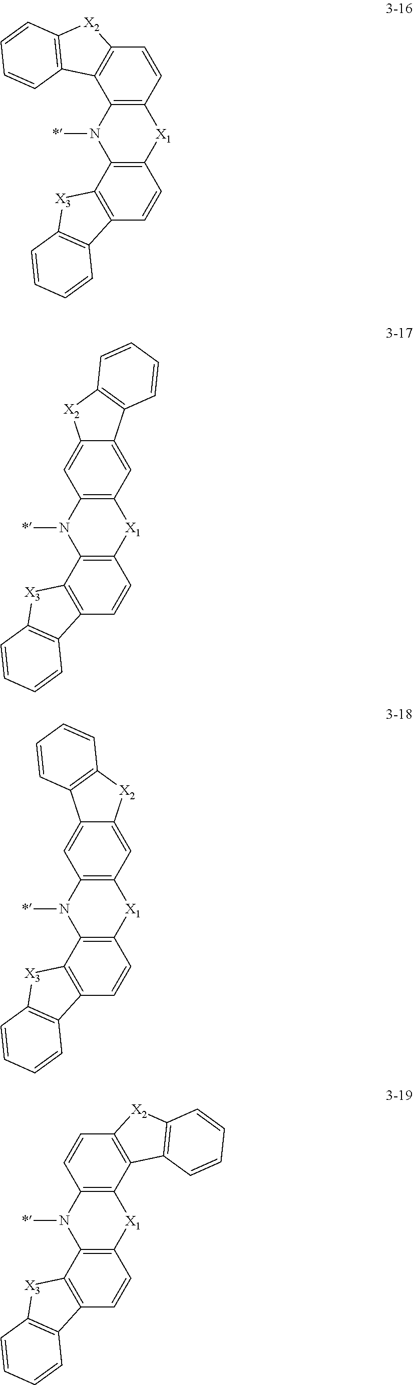 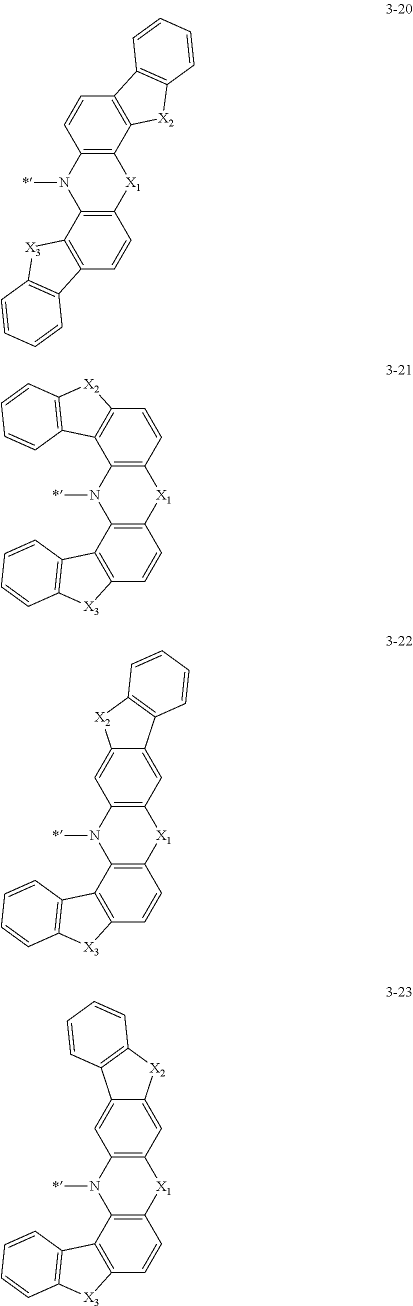 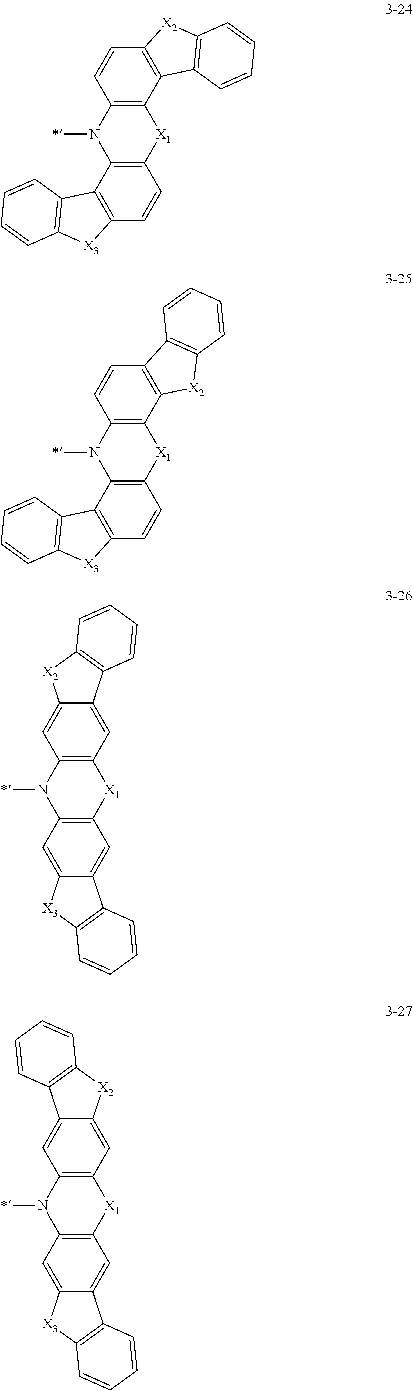 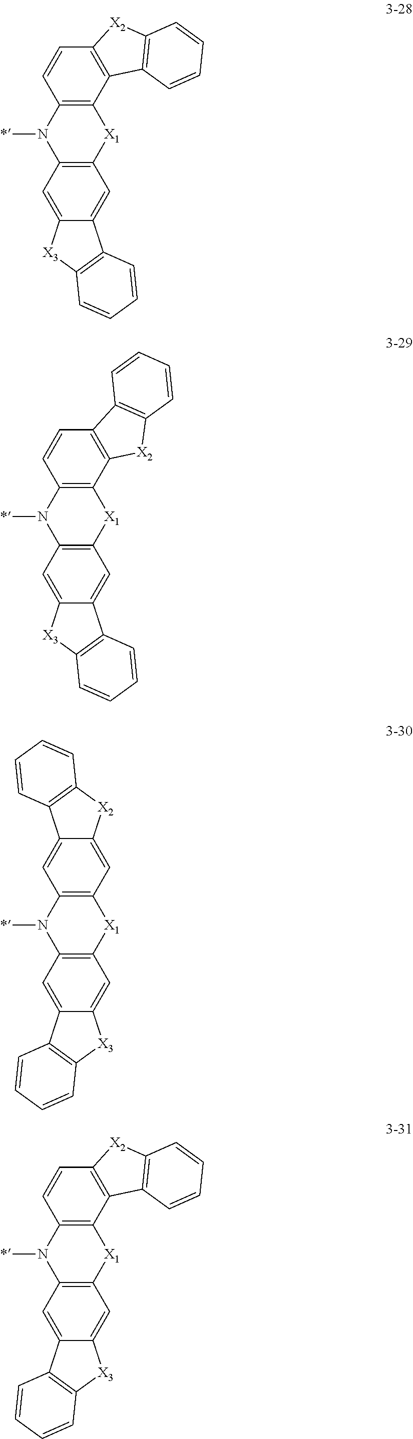 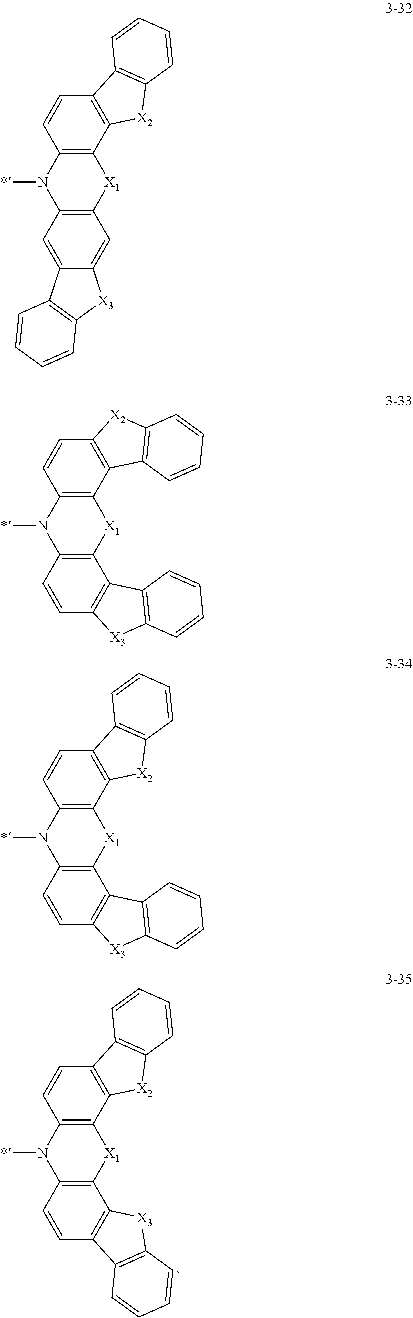
wherein, in Formulae 3-1 to 3-35,
X₁ is the same as described in claim 1,
X₂ is C(R₆)(R₇), Si(R₆)(R₇), N(R₆), O, or S,
X₃ is C(R₈)(R₉), Si(R₈)(R₉), N(R₈), O, or S,
R₆ to R₉ are the same as described in connection with R₃ in claim 1, and
*′ indicates a binding site to a neighboring atom.

7. The organic light-emitting device of claim 1, wherein
D₁ in Formula 1 is selected from groups represented by Formulae 2-1(1) to 2-1(82): 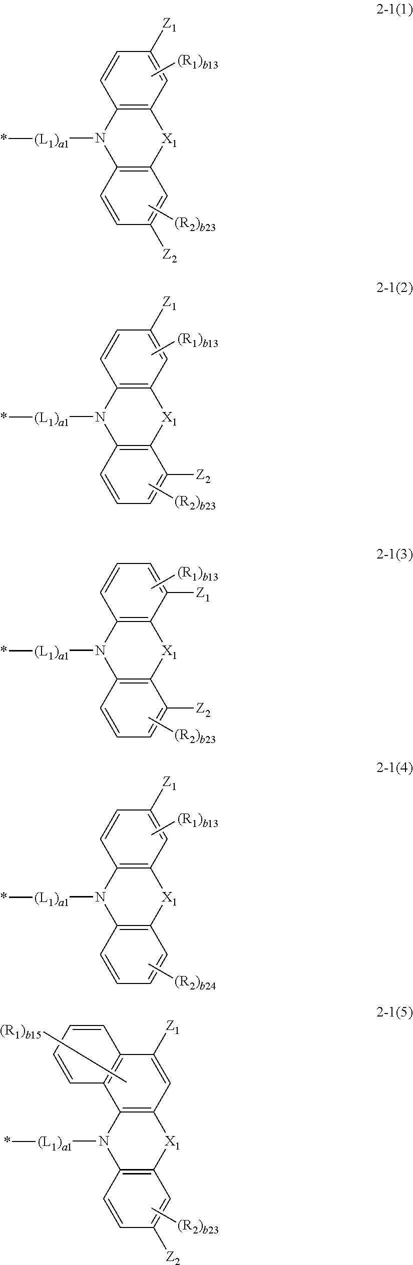 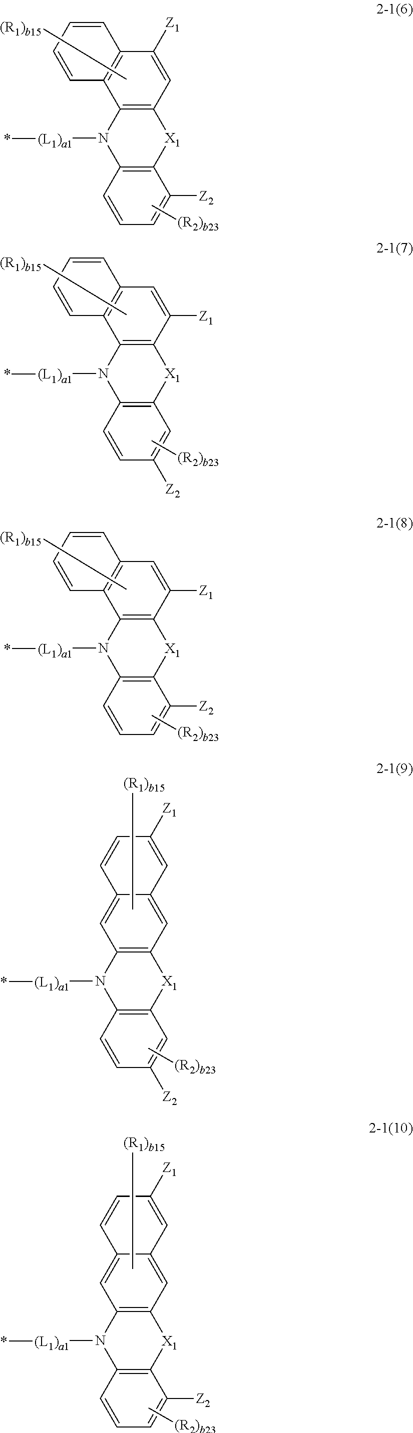 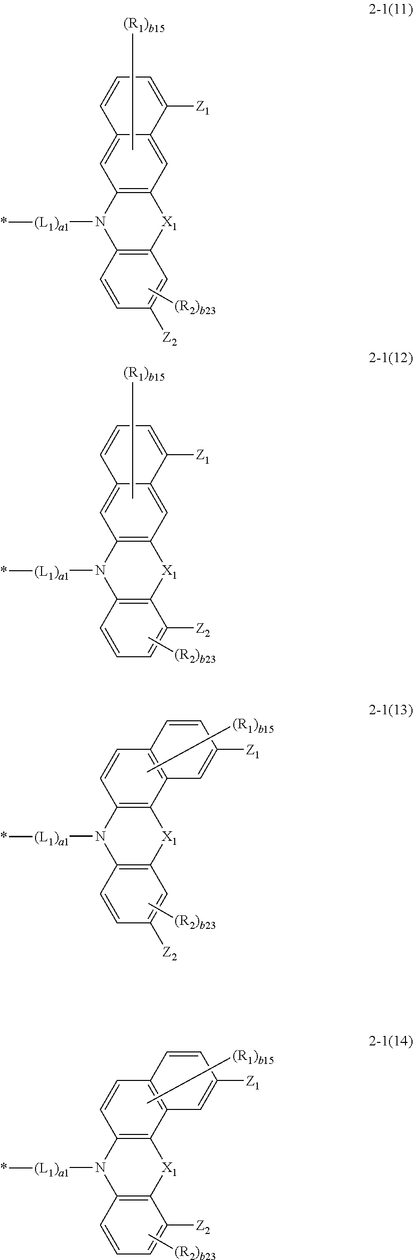 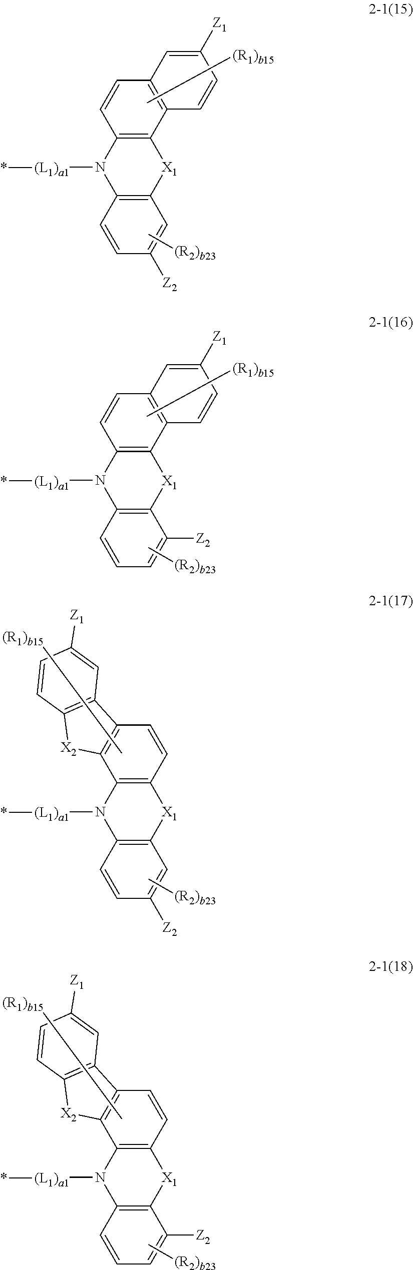 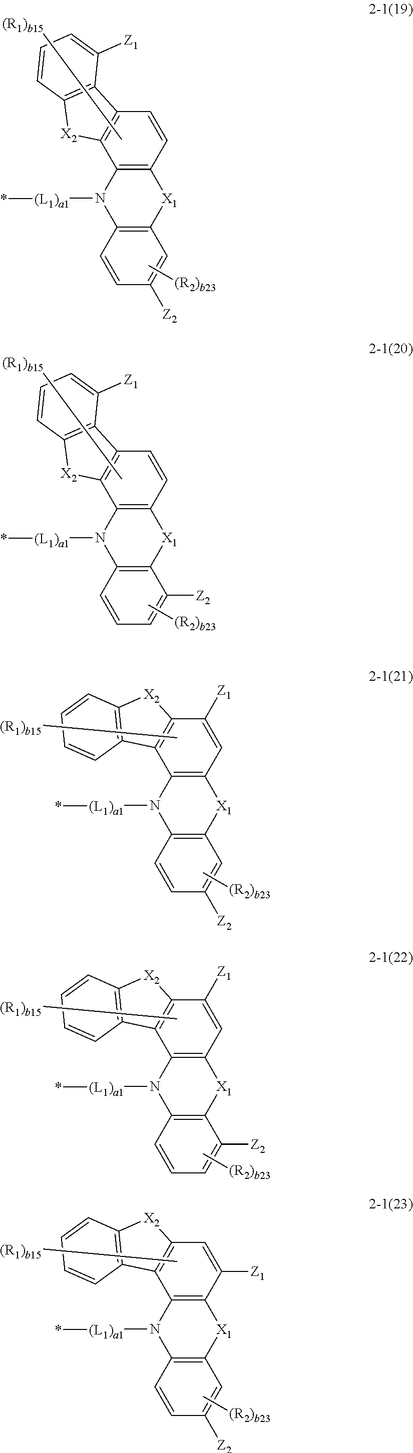 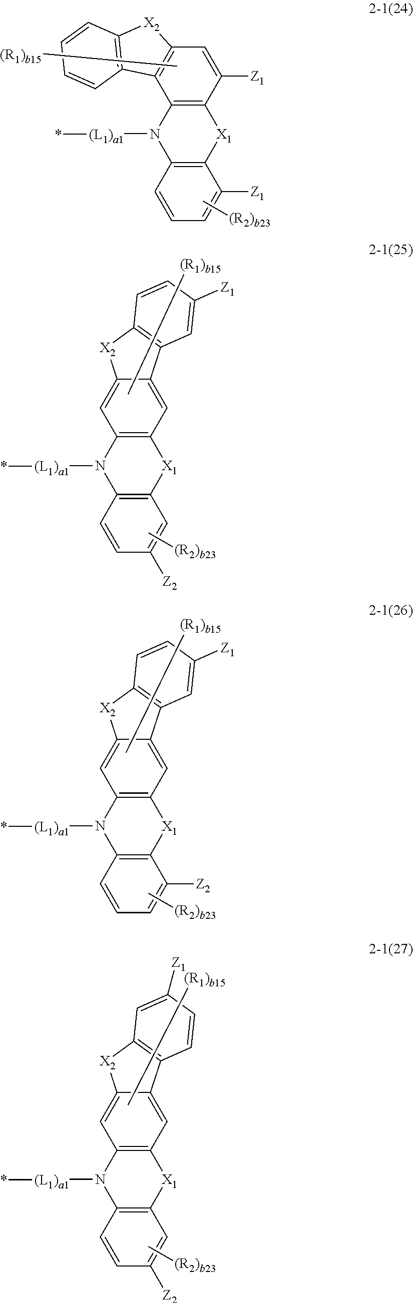 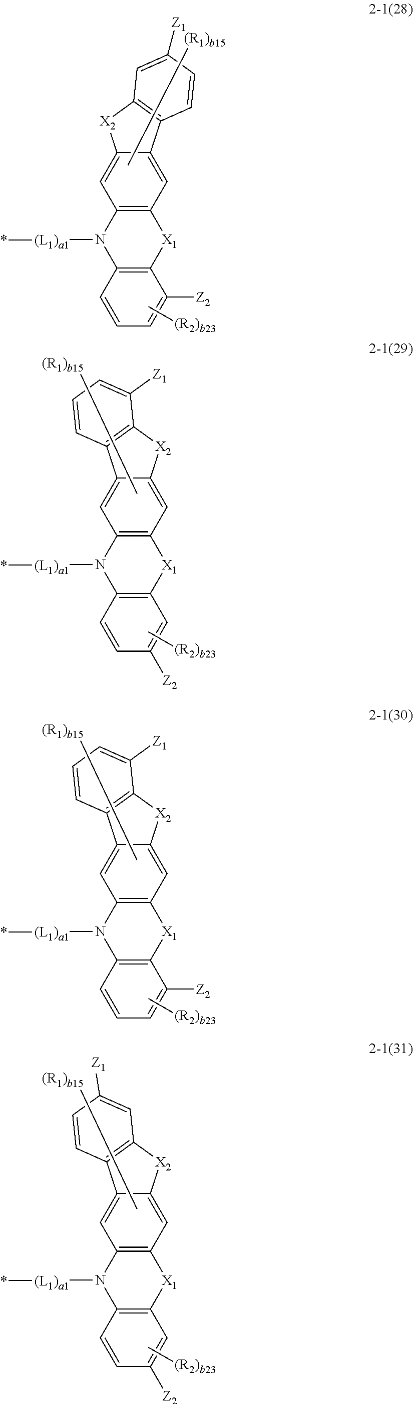 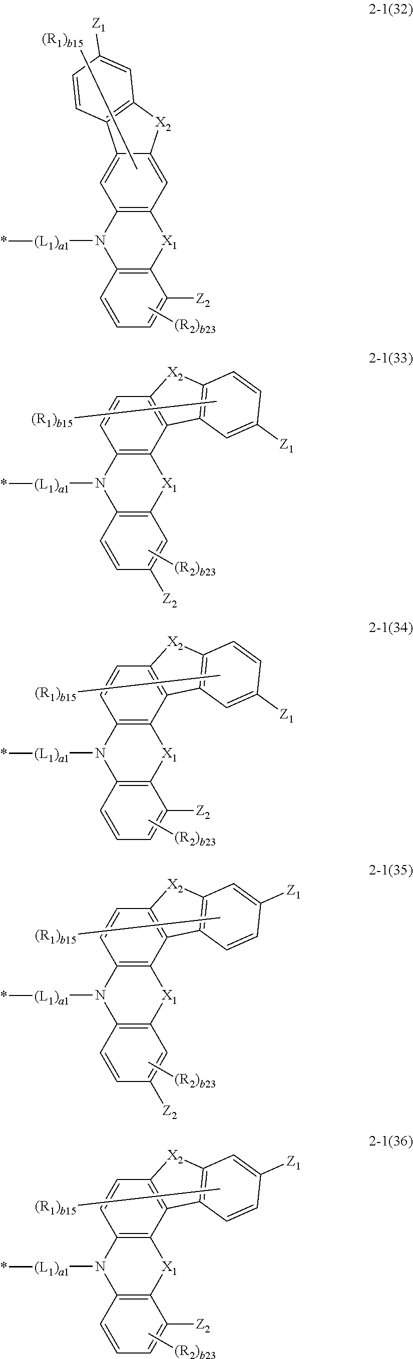 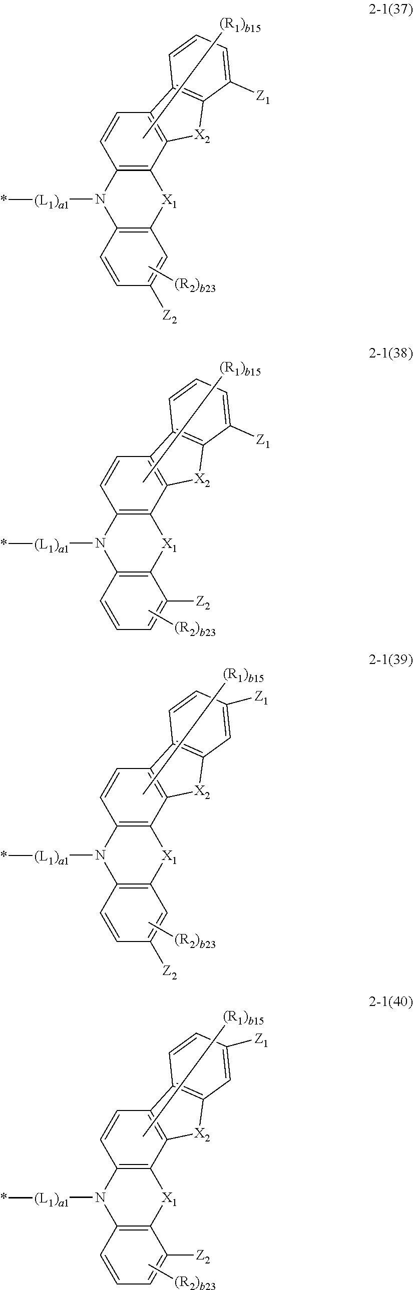 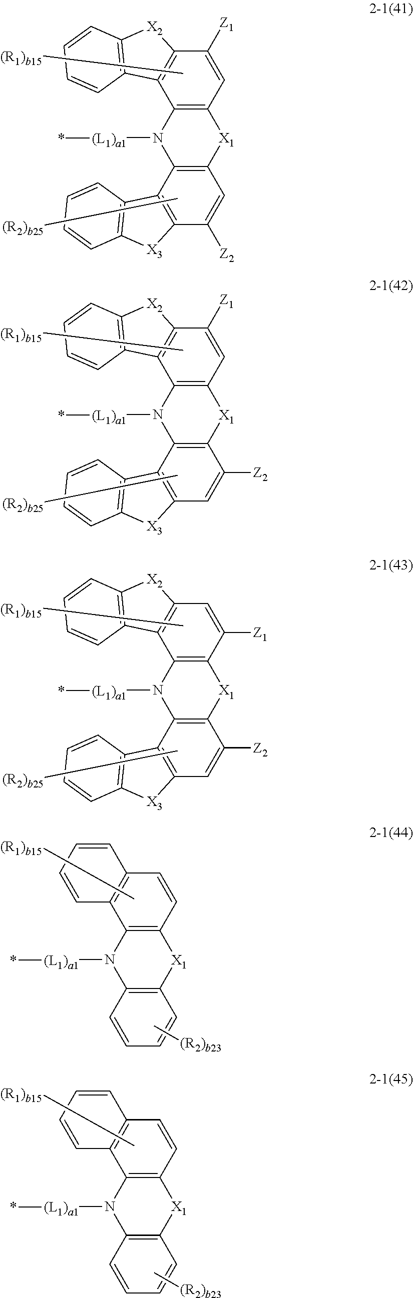 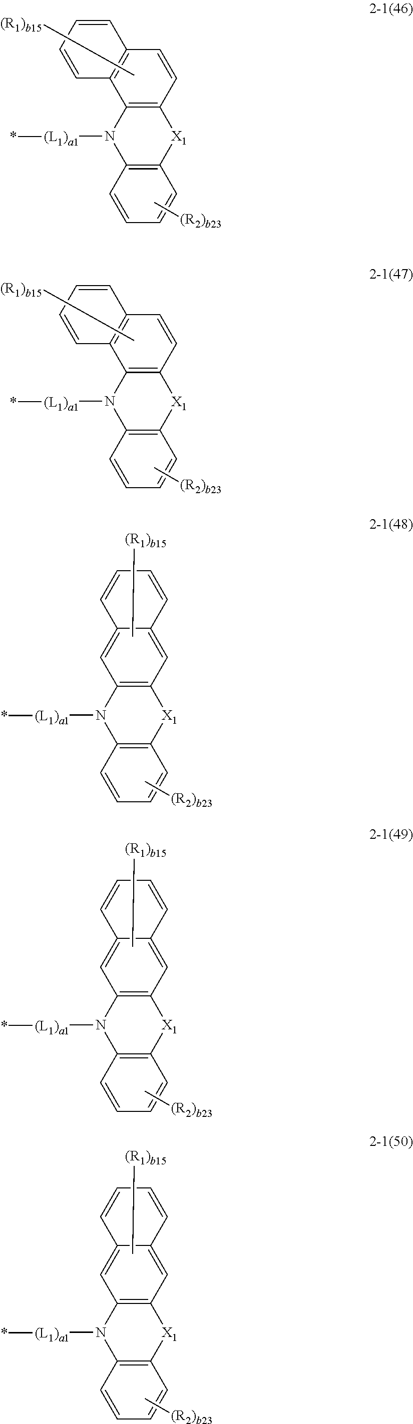 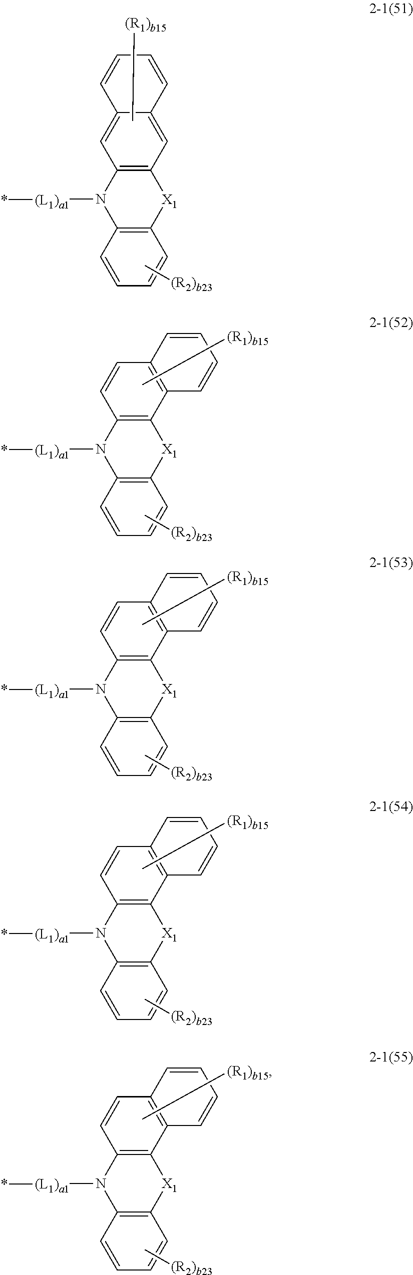 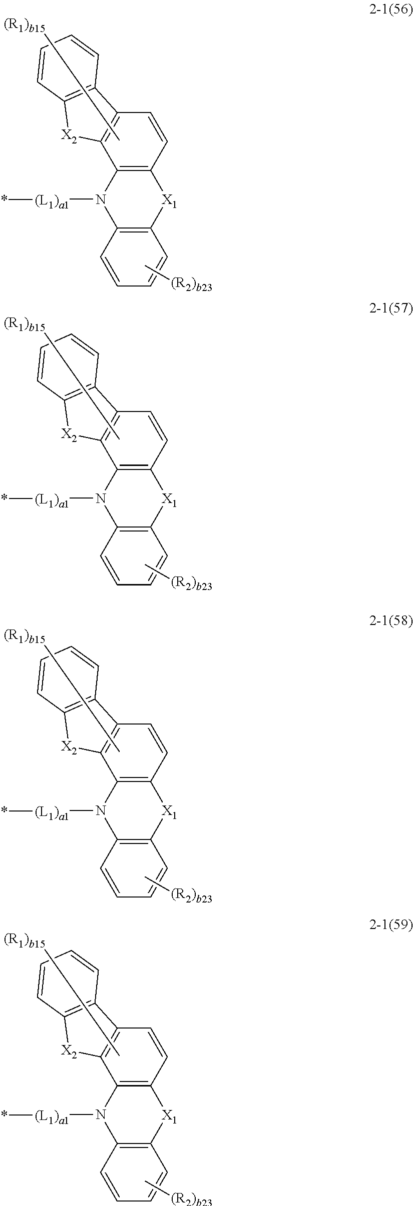 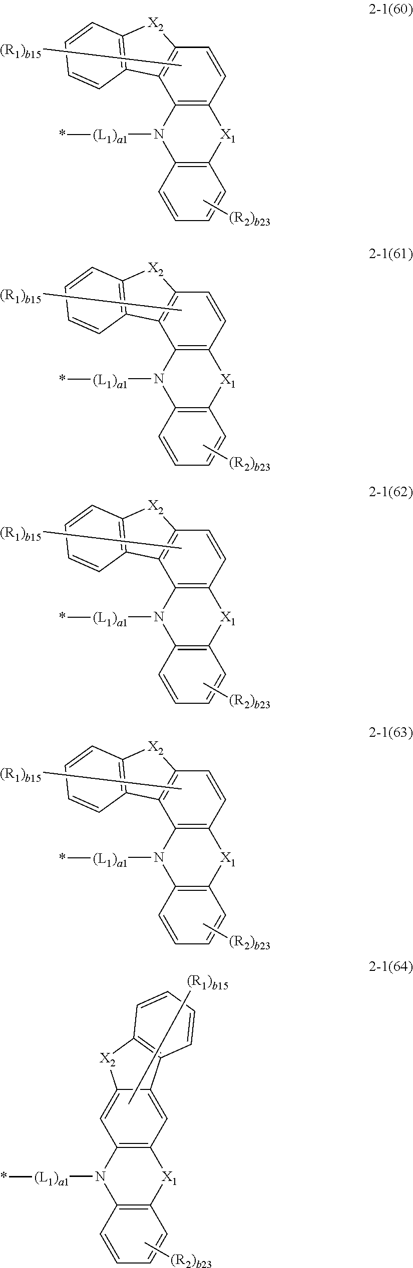 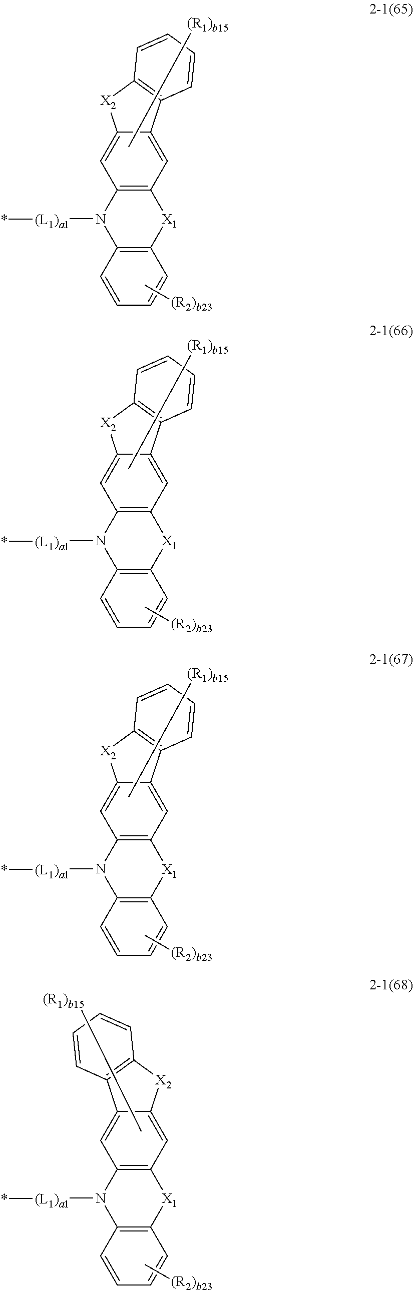 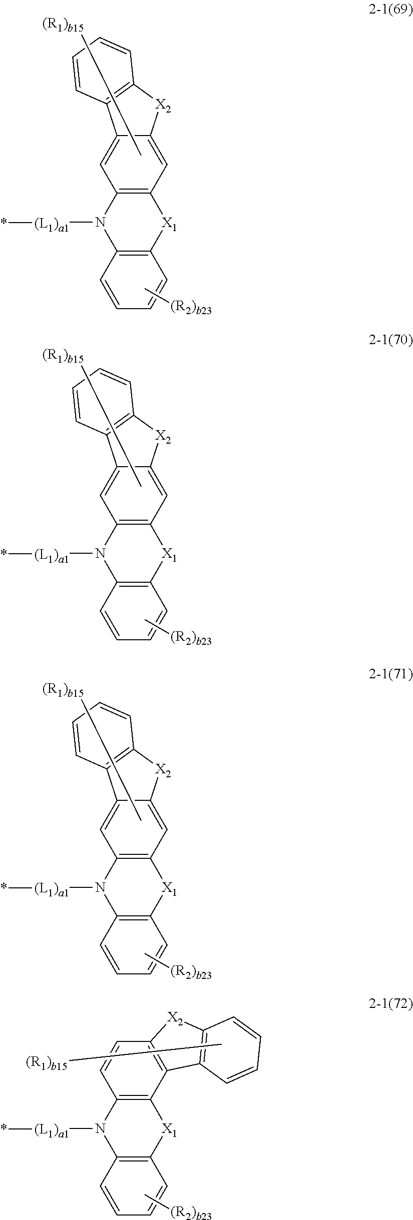 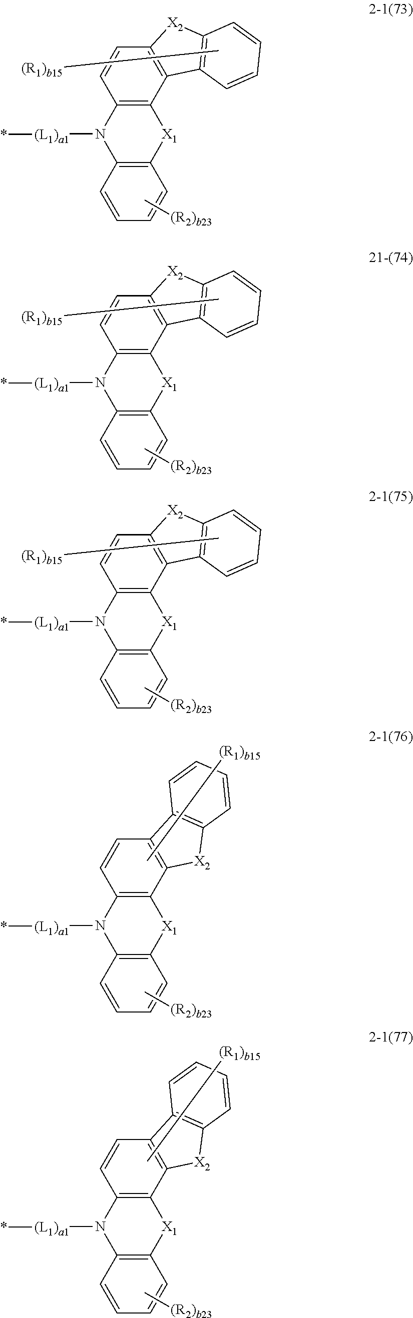 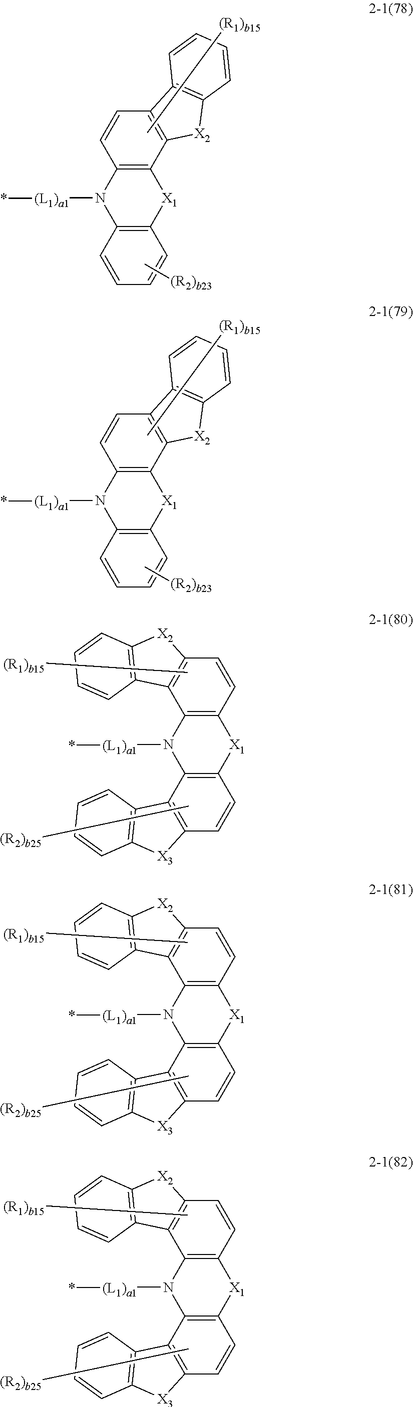
wherein, in Formulae 2-1 (1) to 2-1(82),
X₁, L₁, a1, R₁, R₂, Z₁, and Z₂ are the same as described in claim 1,
X₂ is C(R₆)(R₇), Si(R₆)(R₇), N(R₆), O, or S,
X₃ is C(R₈)(R₉), Si(R₈)(R₉), N(R₈), O, or S,
R₆ to R₉ are the same as described in connection with R₁ in claim 1,
b13 and b23 are each independently an integer from 0 to 3,
b24 is an integer from 0 to 4,
b15 and b25 are each independently an integer from 0 to 5, and
* indicates a binding site to a neighboring atom.

8. The organic light-emitting device of claim 1, wherein
a difference between a singlet energy level and a triplet energy level of the auxiliary dopant is about 0.5 electron volts or less.

9. The organic light-emitting device of claim 1, wherein
the auxiliary dopant comprises at least one of Compounds AD1 to AD22:

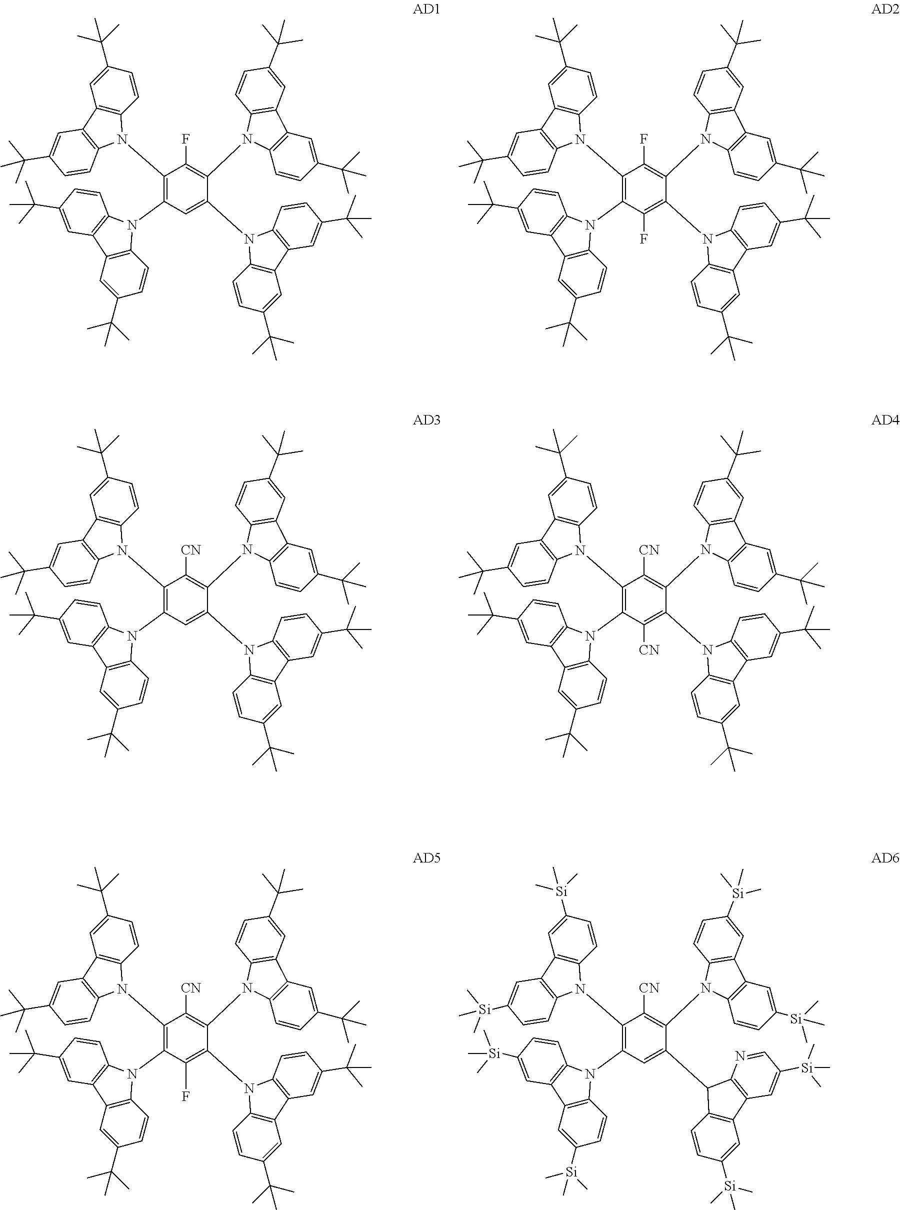

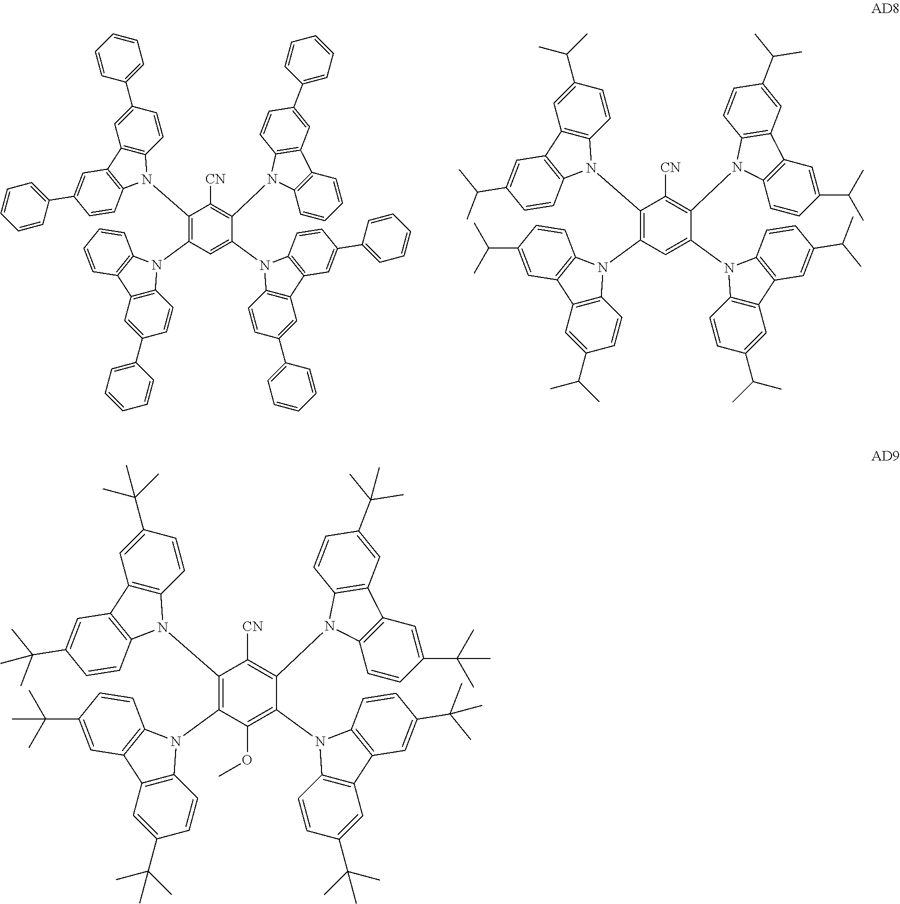

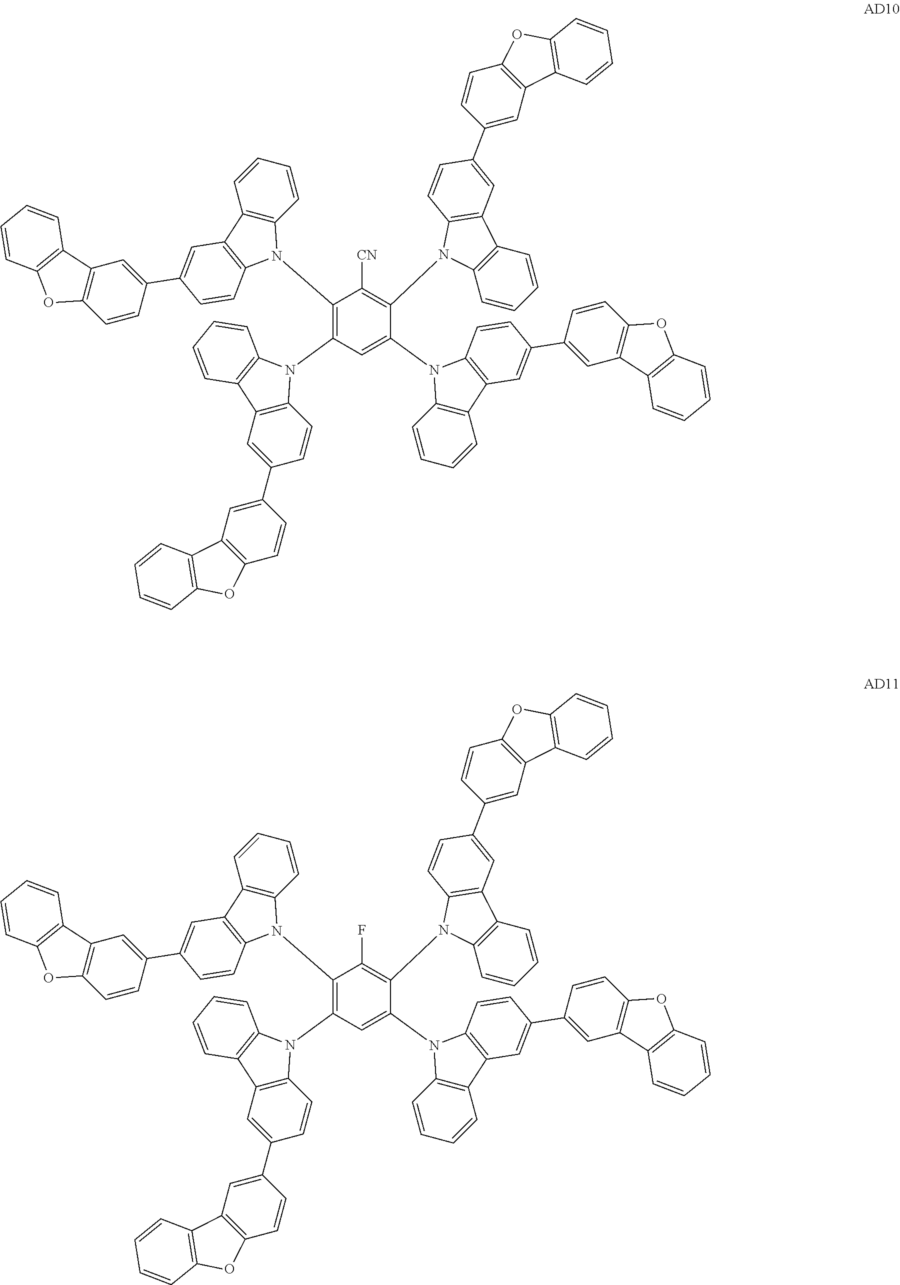 [SMILES: N#Cc1c(-n2c3ccccc3c3cc(-c4ccc5oc6ccccc6c5c4)ccc32)c(-n2c3ccccc3c3cc(-c4ccc5oc6ccccc6c5c4)ccc32)cc(-n2c3ccccc3c3cc(-c4ccc5oc6ccccc6c5c4)ccc32)c1-n1c2ccccc2c2cc(-c3ccc4oc5ccccc5c4c3)ccc21 ; Fc1c(-n2c3ccccc3c3cc(-c4ccc5oc6ccccc6c5c4)ccc32)c(-n2c3ccccc3c3cc(-c4ccc5oc6ccccc6c5c4)ccc32)cc(-n2c3ccccc3c3cc(-c4ccc5oc6ccccc6c5c4)ccc32)c1-n1c2ccccc2c2cc(-c3ccc4oc5ccccc5c4c3)ccc21]

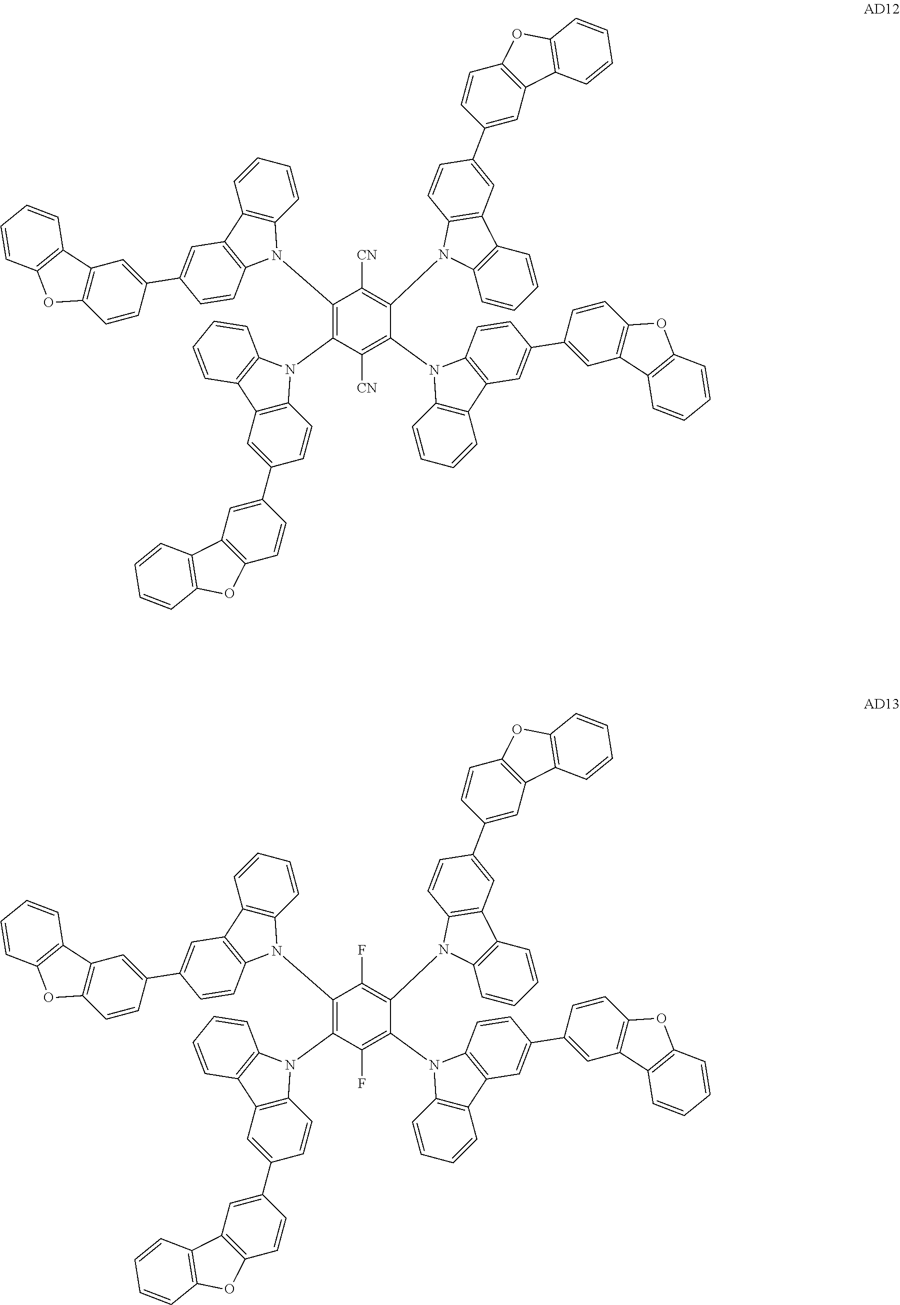 [SMILES: N#Cc1c(-n2c3ccccc3c3cc(-c4ccc5oc6ccccc6c5c4)ccc32)c(-n2c3ccccc3c3cc(-c4ccc5oc6ccccc6c5c4)ccc32)c(C#N)c(-n2c3ccccc3c3cc(-c4ccc5oc6ccccc6c5c4)ccc32)c1-n1c2ccccc2c2cc(-c3ccc4oc5ccccc5c4c3)ccc21 ; Fc1c(-n2c3ccccc3c3cc(-c4ccc5oc6ccccc6c5c4)ccc32)c(-n2c3ccccc3c3cc(-c4ccc5oc6ccccc6c5c4)ccc32)c(F)c(-n2c3ccccc3c3cc(-c4ccc5oc6ccccc6c5c4)ccc32)c1-n1c2ccccc2c2cc(-c3ccc4oc5ccccc5c4c3)ccc21]

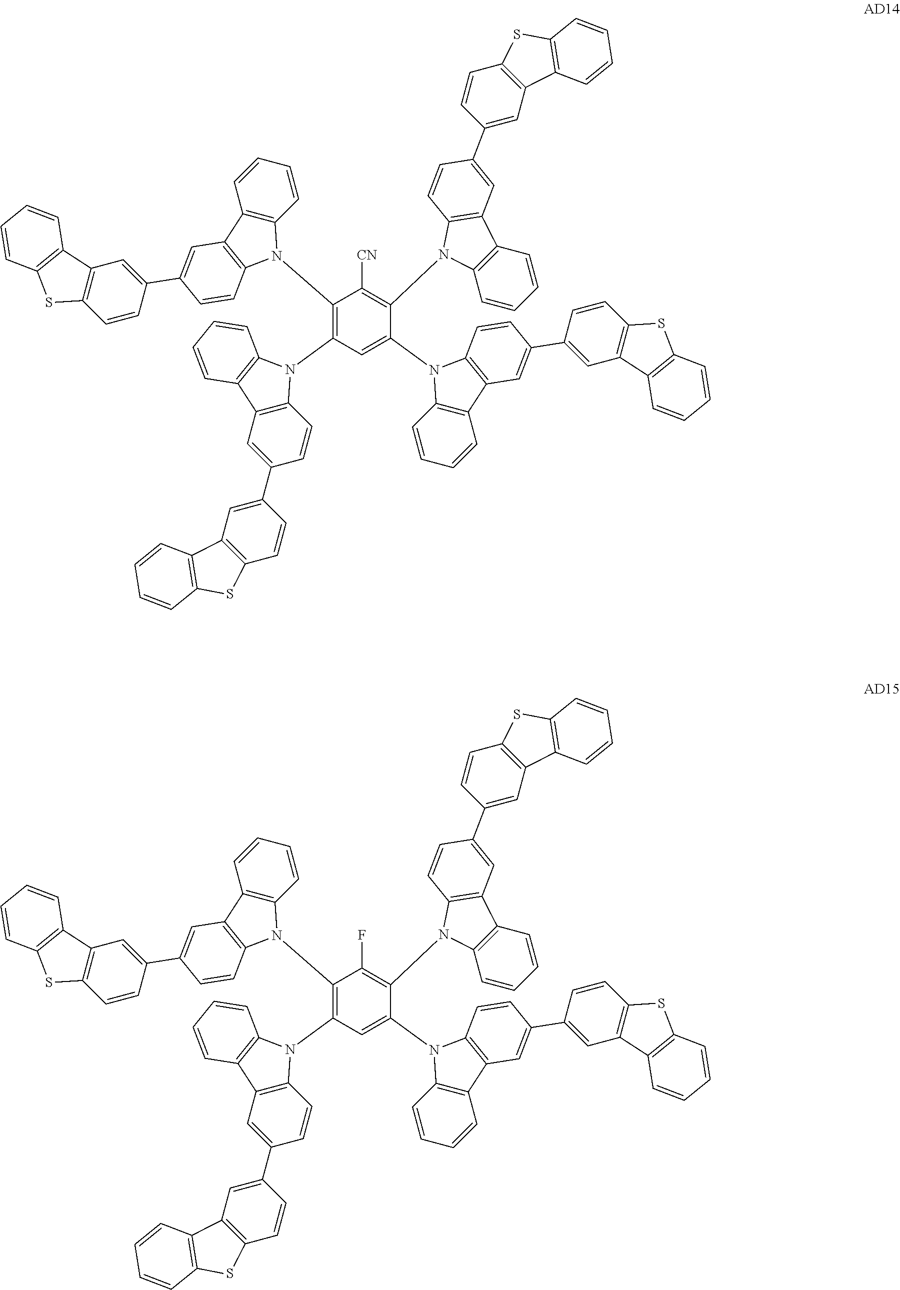 [SMILES: N#Cc1c(-n2c3ccccc3c3cc(-c4ccc5sc6ccccc6c5c4)ccc32)c(-n2c3ccccc3c3cc(-c4ccc5sc6ccccc6c5c4)ccc32)cc(-n2c3ccccc3c3cc(-c4ccc5sc6ccccc6c5c4)ccc32)c1-n1c2ccccc2c2cc(-c3ccc4sc5ccccc5c4c3)ccc21 ; Fc1c(-n2c3ccccc3c3cc(-c4ccc5sc6ccccc6c5c4)ccc32)c(-n2c3ccccc3c3cc(-c4ccc5sc6ccccc6c5c4)ccc32)cc(-n2c3ccccc3c3cc(-c4ccc5sc6ccccc6c5c4)ccc32)c1-n1c2ccccc2c2cc(-c3ccc4sc5ccccc5c4c3)ccc21]

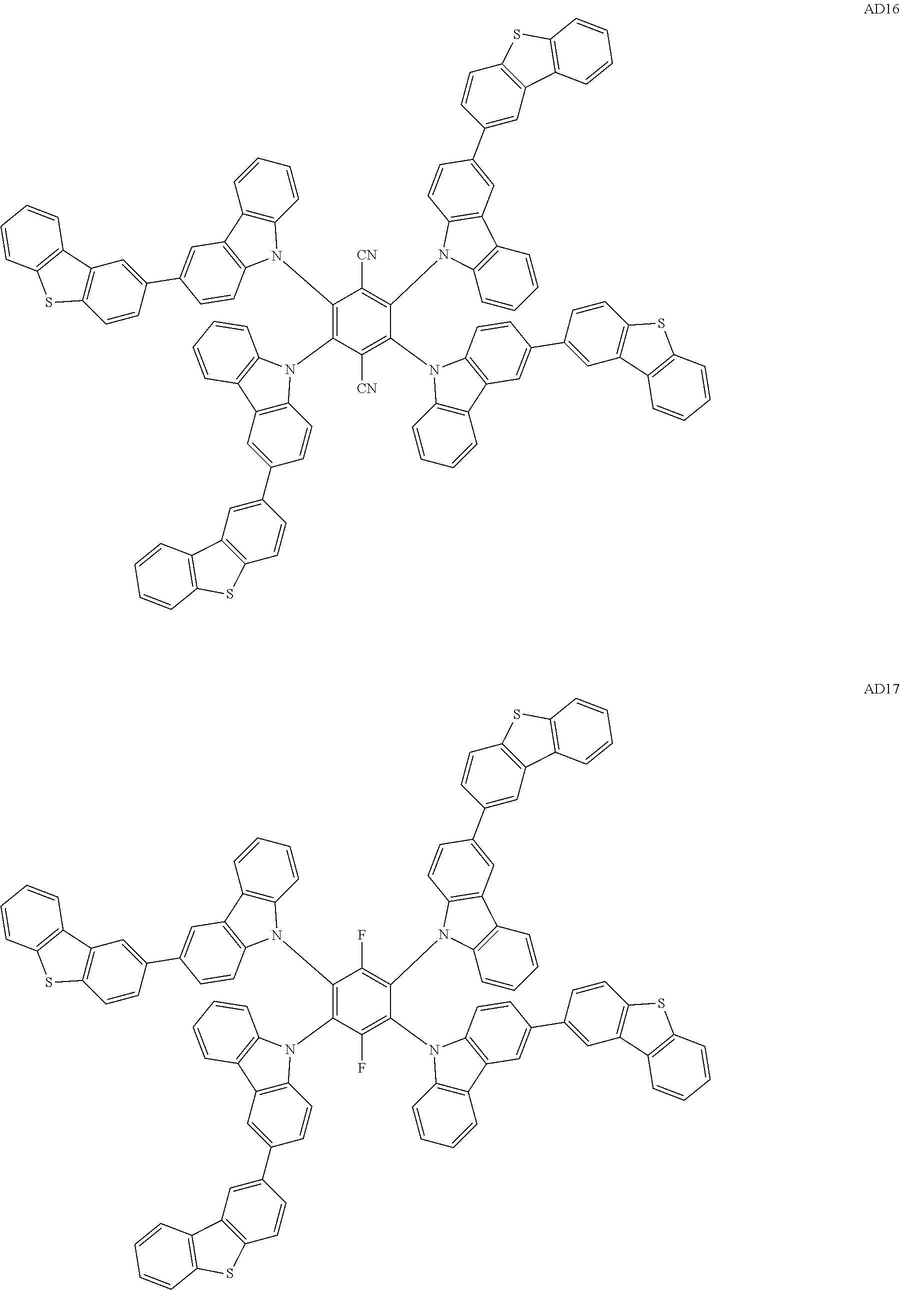 [SMILES: N#Cc1c(-n2c3ccccc3c3cc(-c4ccc5sc6ccccc6c5c4)ccc32)c(-n2c3ccccc3c3cc(-c4ccc5sc6ccccc6c5c4)ccc32)c(C#N)c(-n2c3ccccc3c3cc(-c4ccc5sc6ccccc6c5c4)ccc32)c1-n1c2ccccc2c2cc(-c3ccc4sc5ccccc5c4c3)ccc21 ; Fc1c(-n2c3ccccc3c3cc(-c4ccc5sc6ccccc6c5c4)ccc32)c(-n2c3ccccc3c3cc(-c4ccc5sc6ccccc6c5c4)ccc32)c(F)c(-n2c3ccccc3c3cc(-c4ccc5sc6ccccc6c5c4)ccc32)c1-n1c2ccccc2c2cc(-c3ccc4sc5ccccc5c4c3)ccc21]

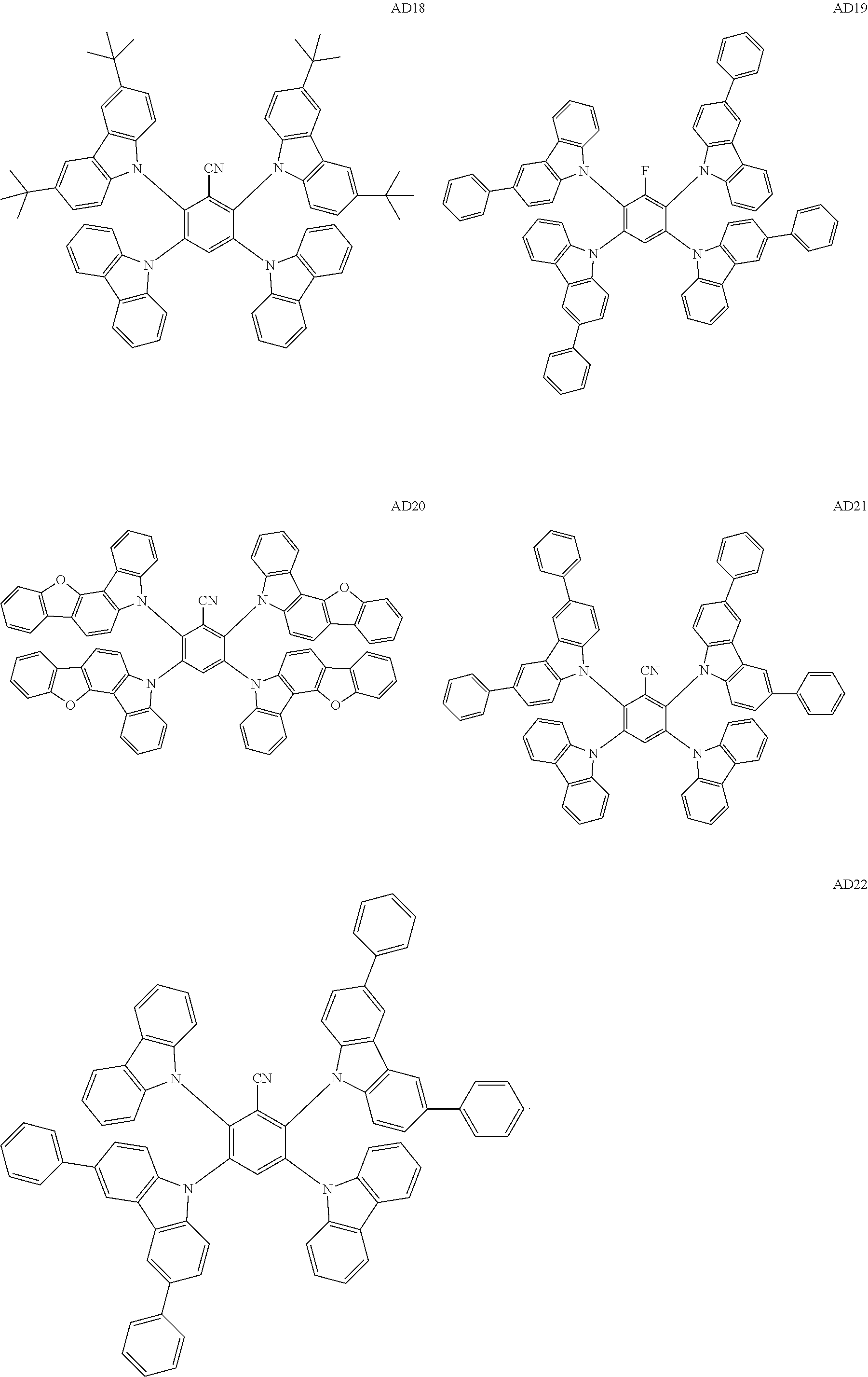

10. The organic light-emitting device of claim 1, wherein
the fluorescent dopant is selected from a condensed cyclic group-containing compound, an amino group-containing compound, a styryl group-containing compound, and a boron-containing compound.

11. The organic light-emitting device of claim 1, wherein
the fluorescent dopant comprises at least one compound selected from a naphthalene-containing compound, a fluorene-containing compound, a spiro-bifluorene-containing compound, a benzofluorene-containing compound, a dibenzofluorene-containing compound, a phenanthrene-containing compound, an anthracene-containing compound, a fluoranthene-containing compound, a triphenylene-containing compound, a pyrene-containing compound, a chrysene-containing compound, a naphthacene-containing compound, a picene-containing compound, a perylene-containing compound, a pentaphene-containing compound, an indenoanthracene-containing compound, a tetracene-containing compound, a bisanthracene-containing compound, and a compound comprising one of groups represented by Formulae 501-1 to 501-21:

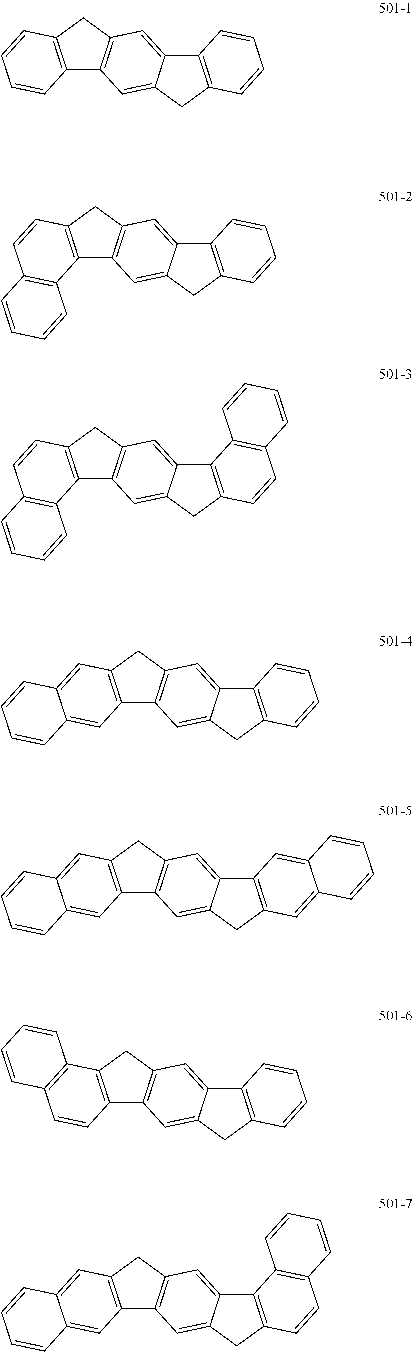

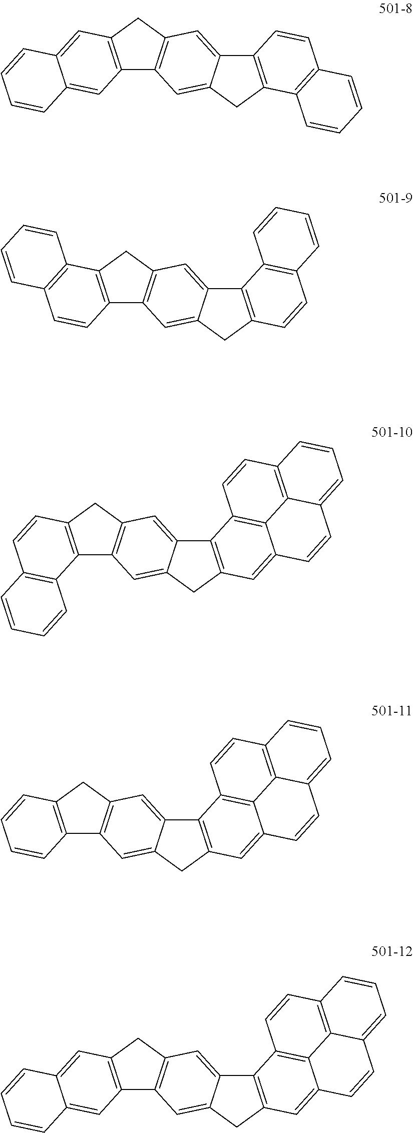

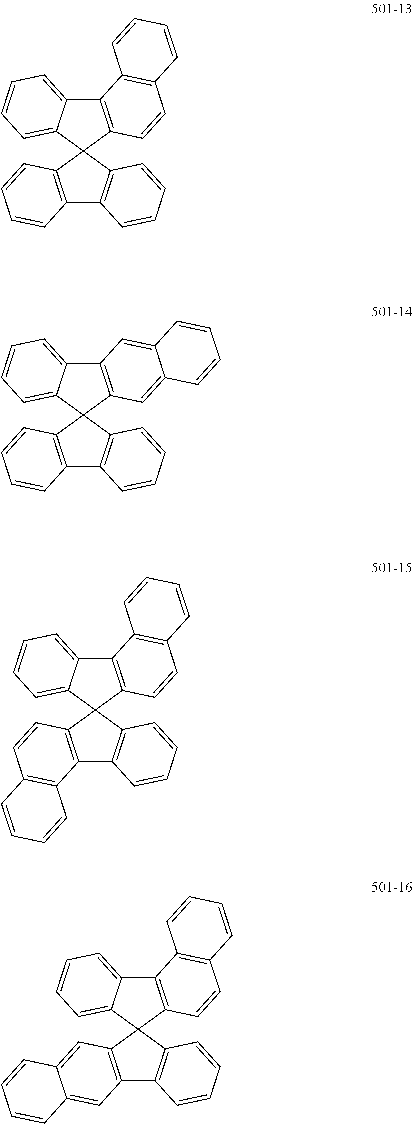

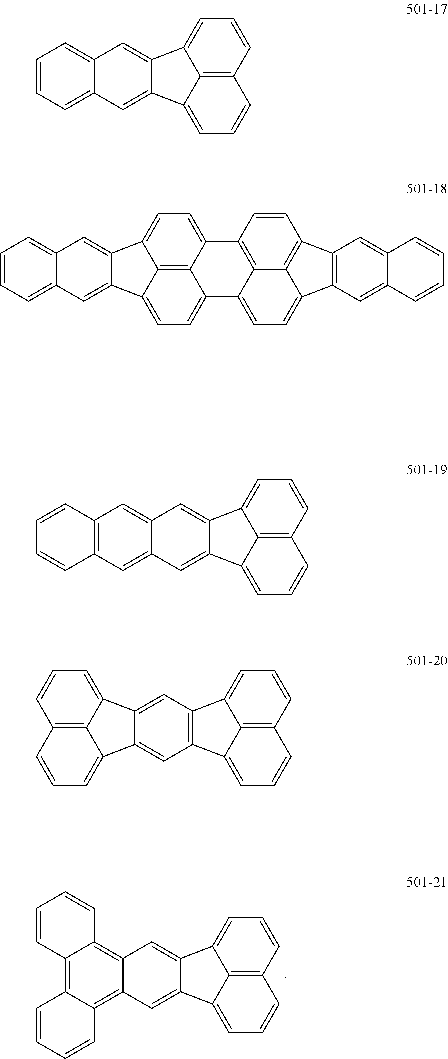

12. The organic light-emitting device of claim 1, wherein
the fluorescent dopant comprises a compound represented by Formula 501A or 501B: 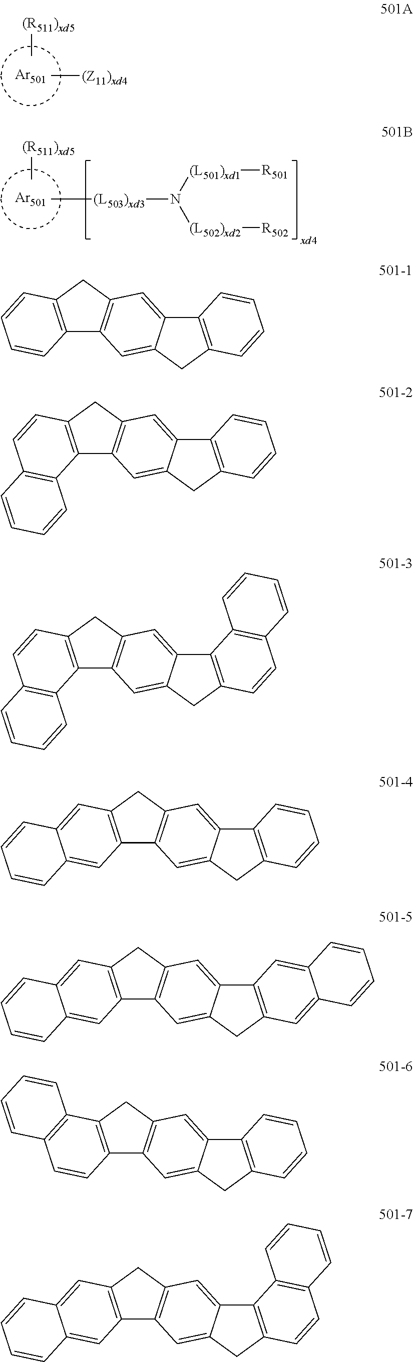 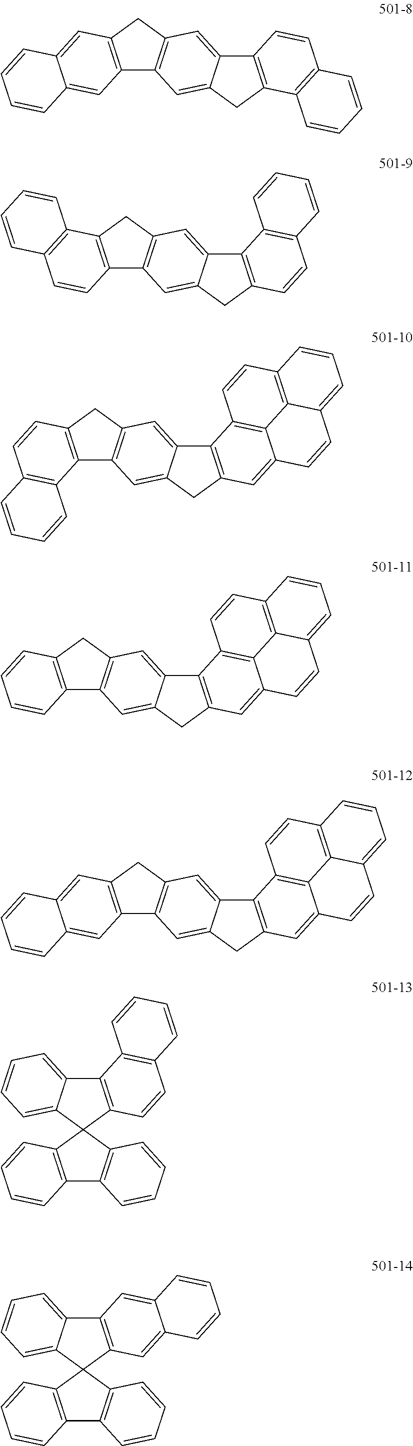 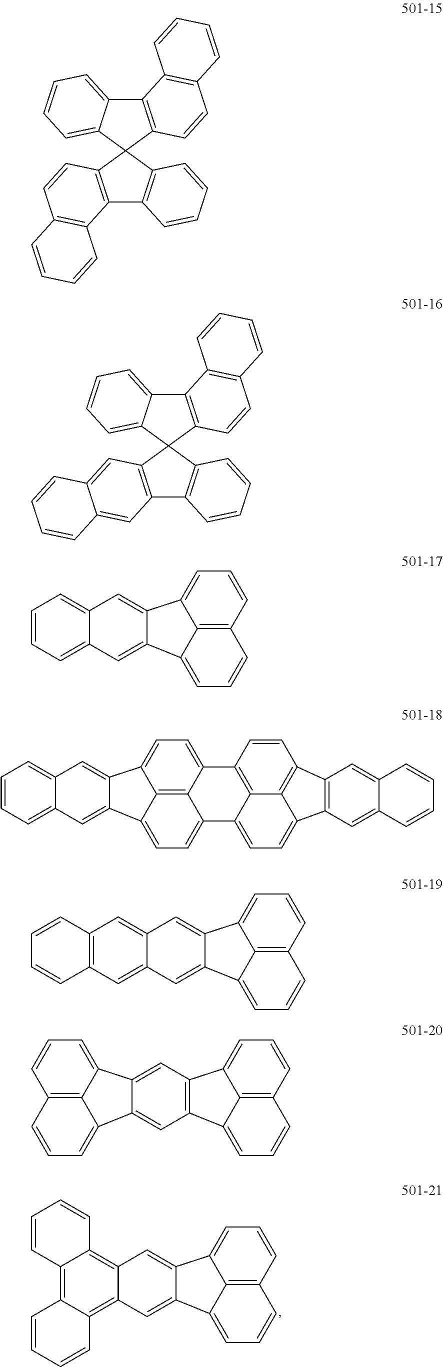
wherein, in Formulae 501A and 501B,
Ar₅₀₁ is selected from a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group, a picene group, a perylene group, a pentaphene group, an indenoanthracene group, a tetracene group, a bisanthracene group, and groups represented by Formulae 501-1 to 501-21,
R₅₁₁ is selected from hydrogen, deuterium, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₅₀₁)(Q₅₀₂)(Q₅₀₃),
xd5 is an integer from 0 to 10,
L₅₀₁ to L₅₀₃ are each independently selected from:
a single bond; and
a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group, each unsubstituted or substituted with at least one selected from deuterium, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₅₀₁)(Q₅₀₂)(Q₅₀₃),
xd1 to xd3 are each independently selected from 1, 2, and 3,
R₅₀₁ and R₅₀₂ are each independently selected from a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, a dibenzothiophenyl group, and a dibenzosilolyl group, each unsubstituted or substituted with at least one selected from Z₁₁, deuterium, a C₁-C₂₀ alkoxy group, a pyridinyl group, a pyrimidinyl group, a pyridazinyl group, a pyrazinyl group, a triazinyl group, a quinolinyl group, an isoquinolinyl group, a quinoxalinyl group, a quinazolinyl group, and a phenanthrolinyl group,
Z₁₁ is the same as described in connection with Z₁ in claim 1,
xd4 is selected from 1, 2, 3, 4, 5, and 6, and
Q₅₀₁ to Q₅₀₃ are each independently selected from hydrogen, a C₁-C₆₀ alkyl group, a C₁-C₆₀ alkoxy group, a C₆-C₆₀ aryl group, a C₁-C₆₀ heteroaryl group, a monovalent non-aromatic condensed polycyclic group, and a monovalent non-aromatic condensed heteropolycyclic group.

13. The organic light-emitting device of claim 12, wherein
xd4 in Formula 501A is 3, 4, 5, or 6,
xd4 in Formula 501B is 2, 3, or 4, and
R₅₀₁ and R₅₀₂ in Formula 501B are each independently a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, a dibenzothiophenyl group, and a dibenzosilolyl group, each substituted with at least one selected from Z₁₁.

14. The organic light-emitting device of claim 1, wherein
the host has a triplet energy level of about 2.9 electron volts or more.

15. The organic light-emitting device of claim 1, wherein
the host comprises at least one compound selected from a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, and a sulphonyl-containing compound.

16. The organic light-emitting device of claim 1, wherein
the organic light-emitting device satisfies Equation 1:
E_{T1(HOST)}−E_{T1(AD)}>0.05electron volts, Equation 1
wherein, in Equation 1,
E_{T1(HOST)} is a triplet energy level of the host, and
E_{T1(AD)} is a triplet energy level of the auxiliary dopant.

17. The organic light-emitting device of claim 1, wherein
the organic light-emitting device satisfies Equation 2:
E_{S1(FD)}−E_{S1(AD)}<0 electron volts, Equation 2
wherein, in Equation 2,
E_{S1(FD)} is a singlet energy level of the fluorescent dopant, and
E_{S1(AD)} is a singlet energy level of the auxiliary dopant.

18. The organic light-emitting device of claim 1, wherein
a ratio of a fluorescence component emitted from the fluorescent dopant to a total of light-emitting components emitted from the emission layer is 90% or more.

19. The organic light-emitting device of claim 1, wherein
an amount of the auxiliary dopant in the organic layer is larger than an amount of the fluorescent dopant.

20. The organic light-emitting device of claim 1, wherein, in the organic layer,
a weight ratio of the host to the auxiliary dopant in the organic layer is in a range of about 60:40 to about 95:5, and
a weight ratio of the auxiliary dopant to the fluorescent dopant is in a range of about 10:0.1 to about 20:5.
